(19) United States
(12) Patent Application Publication
(10) Pub. No.: US 2026/0136758 A1
(43) Pub. Date: May 14, 2026

(54) COMPOUNDS FOR ELECTRONIC DEVICES

(71) Applicant: Merck Patent GmbH, Darmstadt (DE)

(72) Inventors: Elvira MONTENEGRO, Darmstadt (DE); Jens ENGELHART, Darmstadt (DE); Sebastian MEYER, Darmstadt (DE)

(21) Appl. No.: 18/695,429

(22) PCT Filed: Aug. 18, 2022
(86) PCT No.: PCT/EP2022/073050

§ 371 Date: Mar. 26, 2024

(30) Foreign Application Priority Data
Sep. 30, 2021 (EP) 21200276.0
Apr. 12, 2022 (EP) 22167862.6

(51) Int. Cl. H10K 50/18; C07B 59/00; H10K 85/30; H10K 85/60

(52) U.S. Cl. CPC H10K 50/181; C07B 59/004; H10K 85/342; H10K 85/623; H10K 85/624; H10K 85/626; H10K 85/633; H10K 85/636; H10K 85/654; H10K 85/6574; C07B 2200/05

(57) ABSTRACT

The present application relates to fluorenylamine derivatives and to spirobifluorenylamine derivatives which are partially deuterated. The invention further relates to processes for preparing such compounds, to the use of such compounds in electronic devices and to electronic devices containing such compounds.

The present application relates to fluorenylamine derivatives and spirobifluorenylamine derivatives that are partly deuterated. The compounds are suitable for use in electronic devices.

Partial deuteration is understood here to mean that at least one hydrogen atom in the compound has been replaced by a deuterium atom, and preferably two or more hydrogen atoms in the compound have been replaced by deuterium atoms, but not all hydrogen atoms, such that there is also at least one hydrogen atom in the compound as well as the one or more deuterium atoms. The term “H atom” or “H” or “hydrogen” or “hydrogen atom” is understood here and in the overall application to mean a protium atom, i.e. the isotope ¹H. The term “D atom” or “D” or “deuterium” or “deuterium atom” is understood here and in the overall application to mean the isotope ²H.

Electronic devices in the context of this application are understood to mean what are called organic electronic devices, which comprise organic semiconductor materials as functional materials. More particularly, these are understood to mean OLEDs (organic electroluminescent devices). The term OLEDs is understood to mean electronic devices which have one or more layers comprising organic compounds and emit light on application of electrical voltage. The structure and general principle of function of OLEDs are known to those skilled in the art.

In electronic devices, especially OLEDs, there is great interest in an improvement in the performance data. In these aspects, it has not yet been possible to find any entirely satisfactory solution.

A great influence on the performance data of electronic devices is possessed by layers having a hole-transporting function. For use in these layers, there is a continuing search for new compounds, especially hole-transporting compounds and electron-blocking compounds. For this purpose, there is a search in particular for compounds that have a high glass transition temperature, high stability, and high conductivity for holes. A high stability of the compound is still desirable in order to achieve a long lifetime of the electronic device. There is also a search for compounds whose use in electronic devices results in improvement of the performance data of the devices, especially in high efficiency, long lifetime and low operating voltage.

In the prior art, triarylamine compounds in particular, for example spirobifluoreneamines and fluoreneamines, are known as hole transport materials and hole-transporting matrix materials for electronic devices.

However, there is still a need for improvement with regard to the abovementioned properties, especially with regard to the lifetime and efficiency of the devices. Some prior art documents disclose that deuterated isotopologs of compounds in particular cases result in a longer lifetime of the electronic device with otherwise identical performance data by comparison with the corresponding undeuterated compounds.

Compounds containing one or more hydrogen atoms can be converted by a deuteration reaction to their H/D isotopologs in which one or more of the hydrogen atoms in the compounds have been replaced by deuterium atoms. The deuteration reaction can achieve complete deuteration of the compound, such that all the hydrogen atoms in the reactant have been replaced by deuterium atoms in the reaction product. However, the performance of a deuteration reaction in which the reactant is fully deuterated is time-consuming and in many cases entails high complexity and/or stress on the material that can lead to by-products and/or a low yield.

It has now been found that, surprisingly, even only a partial deuteration of fluoreneamines and spirobifluoreneamines can achieve a comparable improvement in lifetime with otherwise identical performance data to that resulting from complete deuteration. At the same time, the partial deuteration can be achieved in a synthetically simpler and less complex manner.

The present application thus provides a compound of the formula (I)

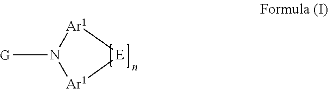

where:
G conforms to formula (G-1), (G-2) or (G-3)

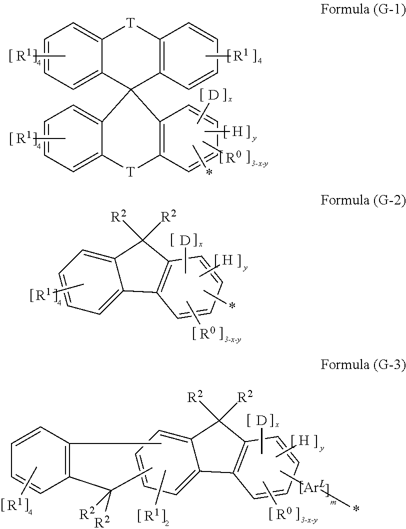

where the bond to the rest of the formula (I) is labeled *, and where:
T is the same or different at each instance and is selected from single bond, C(R²)₂, C═O, Si(R²)₄, NR², O and S;
E is selected from single bond, C(R³)₂, C(R³)₂—C(R³)₂, C(R³)═C(R³), C═O, Si(R³)₄, NR³, O and S;
Ar¹ is the same or different at each instance and is selected from aromatic ring systems which have 6 to 40 aromatic ring atoms and are substituted by R³ radicals, and heteroaromatic ring systems which have 5 to 40 aromatic ring atoms and are substituted by R³ radicals;
Ar^{L} is selected from aromatic ring systems which have 6 to 40 aromatic ring atoms and are substituted by R³ radicals and heteroaromatic ring systems which have 5 to 40 aromatic ring atoms and are substituted by R³ radicals;
R⁰ is the same or different at each instance and is selected from F, Cl, Br, I, C(═O)R⁴, CN, Si(R⁴)₃, N(R⁴)₂, P(═O)(R⁴)₂, OR⁴, S(═O)R⁴, S(═O)₂R⁴, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R⁰ radicals may be joined to one another and may form a ring; where the alkyl, alkoxy, alkenyl and alkynyl groups mentioned and the aromatic ring systems and heteroaromatic ring systems mentioned are each substituted by R⁴ radicals; and where one or more CH₂ groups in the alkyl, alkoxy, alkenyl and alkynyl groups mentioned may be replaced by —R⁴C═CR⁴—, —C≡C—, Si(R⁴)₂, C═O, C═NR⁴, —C(═O)O—, —C(═O)NR⁴—, NR⁴, P(═O)(R⁴), —O—, —S—, SO or SO₂;
R¹ is the same or different at each instance and is selected from H, D, F, Cl, Br, I, C(═O)R⁴, CN, Si(R⁴)₃, N(R⁴)₂, P(═O)(R⁴)₂, OR⁴, S(═O)R⁴, S(═O)₂R⁴, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R¹ radicals may be joined to one another and may form a ring; where the alkyl, alkoxy, alkenyl and alkynyl groups mentioned and the aromatic ring systems and heteroaromatic ring systems mentioned are each substituted by R⁴ radicals; and where one or more CH₂ groups in the alkyl, alkoxy, alkenyl and alkynyl groups mentioned may be replaced by —R⁴C═CR⁴—, —C≡C—, Si(R⁴)₂, C═O, C═NR⁴, —C(═O)O—, —C(═O)NR⁴—, NR⁴, P(═O)(R⁴), —O—, —S—, SO or SO₂;
R² is the same or different at each instance and is selected from H, D, F, Cl, Br, I, C(═O)R⁴, CN, Si(R⁴)₃, N(R⁴)₂, P(═O)(R⁴)₂, OR⁴, S(═O)R⁴, S(═O)₂R⁴, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R² radicals may be joined to one another and may form a ring; where the alkyl, alkoxy, alkenyl and alkynyl groups mentioned and the aromatic ring systems and heteroaromatic ring systems mentioned are each substituted by R⁴ radicals; and where one or more CH₂ groups in the alkyl, alkoxy, alkenyl and alkynyl groups mentioned may be replaced by —R⁴C═CR⁴—, —C≡C—, Si(R⁴)₂, C═O, C═NR⁴, —C(═O)O—, —C(═O)NR⁴—, NR⁴, P(═O)(R⁴), —O—, —S—, SO or SO₂;
R³ is the same or different at each instance and is selected from H, D, F, Cl, Br, I, C(═O)R⁴, CN, Si(R⁴)₃, N(R⁴)₂, P(═O)(R⁴)₂, OR⁴, S(═O)R⁴, S(═O)₂R⁴, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R³ radicals may be joined to one another and may form a ring; where the alkyl, alkoxy, alkenyl and alkynyl groups mentioned and the aromatic ring systems and heteroaromatic ring systems mentioned are each substituted by R⁴ radicals; and where one or more CH₂ groups in the alkyl, alkoxy, alkenyl and alkynyl groups mentioned may be replaced by —R⁴C═CR⁴—, —C≡C—, Si(R⁴)₂, C═O, C═NR⁴, —C(═O)O—, —C(═O)NR⁴—, NR⁴, P(═O)(R⁴), —O—, —S—, SO or SO₂;
R⁴ is the same or different at each instance and is selected from H, D, F, Cl, Br, I, C(═O)R⁵, CN, Si(R⁵)₃, N(R⁵)₂, P(═O)(R⁵)₂, ORS, S(═O)R⁵, S(═O)₂R⁵, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R⁴ radicals may be joined to one another and may form a ring; where the alkyl, alkoxy, alkenyl and alkynyl groups mentioned and the aromatic ring systems and heteroaromatic ring systems mentioned are each substituted by R⁵ radicals; and where one or more CH₂ groups in the alkyl, alkoxy, alkenyl and alkynyl groups mentioned may be replaced by —R⁵C═CR⁵—, —C≡C—, Si(R⁵)₂, C═O, C═NR⁵, —C(═O)O—, —C(═O)NR⁵—, NR⁵, P(═O)(R⁵), —O—, —S—, SO or SO₂;
R⁵ is the same or different at each instance and is selected from H, D, F, Cl, Br, I, CN, alkyl or alkoxy groups having 1 to 20 carbon atoms, alkenyl or alkynyl groups having 2 to 20 carbon atoms, aromatic ring systems having 6 to 40 aromatic ring atoms and heteroaromatic ring systems having 5 to 40 aromatic ring atoms; where two or more R⁵ radicals may be joined to one another and may form a ring; and where the alkyl, alkoxy, alkenyl and alkynyl groups, aromatic ring systems and heteroaromatic ring systems mentioned may be substituted by one or more radicals selected from F and CN;
x is 1 or 2; where the sum total of x and y is not more than 3;
y is 1 or 2; where the sum total of x and y is not more than 3;
n is 0 or 1, where, when n=0, the E group is absent, and the two Ar¹ groups are not bonded to one another;
m is 0 or 1, where, when m=0, the two groups that bind to Ar^{L} are bonded directly to one another.

The group shown in formula (G-3) as being variably bound to the benzene ring

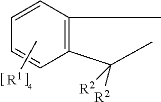

may be bound in all six possible positions on the benzene ring, such that the following six variants of the group of the formula (G-3) can occur:

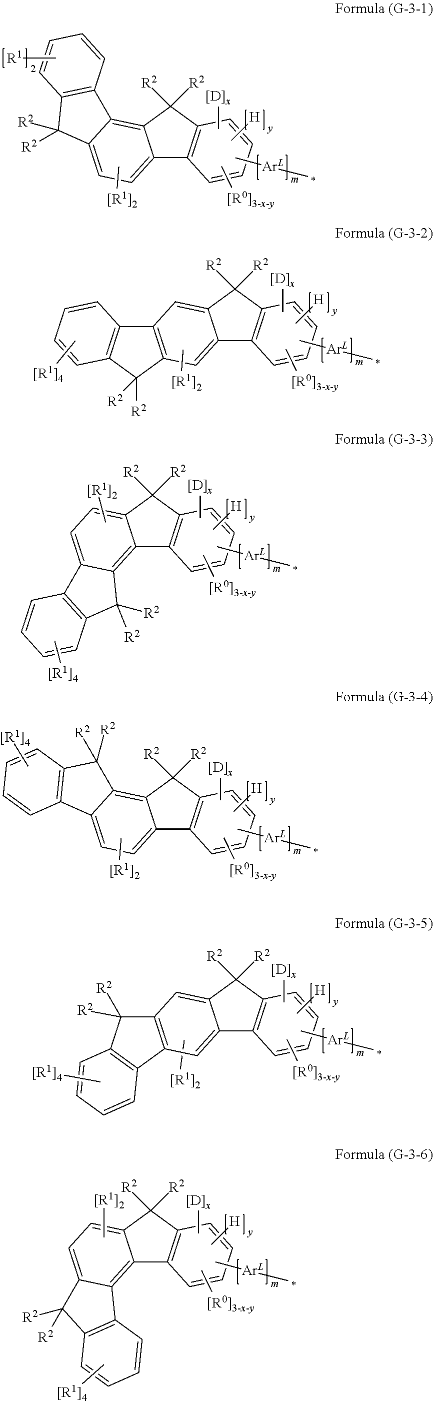

Among the formulae given, preference is given to formula (G-3-2).

[D]ₓ is understood here to mean that one deuterium atom is bonded at each of x=1 or 2 of the four positions shown as unsubstituted in the benzene ring of the formula (G-1), (G-2) or (G-3).

[H]_{y} is understood here to mean that one hydrogen atom (and not a deuterium atom; see definition above) is bonded at each of y=1 or 2 of the four positions shown as unsubstituted in the benzene ring of the formula (G-1), (G-2) or (G-3).

[R⁰]_{3-x-y} is understood here to mean that one R⁰ group is bonded at each of (3-x-y) of the four positions shown as unsubstituted in the benzene ring of the formula (G-1), (G-2) or (G-3). According to the definition of x and y above, (3-x-y) may assume either the value of 0 or the value of 1. In the former case, no R⁰ group is attached; in the latter case, exactly one R⁰ group is attached.

The same applies to the representation [R¹]₄ and [R¹]₂ in the benzene rings of the formulae (G-1), (G-2) and (G-3), namely that one R¹ radical is bonded to each of the four or two positions shown as unsubstituted in the benzene rings in question, and to further corresponding representations in the formulae in this application.

The definitions which follow are applicable to the chemical groups that are used in the present application. They are applicable unless any more specific definitions are given.

An aryl group in the context of this invention is understood to mean either a single aromatic cycle, i.e. benzene, or a fused aromatic polycycle, for example naphthalene, phenanthrene or anthracene. A fused aromatic polycycle in the context of the present application consists of two or more single aromatic cycles fused to one another. Fusion between cycles is understood here to mean that the cycles share at least one edge with one another. An aryl group in the context of this invention contains 6 to 40 aromatic ring atoms. In addition, an aryl group does not contain any heteroatom as aromatic ring atom, but only carbon atoms.

A heteroaryl group in the context of this invention is understood to mean either a single heteroaromatic cycle, for example pyridine, pyrimidine or thiophene, or a fused heteroaromatic polycycle, for example quinoline or carbazole. A fused heteroaromatic polycycle in the context of the present application consists of two or more single aromatic or heteroaromatic cycles that are fused to one another, where at least one of the aromatic and heteroaromatic cycles is a heteroaromatic cycle. Fusion between cycles is understood here to mean that the cycles share at least one edge with one another. A heteroaryl group in the context of this invention contains 5 to 40 aromatic ring atoms of which at least one is a heteroatom. The heteroatoms of the heteroaryl group are preferably selected from N, O and S.

An aryl or heteroaryl group, each of which may be substituted by the abovementioned radicals, is especially understood to mean groups derived from benzene, naphthalene, anthracene, phenanthrene, pyrene, dihydropyrene, chrysene, perylene, triphenylene, fluoranthene, benzanthracene, benzophenanthrene, tetracene, pentacene, benzopyrene, furan, benzofuran, isobenzofuran, dibenzofuran, thiophene, benzothiophene, isobenzothiophene, dibenzothiophene, pyrrole, indole, isoindole, carbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, benzimidazolo[1,2-a]benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, quinoxaline, pyrazine, phenazine, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole.

An aromatic ring system in the context of this invention is a system which does not necessarily contain solely aryl groups, but which may additionally contain one or more nonaromatic rings fused to at least one aryl group. These nonaromatic rings contain exclusively carbon atoms as ring atoms. Examples of groups covered by this definition are tetrahydronaphthalene, fluorene and spirobifluorene. In addition, the term “aromatic ring system” includes systems that consist of two or more aromatic ring systems joined to one another via single bonds, for example biphenyl, terphenyl, 7-phenyl-2-fluorenyl, quaterphenyl and 3,5-diphenyl-1-phenyl. An aromatic ring system in the context of this invention contains 6 to 40 carbon atoms and no heteroatoms in the ring system. The definition of “aromatic ring system” does not include heteroaryl groups.

A heteroaromatic ring system conforms to the abovementioned definition of an aromatic ring system, except that it must contain at least one heteroatom as ring atom. As is the case for the aromatic ring system, the heteroaromatic ring system need not contain exclusively aryl groups and heteroaryl groups, but may additionally contain one or more nonaromatic rings fused to at least one aryl or heteroaryl group. The nonaromatic rings may contain exclusively carbon atoms as ring atoms, or they may additionally contain one or more heteroatoms, where the heteroatoms are preferably selected from N, O and S. One example of such a heteroaromatic ring system is benzopyranyl. In addition, the term “heteroaromatic ring system” is understood to mean systems that consist of two or more aromatic or heteroaromatic ring systems that are bonded to one another via single bonds, for example 4,6-diphenyl-2-triazinyl. A heteroaromatic ring system in the context of this invention contains 5 to 40 ring atoms selected from carbon and heteroatoms, where at least one of the ring atoms is a heteroatom. The heteroatoms of the heteroaromatic ring system are preferably selected from N, O and S.

The terms “heteroaromatic ring system” and “aromatic ring system” as defined in the present application thus differ from one another in that an aromatic ring system cannot have a heteroatom as ring atom, whereas a heteroaromatic ring system must have at least one heteroatom as ring atom. This heteroatom may be present as a ring atom of a nonaromatic heterocyclic ring or as a ring atom of an aromatic heterocyclic ring.

In accordance with the above definitions, any aryl group is covered by the term “aromatic ring system”, and any heteroaryl group is covered by the term “heteroaromatic ring system”.

An aromatic ring system having 6 to 40 aromatic ring atoms or a heteroaromatic ring system having 5 to 40 aromatic ring atoms is especially understood to mean groups derived from the groups mentioned above under aryl groups and heteroaryl groups, and from biphenyl, terphenyl, quaterphenyl, fluorene, spirobifluorene, dihydrophenanthrene, dihydropyrene, tetrahydropyrene, indenofluorene, truxene, isotruxene, spirotruxene, spiroisotruxene, indenocarbazole, or from combinations of these groups.

In the context of the present invention, a straight-chain alkyl group having 1 to 20 carbon atoms and a branched or cyclic alkyl group having 3 to 20 carbon atoms and an alkenyl or alkynyl group having 2 to 40 carbon atoms in which individual hydrogen atoms or CH₂ groups may also be substituted by the groups mentioned above in the definition of the radicals are preferably understood to mean the methyl, ethyl, n-propyl, i-propyl, n-butyl, i-butyl, s-butyl, t-butyl, 2-methylbutyl, n-pentyl, s-pentyl, cyclopentyl, neopentyl, n-hexyl, cyclohexyl, neohexyl, n-heptyl, cycloheptyl, n-octyl, cyclooctyl, 2-ethylhexyl, trifluoromethyl, pentafluoroethyl, 2,2,2-trifluoroethyl, ethenyl, propenyl, butenyl, pentenyl, cyclopentenyl, hexenyl, cyclohexenyl, heptenyl, cycloheptenyl, octenyl, cyclooctenyl, ethynyl, propynyl, butynyl, pentynyl, hexynyl or octynyl radicals.

An alkoxy or thioalkyl group having 1 to 20 carbon atoms in which individual hydrogen atoms or CH₂ groups may also be substituted by the groups mentioned above in the definition of the radicals is preferably understood to mean methoxy, trifluoromethoxy, ethoxy, n-propoxy, i-propoxy, n-butoxy, i-butoxy, s-butoxy, t-butoxy, n-pentoxy, s-pentoxy, 2-methylbutoxy, n-hexoxy, cyclohexyloxy, n-heptoxy, cycloheptyloxy, n-octyloxy, cyclooctyloxy, 2-ethylhexyloxy, pentafluoroethoxy, 2,2,2-trifluoroethoxy, methylthio, ethylthio, n-propylthio, i-propylthio, n-butylthio, i-butylthio, s-butylthio, t-butylthio, n-pentylthio, s-pentylthio, n-hexylthio, cyclohexylthio, n-heptylthio, cycloheptylthio, n-octylthio, cyclooctylthio, 2-ethylhexylthio, trifluoromethylthio, pentafluoroethylthio, 2,2,2-trifluoroethylthio, ethenylthio, propenylthio, butenylthio, pentenylthio, cyclopentenylthio, hexenylthio, cyclohexenylthio, heptenylthio, cycloheptenylthio, octenylthio, cyclooctenylthio, ethynylthio, propynylthio, butynylthio, pentynylthio, hexynylthio, heptynylthio or octynylthio.

The wording that two or more radicals together may form a ring, in the context of the present application, shall be understood to mean, inter alia, that the two radicals are joined to one another by a chemical bond. In addition, however, the abovementioned wording shall also be understood to mean that, if one of the two radicals is hydrogen, the second radical binds to the position to which the hydrogen atom was bonded, forming a ring.

In a preferred embodiment of the compound of the formula (I), it is a monoamine, meaning that the compound contains only a single triarylamino group, preferably only a single amino group. Groups such as carbazole, indole and pyrrole and the derivatives thereof are preferably not regarded as groups containing a triarylamino group or as groups containing an amino group. A triarylamino group is understood here to mean all groups in which a nitrogen atom binds to three groups, where the groups are selected from optionally substituted aromatic and heteroaromatic ring systems, especially from optionally substituted aryl and heteroaryl groups.

The compound is partly deuterated, i.e. contains at least one hydrogen atom. The ratio between hydrogen atoms and deuterium atoms in the compound is preferably between 1:10 and 10:1, more preferably between 1:3 and 3:1, most preferably between 1:2 and 2:1.

In a preferred embodiment, in formula (I), the Ar¹, Ar¹ and G groups that bind to the nitrogen atom are each partly deuterated or fully deuterated, preferably partly deuterated, on their aromatic or heteroaromatic rings.

In an alternative preferred embodiment, in formula (I), only the G group is partly deuterated or fully deuterated, preferably partly deuterated, on its aromatic or heteroaromatic rings, and the Ar¹ groups are undeuterated.

What is meant by “fully deuterated” in this context is that all hydrogen atoms that bind to the aromatic or heteroaromatic rings of the group have been exchanged for deuterium. What is meant by “partly deuterated” in this context is that one or more, but not all, of the hydrogen atoms that bind to the aromatic or heteroaromatic rings of the groups have been replaced by deuterium.

The aromatic or heteroaromatic rings of the Ar¹ groups are preferably understood to mean those rings that form the Ar¹ group itself, not any rings present in substituents R³ of the Ar¹ groups. More preferably, this is also understood to mean rings of substituents R³ of the Ar¹ groups, substituents R⁴ of substituents R³ of the Ar¹ groups, and substituents R⁵ of substituents R⁴ of substituents R³ of the Ar¹ groups. The same applies to the G group, such that the aromatic or heteroaromatic rings of the G group are preferably understood to mean those rings that form the G group itself, not any rings present in substituents R⁰ or R¹ of the G group. More preferably, this is also understood to mean rings of substituents R⁰, R¹ and R² of the G groups, substituents R⁴ of substituents R⁰, R¹ and R² of the G groups, and substituents R⁵ of substituents R⁴ of substituents R⁰, R¹ and R² of the G groups.

Parts of the Ar¹ and G groups that are not aromatic or heteroaromatic rings but have hydrogen atoms may be undeuterated, fully deuterated or partly deuterated. Substituents of the Ar¹ and G groups that are not aromatic or heteroaromatic rings and have hydrogen atoms may be undeuterated, partly deuterated or fully deuterated and are preferably partly deuterated or fully deuterated, more preferably fully deuterated, in the case of aromatic or heteroaromatic rings, and are preferably undeuterated or partly deuterated, more preferably undeuterated, in the case of aliphatic groups, especially alkyl groups.

In addition, it is preferable that all the aliphatic groups present in the compound of the formula (I) are undeuterated. Aliphatic groups are understood to mean all groups that are nonaromatic, especially all alkyl groups, alkenyl groups and alkynyl groups, including cyclic forms thereof. In particular, it is preferable that the alkyl groups in the 9 position of fluorenyl groups in formula (I) are undeuterated.

In general, with regard to any chemical groups, what is meant by “undeuterated” is that all hydrogen atoms present in the group are ¹H. What is meant by “partly deuterated” is that two or more hydrogen atoms are present in the group, of which one or more are ¹H and one or more are ²H. In a preferred embodiment, what is meant by “partly deuterated” is that two or more hydrogen atoms are present in the group, of which half or more are ²H and at least one is, but at most half are, ¹H. What is meant by “fully deuterated” is that all hydrogen atoms present in the group are ²H.

In the consideration of whether an Ar¹ group is fully deuterated or partly deuterated, it is preferable that the permissible size of the aromatic or heteroaromatic ring system of Ar¹ by definition is fully exhausted before substituents R³ are included for extension of the aromatic or heteroaromatic ring system. For example, when Ar¹ is defined as an aromatic ring system which has 6 to 40 aromatic ring atoms and is substituted by R³ radicals, or heteroaromatic ring system which has 5 to 40 aromatic ring atoms and is substituted by R³ radicals, a biphenyl group is considered to be an aromatic ring system having 12 aromatic ring atoms that does not bear an R³ radical, and not as an aromatic ring system having 6 aromatic ring atoms that bears an R³ radical which is a phenyl group.

The compound of the formula (I) is preferably present in a mixture with a proportion of other compounds of the formula (I) that differ from the compound of the formula (I) merely in that they are H/D isotopomers of that compound, or H/D isotopologs of that compound. An H/D isotopomer of a first compound is understood to mean a compound that differs from the first compound merely by the position of the H and D isotopes in the chemical structure of the compound. The first compound and the H/D isotopomer thereof are both referred to as H/D isotopomers (of one another). One example of two H/D isotopomers is the compounds (a) and (b) shown below.

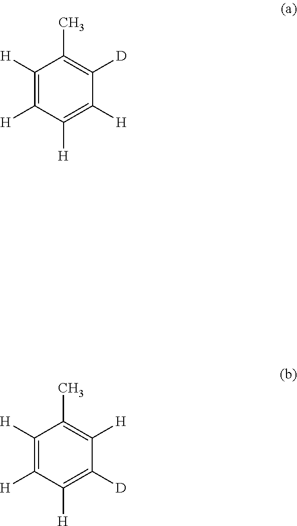

An H/D isotopolog of a first compound is understood to mean a compound that differs from the first compound merely by the number of isotopes ²H (=D) in the compound but is otherwise identical, where the position of the isotopes ²H in the chemical structure of the compounds may also additionally be different. The first compound and the H/D isotopolog thereof are both referred to as H/D isotopologs (of one another). One example of H/D isotopologs is the three compounds (c), (d) and (e) shown below.

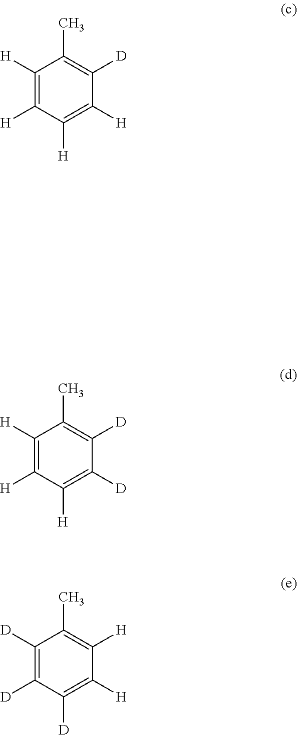

Averaged over all isotopomeric and isotopologous compounds in the mixture, the ratio of hydrogen atoms to deuterium atoms is preferably between 1:10 and 10:1, more preferably between 1:3 and 3:1, and most preferably between 1:2 and 2:1.

The proportion of other compounds of the formula (I) in the mixture that differ from the compound of the formula (I) merely in that they are H/D isotopomers of that compound, or H/D isotopologs of that compound, is preferably between 50% and 99% by weight.

Compounds that are neither H/D isotopomers of the first compound nor H/D isotopologs of the first compound are preferably present only in a negligible proportion, if any, in the mixture. This proportion is preferably below 0.5% by weight, more preferably below 0.1% by weight, even more preferably below 0.01% by weight, and most preferably below 0.001% by weight.

The present application thus also provides a mixture containing two or more compounds that are H/D isotopomers or H/D isotopologs of one another and are covered by formula (I). The mixture, aside from the two or more H/D isotopologs and/or H/D isotopomers, preferably contains merely a small proportion of further compounds that are neither H/D isotopomers nor H/D isotopologs of one another, preferably in the abovementioned proportions. It is further preferable that the mixture consists of two or more compounds that are H/D isotopomers or H/D isotopologs of one another and are covered by formula (I).

Formula (1) preferably conforms to one of the two following formulae:

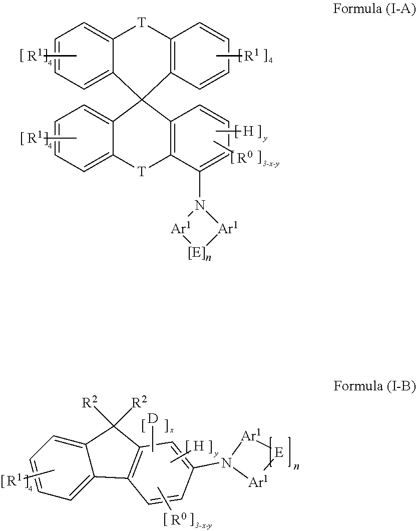

where the variables that occur are as defined above. Especially preferably, in formula (I-A), each T is a single bond, so as to result in the formula (I-A-1) below. In addition, especially preferably, in the abovementioned formulae, n=0. In addition, the preferred embodiments of the variables that are cited hereinafter are considered to be preferred in association with the formulae. In addition, it is preferable that each R² in the 9 position of the fluorene of the formula (I-B) is an undeuterated chemical group, and is preferably the same or different and is undeuterated methyl or undeuterated phenyl.

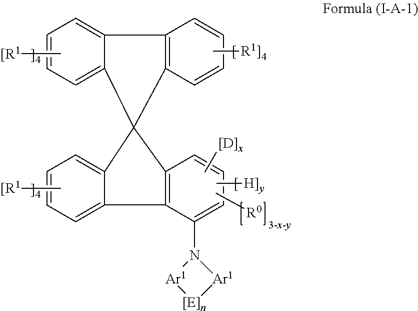

Further preferably, formula (I) conforms to one of the following formulae:

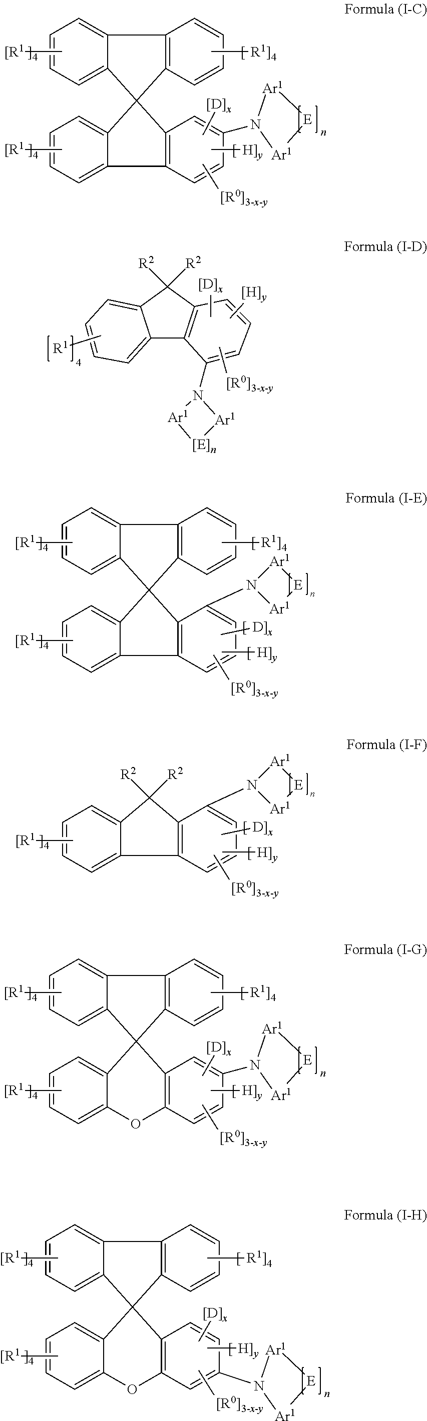

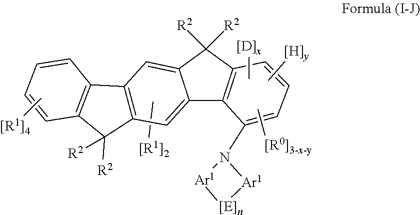

where the variables that occur are as defined above, and where n is preferably 0, and where preference is also given to the preferred embodiments of the variables cited hereinafter. In addition, it is preferable that each R² in the 9 position of the fluorene of the formulae (I-D), (I-F) and (I-J) is an undeuterated chemical group, and is preferably the same or different and is undeuterated methyl or undeuterated phenyl.

Especially preferably, the compound conforms to one of the formulae (I-A-1), (I-B), (I-C), (I-D), (I-E), (I-F), (I-G), (I-H) and (I-J).

Preferably, the formulae (I-A) to (I-J) conform to the following formulae:

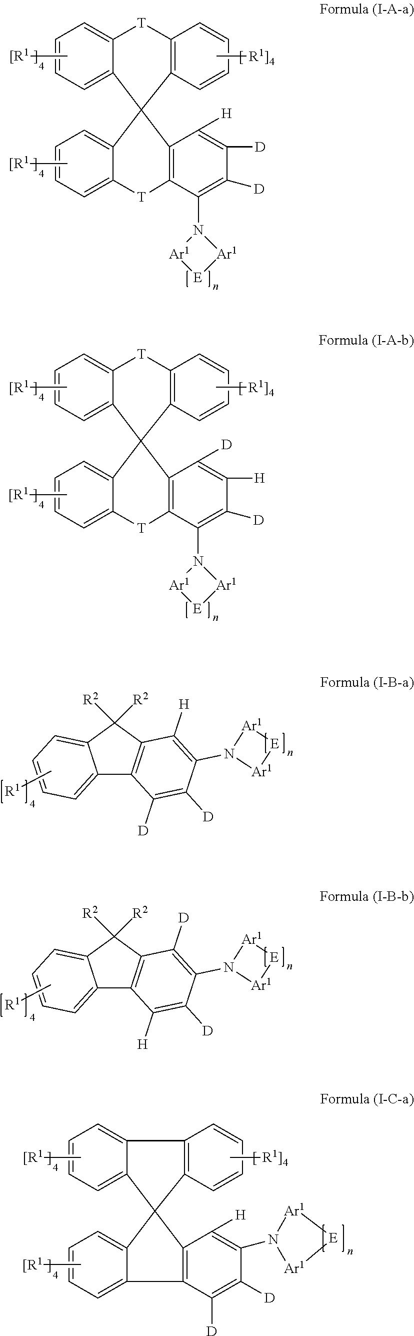

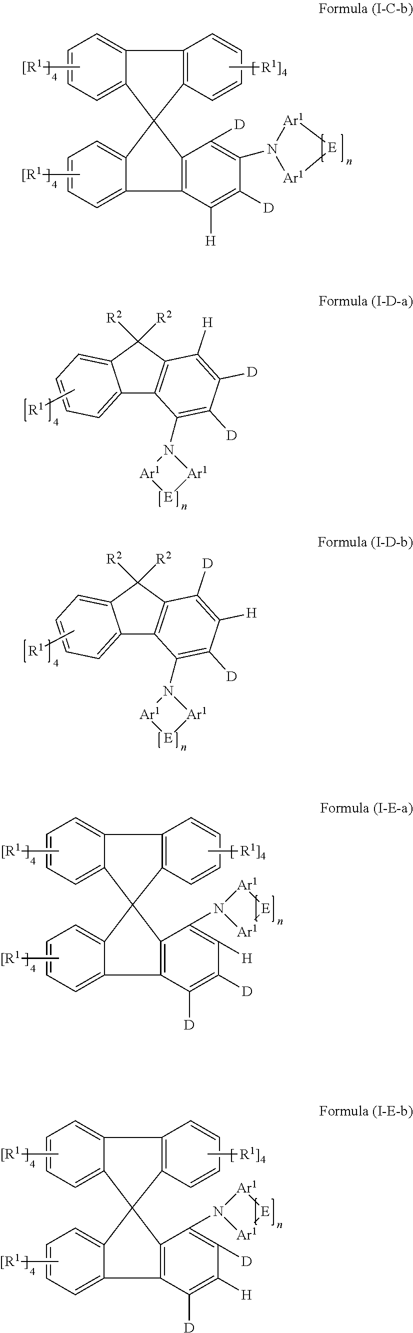

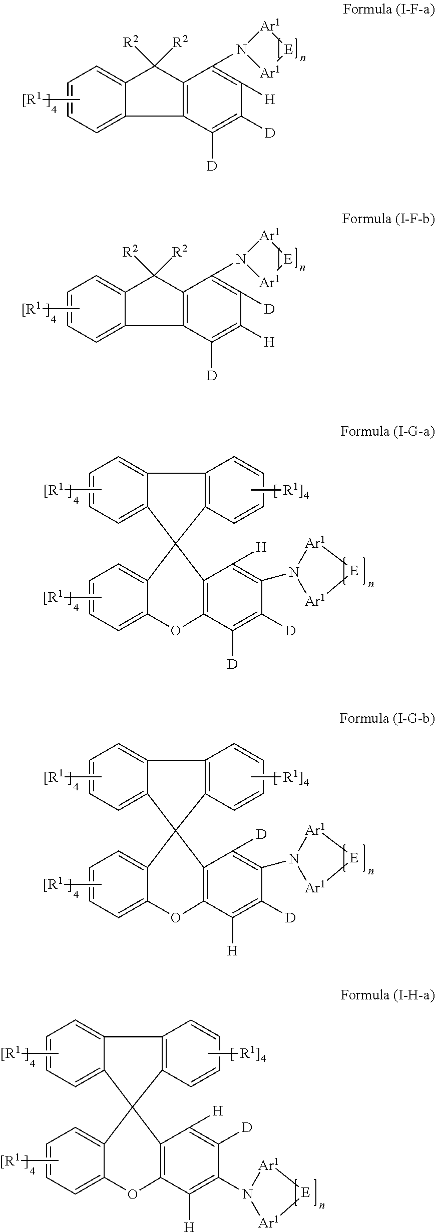

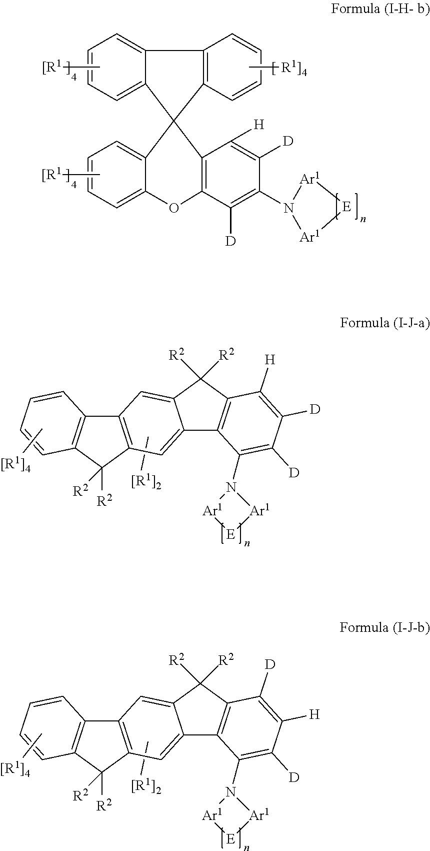

where the variables that occur are as defined above, and where n is preferably 0, and where preference is also given to the preferred embodiments of the variables cited hereinafter. In addition, it is preferable that each R² in the 9 position of the fluorene of the formulae (I-B) and (I-D) and (I-F) and (I-J) is an undeuterated chemical group, and is preferably the same or different and is undeuterated methyl or undeuterated phenyl.

Formulae (I-A-a) and (I-A-b) preferably conform to the following formulae:

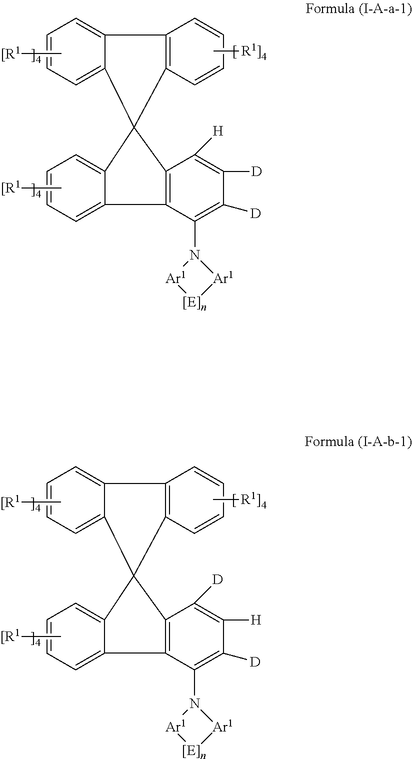

where the variables that occur are as defined above, and where n is preferably 0, and where preference is also given to the preferred embodiments of the variables cited hereinafter.

Especially preferably, the compound conforms to one of the formulae (I-A-a-1), (I-A-b-1), (I-B-a), (I-B-b), (I-C-a), (I-C-b), (I-D-a), (I-D-b), (I-E-a), (I-E-b), (I-F-a), (I-F-b), (I-G-a), (I-G-b), (I-H-a) (I-H-b), (I-J-a) and (I-J-b).

It is preferable that the compound of the formula (I) contains at least one group selected from 1-spirobifluorenyl groups, 4-spirobifluorenyl groups, 1-fluorenyl groups, 4-fluorenyl groups and 4-indenofluorenyl groups, preferably as Ar¹ and/or G group. It is further preferable that the compound of the formula (I) contains at least one group selected from 2-spirobifluorenyl groups and 2-fluorenyl groups, preferably as Ar¹ and/or G group. More preferably, the compound of the formula (I) contains at least one group selected from 1-spirobifluorenyl groups, 4-spirobifluorenyl groups, 1-fluorenyl groups, 4-fluorenyl groups and 4-indenofluorenyl groups, and at least one group selected from 2-spirobifluorenyl groups and 2-fluorenyl groups, preferably each as Ar¹ and/or G groups.

Most preferably, in the compound of the formula (I), exactly one Ar¹ or G group is selected from 1-spirobifluorenyl groups, 4-spirobifluorenyl groups, 1-fluorenyl groups, 4-fluorenyl groups and 4-indenofluorenyl groups, and exactly one further Ar¹ or G group is selected from 2-spirobifluorenyl groups and 2-fluorenyl groups. The remaining third Ar¹ or G group here is selected from 1-spirobifluorenyl groups, 4-spirobifluorenyl groups, 1-fluorenyl groups, 4-fluorenyl groups, 2-spirobifluorenyl groups, 2-fluorenyl groups, and other aromatic or heteroaromatic ring systems having 5 or 6 to 40 aromatic ring atoms. In a particularly preferred embodiment, these groups selected from 1-spirobifluorenyl groups, 4-spirobifluorenyl groups, 1-fluorenyl groups, 4-fluorenyl groups, 4-indenofluorenyl groups, 2-spirobifluorenyl groups and 2-fluorenyl groups are bonded directly to the nitrogen atom, or bonded via a linker group to the nitrogen atom, where the linker group is preferably selected from phenylene and biphenylene, each of which are substituted by R³ radicals, preferably phenylene substituted by R³ radicals.

In an alternative preferred embodiment, the compound preferably contains a spiroxanthene group as G and/or Ar¹ group, especially a 2-spiroxanthene group or a 3-spiroxanthene group.

A 1-spirobifluorenyl group is understood here to mean a spirobifluorenyl group which is attached in its 1 position and which is optionally substituted. A 4-spirobifluorenyl group is understood here to mean a spirobifluorenyl group which is attached in its 4 position and which is optionally substituted. A 2-spirobifluorenyl group is understood here to mean a spirobifluorenyl group which is attached in its 2 position and which is optionally substituted. A 1-fluorenyl group is understood here to mean a fluorenyl group which is attached in its 1 position and which is optionally substituted. A 4-fluorenyl group is understood here to mean a fluorenyl group which is attached in its 4 position and which is optionally substituted. A 2-fluorenyl group is understood here to mean a fluorenyl group which is attached in its 2 position and which is optionally substituted. A 4-indenofluorenyl group is understood here to mean an indenofluorenyl group which is attached in its 4 position and which is optionally substituted.

A 2-spiroxanthene group is understood to mean the following group:

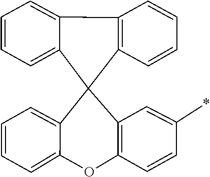 [SMILES: *c1ccc2c(c1)C1(c3ccccc3O2)c2ccccc2-c2ccccc21]

and a 3-spiroxanthene group is understood to mean the following group:

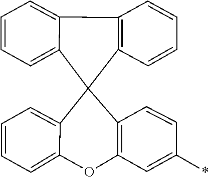 [SMILES: *c1ccc2c(c1)Oc1ccccc1C21c2ccccc2-c2ccccc21]

where each of the two groups may be optionally substituted and the attachment position is labeled *.

In formula (I-A) and formula (I-A-1), it is preferable that at least one Ari group, preferably both Ar¹ groups, contain(s) a 2-fluorenyl group or a 2-spirobifluorenyl group, each substituted by R³ radicals. Formula (I-A-1) preferably conforms to one of the following formulae:

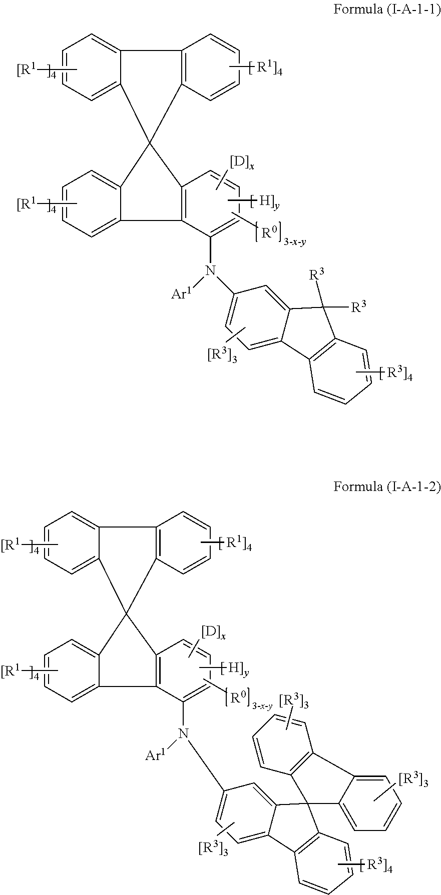

where the groups that occur are as defined above, and preferably correspond to their preferred embodiments. In addition, it is preferable that each R³ in the 9 position of the fluorene of the formula (I-A-1) is an undeuterated chemical group, and is preferably the same or different and is undeuterated methyl or undeuterated phenyl.

In formula (I-B), it is preferable that at least one Ar¹ group, preferably both Ar¹ groups, contain(s) a 4-spirobifluorenyl group or a 4-fluorenyl group, substituted by R³ radicals. Formula (I-B) preferably conforms to one of the following formulae:

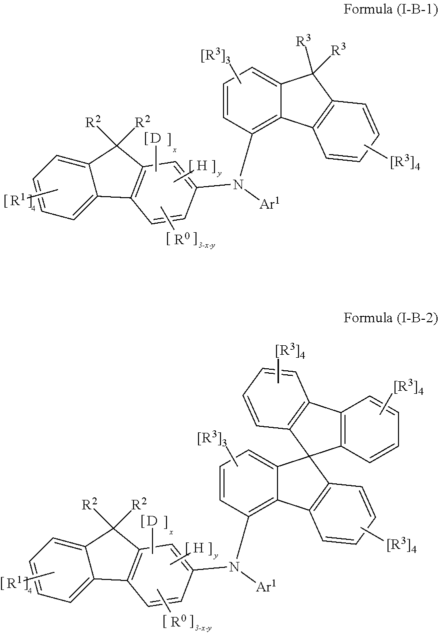

where the groups that occur are as defined above, and preferably correspond to their preferred embodiments. In addition, it is preferable that each R³ in the 9 position of the fluorene of the formula (I-B-1) and each R² in the 9 position of the fluorene of the formulae (I-B-1) and (I-B-2) is an undeuterated chemical group, and is preferably the same or different and is undeuterated methyl or undeuterated phenyl.

In formula (I-C), it is preferable that at least one Ar¹ group, preferably both Ar¹ groups, contain(s) a 4-spirobifluorenyl group or a 4-fluorenyl group, substituted by R³ radicals. Formula (I-C) preferably conforms to one of the following formulae:

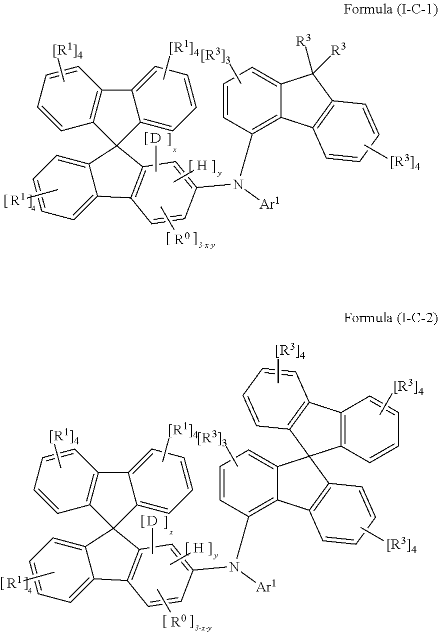

where the groups that occur are as defined above, and preferably correspond to their preferred embodiments. In addition, it is preferable that each R³ in the 9 position of the fluorene of the formula (I-C-1) is an undeuterated chemical group, and is preferably the same or different and is undeuterated methyl or undeuterated phenyl.

In formula (I-D), it is preferable that at least one Ar¹ group, preferably both Ar¹ groups, contain(s) a 2-fluorenyl group or a 2-spirobifluorenyl group, each substituted by R³ radicals. Formula (I-D) preferably conforms to one of the following formulae:

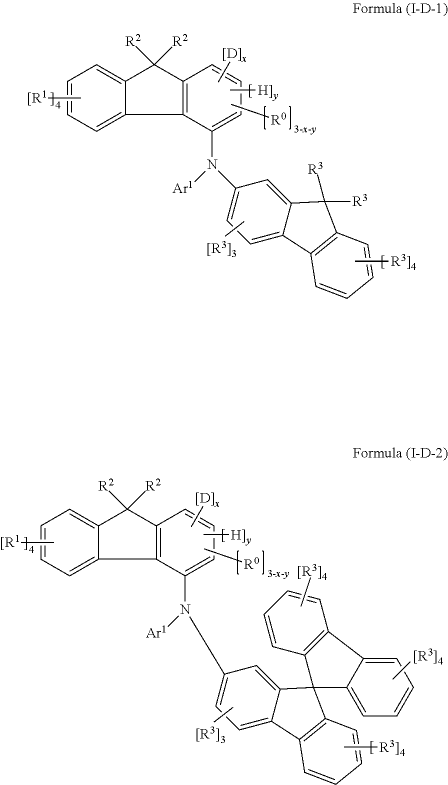

where the groups that occur are as defined above, and preferably correspond to their preferred embodiments. In addition, it is preferable that each R³ in the 9 position of the fluorene of the formula (I-D-1) and each R² in the 9 position of the fluorene of the formulae (I-D-1) and (I-D-2) is an undeuterated chemical group, and is preferably the same or different and is undeuterated methyl or undeuterated phenyl.

In a preferred embodiment, Ar¹ groups are partly deuterated or fully deuterated, more preferably partly deuterated.

In an alternative preferred embodiment, the Ar¹ groups are undeuterated, more preferably undeuterated even with inclusion of their substituents R³, the substituents R⁴ of their substituents R³, and the substituents R⁵ of the substituents R⁴ of their substituents R³.

The Ar¹ groups selected are preferably different.

In a preferred embodiment, in formula (I) and in the abovementioned preferred formulae, at least one Ar¹ group conforms to one of the following formulae:

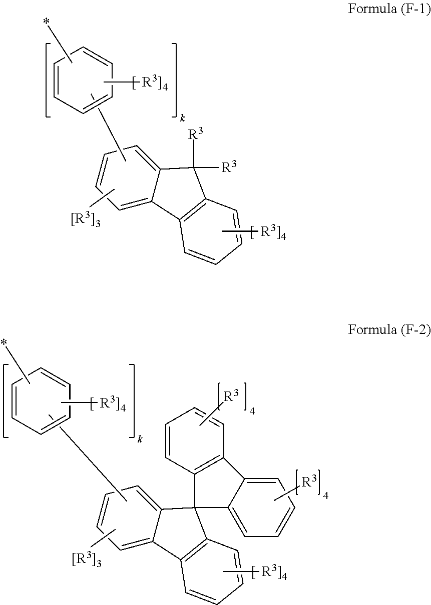

where k is 0, 1, 2 or 3, preferably 0 or 1, most preferably 0, and the position of attachment to the rest of the formula is labeled *, and the other variables are as defined above. In a preferred embodiment, R³ in formulae (F-1) and (F-2) is the same or different at each instance and is selected from H and D.

In a preferred embodiment, the groups of the formulae (F-1) and (F-2) are partly deuterated or fully deuterated, more preferably fully deuterated. In addition, it is preferable that R³ in the 9 position of the fluorene of the formula (F-1) is an undeuterated chemical group, and is preferably undeuterated methyl or undeuterated phenyl.

In an alternative preferred embodiment, the groups in the formulae (F-1) and (F-2) are undeuterated, even with inclusion of their substituents R³, the substituents R⁴ of their substituents R³, and the substituents R⁵ of the substituents R⁴ of their substituents R³.

In a further preferred embodiment, in formula (I) and in the abovementioned preferred formulae (I-A) to (I-J), especially in the formulae (I-A-a) to (I-J-b), at least one Ar¹ group, preferably exactly one Ar¹ group, conforms to one of the following formulae:

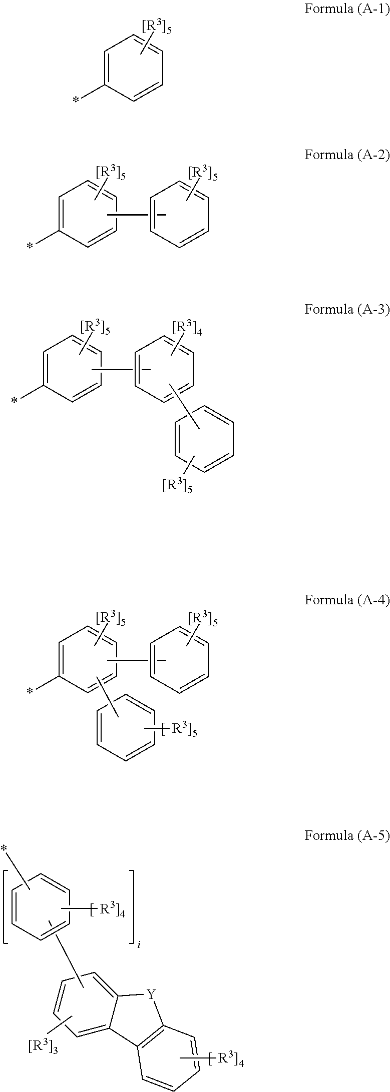

where Y is O or S, and i is 0, 1, 2 or 3, preferably 0 or 1, and the position of attachment to the rest of the formula is labeled *, and the other variables are as defined above. In a preferred embodiment, R³ in formulae (A-1) to (A-5) is the same or different at each instance and is selected from H and D; in particular, R³ in formula (A-5) is the same or different at each instance and is selected from H and D.

In a preferred embodiment, the groups of the formulae (A-1) to (A-5) are partly deuterated or fully deuterated, more preferably fully deuterated.

In an alternative preferred embodiment, the groups in the formulae (A-1) to (A-5) are undeuterated, even with inclusion of their substituents R³, the substituents R⁴ of their substituents R³, and the substituents R⁵ of the substituents R⁴ of their substituents R³.

In a particularly preferred embodiment, in formula (I), exactly one of the two Ar¹ groups conforms to a formula selected from the abovementioned formulae (F-1) and (F-2), and the other of the two Ar¹ groups conforms to a formula selected from the abovementioned formulae (A-1) to (A-5).

Preference is therefore given in particular to the following combinations of Ar¹ groups with G groups in the compounds of the formula (I):

| Formula | G | Ar¹ | Ar¹ |
|---|---|---|---|
| (I-a) | (G-1) | (F-1) | (A-1) |
| (I-b) | (G-1) | (F-1) | (A-2) |
| (I-c) | (G-1) | (F-1) | (A-3) |
| (I-d) | (G-1) | (F-1) | (A-4) |
| (I-e) | (G-1) | (F-1) | (A-5) |
| (I-f) | (G-1) | (F-2) | (A-1) |
| (I-g) | (G-1) | (F-2) | (A-2) |
| (I-h) | (G-1) | (F-2) | (A-3) |
| (I-i) | (G-1) | (F-2) | (A-4) |
| (I-j) | (G-1) | (F-2) | (A-5) |
| (I-k) | (G-2) | (F-1) | (A-1) |
| (I-l) | (G-2) | (F-1) | (A-2) |
| (I-m) | (G-2) | (F-1) | (A-3) |
| (I-n) | (G-2) | (F-1) | (A-4) |
| (I-o) | (G-2) | (F-1) | (A-5) |
| (I-p) | (G-2) | (F-2) | (A-1) |
| (I-q) | (G-2) | (F-2) | (A-2) |
| (I-r) | (G-2) | (F-2) | (A-3) |
| (I-s) | (G-2) | (F-2) | (A-4) |
| (I-t) | (G-2) | (F-2) | (A-5) |
| (I-u) | (G-3) | (F-1) | (A-1) |
| (I-v) | (G-3) | (F-1) | (A-2) |
| (I-w) | (G-3) | (F-1) | (A-3) |
| (I-x) | (G-3) | (F-1) | (A-4) |
| (I-y) | (G-3) | (F-1) | (A-5) |
| (I-z) | (G-3) | (F-2) | (A-1) |
| (I-aa) | (G-3) | (F-2) | (A-2) |
| (I-ab) | (G-3) | (F-2) | (A-3) |
| (I-ac) | (G-3) | (F-2) | (A-4) |
| (I-ad) | (G-3) | (F-2) | (A-5) |

where the variables are as defined above, and preferably correspond to their preferred embodiments.

Ar¹ groups are preferably the same or different at each instance and are selected from benzene, biphenyl, terphenyl, quaterphenyl, naphthyl, fluorenyl, especially 9,9′-dimethylfluorenyl and 9,9′-diphenylfluorenyl, benzofluorenyl, spirobifluorenyl, indenofluorenyl, indenocarbazolyl, dibenzofuranyl, dibenzothiophenyl, carbazolyl, benzofuranyl, benzothiophenyl, and phenyl substituted by a group selected from naphthyl, fluorenyl, spirobifluorenyl, dibenzofuranyl, dibenzothiophenyl, carbazolyl, pyridyl, pyrimidyl and triazinyl, where the abovementioned embodiments are each substituted by R³ radicals.

Particularly preferred embodiments of the formulae (A-I) to (A-5) are selected from the following formulae:

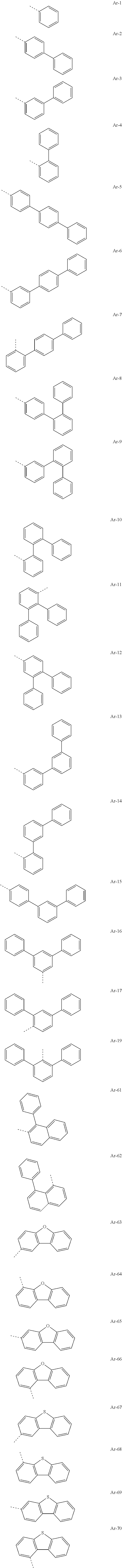

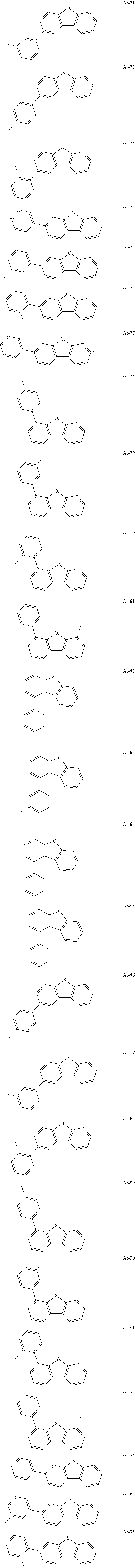

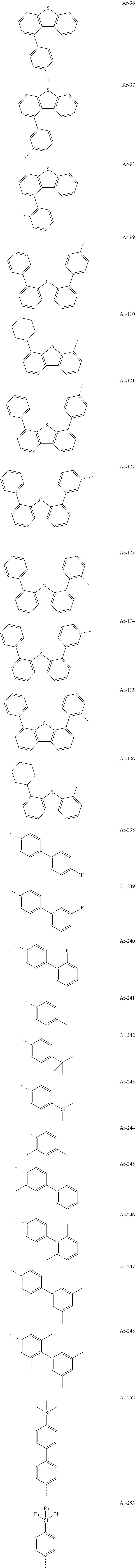

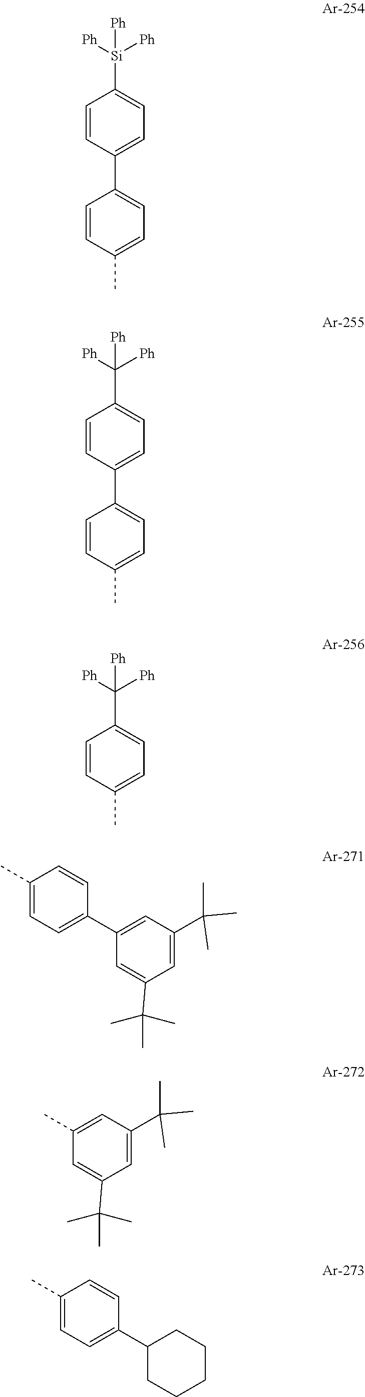

which are each substituted by R³ radicals at the positions shown as unsubstituted, where the R³ radicals in these cases are preferably H or D.

In a further preferred embodiment, Ar¹ is the same or different at each instance and is selected from the following formulae:

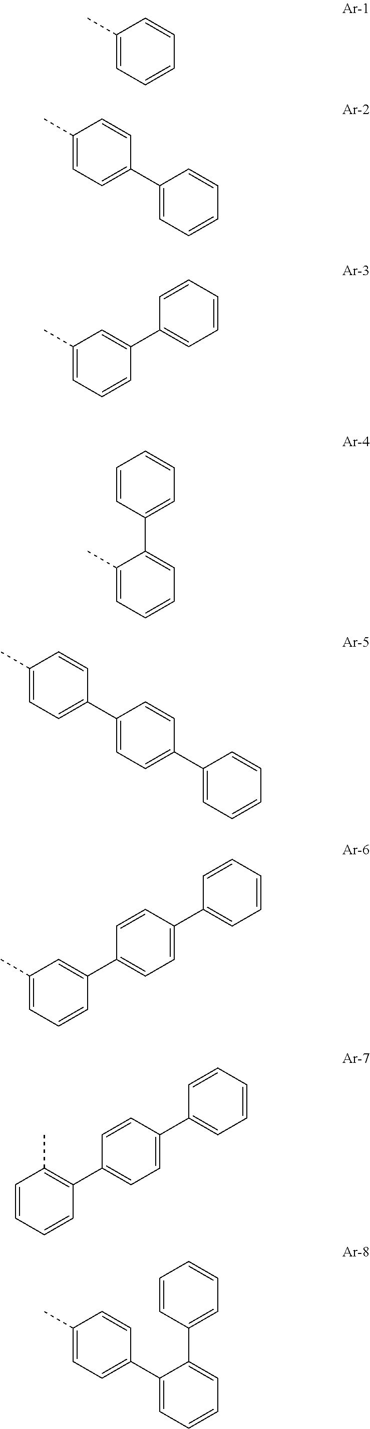

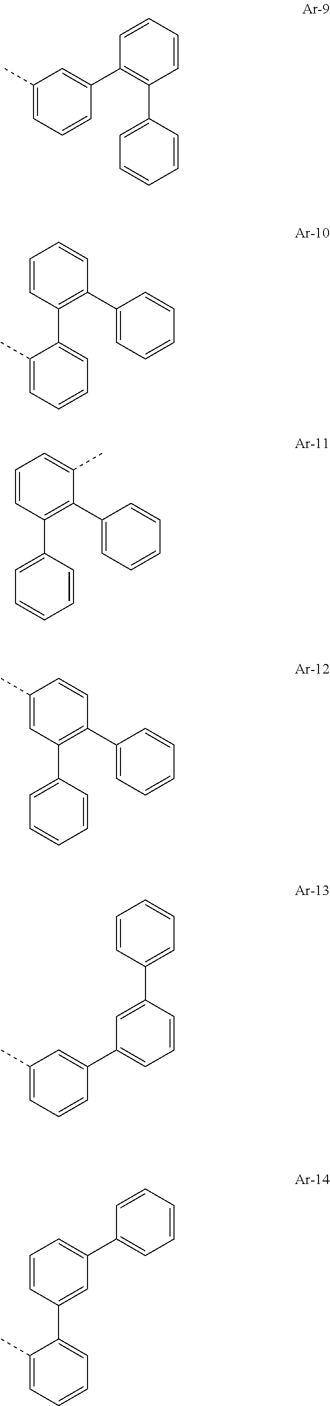

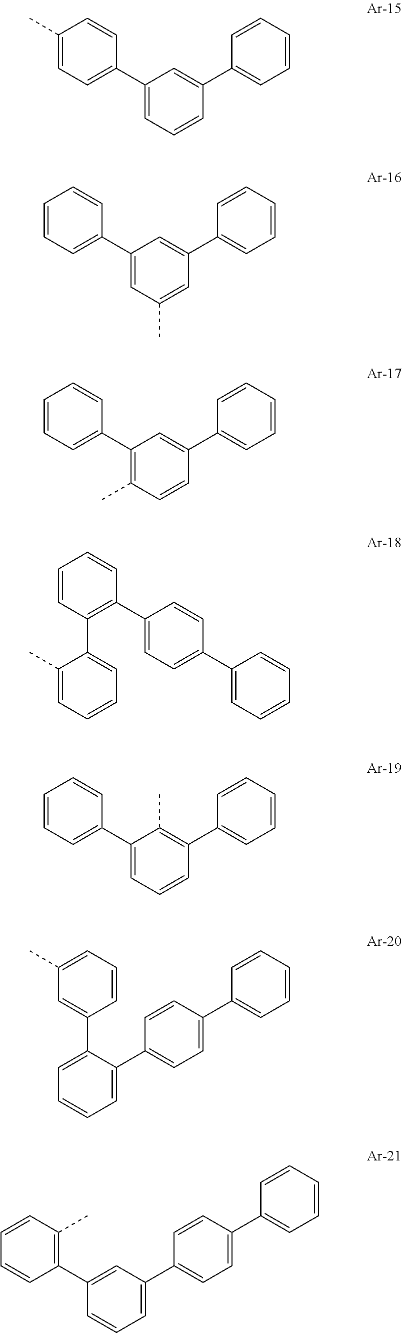

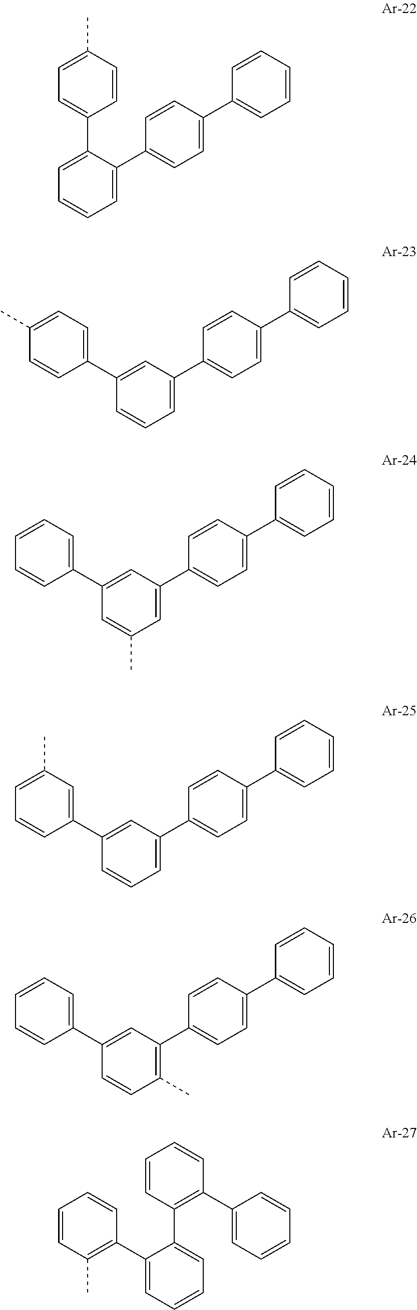

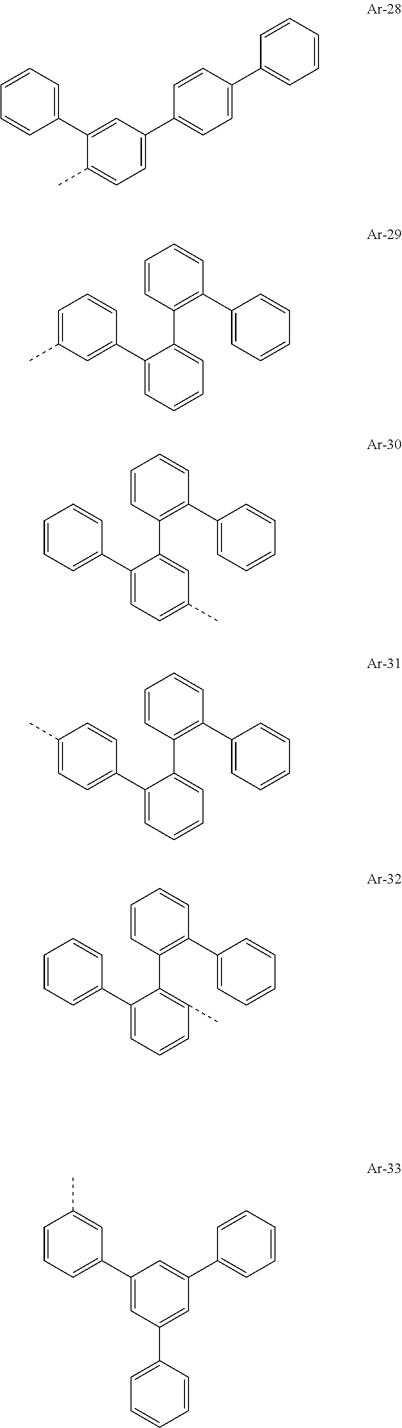

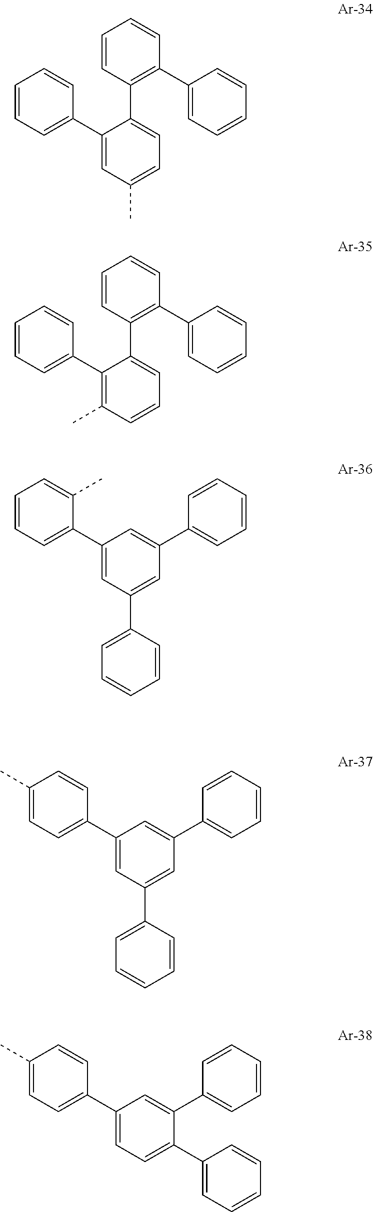

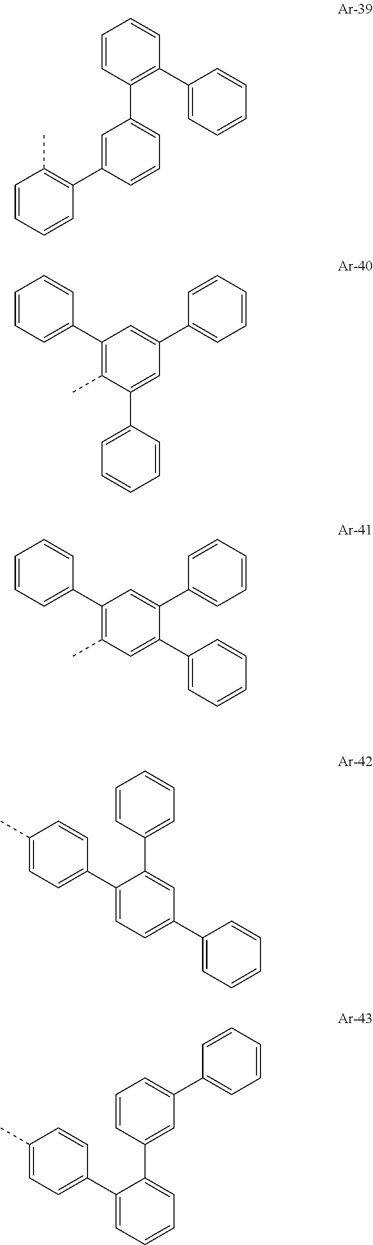

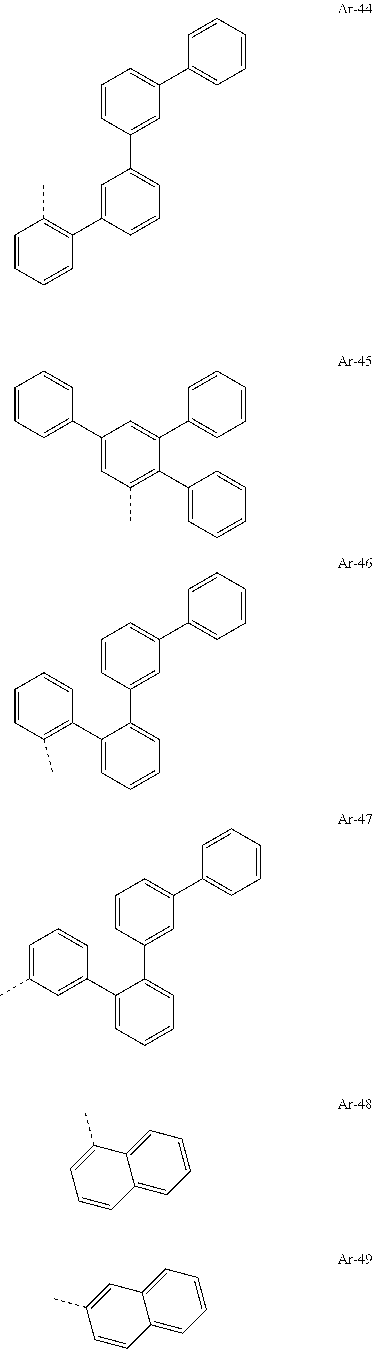

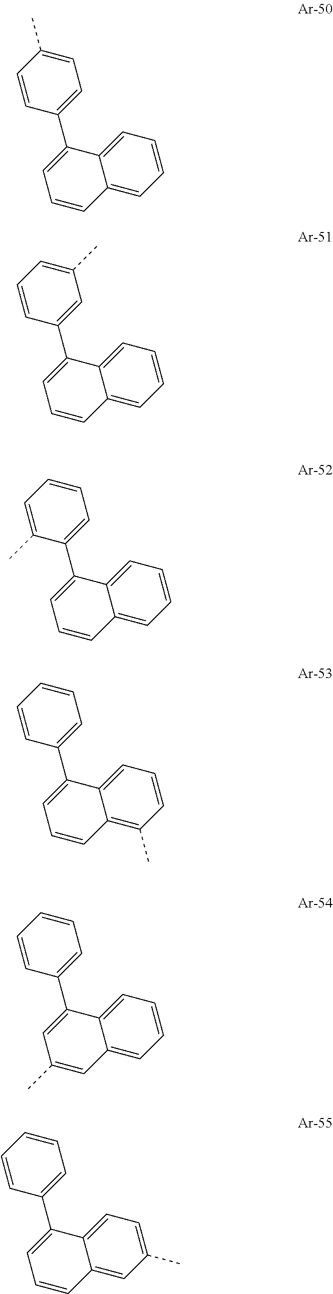

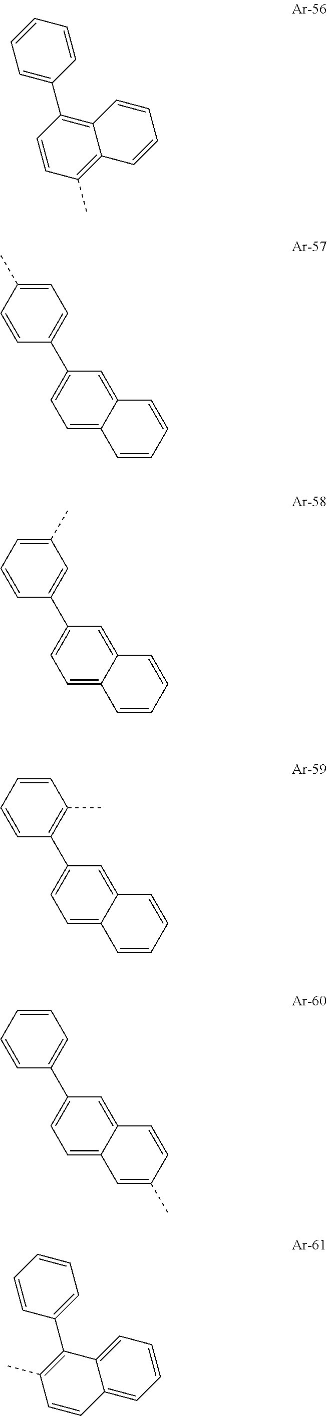

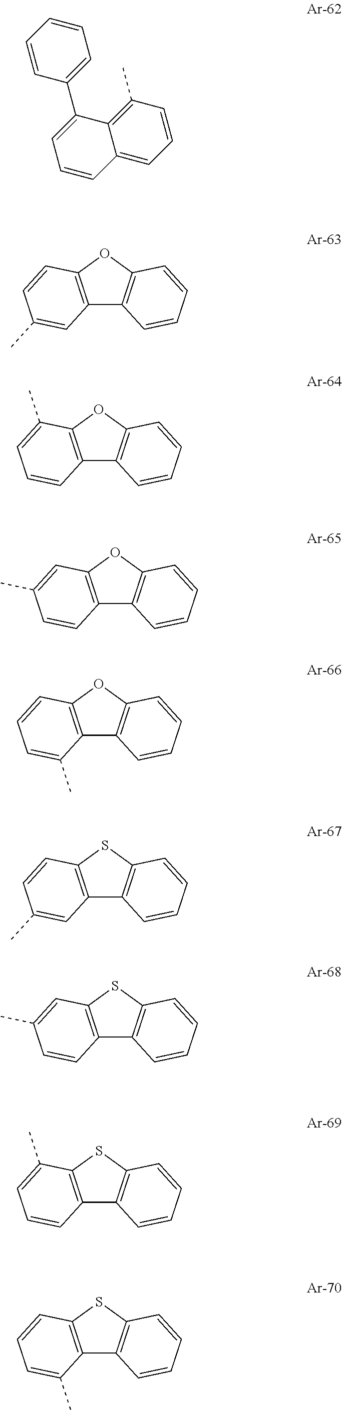

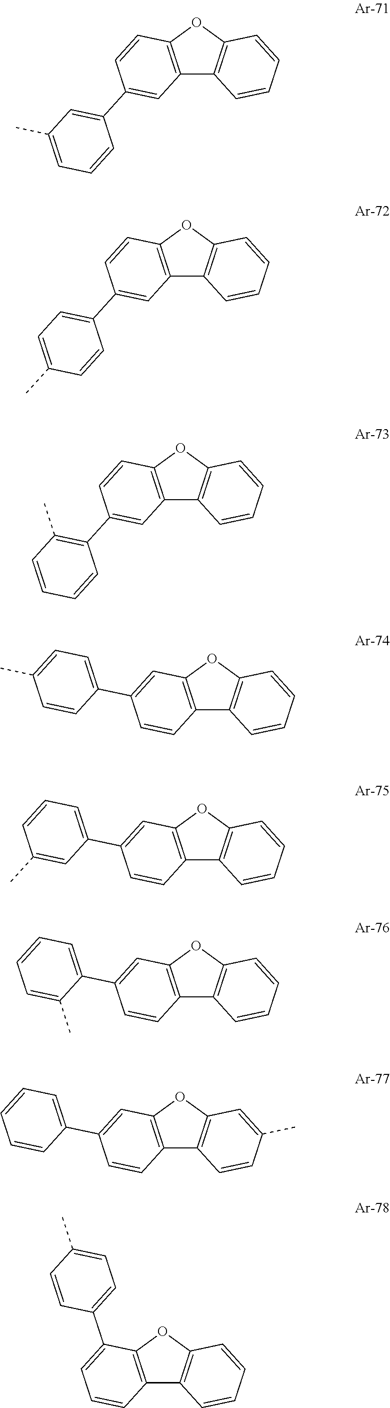

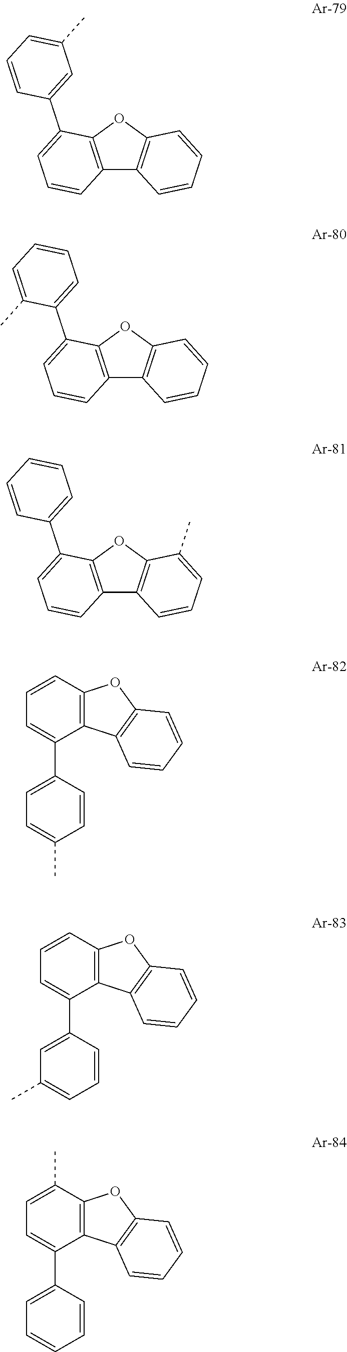

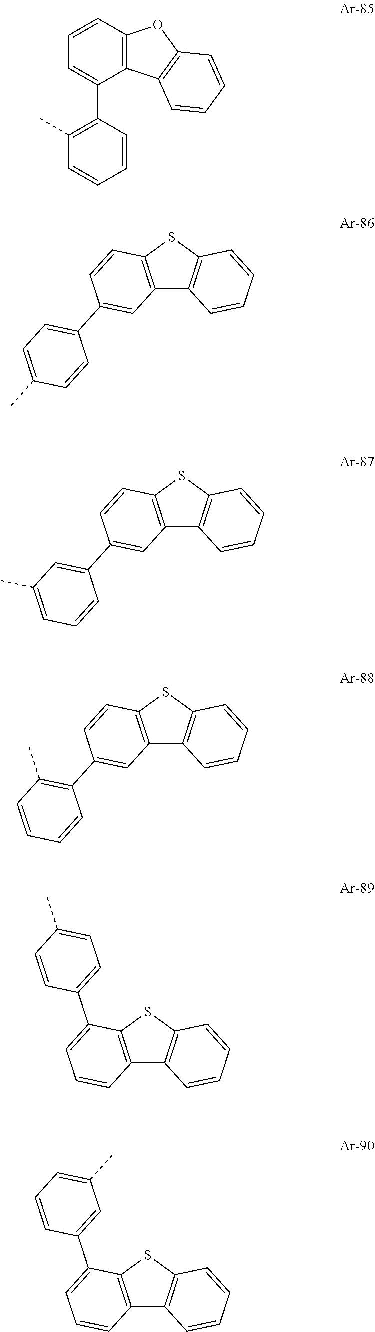

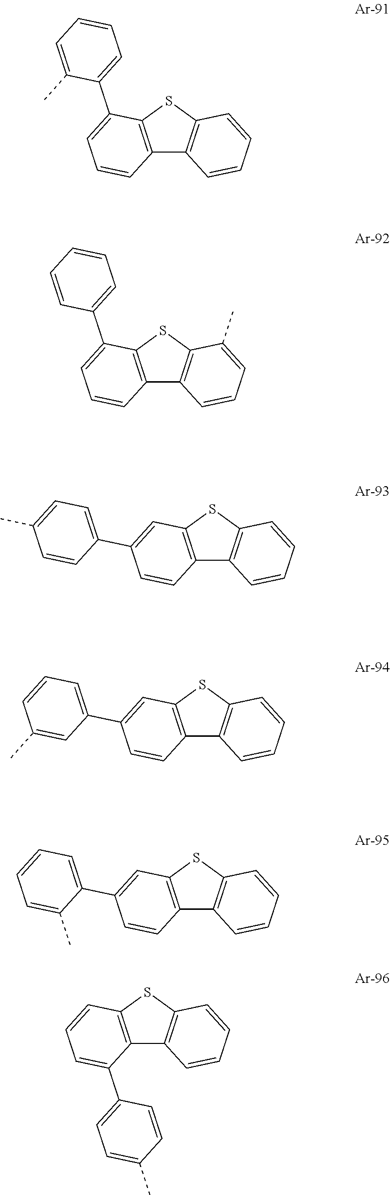

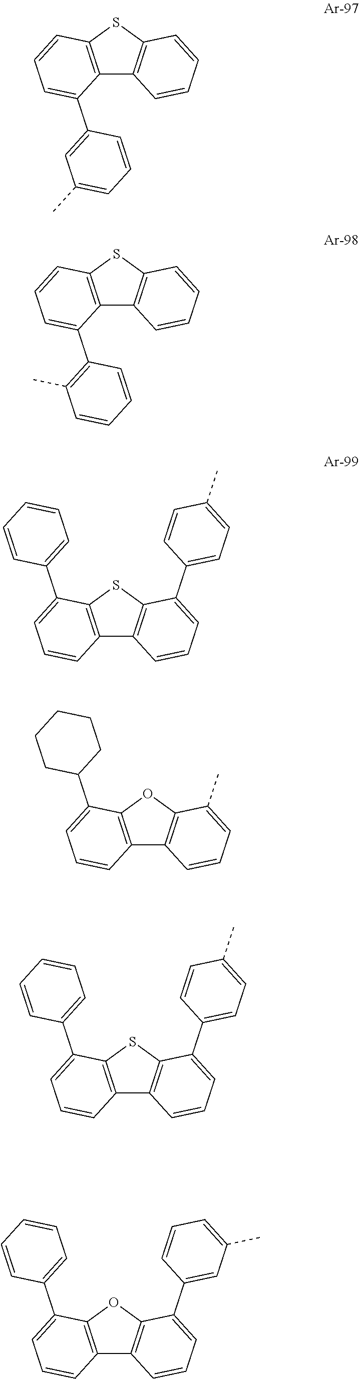

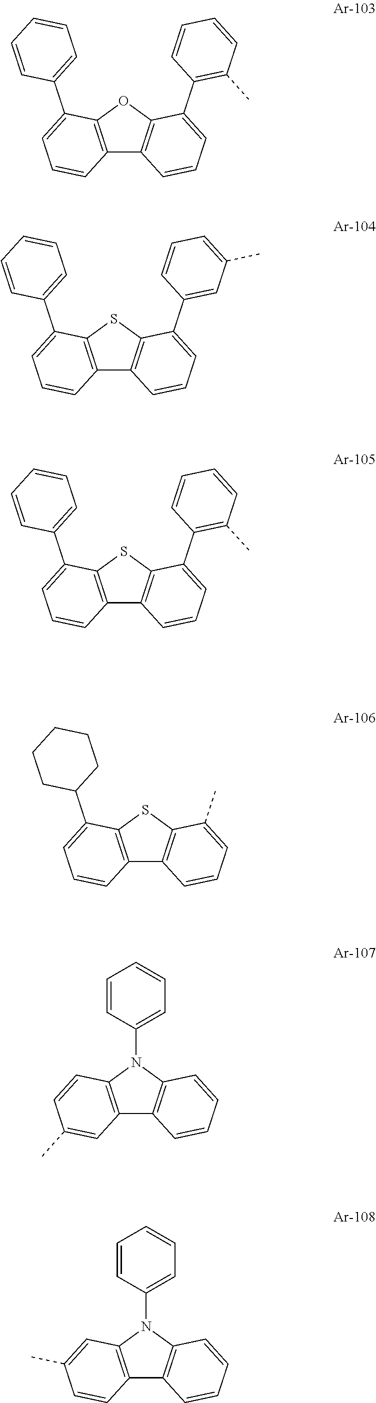

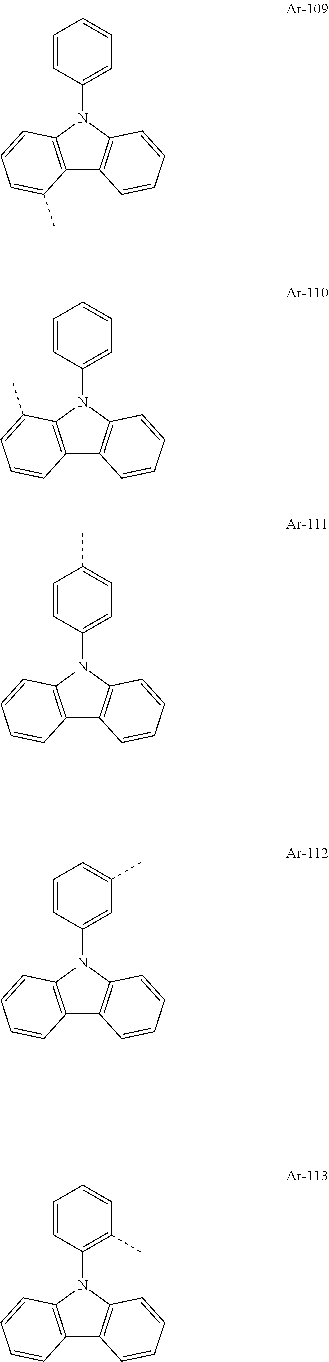

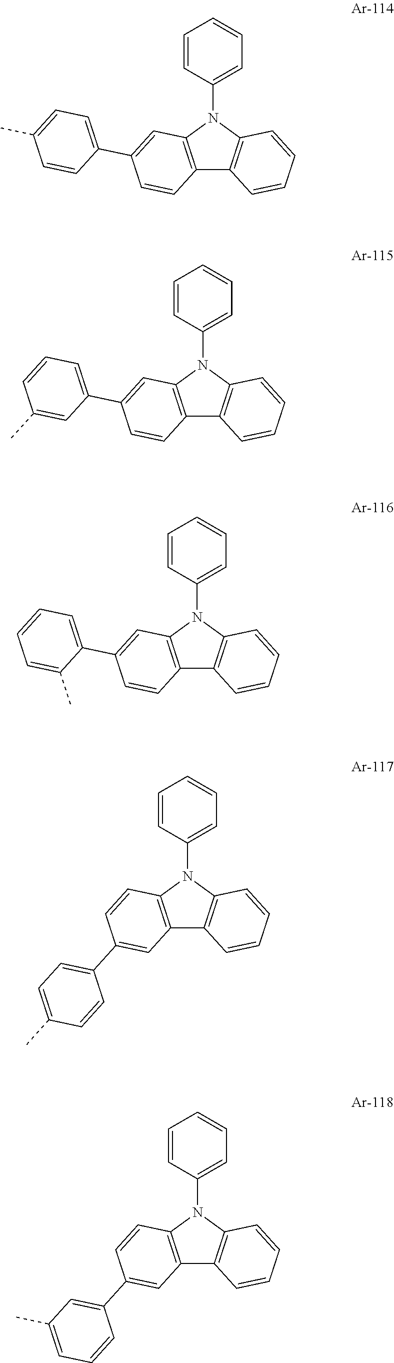

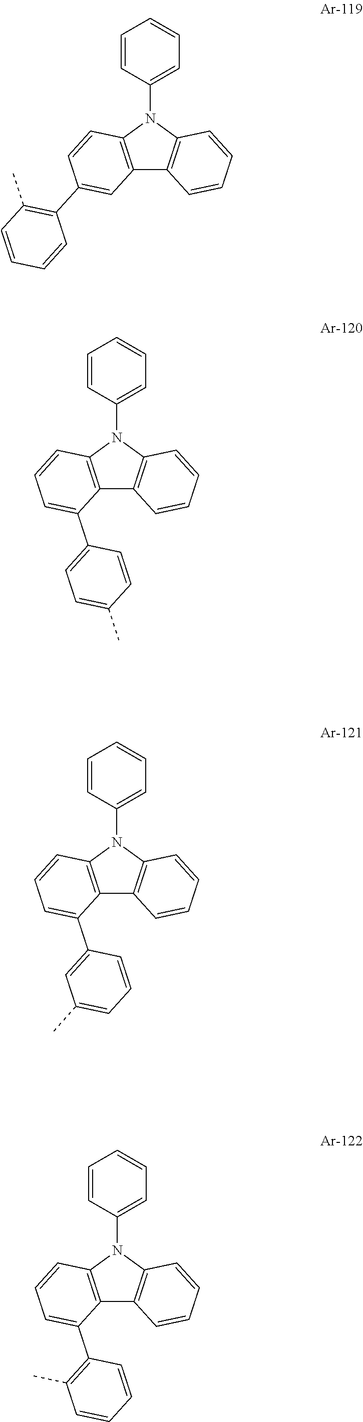

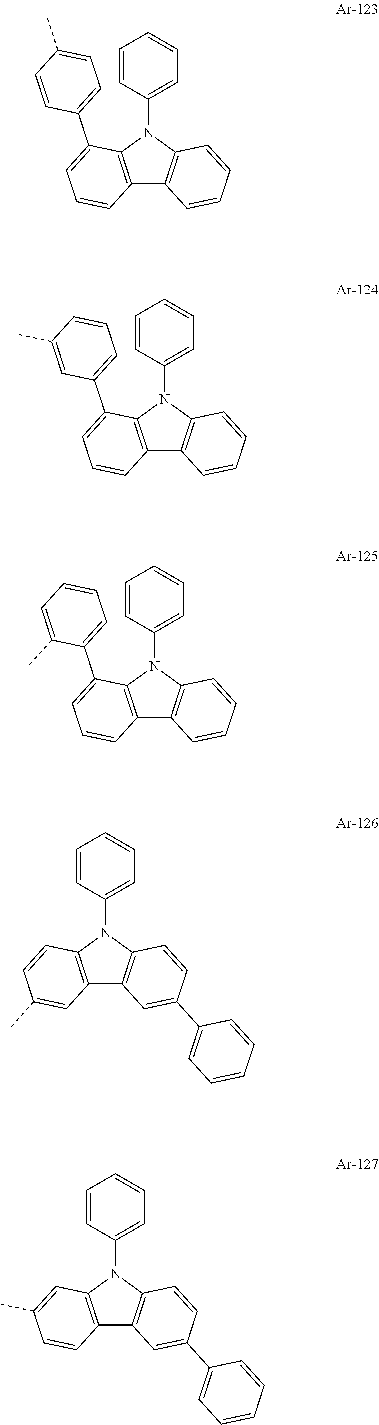

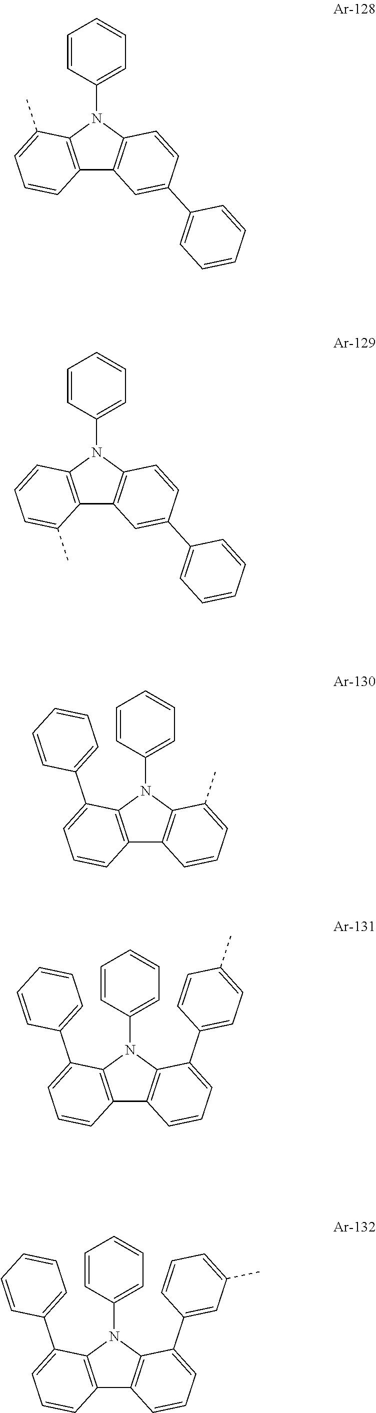

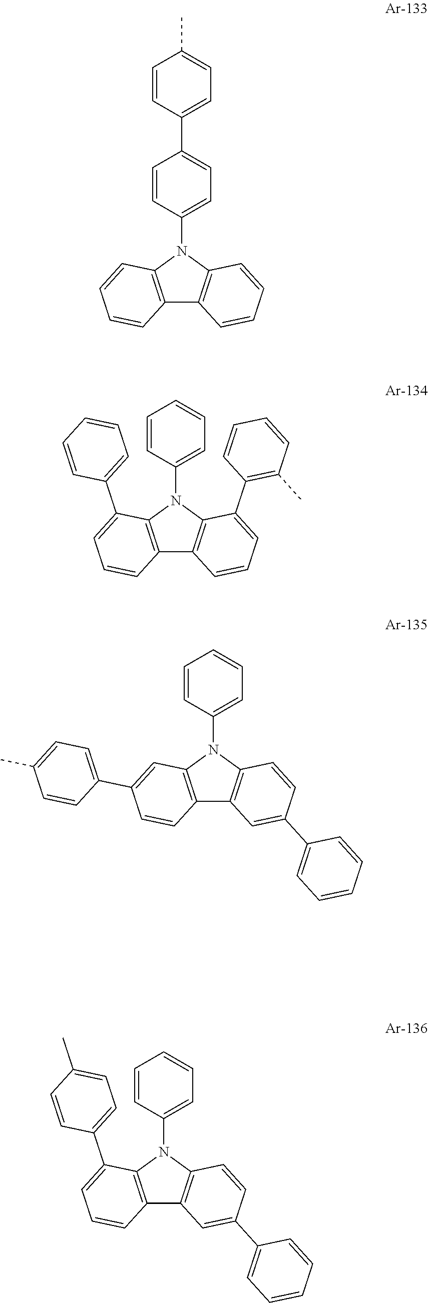

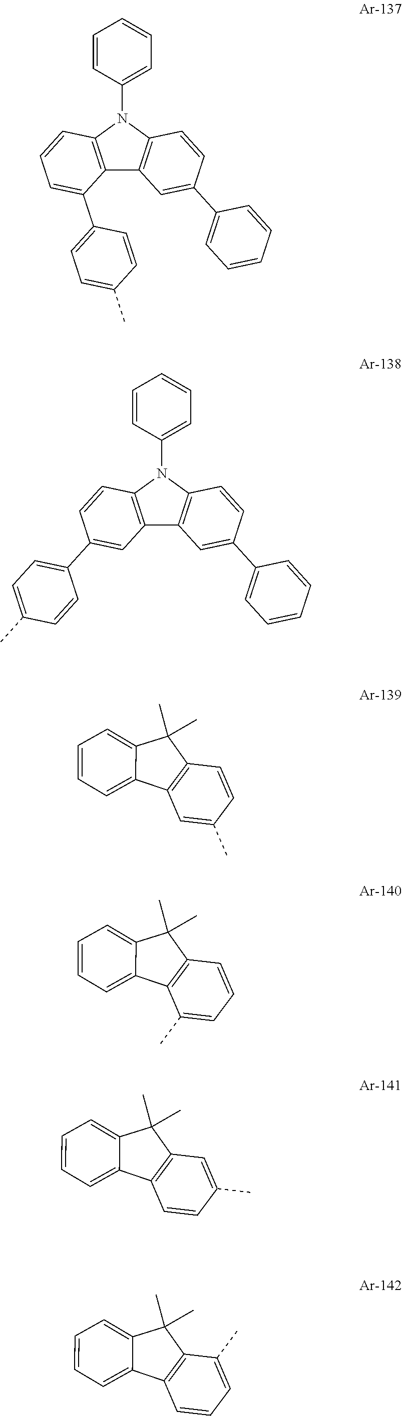

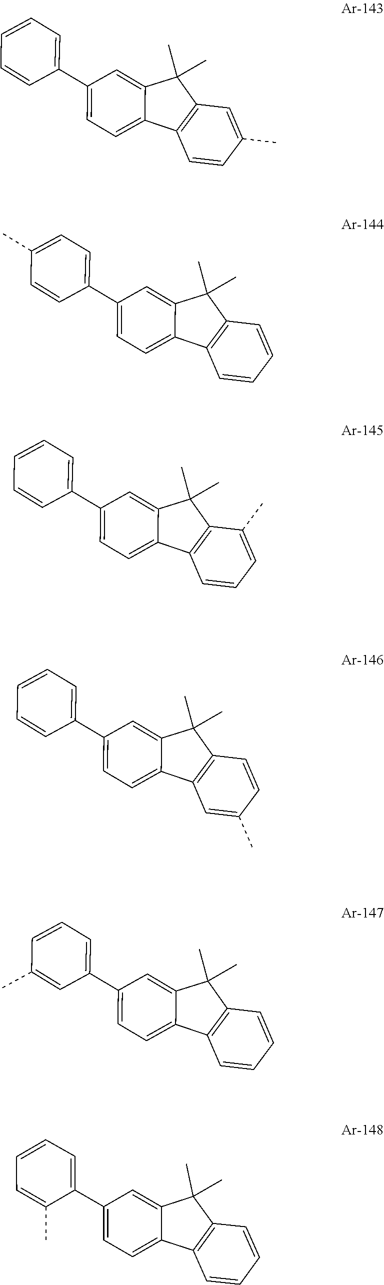

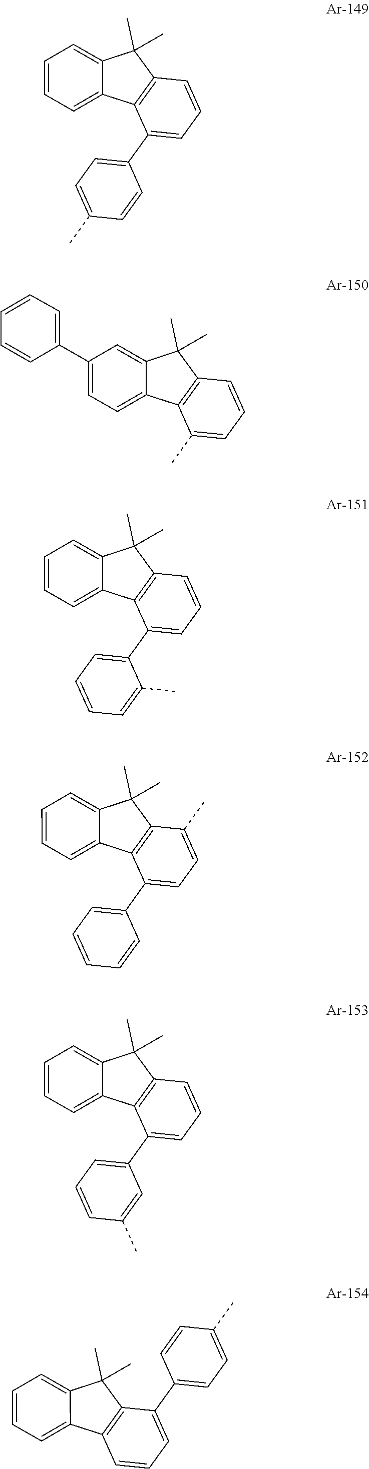

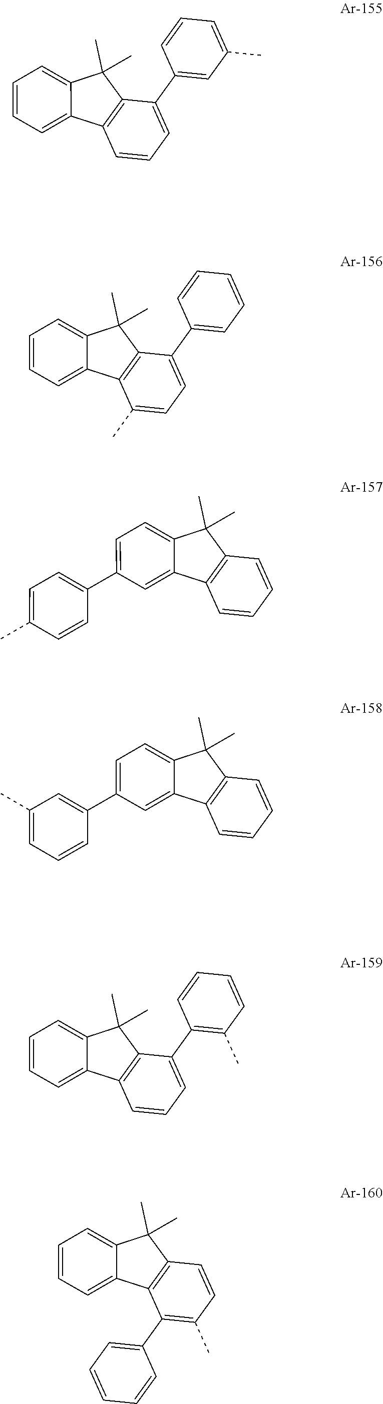

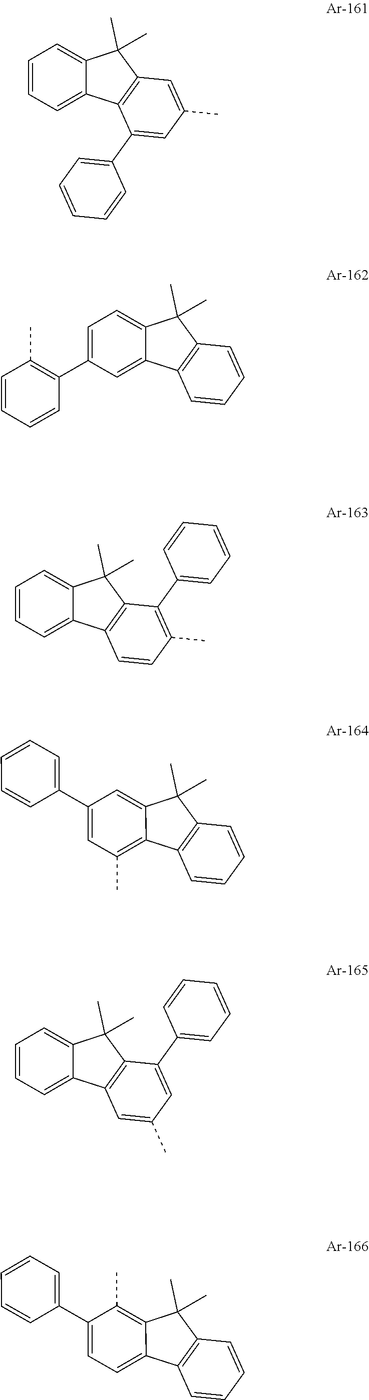

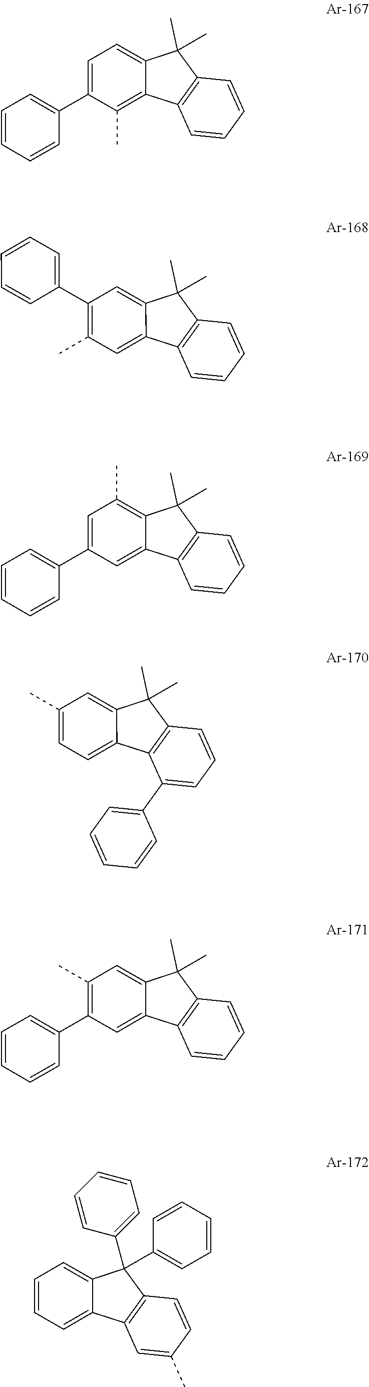

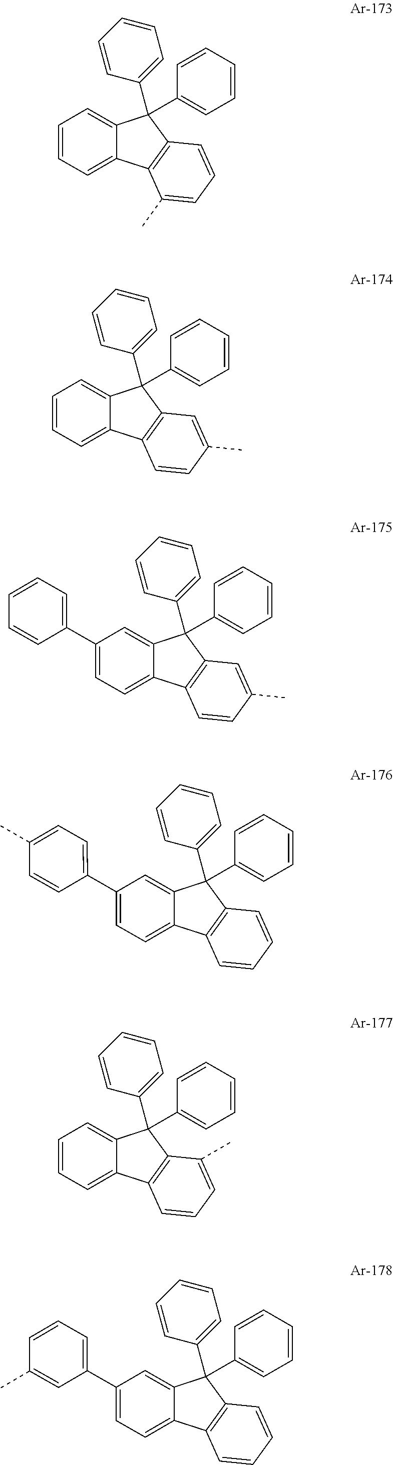

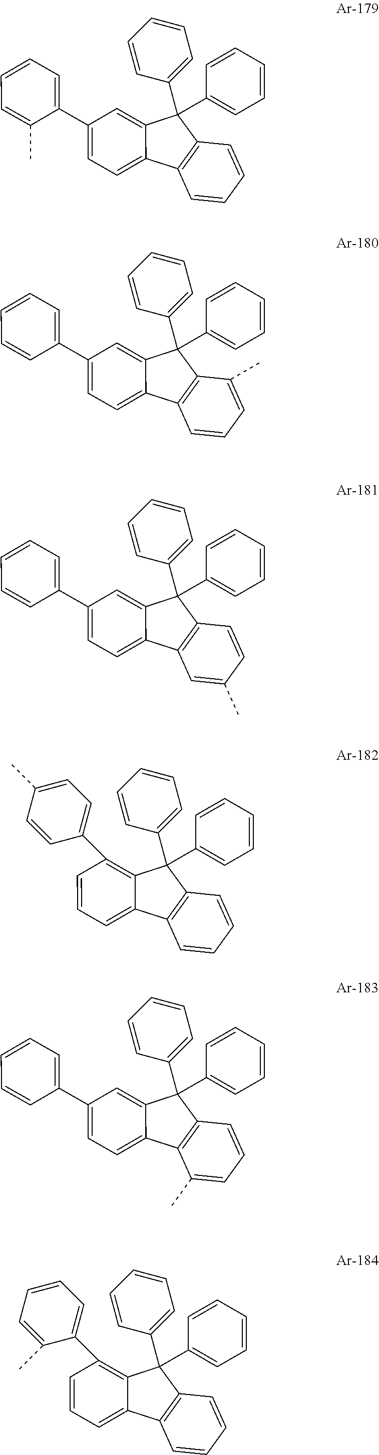

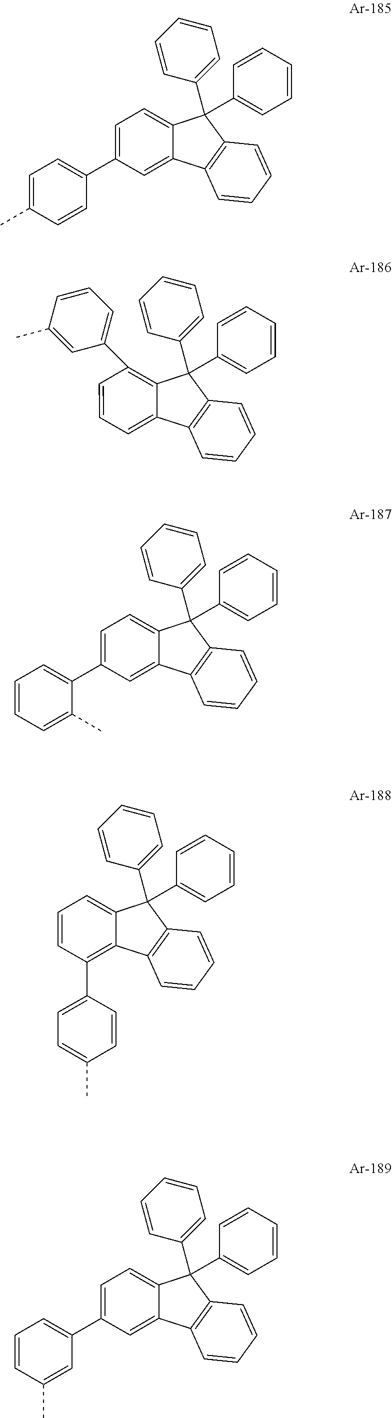

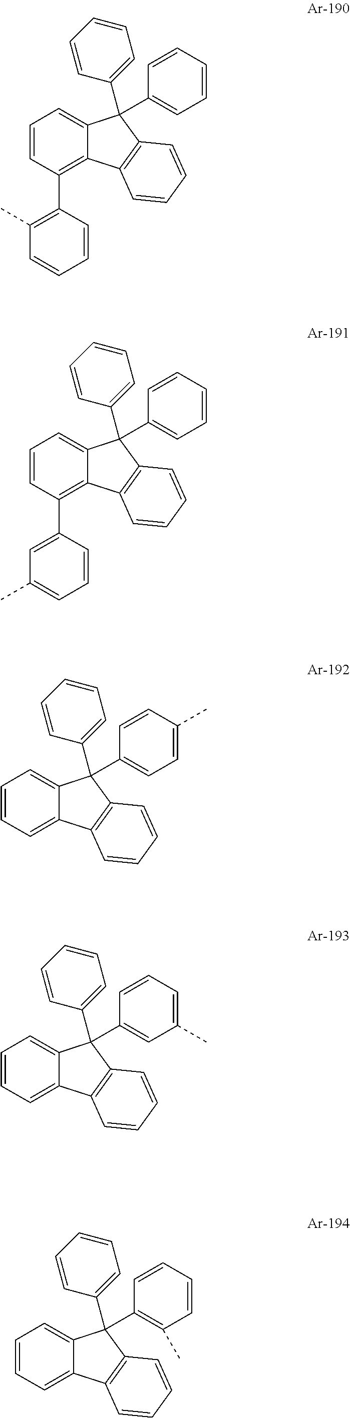

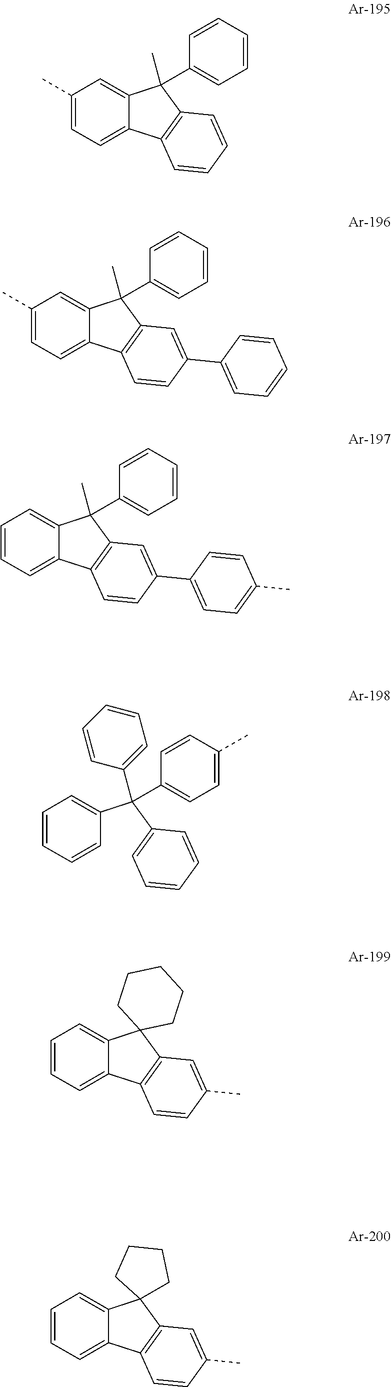

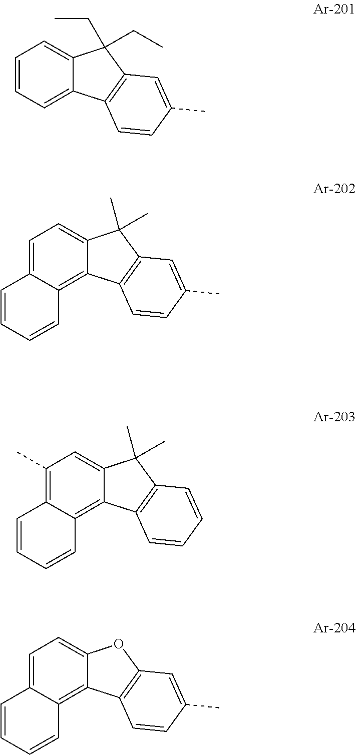

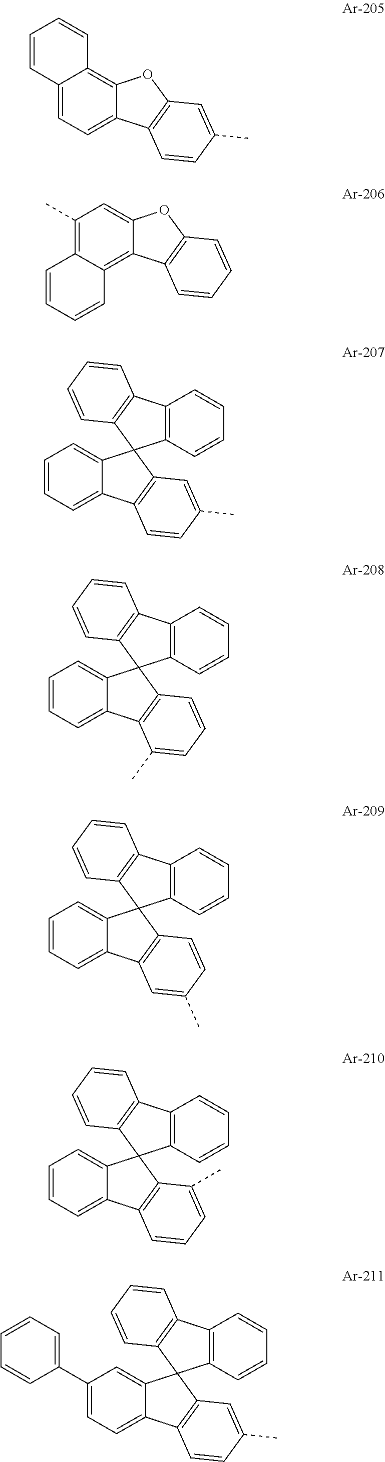

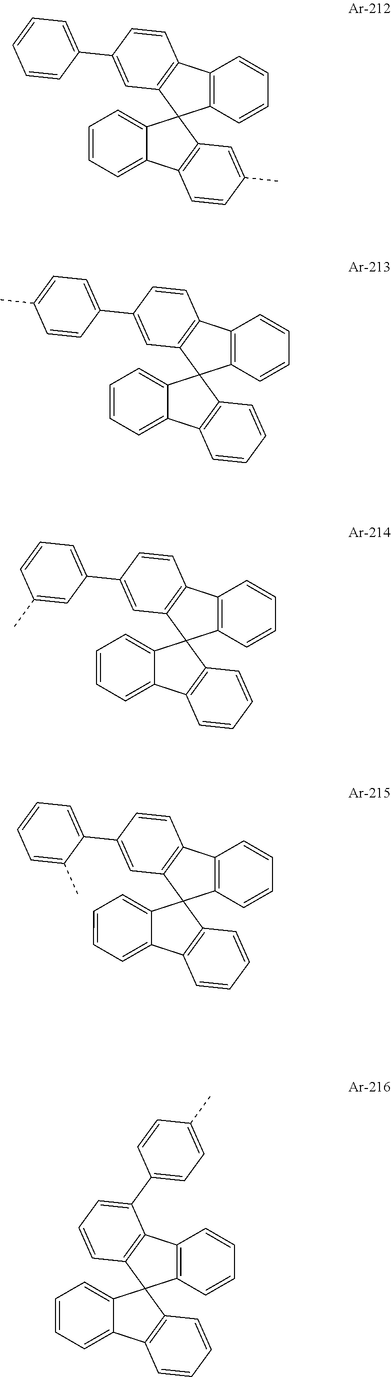

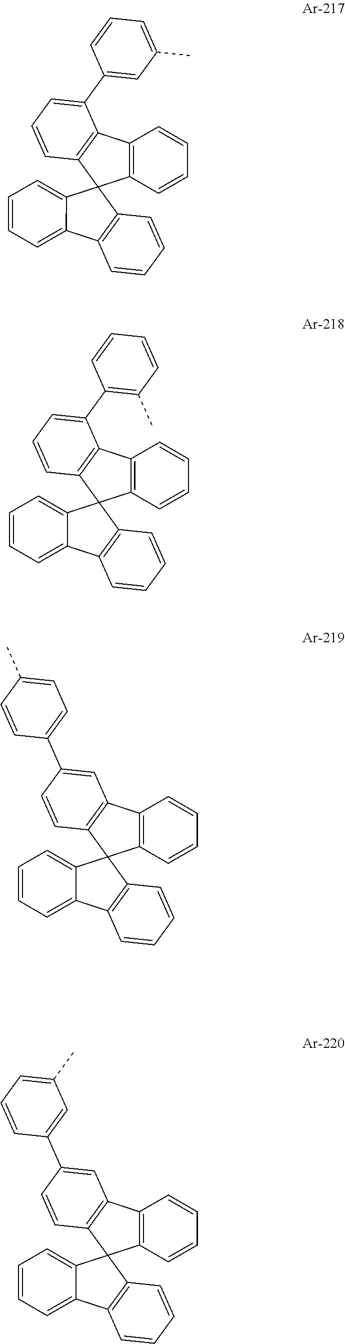

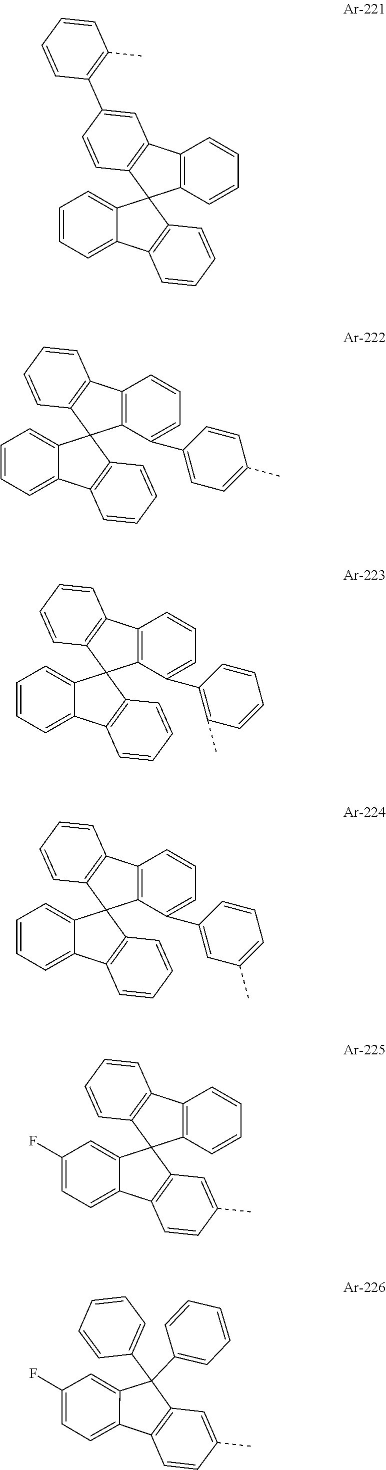

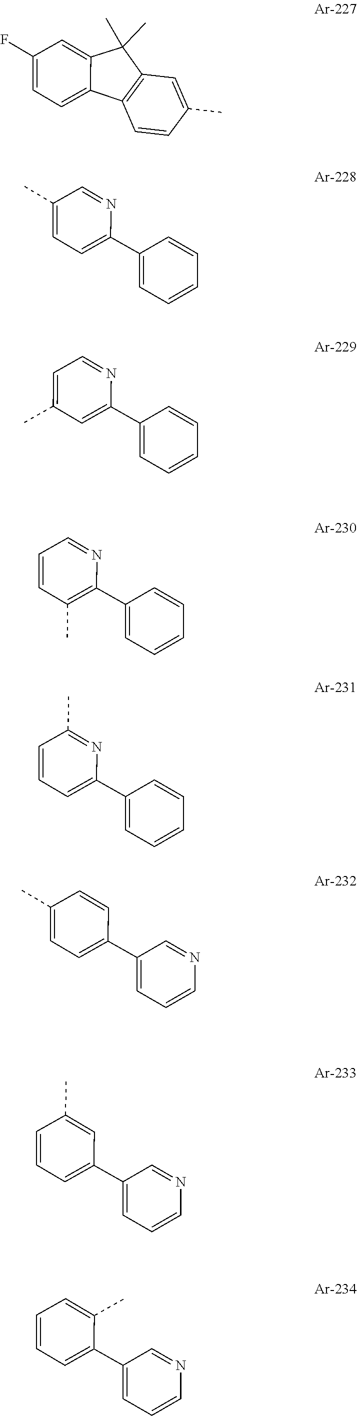

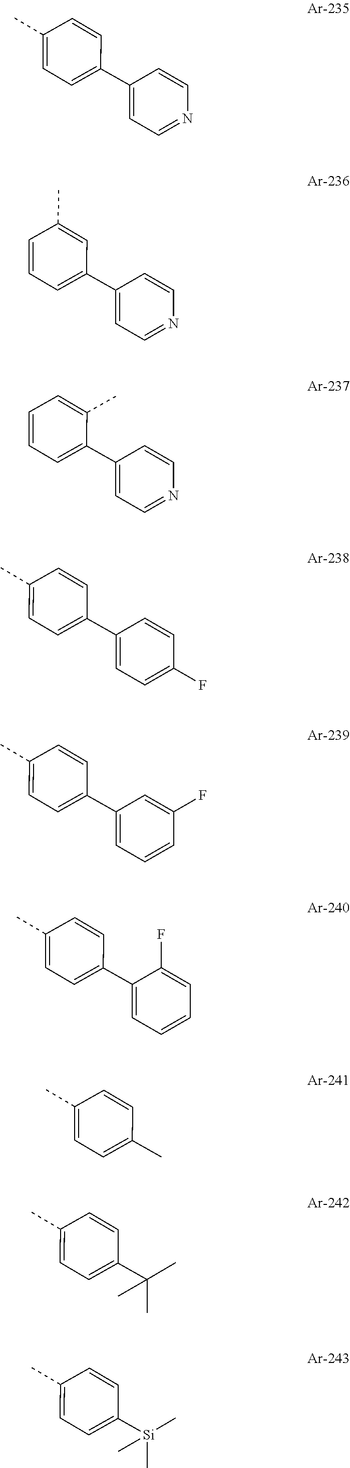

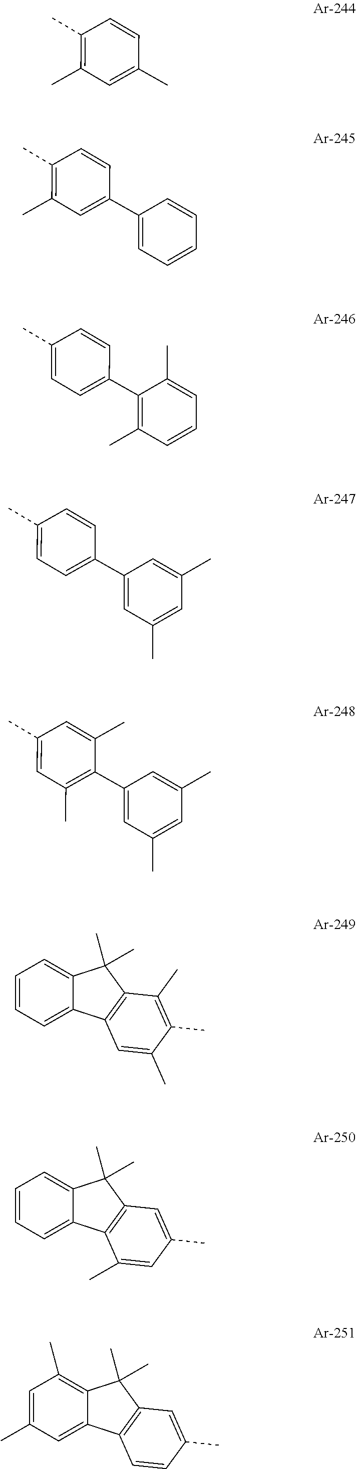

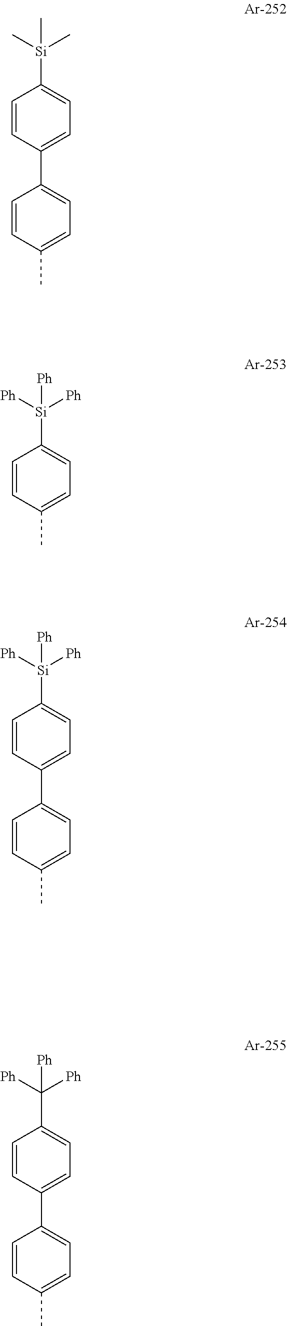

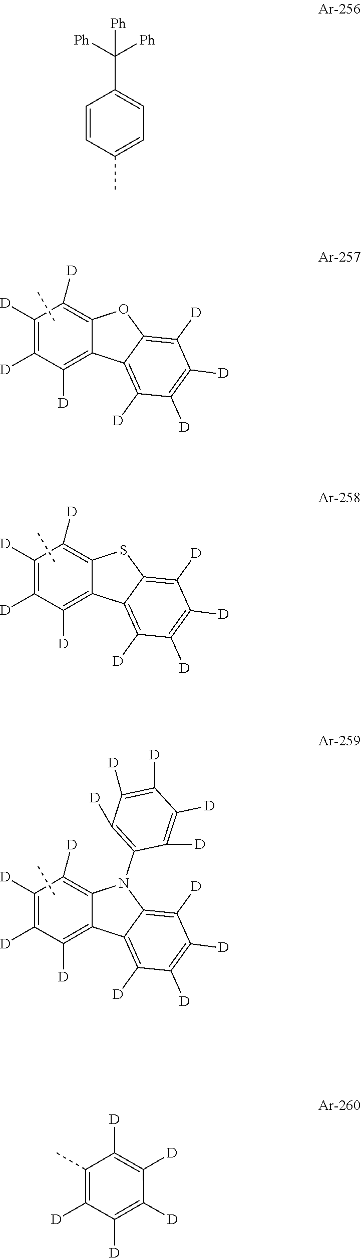

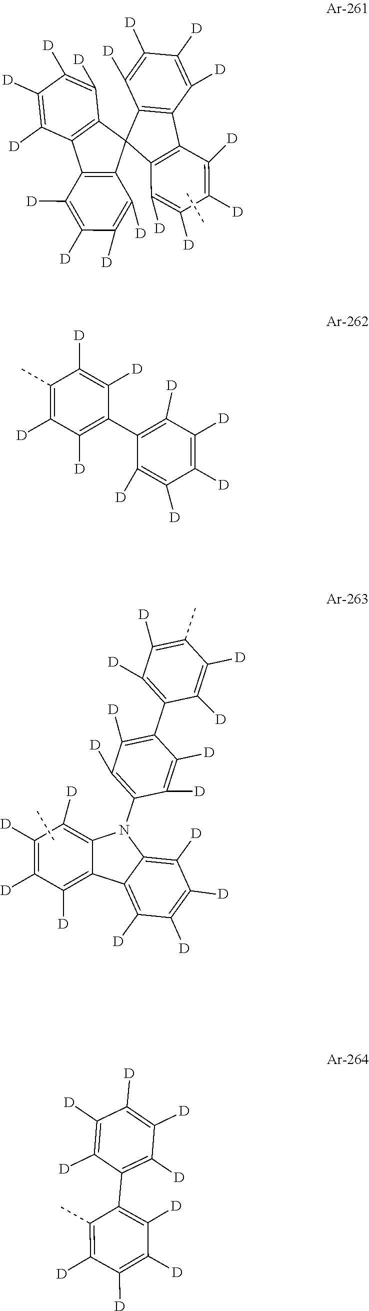

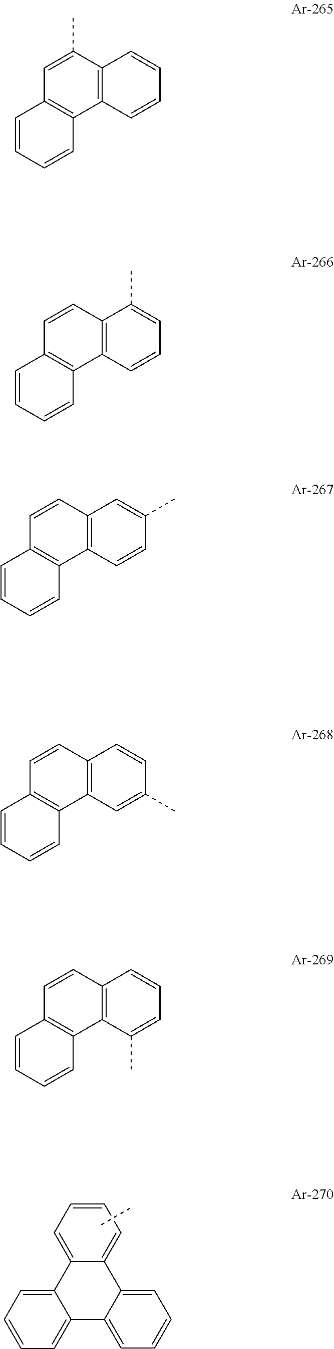

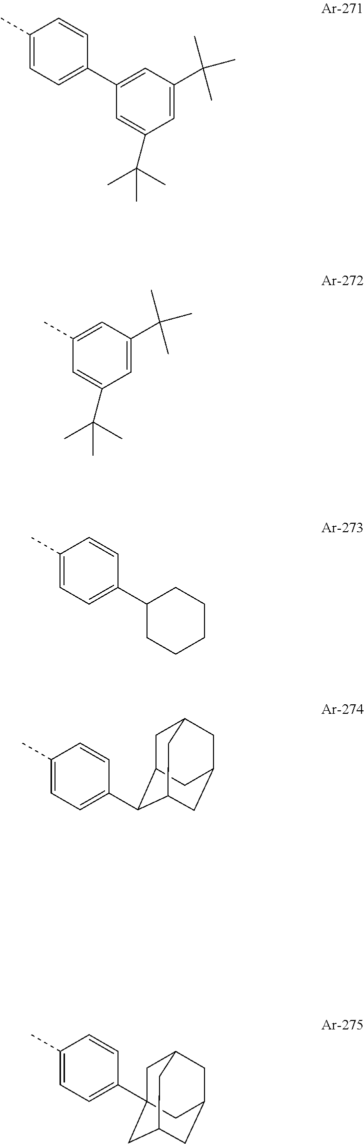

which are each substituted by R³ radicals at the positions shown as unsubstituted, where the R³ radicals in these cases are preferably H or D.

Ar^{L} is preferably an aromatic ring system which has 6 to 25 aromatic ring atoms and is substituted by R³ radicals, more preferably phenyl, biphenyl, naphthyl or fluorenyl, each substituted by R³ radicals; and most preferably phenyl substituted by R³ radicals.

T is preferably the same or different at each instance and is selected from a single bond, O and S, especially a single bond and O.

In a particularly preferred embodiment, T at each instance is a single bond. In an alternative particularly preferred embodiment, T at one instance in the formula in question is selected from a single bond, and at another instance in the formula in question is selected from O.

In addition, E is preferably a single bond, or n is 0, such that E is absent. More preferably, n is 0.

R⁰ is preferably the same or different at each instance and is selected from F, CN, Si(R⁴)₃, N(R⁴)₂, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where the alkyl and alkoxy groups mentioned, the aromatic ring systems mentioned and the heteroaromatic ring systems mentioned are each substituted by R⁴ radicals; and where one or more CH₂ groups in the alkyl or alkoxy groups mentioned may be replaced by —C≡C—, —R⁴C═CR⁴—, Si(R⁴)₂, C═O, C═NR⁴, —NR⁴—, —O—, —S—, —C(═O)O— or —C(═O)NR⁴—.

Preferably, the sum of x and y is 3, such that R⁰ is absent.

Preferably, m=0.

R¹ is preferably the same or different at each instance and is selected from H, D, F, CN, Si(R⁴)₃, N(R⁴)₂, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where the alkyl and alkoxy groups mentioned, the aromatic ring systems mentioned and the heteroaromatic ring systems mentioned are each substituted by R⁴ radicals; and where one or more CH₂ groups in the alkyl or alkoxy groups mentioned may be replaced by —C≡C—, —R⁴C═CR⁴—, Si(R⁴)₂, C═O, C═NR⁴, —NR⁴—, —O—, —S—, —C(═O)O— or —C(═O)NR⁴—.

Preferably, at least one R¹ group per aromatic ring in formula (G-1) or (G-2) or (G-3) is H, and at least one R¹ group per aromatic ring in formula (G-1) or (G-2) or (G-3) is D. More preferably, R¹ is the same or different at each instance and is selected from H and D, where at least one R¹ group per aromatic ring in formula (G-1) or (G-2) or (G-3) is H, and at least one R¹ group per aromatic ring in formula (G-1) or (G-2) or (G-3) is D. The ratio of R¹ radicals that are H and R¹ radicals that are D is preferably between 1:10 and 10:1, more preferably between 1:3 and 3:1, most preferably between 1:2 and 2:1.

R² is preferably the same or different at each instance and is selected from F, CN, Si(R⁴)₃, N(R⁴)₂, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where the alkyl and alkoxy groups mentioned, the aromatic ring systems mentioned and the heteroaromatic ring systems mentioned are each substituted by R⁴ radicals; and where one or more CH₂ groups in the alkyl or alkoxy groups mentioned may be replaced by —C≡C—, —R⁴C═CR⁴—, Si(R⁴)₂, C═O, C═NR⁴, —NR⁴—, —O—, —S—, —C(═O)O— or —C(═O)NR⁴—. More preferably, R² is the same or different at each instance and is selected from straight-chain alkyl groups having 1 to 20 carbon atoms, branched or cyclic alkyl groups having 3 to 20 carbon atoms, aromatic ring systems having 6 to 40 aromatic ring atoms and heteroaromatic ring systems having 5 to 40 aromatic ring atoms, where said alkyl groups, said aromatic ring systems and said heteroaromatic ring systems are each substituted by R⁴ radicals. Most preferably, R² is the same or different at each instance and is selected from methyl and phenyl, each substituted by R⁴ radicals, most preferably from unsubstituted methyl and phenyl. R⁴ radicals on R² radicals are preferably not H, and preferably do not contain a deuterium atom.

Preferably, R³ is the same or different at each instance and is selected from H, D, F, CN, Si(R⁴)₃, N(R⁴)₂, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where the alkyl and alkoxy groups mentioned, the aromatic ring systems mentioned and the heteroaromatic ring systems mentioned are each substituted by R⁴ radicals; and where one or more CH₂ groups in the alkyl or alkoxy groups mentioned may be replaced by —C≡C—, —R⁴C═CR⁴—, Si(R⁴)₂, C═O, C═NR⁴, —NR⁴—, —O—, —S—, —C(═O)O— or —C(═O)NR⁴—. Preferably, at least one R³ group per aromatic ring of the Ar¹ group is H, and at least one R¹ group per aromatic ring of the Ar¹ group is D.

In a preferred embodiment, the ratio of R³ radicals that are H and R³ radicals that are D is between 1:10 and 10:1, more preferably between 1:3 and 3:1, most preferably between 1:2 and 2:1.

In an alternative preferred embodiment, R³ is not D.

Preferably, R⁴ is the same or different at each instance and is selected from H, D, F, CN, Si(R⁵)₃, N(R⁵)₂, straight-chain alkyl or alkoxy groups having 1 to 20 carbon atoms, branched or cyclic alkyl or alkoxy groups having 3 to 20 carbon atoms, aromatic ring systems having 6 to 40 aromatic ring atoms and heteroaromatic ring systems having 5 to 40 aromatic ring atoms; where the alkyl and alkoxy groups mentioned, the aromatic ring systems mentioned and the heteroaromatic ring systems mentioned are each substituted by R⁵ radicals; and where one or more CH₂ groups in the alkyl or alkoxy groups mentioned may be replaced by —C≡C—, —R⁵C═CR⁵—, Si(R⁵)₂, C═O, C═NR⁵, —NR⁵—, —O—, —S—, —C(═O)O— or —C(═O)NR⁵—. More preferably, R⁴ is the same or different at each instance and is selected from H, D, F, CN, straight-chain alkyl groups having 1 to 20 carbon atoms, branched or cyclic alkyl groups having 3 to 20 carbon atoms, aromatic ring systems having 6 to 40 aromatic ring atoms and heteroaromatic ring systems having 5 to 40 aromatic ring atoms. The ratio of R⁴ radicals that are H and R⁴ radicals that are D is preferably between 1:10 and 10:1, more preferably between 1:3 and 3:1, most preferably between 1:2 and 2:1.

Preferably, R⁵ is the same or different at each instance and is selected from H, D, F, CN, alkyl groups having 1 to 20 carbon atoms, aromatic ring systems having 6 to 40 aromatic ring atoms, and heteroaromatic ring systems having 5 to 40 aromatic ring atoms. The ratio of R⁵ radicals that are H and R⁵ radicals that are D is preferably between 1:10 and 10:1, more preferably between 1:3 and 3:1, most preferably between 1:2 and 2:1.

x is preferably 2. Index y is preferably 1. More preferably, x is 2 and y is 1.

Preferred embodiments of compounds of the formula (I) are shown in the following table:

| | |
|---|---|
| 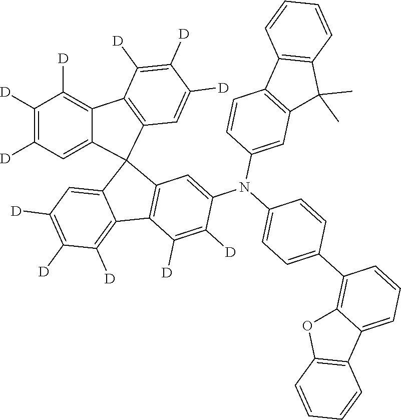 [SMILES: [2H]c1cc2c(c([2H])c1[2H])-c1c(cc([2H])c([2H])c1[2H])C21c2cc([2H])c([2H])c([2H])c2-c2c1cc(N(c1ccc(-c3cccc4c3oc3ccccc34)cc1)c1ccc3c(c1)C(C)(C)c1ccccc1-3)c([2H])c2[2H]] | 1 |
| 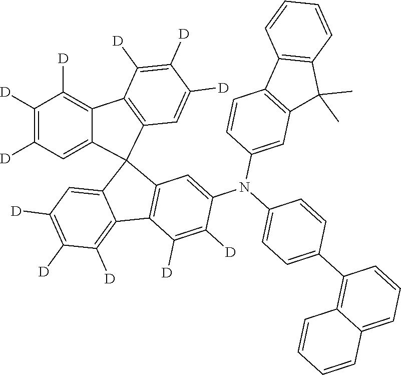 [SMILES: [2H]c1cc2c(c([2H])c1[2H])-c1c(cc([2H])c([2H])c1[2H])C21c2cc([2H])c([2H])c([2H])c2-c2c1cc(N(c1ccc(-c3cccc4ccccc34)cc1)c1ccc3c(c1)C(C)(C)c1ccccc1-3)c([2H])c2[2H]] | 2 |
| 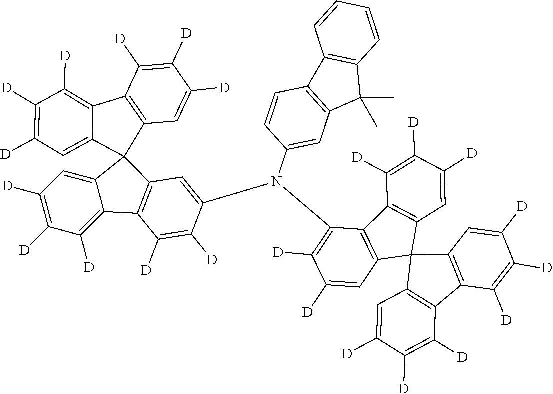 [SMILES: [2H]c1cc2c(c([2H])c1[2H])-c1c(cc([2H])c([2H])c1[2H])C21c2cc([2H])c([2H])c([2H])c2-c2c1cc(N(c1ccc3c(c1)C(C)(C)c1ccccc1-3)c1c([2H])c([2H])cc3c1-c1c(cc([2H])c([2H])c1[2H])C31c3cc([2H])c([2H])c([2H])c3-c3c1cc([2H])c([2H])c3[2H])c([2H])c2[2H]] | 3 |
| 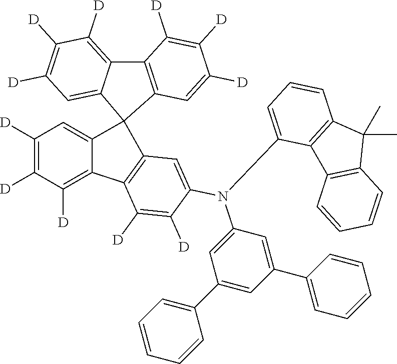 [SMILES: [2H]c1cc2c(c([2H])c1[2H])-c1c(cc([2H])c([2H])c1[2H])C21c2cc([2H])c([2H])c([2H])c2-c2c1cc(N(c1cc(-c3ccccc3)cc(-c3ccccc3)c1)c1cccc3c1-c1ccccc1C3(C)C)c([2H])c2[2H]] | 4 |
| 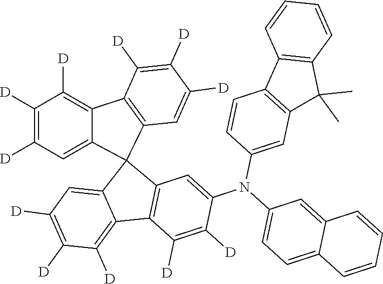 [SMILES: [2H]c1cc2c(c([2H])c1[2H])-c1c(cc([2H])c([2H])c1[2H])C21c2cc([2H])c([2H])c([2H])c2-c2c1cc(N(c1ccc3c(c1)C(C)(C)c1ccccc1-3)c1ccc3ccccc3c1)c([2H])c2[2H]] | 5 |
| 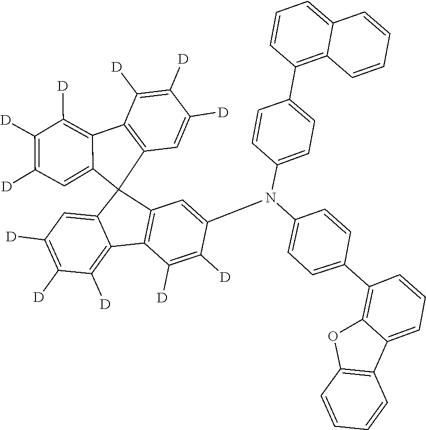 [SMILES: [2H]c1cc2c(c([2H])c1[2H])-c1c(cc([2H])c([2H])c1[2H])C21c2cc([2H])c([2H])c([2H])c2-c2c1cc(N(c1ccc(-c3cccc4ccccc34)cc1)c1ccc(-c3cccc4c3oc3ccccc34)cc1)c([2H])c2[2H]] | 6 |
| 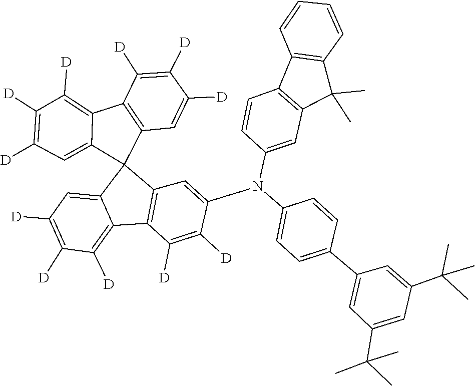 [SMILES: [2H]c1cc2c(c([2H])c1[2H])-c1c(cc([2H])c([2H])c1[2H])C21c2cc([2H])c([2H])c([2H])c2-c2c1cc(N(c1ccc(-c3cc(C(C)(C)C)cc(C(C)(C)C)c3)cc1)c1ccc3c(c1)C(C)(C)c1ccccc1-3)c([2H])c2[2H]] | 7 |
| 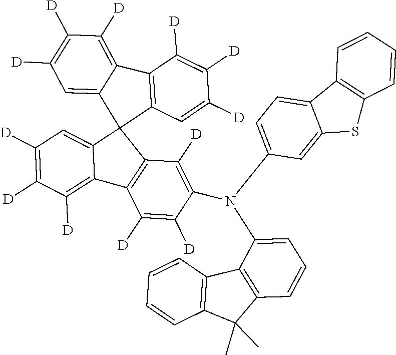 [SMILES: [2H]c1cc2c(c([2H])c1[2H])-c1c(cc([2H])c([2H])c1[2H])C21c2cc([2H])c([2H])c([2H])c2-c2c([2H])c([2H])c(N(c3ccc4c(c3)sc3ccccc34)c3cccc4c3-c3ccccc3C4(C)C)c([2H])c21] | 8 |
| 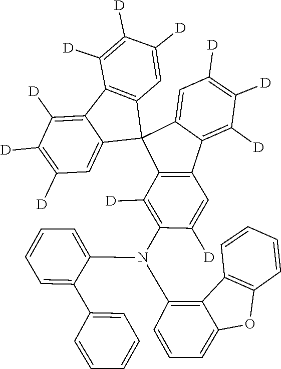 [SMILES: [2H]c1cc2c(c([2H])c1[2H])-c1cc([2H])c(N(c3ccccc3-c3ccccc3)c3cccc4oc5ccccc5c34)c([2H])c1C21c2cc([2H])c([2H])c([2H])c2-c2c1cc([2H])c([2H])c2[2H]] | 9 |
| 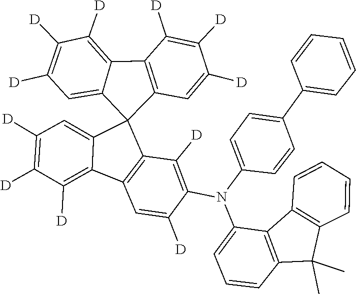 [SMILES: [2H]c1cc2c(c([2H])c1[2H])-c1cc([2H])c(N(c3ccc(-c4ccccc4)cc3)c3cccc4c3-c3ccccc3C4(C)C)c([2H])c1C21c2cc([2H])c([2H])c([2H])c2-c2c1cc([2H])c([2H])c2[2H]] | 10 |
| 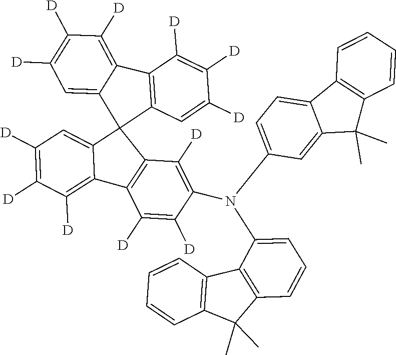 [SMILES: [2H]c1cc2c(c([2H])c1[2H])-c1c(cc([2H])c([2H])c1[2H])C21c2cc([2H])c([2H])c([2H])c2-c2c([2H])c([2H])c(N(c3ccc4c(c3)C(C)(C)c3ccccc3-4)c3cccc4c3-c3ccccc3C4(C)C)c([2H])c21] | 11 |
| 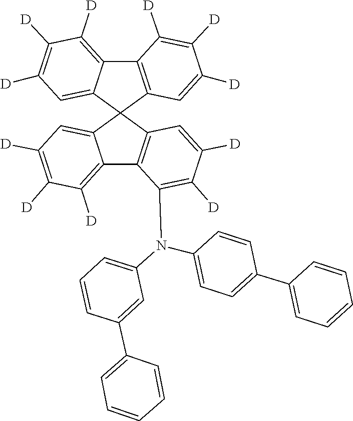 [SMILES: [2H]c1cc2c(c([2H])c1[2H])-c1c(cc([2H])c([2H])c1[2H])C21c2cc([2H])c([2H])c([2H])c2-c2c1cc([2H])c([2H])c2N(c1ccc(-c2ccccc2)cc1)c1cccc(-c2ccccc2)c1] | 12 |
| 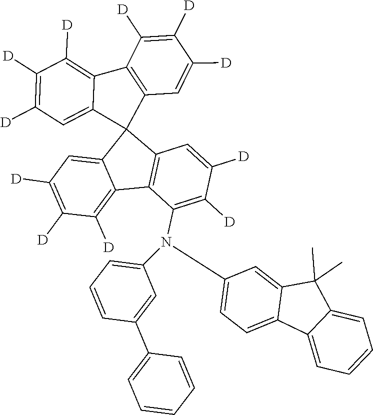 [SMILES: [2H]c1cc2c(c([2H])c1[2H])-c1c(cc([2H])c([2H])c1[2H])C21c2cc([2H])c([2H])c([2H])c2-c2c1cc([2H])c([2H])c2N(c1cccc(-c2ccccc2)c1)c1ccc2c(c1)C(C)(C)c1ccccc1-2] | 13 |
| 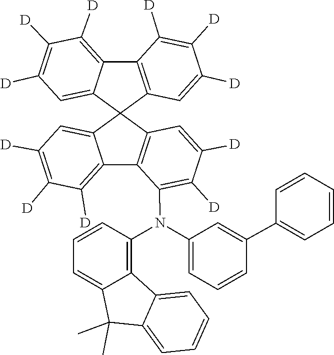 [SMILES: [2H]c1cc2c(c([2H])c1[2H])-c1c(cc([2H])c([2H])c1[2H])C21c2cc([2H])c([2H])c([2H])c2-c2c1cc([2H])c([2H])c2N(c1cccc(-c2ccccc2)c1)c1cccc2c1-c1ccccc1C2(C)C] | 14 |
| 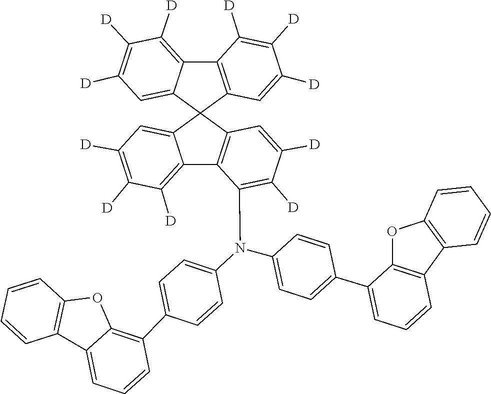 [SMILES: [2H]c1cc2c(c([2H])c1[2H])-c1c(cc([2H])c([2H])c1[2H])C21c2cc([2H])c([2H])c([2H])c2-c2c1cc([2H])c([2H])c2N(c1ccc(-c2cccc3c2oc2ccccc23)cc1)c1ccc(-c2cccc3c2oc2ccccc23)cc1] | 15 |
| 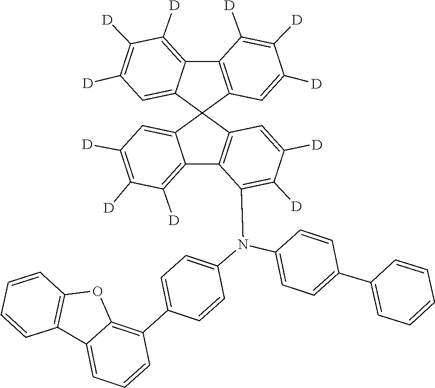 [SMILES: [2H]c1cc2c(c([2H])c1[2H])-c1c(cc([2H])c([2H])c1[2H])C21c2cc([2H])c([2H])c([2H])c2-c2c1cc([2H])c([2H])c2N(c1ccc(-c2ccccc2)cc1)c1ccc(-c2cccc3c2oc2ccccc23)cc1] | 16 |
| 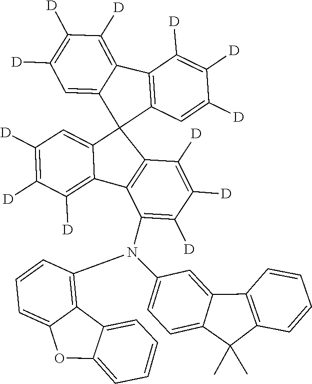 [SMILES: [2H]c1cc2c(c([2H])c1[2H])-c1c(cc([2H])c([2H])c1[2H])C21c2cc([2H])c([2H])c([2H])c2-c2c(N(c3ccc4c(c3)-c3ccccc3C4(C)C)c3cccc4oc5ccccc5c34)c([2H])c([2H])c([2H])c21] | 17 |
| 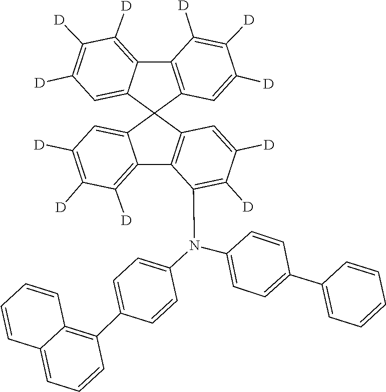 [SMILES: [2H]c1cc2c(c([2H])c1[2H])-c1c(cc([2H])c([2H])c1[2H])C21c2cc([2H])c([2H])c([2H])c2-c2c1cc([2H])c([2H])c2N(c1ccc(-c2ccccc2)cc1)c1ccc(-c2cccc3ccccc23)cc1] | 18 |
| 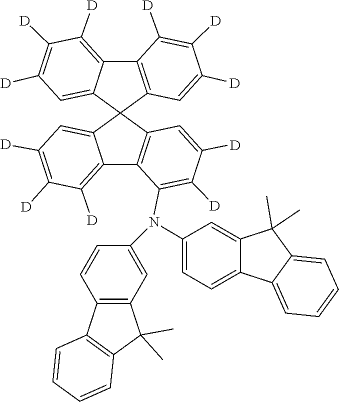 [SMILES: [2H]c1cc2c(c([2H])c1[2H])-c1c(cc([2H])c([2H])c1[2H])C21c2cc([2H])c([2H])c([2H])c2-c2c1cc([2H])c([2H])c2N(c1ccc2c(c1)C(C)(C)c1ccccc1-2)c1ccc2c(c1)C(C)(C)c1ccccc1-2] | 19 |
| 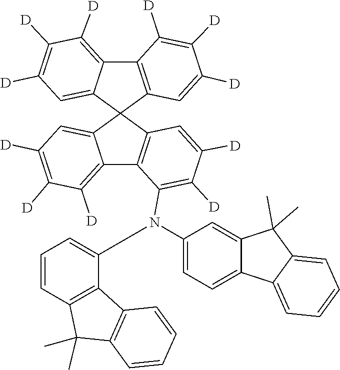 [SMILES: [2H]c1cc2c(c([2H])c1[2H])-c1c(cc([2H])c([2H])c1[2H])C21c2cc([2H])c([2H])c([2H])c2-c2c1cc([2H])c([2H])c2N(c1ccc2c(c1)C(C)(C)c1ccccc1-2)c1cccc2c1-c1ccccc1C2(C)C] | 20 |
| 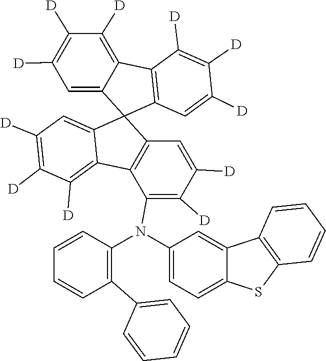 [SMILES: [2H]c1cc2c(c([2H])c1[2H])-c1c(cc([2H])c([2H])c1[2H])C21c2cc([2H])c([2H])c([2H])c2-c2c1cc([2H])c([2H])c2N(c1ccc2sc3ccccc3c2c1)c1ccccc1-c1ccccc1] | 21 |
| 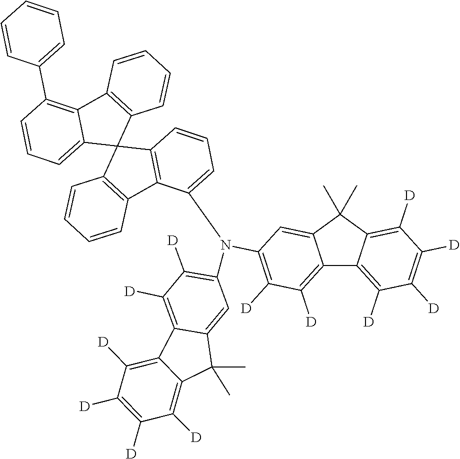 [SMILES: [2H]c1c(N(c2cc3c(c([2H])c2[2H])-c2c([2H])c([2H])c([2H])c([2H])c2C3(C)C)c2cccc3c2-c2ccccc2C32c3ccccc3-c3c(-c4ccccc4)cccc32)cc2c(c1[2H])-c1c([2H])c([2H])c([2H])c([2H])c1C2(C)C] | 22 |
| 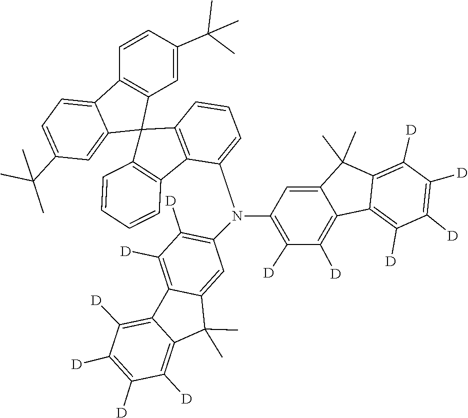 [SMILES: [2H]c1c(N(c2cc3c(c([2H])c2[2H])-c2c([2H])c([2H])c([2H])c([2H])c2C3(C)C)c2cccc3c2-c2ccccc2C32c3cc(C(C)(C)C)ccc3-c3ccc(C(C)(C)C)cc32)cc2c(c1[2H])-c1c([2H])c([2H])c([2H])c([2H])c1C2(C)C] | 23 |
| 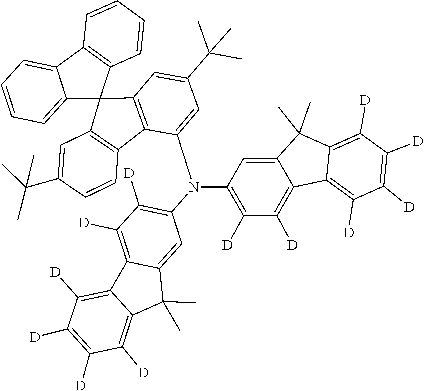 [SMILES: [2H]c1c(N(c2cc3c(c([2H])c2[2H])-c2c([2H])c([2H])c([2H])c([2H])c2C3(C)C)c2cc(C(C)(C)C)cc3c2-c2ccc(C(C)(C)C)cc2C32c3ccccc3-c3ccccc32)cc2c(c1[2H])-c1c([2H])c([2H])c([2H])c([2H])c1C2(C)C] | 24 |
| 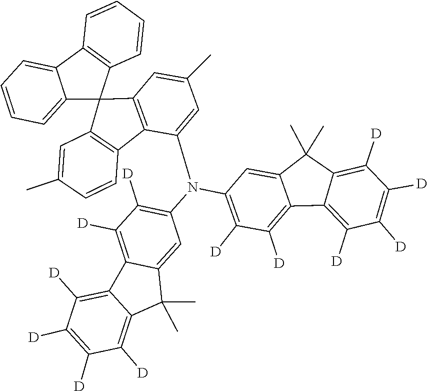 [SMILES: [2H]c1c(N(c2cc3c(c([2H])c2[2H])-c2c([2H])c([2H])c([2H])c([2H])c2C3(C)C)c2cc(C)cc3c2-c2ccc(C)cc2C32c3ccccc3-c3ccccc32)cc2c(c1[2H])-c1c([2H])c([2H])c([2H])c([2H])c1C2(C)C] | 25 |
| 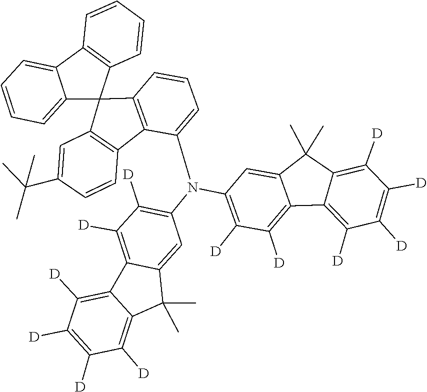 [SMILES: [2H]c1c(N(c2cc3c(c([2H])c2[2H])-c2c([2H])c([2H])c([2H])c([2H])c2C3(C)C)c2cccc3c2-c2ccc(C(C)(C)C)cc2C32c3ccccc3-c3ccccc32)cc2c(c1[2H])-c1c([2H])c([2H])c([2H])c([2H])c1C2(C)C] | 26 |
| 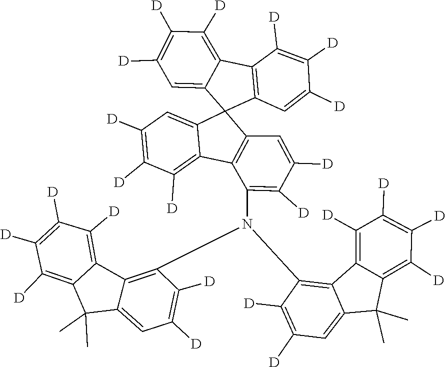 [SMILES: [2H]c1cc2c(c([2H])c1[2H])-c1c(cc([2H])c([2H])c1[2H])C21c2cc([2H])c([2H])c([2H])c2-c2c1cc([2H])c([2H])c2N(c1c([2H])c([2H])cc2c1-c1c([2H])c([2H])c([2H])c([2H])c1C2(C)C)c1c([2H])c([2H])cc2c1-c1c([2H])c([2H])c([2H])c([2H])c1C2(C)C] | 27 |
| 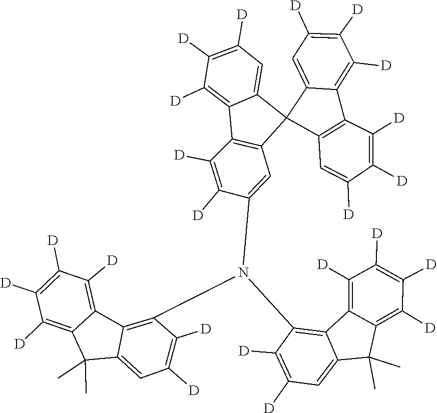 [SMILES: [2H]c1cc2c(c([2H])c1[2H])-c1c(cc([2H])c([2H])c1[2H])C21c2cc([2H])c([2H])c([2H])c2-c2c1cc(N(c1c([2H])c([2H])cc3c1-c1c([2H])c([2H])c([2H])c([2H])c1C3(C)C)c1c([2H])c([2H])cc3c1-c1c([2H])c([2H])c([2H])c([2H])c1C3(C)C)c([2H])c2[2H]] | 28 |
| 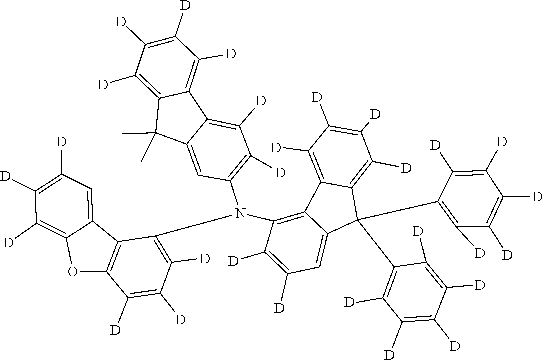 [SMILES: [2H]c1cc2c(c(N(c3cc4c(c([2H])c3[2H])-c3c([2H])c([2H])c([2H])c([2H])c3C4(C)C)c3c([2H])c([2H])c([2H])c4oc5c([2H])c([2H])c([2H])cc5c34)c1[2H])-c1c([2H])c([2H])c([2H])c([2H])c1C2(c1c([2H])c([2H])c([2H])c([2H])c1[2H])c1c([2H])c([2H])c([2H])c([2H])c1[2H]] | 29 |
| 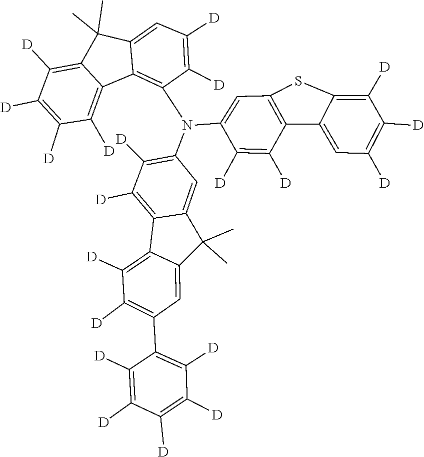 [SMILES: [2H]c1cc2c(c(N(c3cc4c(c([2H])c3[2H])-c3c(cc(-c5c([2H])c([2H])c([2H])c([2H])c5[2H])c([2H])c3[2H])C4(C)C)c3cc4sc5c([2H])c([2H])c([2H])cc5c4c([2H])c3[2H])c1[2H])-c1c([2H])c([2H])c([2H])c([2H])c1C2(C)C] | 30 |
| 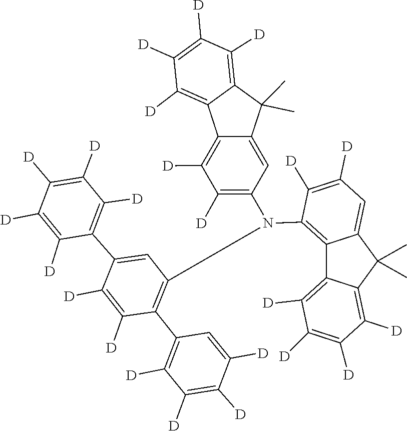 [SMILES: [2H]c1cc(-c2c(N(c3cc4c(c([2H])c3[2H])-c3c([2H])c([2H])c([2H])c([2H])c3C4(C)C)c3c([2H])c([2H])cc4c3-c3c([2H])c([2H])c([2H])c([2H])c3C4(C)C)cc(-c3c([2H])c([2H])c([2H])c([2H])c3[2H])c([2H])c2[2H])c([2H])c([2H])c1[2H]] | 31 |
| 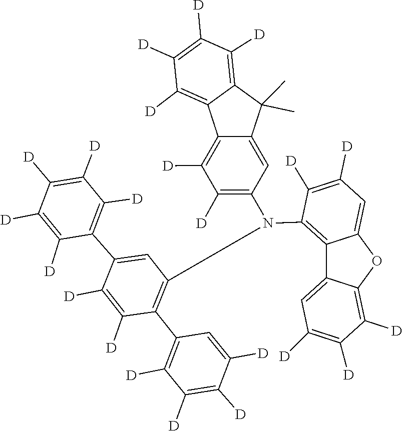 [SMILES: [2H]c1cc(-c2c(N(c3cc4c(c([2H])c3[2H])-c3c([2H])c([2H])c([2H])c([2H])c3C4(C)C)c3c([2H])c([2H])cc4oc5c([2H])c([2H])c([2H])cc5c34)cc(-c3c([2H])c([2H])c([2H])c([2H])c3[2H])c([2H])c2[2H])c([2H])c([2H])c1[2H]] | 32 |
| 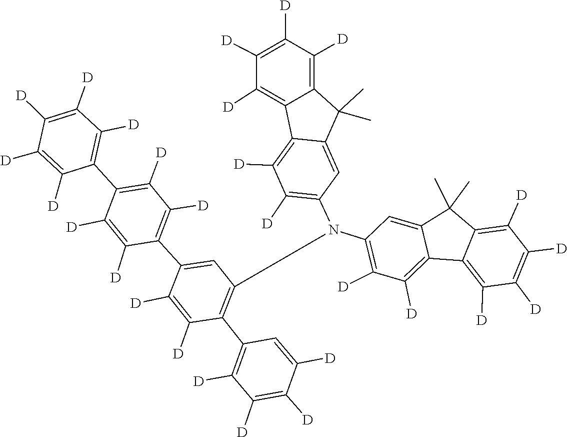 [SMILES: [2H]c1cc(-c2c(N(c3cc4c(c([2H])c3[2H])-c3c([2H])c([2H])c([2H])c([2H])c3C4(C)C)c3cc4c(c([2H])c3[2H])-c3c([2H])c([2H])c([2H])c([2H])c3C4(C)C)cc(-c3c([2H])c([2H])c(-c4c([2H])c([2H])c([2H])c([2H])c4[2H])c([2H])c3[2H])c([2H])c2[2H])c([2H])c([2H])c1[2H]] | 33 |
| 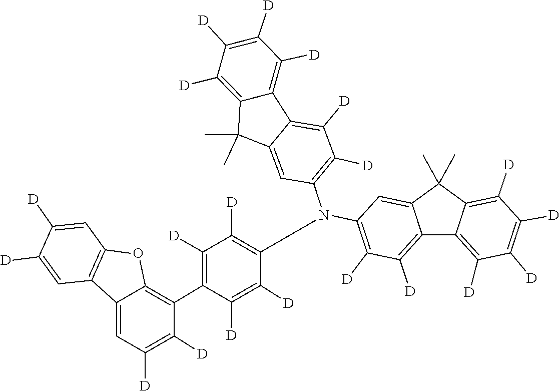 [SMILES: [2H]c1cc2oc3c(-c4c([2H])c([2H])c(N(c5cc6c(c([2H])c5[2H])-c5c([2H])c([2H])c([2H])c([2H])c5C6(C)C)c5cc6c(c([2H])c5[2H])-c5c([2H])c([2H])c([2H])c([2H])c5C6(C)C)c([2H])c4[2H])c([2H])c([2H])cc3c2cc1[2H]] | 34 |
| 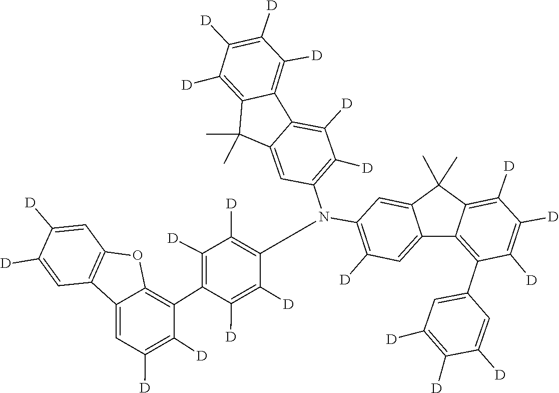 [SMILES: [2H]c1cc2oc3c(-c4c([2H])c([2H])c(N(c5cc6c(cc5[2H])-c5c(-c7cc([2H])c([2H])c([2H])c7)c([2H])c([2H])c([2H])c5C6(C)C)c5cc6c(c([2H])c5[2H])-c5c([2H])c([2H])c([2H])c([2H])c5C6(C)C)c([2H])c4[2H])c([2H])c([2H])cc3c2cc1[2H]] | 35 |
| 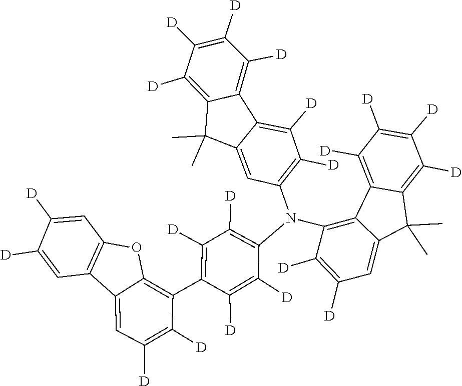 [SMILES: [2H]c1cc2oc3c(-c4c([2H])c([2H])c(N(c5cc6c(c([2H])c5[2H])-c5c([2H])c([2H])c([2H])c([2H])c5C6(C)C)c5c([2H])c([2H])cc6c5-c5c([2H])c([2H])c([2H])c([2H])c5C6(C)C)c([2H])c4[2H])c([2H])c([2H])cc3c2cc1[2H]] | 36 |
| 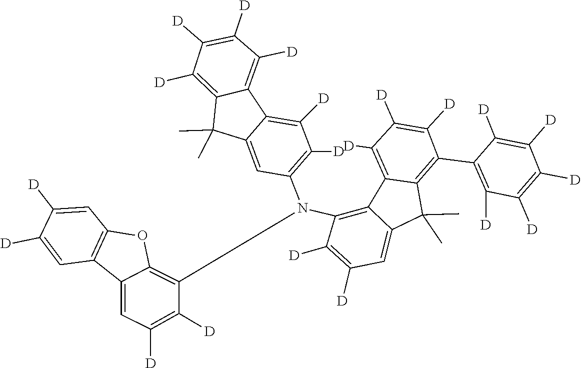 [SMILES: [2H]c1cc2oc3c(N(c4cc5c(c([2H])c4[2H])-c4c([2H])c([2H])c([2H])c([2H])c4C5(C)C)c4c([2H])c([2H])cc5c4-c4c([2H])c([2H])c([2H])c(-c6c([2H])c([2H])c([2H])c([2H])c6[2H])c4C5(C)C)c([2H])c([2H])cc3c2cc1[2H]] | 37 |
| 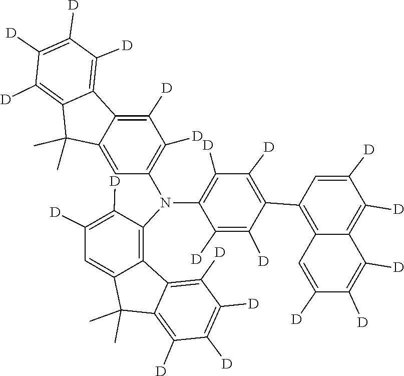 [SMILES: [2H]c1cc2c(c(N(c3cc4c(c([2H])c3[2H])-c3c([2H])c([2H])c([2H])c([2H])c3C4(C)C)c3c([2H])c([2H])c(-c4cc([2H])c([2H])c5c([2H])c([2H])c([2H])cc45)c([2H])c3[2H])c1[2H])-c1c([2H])c([2H])c([2H])c([2H])c1C2(C)C] | 38 |
| 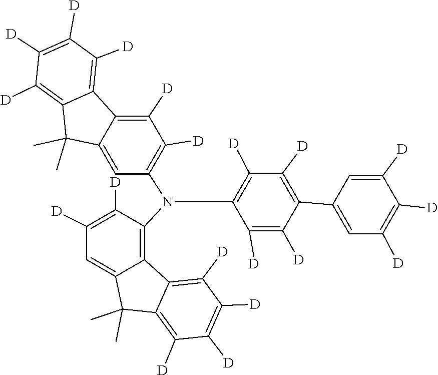 [SMILES: [2H]c1cc(-c2c([2H])c([2H])c(N(c3cc4c(c([2H])c3[2H])-c3c([2H])c([2H])c([2H])c([2H])c3C4(C)C)c3c([2H])c([2H])cc4c3-c3c([2H])c([2H])c([2H])c([2H])c3C4(C)C)c([2H])c2[2H])cc([2H])c1[2H]] | 39 |
| 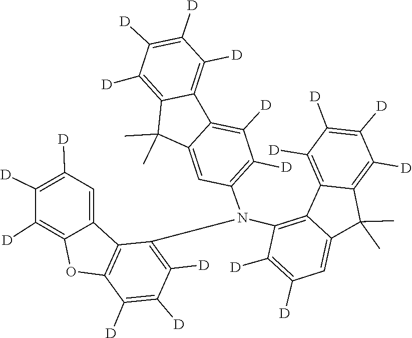 [SMILES: [2H]c1cc2c(c(N(c3cc4c(c([2H])c3[2H])-c3c([2H])c([2H])c([2H])c([2H])c3C4(C)C)c3c([2H])c([2H])c([2H])c4oc5c([2H])c([2H])c([2H])cc5c34)c1[2H])-c1c([2H])c([2H])c([2H])c([2H])c1C2(C)C] | 40 |
| 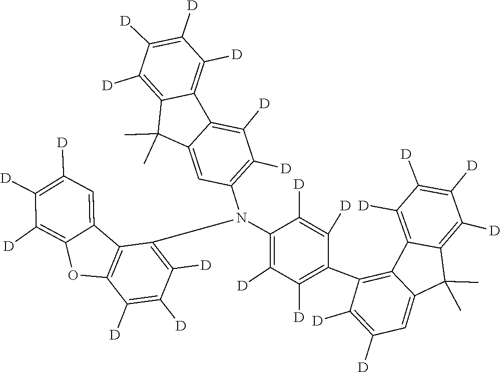 [SMILES: [2H]c1cc2c(c(-c3c([2H])c([2H])c(N(c4cc5c(c([2H])c4[2H])-c4c([2H])c([2H])c([2H])c([2H])c4C5(C)C)c4c([2H])c([2H])c([2H])c5oc6c([2H])c([2H])c([2H])cc6c45)c([2H])c3[2H])c1[2H])-c1c([2H])c([2H])c([2H])c([2H])c1C2(C)C] | 41 |
| 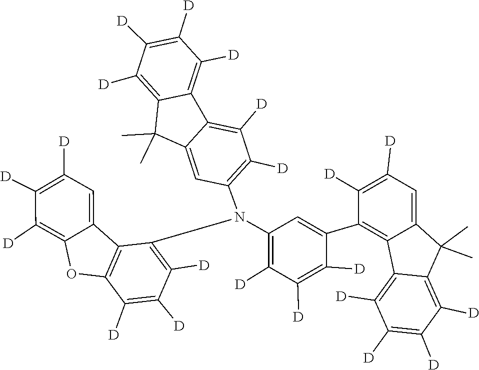 [SMILES: [2H]c1cc2c(c(-c3cc(N(c4cc5c(c([2H])c4[2H])-c4c([2H])c([2H])c([2H])c([2H])c4C5(C)C)c4c([2H])c([2H])c([2H])c5oc6c([2H])c([2H])c([2H])cc6c45)c([2H])c([2H])c3[2H])c1[2H])-c1c([2H])c([2H])c([2H])c([2H])c1C2(C)C] | 42 |
| 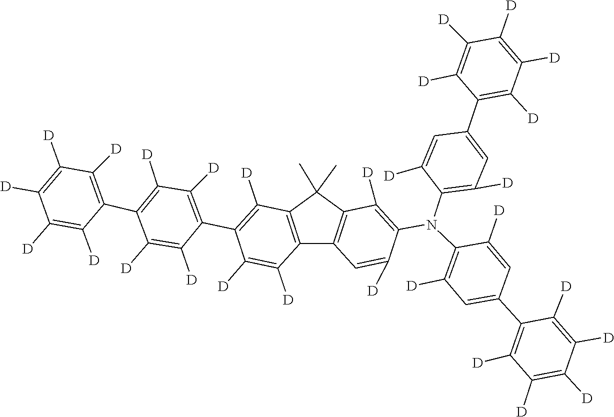 [SMILES: [2H]c1cc(-c2c([2H])c([2H])c([2H])c([2H])c2[2H])cc([2H])c1N(c1c([2H])cc(-c2c([2H])c([2H])c([2H])c([2H])c2[2H])cc1[2H])c1c([2H])cc2c(c1[2H])C(C)(C)c1c([2H])c(-c3c([2H])c([2H])c(-c4c([2H])c([2H])c([2H])c([2H])c4[2H])c([2H])c3[2H])c([2H])c([2H])c1-2] | 43 |
| 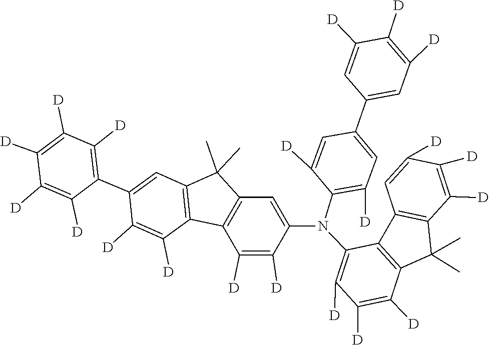 [SMILES: [2H]c1cc(-c2cc([2H])c(N(c3cc4c(c([2H])c3[2H])-c3c(cc(-c5c([2H])c([2H])c([2H])c([2H])c5[2H])c([2H])c3[2H])C4(C)C)c3c([2H])c([2H])c([2H])c4c3-c3cc([2H])c([2H])c([2H])c3C4(C)C)c([2H])c2)cc([2H])c1[2H]] | 44 |
| 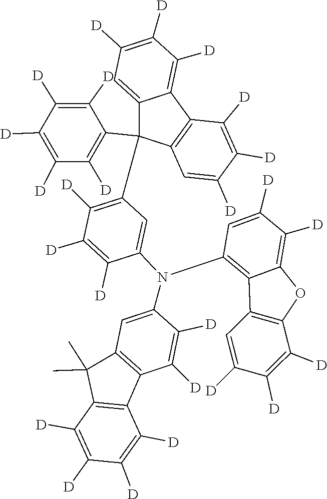 [SMILES: [2H]c1cc2c(c([2H])c1[2H])-c1c(cc([2H])c([2H])c1[2H])C2(c1cc(N(c2cc3c(c([2H])c2[2H])-c2c([2H])c([2H])c([2H])c([2H])c2C3(C)C)c2cc([2H])c([2H])c3oc4c([2H])c([2H])c([2H])cc4c23)c([2H])c([2H])c1[2H])c1c([2H])c([2H])c([2H])c([2H])c1[2H]] | 45 |
| 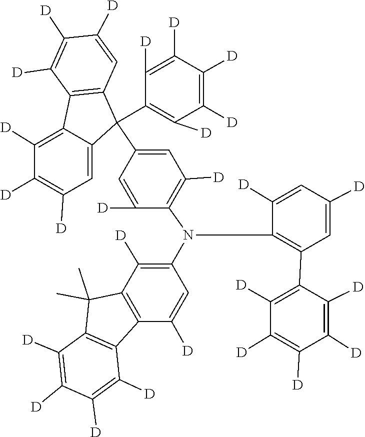 [SMILES: [2H]c1cc([2H])c(N(c2cc([2H])c3c(c2[2H])C(C)(C)c2c([2H])c([2H])c([2H])c([2H])c2-3)c2c([2H])cc(C3(c4c([2H])c([2H])c([2H])c([2H])c4[2H])c4cc([2H])c([2H])c([2H])c4-c4c3cc([2H])c([2H])c4[2H])cc2[2H])c(-c2c([2H])c([2H])c([2H])c([2H])c2[2H])c1] | 46 |
| 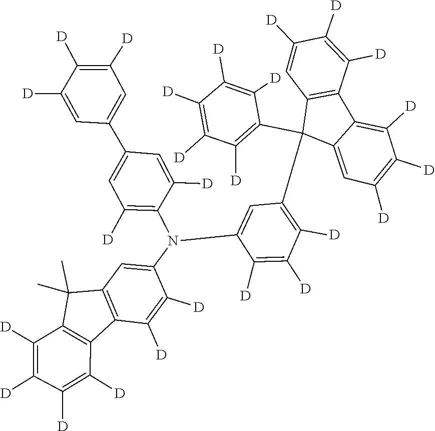 [SMILES: [2H]c1cc(-c2cc([2H])c(N(c3cc(C4(c5c([2H])c([2H])c([2H])c([2H])c5[2H])c5cc([2H])c([2H])c([2H])c5-c5c4cc([2H])c([2H])c5[2H])c([2H])c([2H])c3[2H])c3cc4c(c([2H])c3[2H])-c3c([2H])c([2H])c([2H])c([2H])c3C4(C)C)c([2H])c2)cc([2H])c1[2H]] | 47 |
| 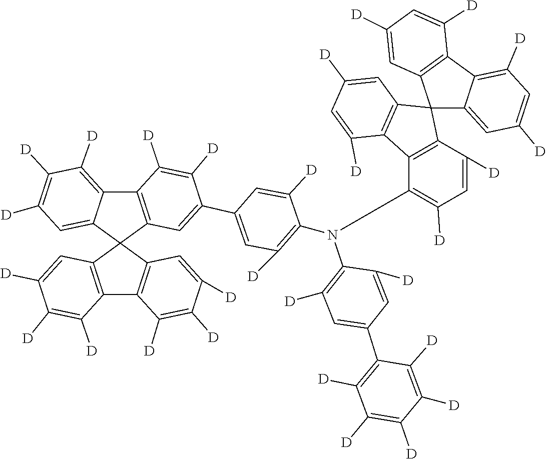 [SMILES: [2H]c1cc([2H])c2c(c1)C1(c3cc([2H])cc([2H])c3-2)c2cc([2H])cc([2H])c2-c2c(N(c3c([2H])cc(-c4cc5c(c([2H])c4[2H])-c4c(cc([2H])c([2H])c4[2H])C54c5cc([2H])c([2H])c([2H])c5-c5c4cc([2H])c([2H])c5[2H])cc3[2H])c3c([2H])cc(-c4c([2H])c([2H])c([2H])c([2H])c4[2H])cc3[2H])c([2H])cc([2H])c21] | 48 |
| 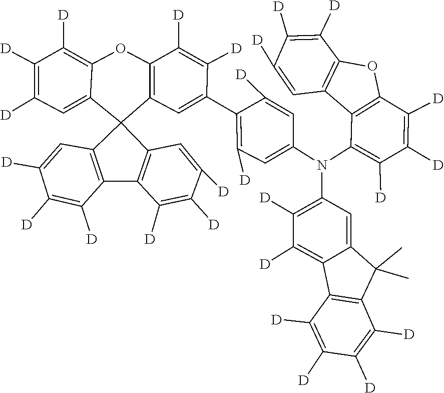 [SMILES: [2H]c1cc2c(c([2H])c1[2H])Oc1c(cc(-c3c([2H])cc(N(c4cc5c(c([2H])c4[2H])-c4c([2H])c([2H])c([2H])c([2H])c4C5(C)C)c4c([2H])c([2H])c([2H])c5oc6c([2H])c([2H])c([2H])cc6c45)cc3[2H])c([2H])c1[2H])C21c2cc([2H])c([2H])c([2H])c2-c2c1cc([2H])c([2H])c2[2H]] | 49 |
| 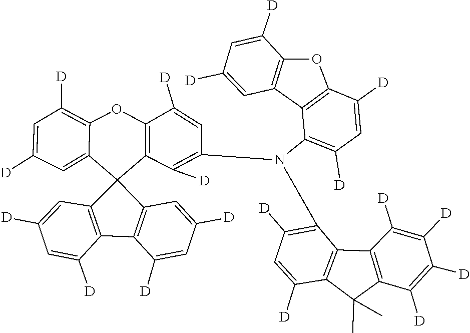 [SMILES: [2H]c1cc([2H])c2c(c1)C1(c3cc([2H])cc([2H])c3-c3c([2H])cc([2H])cc31)c1c([2H])c(N(c3c([2H])cc([2H])c4c3-c3c([2H])c([2H])c([2H])c([2H])c3C4(C)C)c3c([2H])cc([2H])c4oc5c([2H])cc([2H])cc5c34)cc([2H])c1O2] | 50 |
| 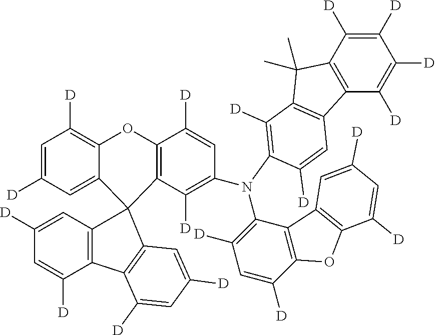 [SMILES: [2H]c1cc([2H])c2c(c1)C1(c3cc([2H])cc([2H])c3-c3c([2H])cc([2H])cc31)c1c([2H])c(N(c3c([2H])cc4c(c3[2H])C(C)(C)c3c([2H])c([2H])c([2H])c([2H])c3-4)c3c([2H])cc([2H])c4oc5c([2H])cc([2H])cc5c34)cc([2H])c1O2] | 51 |
| 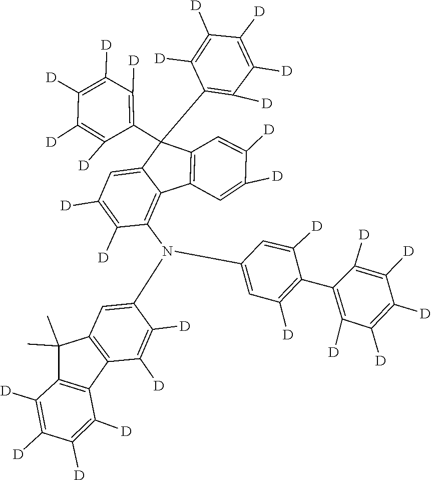 [SMILES: [2H]c1cc2c(cc1[2H])C(c1c([2H])c([2H])c([2H])c([2H])c1[2H])(c1c([2H])c([2H])c([2H])c([2H])c1[2H])c1cc([2H])c([2H])c(N(c3cc([2H])c(-c4c([2H])c([2H])c([2H])c([2H])c4[2H])c([2H])c3)c3cc4c(c([2H])c3[2H])-c3c([2H])c([2H])c([2H])c([2H])c3C4(C)C)c1-2] | 52 |
| 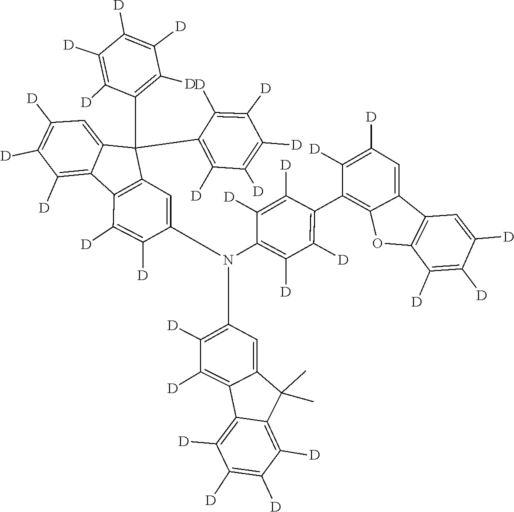 [SMILES: [2H]c1cc2c(c([2H])c1[2H])-c1c(cc(N(c3cc4c(c([2H])c3[2H])-c3c([2H])c([2H])c([2H])c([2H])c3C4(C)C)c3c([2H])c([2H])c(-c4c([2H])c([2H])cc5c4oc4c([2H])c([2H])c([2H])cc45)c([2H])c3[2H])c([2H])c1[2H])C2(c1c([2H])c([2H])c([2H])c([2H])c1[2H])c1c([2H])c([2H])c([2H])c([2H])c1[2H]] | 53 |
| 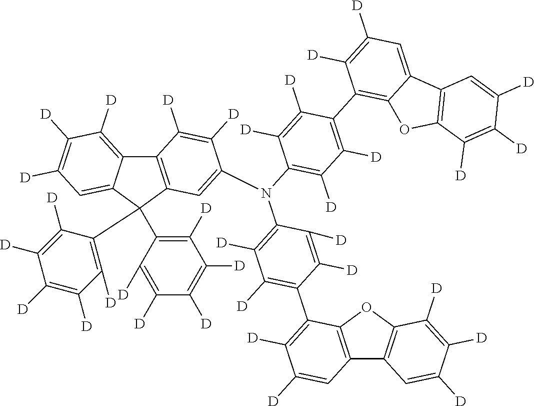 [SMILES: [2H]c1cc2c(c([2H])c1[2H])-c1c(cc(N(c3c([2H])c([2H])c(-c4c([2H])c([2H])cc5c4oc4c([2H])c([2H])c([2H])cc45)c([2H])c3[2H])c3c([2H])c([2H])c(-c4c([2H])c([2H])cc5c4oc4c([2H])c([2H])c([2H])cc45)c([2H])c3[2H])c([2H])c1[2H])C2(c1c([2H])c([2H])c([2H])c([2H])c1[2H])c1c([2H])c([2H])c([2H])c([2H])c1[2H]] | 54 |
| 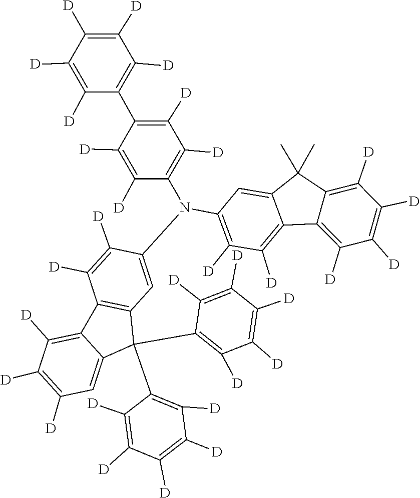 [SMILES: [2H]c1cc2c(c([2H])c1[2H])-c1c(cc(N(c3cc4c(c([2H])c3[2H])-c3c([2H])c([2H])c([2H])c([2H])c3C4(C)C)c3c([2H])c([2H])c(-c4c([2H])c([2H])c([2H])c([2H])c4[2H])c([2H])c3[2H])c([2H])c1[2H])C2(c1c([2H])c([2H])c([2H])c([2H])c1[2H])c1c([2H])c([2H])c([2H])c([2H])c1[2H]] | 55 |
| 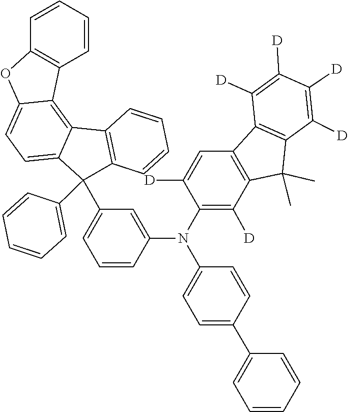 [SMILES: [2H]c1cc2c(c([2H])c1N(c1ccc(-c3ccccc3)cc1)c1cccc(C3(c4ccccc4)c4ccccc4-c4c3ccc3oc5ccccc5c43)c1)C(C)(C)c1c([2H])c([2H])c([2H])c([2H])c1-2] | 56 |
| 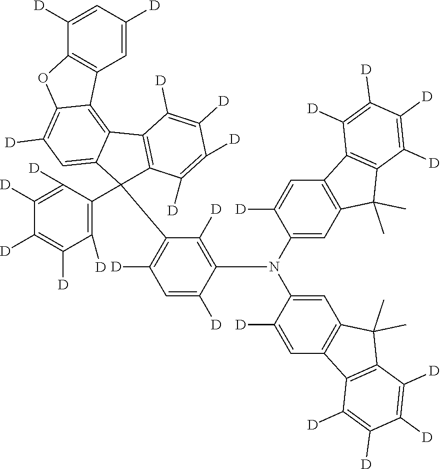 [SMILES: [2H]c1cc([2H])c2oc3c([2H])cc4c(c3c2c1)-c1c([2H])c([2H])c([2H])c([2H])c1C4(c1c([2H])cc([2H])c(N(c2cc3c(cc2[2H])-c2c([2H])c([2H])c([2H])c([2H])c2C3(C)C)c2cc3c(cc2[2H])-c2c([2H])c([2H])c([2H])c([2H])c2C3(C)C)c1[2H])c1c([2H])c([2H])c([2H])c([2H])c1[2H]] | 57 |
| 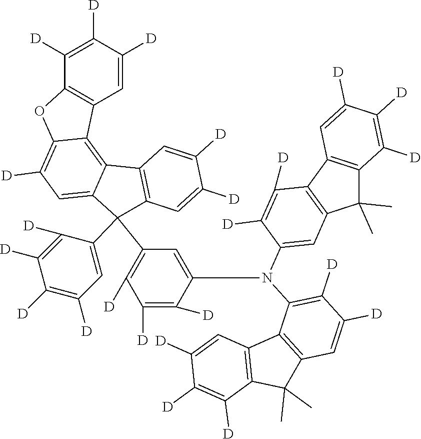 [SMILES: [2H]c1cc2c(cc1[2H])C(c1cc([2H])c([2H])c([2H])c1[2H])(c1cc(N(c3cc4c(c([2H])c3[2H])-c3cc([2H])c([2H])c([2H])c3C4(C)C)c3c([2H])c([2H])cc4c3-c3cc([2H])c([2H])c([2H])c3C4(C)C)c([2H])c([2H])c1[2H])c1cc([2H])c3oc4c([2H])c([2H])c([2H])cc4c3c1-2] | 58 |
| 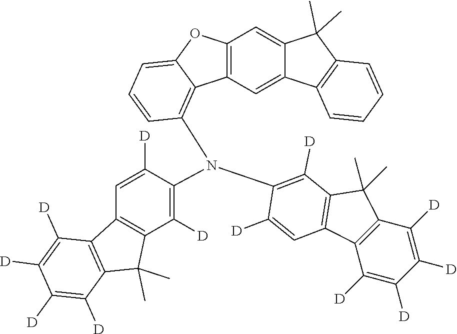 [SMILES: [2H]c1cc2c(c([2H])c1N(c1c([2H])cc3c(c1[2H])C(C)(C)c1c([2H])c([2H])c([2H])c([2H])c1-3)c1cccc3oc4cc5c(cc4c13)-c1ccccc1C5(C)C)C(C)(C)c1c([2H])c([2H])c([2H])c([2H])c1-2] | 59 |
| 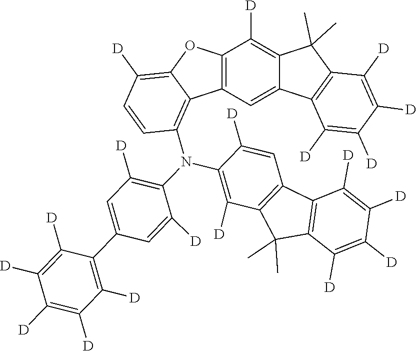 [SMILES: [2H]c1cc(-c2c([2H])c([2H])c([2H])c([2H])c2[2H])cc([2H])c1N(c1c([2H])cc2c(c1[2H])C(C)(C)c1c([2H])c([2H])c([2H])c([2H])c1-2)c1ccc([2H])c2oc3c([2H])c4c(cc3c12)-c1c([2H])c([2H])c([2H])c([2H])c1C4(C)C] | 60 |
| 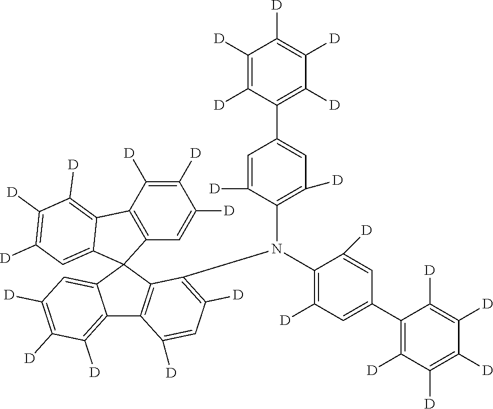 [SMILES: [2H]c1cc2c(c([2H])c1[2H])-c1c(cc([2H])c([2H])c1[2H])C21c2cc([2H])c([2H])c([2H])c2-c2c([2H])cc([2H])c(N(c3c([2H])cc(-c4c([2H])c([2H])c([2H])c([2H])c4[2H])cc3[2H])c3c([2H])cc(-c4c([2H])c([2H])c([2H])c([2H])c4[2H])cc3[2H])c21] | 61 |
| 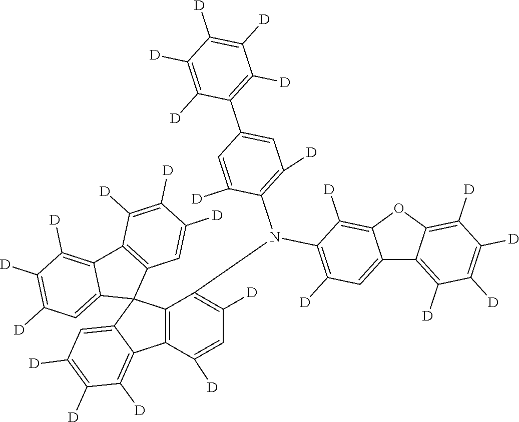 [SMILES: [2H]c1cc2c(c([2H])c1[2H])-c1c(cc([2H])c([2H])c1[2H])C21c2cc([2H])c([2H])c([2H])c2-c2c([2H])cc([2H])c(N(c3c([2H])cc(-c4c([2H])c([2H])c([2H])c([2H])c4[2H])cc3[2H])c3c([2H])cc4c(oc5c([2H])c([2H])c([2H])c([2H])c54)c3[2H])c21] | 62 |
| 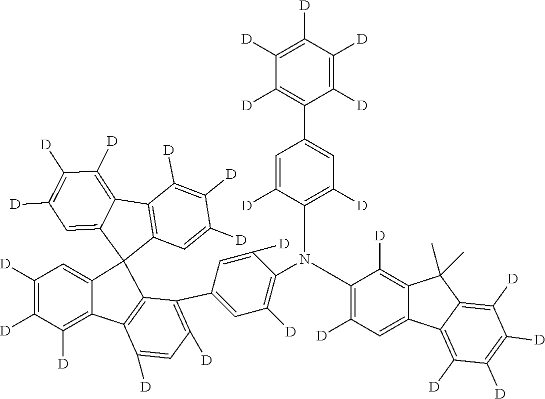 [SMILES: [2H]c1cc2c(c([2H])c1[2H])-c1c(cc([2H])c([2H])c1[2H])C21c2cc([2H])c([2H])c([2H])c2-c2c([2H])cc([2H])c(-c3cc([2H])c(N(c4c([2H])cc(-c5c([2H])c([2H])c([2H])c([2H])c5[2H])cc4[2H])c4c([2H])cc5c(c4[2H])C(C)(C)c4c([2H])c([2H])c([2H])c([2H])c4-5)c([2H])c3)c21] | 63 |
| 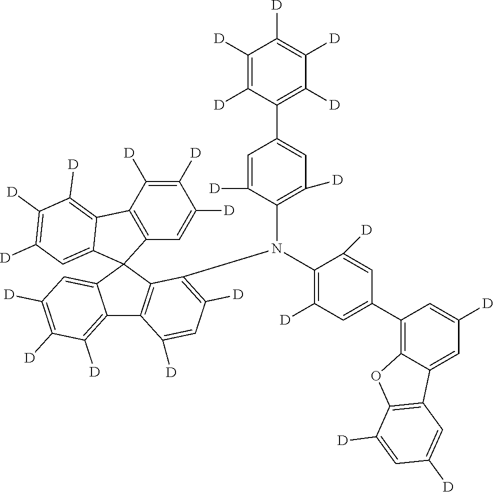 [SMILES: [2H]c1cc([2H])c2oc3c(-c4cc([2H])c(N(c5c([2H])cc(-c6c([2H])c([2H])c([2H])c([2H])c6[2H])cc5[2H])c5c([2H])cc([2H])c6c5C5(c7cc([2H])c([2H])c([2H])c7-c7c5cc([2H])c([2H])c7[2H])c5cc([2H])c([2H])c([2H])c5-6)c([2H])c4)cc([2H])cc3c2c1] | 64 |
| 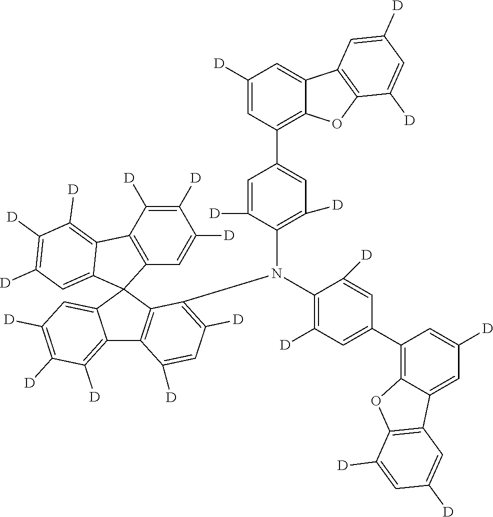 [SMILES: [2H]c1cc([2H])c2oc3c(-c4cc([2H])c(N(c5c([2H])cc(-c6cc([2H])cc7c6oc6c([2H])cc([2H])cc67)cc5[2H])c5c([2H])cc([2H])c6c5C5(c7cc([2H])c([2H])c([2H])c7-c7c5cc([2H])c([2H])c7[2H])c5cc([2H])c([2H])c([2H])c5-6)c([2H])c4)cc([2H])cc3c2c1] | 65 |
| 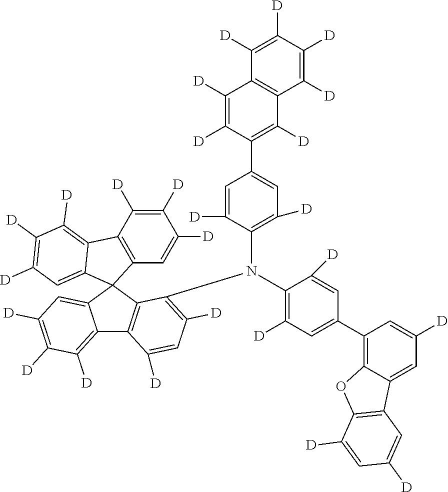 [SMILES: [2H]c1cc([2H])c2oc3c(-c4cc([2H])c(N(c5c([2H])cc(-c6c([2H])c([2H])c7c([2H])c([2H])c([2H])c([2H])c7c6[2H])cc5[2H])c5c([2H])cc([2H])c6c5C5(c7cc([2H])c([2H])c([2H])c7-c7c5cc([2H])c([2H])c7[2H])c5cc([2H])c([2H])c([2H])c5-6)c([2H])c4)cc([2H])cc3c2c1] | 66 |
| 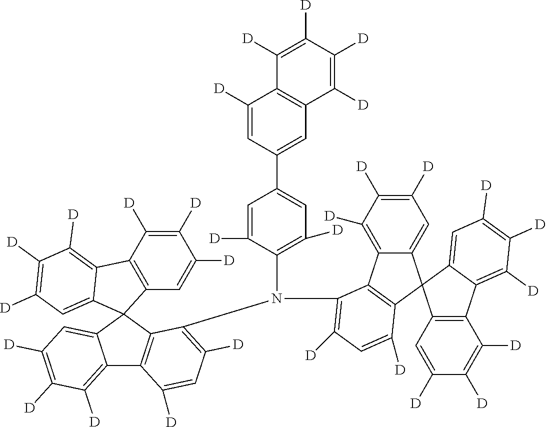 [SMILES: [2H]c1cc2c(c([2H])c1[2H])-c1c(cc([2H])c([2H])c1[2H])C21c2cc([2H])c([2H])c([2H])c2-c2c(N(c3c([2H])cc(-c4cc([2H])c5c([2H])c([2H])c([2H])c([2H])c5c4)cc3[2H])c3c([2H])cc([2H])c4c3C3(c5cc([2H])c([2H])c([2H])c5-c5c3cc([2H])c([2H])c5[2H])c3cc([2H])c([2H])c([2H])c3-4)c([2H])cc([2H])c21] | 67 |
| 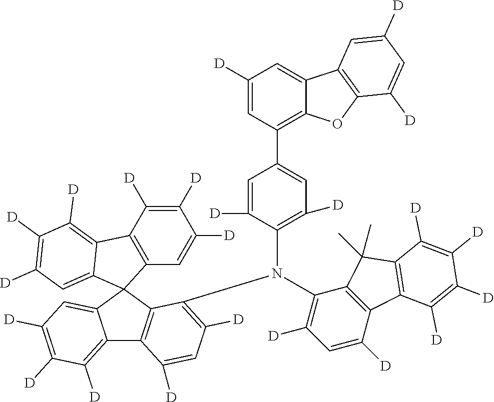 [SMILES: [2H]c1cc([2H])c2oc3c(-c4cc([2H])c(N(c5c([2H])cc([2H])c6c5C(C)(C)c5c([2H])c([2H])c([2H])c([2H])c5-6)c5c([2H])cc([2H])c6c5C5(c7cc([2H])c([2H])c([2H])c7-c7c5cc([2H])c([2H])c7[2H])c5cc([2H])c([2H])c([2H])c5-6)c([2H])c4)cc([2H])cc3c2c1] | 68 |
| 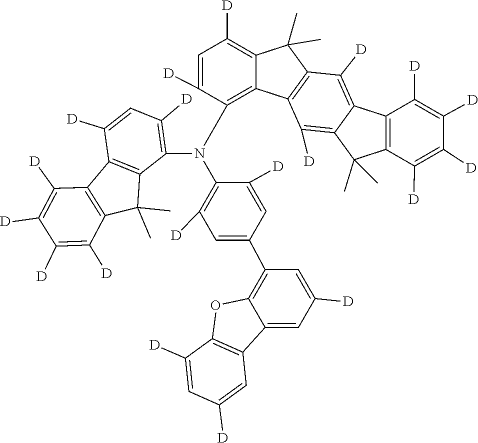 [SMILES: [2H]c1cc([2H])c2oc3c(-c4cc([2H])c(N(c5c([2H])cc([2H])c6c5-c5c([2H])c7c(c([2H])c5C6(C)C)-c5c([2H])c([2H])c([2H])c([2H])c5C7(C)C)c5c([2H])cc([2H])c6c5C(C)(C)c5c([2H])c([2H])c([2H])c([2H])c5-6)c([2H])c4)cc([2H])cc3c2c1] | 69 |
| 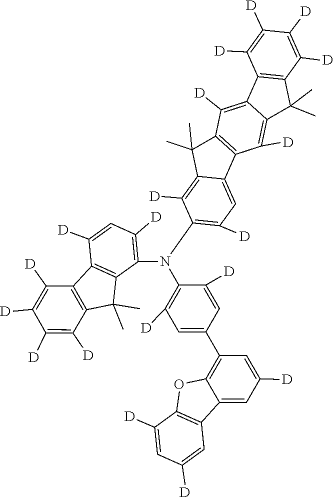 [SMILES: [2H]c1cc([2H])c2oc3c(-c4cc([2H])c(N(c5c([2H])cc6c(c5[2H])C(C)(C)c5c([2H])c7c(c([2H])c5-6)C(C)(C)c5c([2H])c([2H])c([2H])c([2H])c5-7)c5c([2H])cc([2H])c6c5C(C)(C)c5c([2H])c([2H])c([2H])c([2H])c5-6)c([2H])c4)cc([2H])cc3c2c1] | 70 |
| 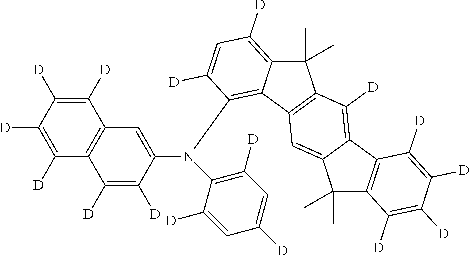 [SMILES: [2H]c1cc([2H])c(N(c2cc3c([2H])c([2H])c([2H])c([2H])c3c([2H])c2[2H])c2c([2H])cc([2H])c3c2-c2cc4c(c([2H])c2C3(C)C)-c2c([2H])c([2H])c([2H])c([2H])c2C4(C)C)c([2H])c1] | 71 |
| 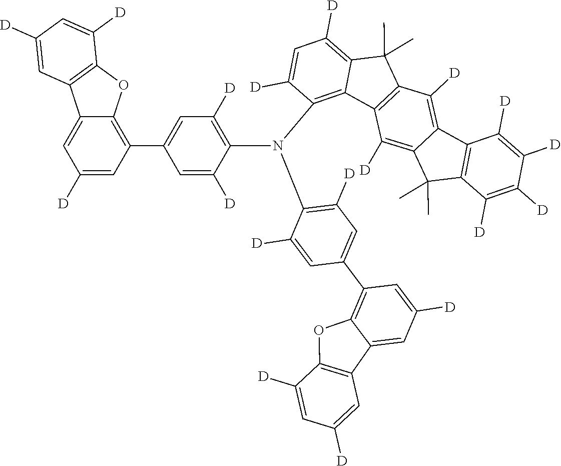 [SMILES: [2H]c1cc([2H])c2oc3c(-c4cc([2H])c(N(c5c([2H])cc(-c6cc([2H])cc7c6oc6c([2H])cc([2H])cc67)cc5[2H])c5c([2H])cc([2H])c6c5-c5c([2H])c7c(c([2H])c5C6(C)C)-c5c([2H])c([2H])c([2H])c([2H])c5C7(C)C)c([2H])c4)cc([2H])cc3c2c1] | 72 |
| 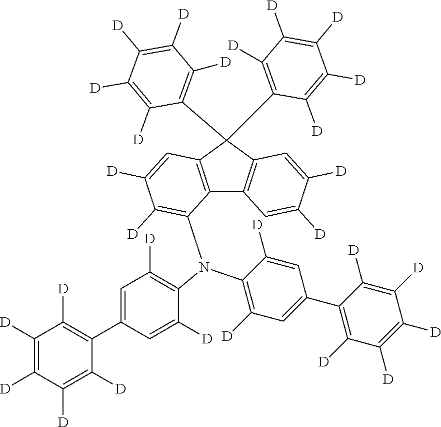 [SMILES: [2H]c1cc2c(cc1[2H])C(c1c([2H])c([2H])c([2H])c([2H])c1[2H])(c1c([2H])c([2H])c([2H])c([2H])c1[2H])c1cc([2H])c([2H])c(N(c3c([2H])cc(-c4c([2H])c([2H])c([2H])c([2H])c4[2H])cc3[2H])c3c([2H])cc(-c4c([2H])c([2H])c([2H])c([2H])c4[2H])cc3[2H])c1-2] | 73 |
| 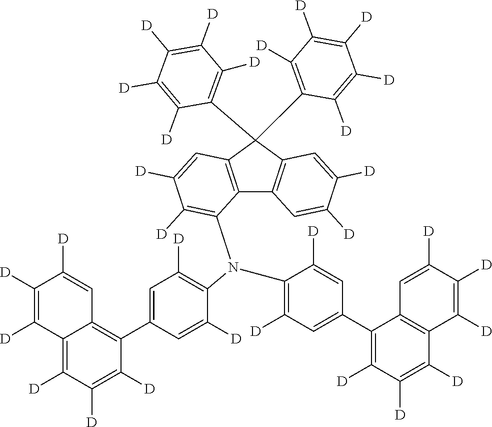 [SMILES: [2H]c1cc2c(cc1[2H])C(c1c([2H])c([2H])c([2H])c([2H])c1[2H])(c1c([2H])c([2H])c([2H])c([2H])c1[2H])c1cc([2H])c([2H])c(N(c3c([2H])cc(-c4c([2H])c([2H])c([2H])c5c([2H])c([2H])c([2H])cc45)cc3[2H])c3c([2H])cc(-c4c([2H])c([2H])c([2H])c5c([2H])c([2H])c([2H])cc45)cc3[2H])c1-2] | 74 |
| 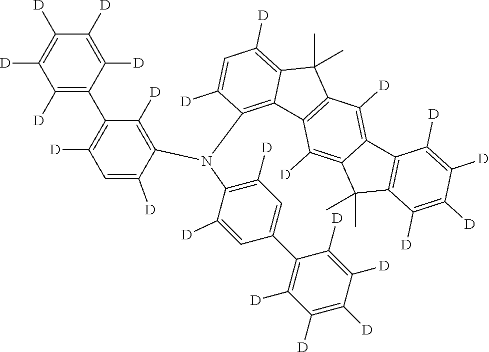 [SMILES: [2H]c1cc([2H])c(N(c2c([2H])cc(-c3c([2H])c([2H])c([2H])c([2H])c3[2H])cc2[2H])c2c([2H])cc([2H])c3c2-c2c([2H])c4c(c([2H])c2C3(C)C)-c2c([2H])c([2H])c([2H])c([2H])c2C4(C)C)c([2H])c1-c1c([2H])c([2H])c([2H])c([2H])c1[2H]] | 75 |
| 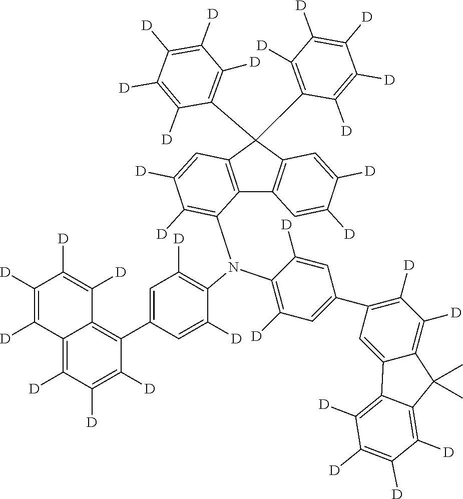 [SMILES: [2H]c1cc2c(cc1[2H])C(c1c([2H])c([2H])c([2H])c([2H])c1[2H])(c1c([2H])c([2H])c([2H])c([2H])c1[2H])c1cc([2H])c([2H])c(N(c3c([2H])cc(-c4cc5c(c([2H])c4[2H])C(C)(C)c4c([2H])c([2H])c([2H])c([2H])c4-5)cc3[2H])c3c([2H])cc(-c4c([2H])c([2H])c([2H])c5c([2H])c([2H])c([2H])c([2H])c45)cc3[2H])c1-2] | 76 |
| 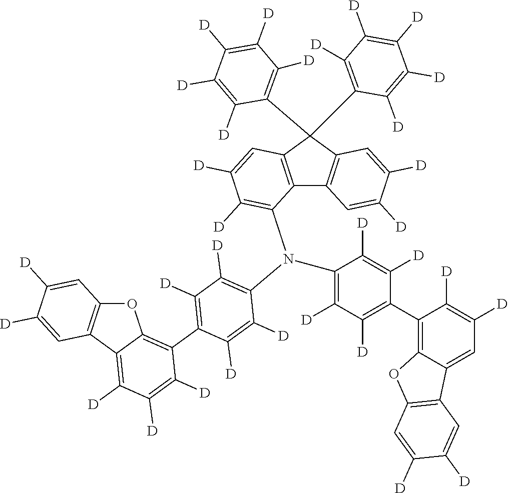 [SMILES: [2H]c1cc2c(cc1[2H])C(c1c([2H])c([2H])c([2H])c([2H])c1[2H])(c1c([2H])c([2H])c([2H])c([2H])c1[2H])c1cc([2H])c([2H])c(N(c3c([2H])c([2H])c(-c4c([2H])c([2H])cc5c4oc4cc([2H])c([2H])cc45)c([2H])c3[2H])c3c([2H])c([2H])c(-c4c([2H])c([2H])c([2H])c5c4oc4cc([2H])c([2H])cc45)c([2H])c3[2H])c1-2] | 77 |
| 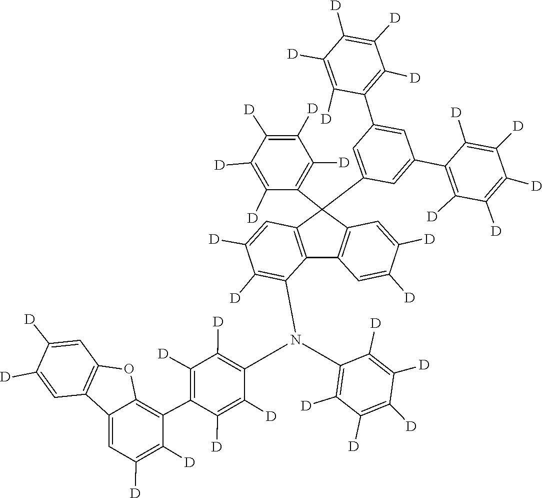 [SMILES: [2H]c1cc2c(cc1[2H])C(c1cc(-c3c([2H])c([2H])c([2H])c([2H])c3[2H])cc(-c3c([2H])c([2H])c([2H])c([2H])c3[2H])c1)(c1c([2H])c([2H])c([2H])c([2H])c1[2H])c1cc([2H])c([2H])c(N(c3c([2H])c([2H])c([2H])c([2H])c3[2H])c3c([2H])c([2H])c(-c4c([2H])c([2H])cc5c4oc4cc([2H])c([2H])cc45)c([2H])c3[2H])c1-2] | 78 |
| 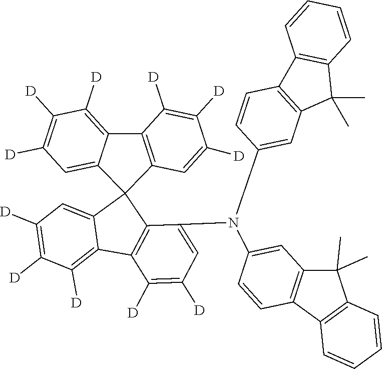 [SMILES: [2H]c1cc2c(c([2H])c1[2H])-c1c(cc([2H])c([2H])c1[2H])C21c2cc([2H])c([2H])c([2H])c2-c2c([2H])c([2H])cc(N(c3ccc4c(c3)C(C)(C)c3ccccc3-4)c3ccc4c(c3)C(C)(C)c3ccccc3-4)c21] | 79 |
| 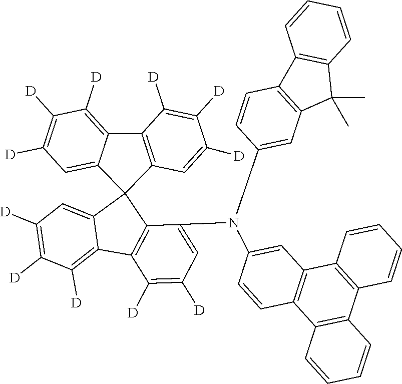 [SMILES: [2H]c1cc2c(c([2H])c1[2H])-c1c(cc([2H])c([2H])c1[2H])C21c2cc([2H])c([2H])c([2H])c2-c2c([2H])c([2H])cc(N(c3ccc4c(c3)C(C)(C)c3ccccc3-4)c3ccc4c5ccccc5c5ccccc5c4c3)c21] | 80 |
| 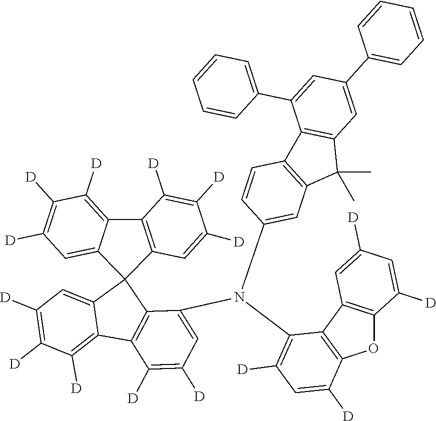 [SMILES: [2H]c1cc([2H])c2oc3c([2H])cc([2H])c(N(c4ccc5c(c4)C(C)(C)c4cc(-c6ccccc6)cc(-c6ccccc6)c4-5)c4cc([2H])c([2H])c5c4C4(c6cc([2H])c([2H])c([2H])c6-c6c4cc([2H])c([2H])c6[2H])c4cc([2H])c([2H])c([2H])c4-5)c3c2c1] | 81 |
| 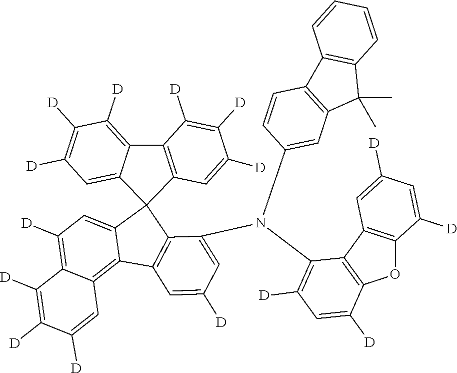 [SMILES: [2H]c1cc2c(c(N(c3ccc4c(c3)C(C)(C)c3ccccc3-4)c3c([2H])cc([2H])c4oc5c([2H])cc([2H])cc5c34)c1)C1(c3cc([2H])c([2H])c([2H])c3-c3c1cc([2H])c([2H])c3[2H])c1cc([2H])c3c([2H])c([2H])c([2H])cc3c1-2] | 82 |
| 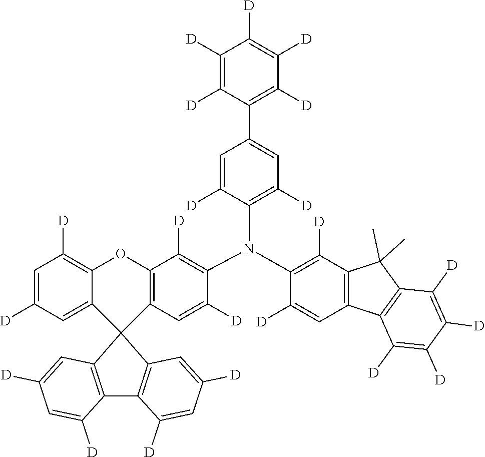 [SMILES: [2H]c1cc([2H])c2c(c1)C1(c3cc([2H])c(N(c4c([2H])cc(-c5c([2H])c([2H])c([2H])c([2H])c5[2H])cc4[2H])c4c([2H])cc5c(c4[2H])C(C)(C)c4c([2H])c([2H])c([2H])c([2H])c4-5)c([2H])c3O2)c2cc([2H])cc([2H])c2-c2c([2H])cc([2H])cc21] | 83 |
| 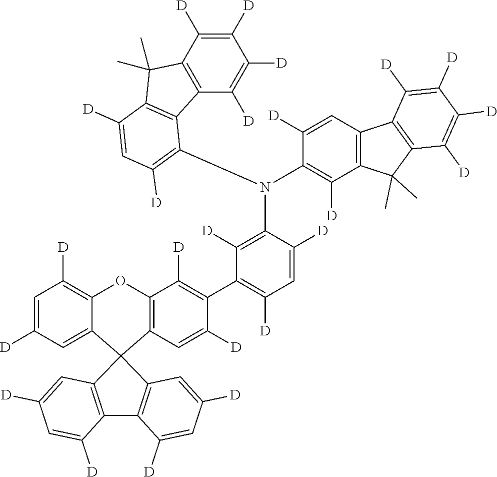 [SMILES: [2H]c1cc([2H])c2c(c1)C1(c3cc([2H])c(-c4c([2H])cc([2H])c(N(c5c([2H])cc6c(c5[2H])C(C)(C)c5c([2H])c([2H])c([2H])c([2H])c5-6)c5c([2H])cc([2H])c6c5-c5c([2H])c([2H])c([2H])c([2H])c5C6(C)C)c4[2H])c([2H])c3O2)c2cc([2H])cc([2H])c2-c2c([2H])cc([2H])cc21] | 84 |
| 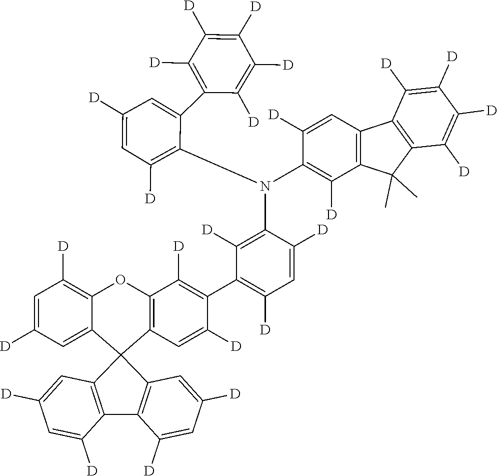 [SMILES: [2H]c1cc([2H])c(N(c2c([2H])cc([2H])c(-c3c([2H])cc4c(c3[2H])Oc3c([2H])cc([2H])cc3C43c4cc([2H])cc([2H])c4-c4c([2H])cc([2H])cc43)c2[2H])c2c([2H])cc3c(c2[2H])C(C)(C)c2c([2H])c([2H])c([2H])c([2H])c2-3)c(-c2c([2H])c([2H])c([2H])c([2H])c2[2H])c1] | 85 |
| 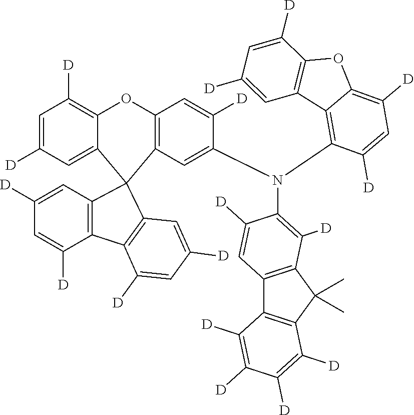 [SMILES: [2H]c1cc([2H])c2c(c1)C1(c3cc(N(c4c([2H])cc5c(c4[2H])C(C)(C)c4c([2H])c([2H])c([2H])c([2H])c4-5)c4c([2H])cc([2H])c5oc6c([2H])cc([2H])cc6c45)c([2H])cc3O2)c2cc([2H])cc([2H])c2-c2c([2H])cc([2H])cc21] | 86 |
| 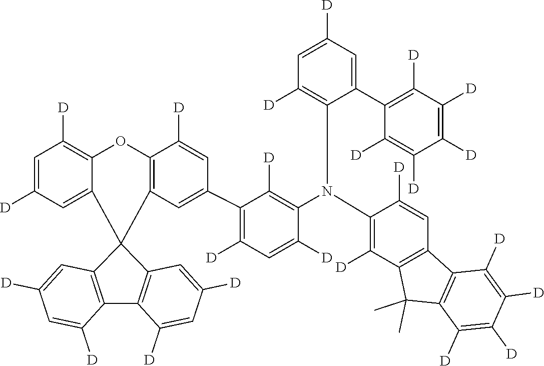 [SMILES: [2H]c1cc([2H])c(N(c2c([2H])cc([2H])c(-c3cc([2H])c4c(c3)C3(c5cc([2H])cc([2H])c5O4)c4cc([2H])cc([2H])c4-c4c([2H])cc([2H])cc43)c2[2H])c2c([2H])cc3c(c2[2H])C(C)(C)c2c([2H])c([2H])c([2H])c([2H])c2-3)c(-c2c([2H])c([2H])c([2H])c([2H])c2[2H])c1] | 87 |
| 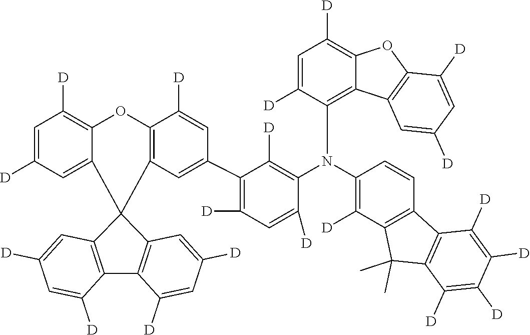 [SMILES: [2H]c1cc([2H])c2c(c1)C1(c3cc(-c4c([2H])cc([2H])c(N(c5ccc6c(c5[2H])C(C)(C)c5c([2H])c([2H])c([2H])c([2H])c5-6)c5c([2H])cc([2H])c6oc7c([2H])cc([2H])cc7c56)c4[2H])cc([2H])c3O2)c2cc([2H])cc([2H])c2-c2c([2H])cc([2H])cc21] | 88 |
| 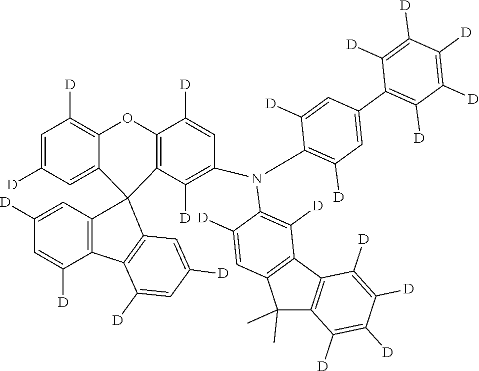 [SMILES: [2H]c1cc([2H])c2c(c1)C1(c3cc([2H])cc([2H])c3-c3c([2H])cc([2H])cc31)c1c([2H])c(N(c3c([2H])cc(-c4c([2H])c([2H])c([2H])c([2H])c4[2H])cc3[2H])c3c([2H])cc4c(c3[2H])-c3c([2H])c([2H])c([2H])c([2H])c3C4(C)C)cc([2H])c1O2] | 89 |
| 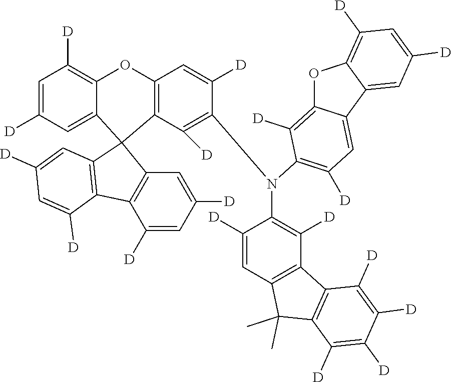 [SMILES: [2H]c1cc([2H])c2c(c1)C1(c3cc([2H])cc([2H])c3-c3c([2H])cc([2H])cc31)c1c(cc([2H])c(N(c3c([2H])cc4c(c3[2H])-c3c([2H])c([2H])c([2H])c([2H])c3C4(C)C)c3c([2H])cc4c(oc5c([2H])cc([2H])cc54)c3[2H])c1[2H])O2] | 90 |
| 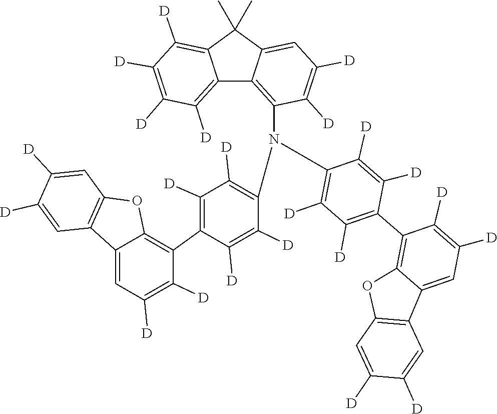 [SMILES: [2H]c1cc2oc3c(-c4c([2H])c([2H])c(N(c5c([2H])c([2H])c(-c6c([2H])c([2H])cc7c6oc6cc([2H])c([2H])cc67)c([2H])c5[2H])c5c([2H])c([2H])cc6c5-c5c([2H])c([2H])c([2H])c([2H])c5C6(C)C)c([2H])c4[2H])c([2H])c([2H])cc3c2cc1[2H]] | 91 |
| 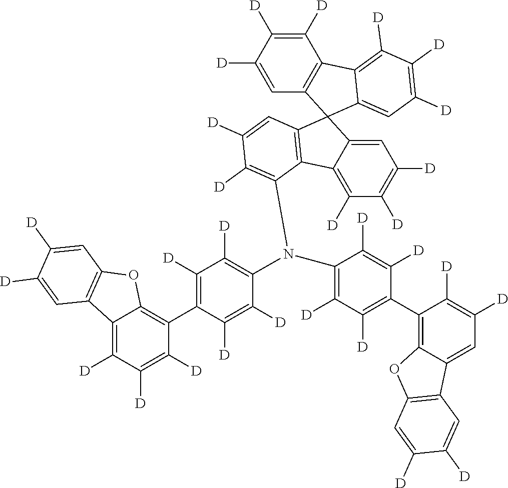 [SMILES: [2H]c1cc2oc3c(-c4c([2H])c([2H])c(N(c5c([2H])c([2H])c(-c6c([2H])c([2H])c([2H])c7c6oc6cc([2H])c([2H])cc67)c([2H])c5[2H])c5c([2H])c([2H])cc6c5-c5c(cc([2H])c([2H])c5[2H])C65c6cc([2H])c([2H])c([2H])c6-c6c5cc([2H])c([2H])c6[2H])c([2H])c4[2H])c([2H])c([2H])cc3c2cc1[2H]] | 92 |
| 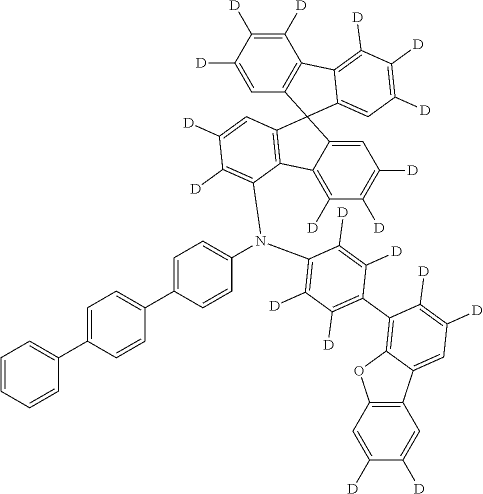 [SMILES: [2H]c1cc2oc3c(-c4c([2H])c([2H])c(N(c5ccc(-c6ccc(-c7ccccc7)cc6)cc5)c5c([2H])c([2H])cc6c5-c5c(cc([2H])c([2H])c5[2H])C65c6cc([2H])c([2H])c([2H])c6-c6c5cc([2H])c([2H])c6[2H])c([2H])c4[2H])c([2H])c([2H])cc3c2cc1[2H]] | 93 |
| 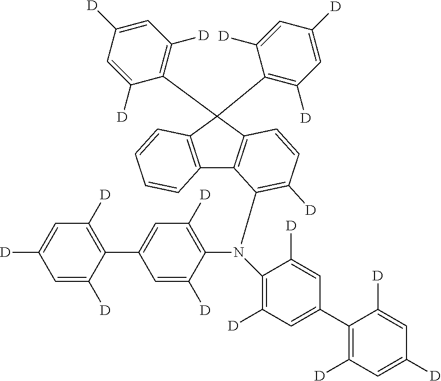 [SMILES: [2H]c1cc([2H])c(-c2cc([2H])c(N(c3c([2H])cc(-c4c([2H])cc([2H])cc4[2H])cc3[2H])c3c([2H])ccc4c3-c3ccccc3C4(c3c([2H])cc([2H])cc3[2H])c3c([2H])cc([2H])cc3[2H])c([2H])c2)c([2H])c1] | 94 |
| 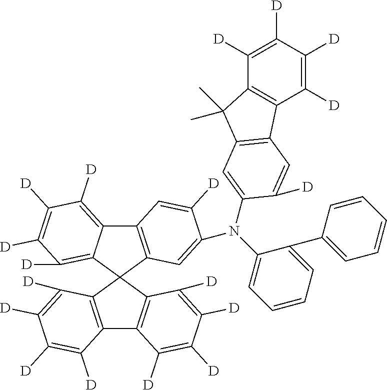 [SMILES: [2H]c1cc2c(cc1N(c1cc3c(cc1[2H])-c1c([2H])c([2H])c([2H])c([2H])c1C31c3c([2H])c([2H])c([2H])c([2H])c3-c3c([2H])c([2H])c([2H])c([2H])c31)c1ccccc1-c1ccccc1)C(C)(C)c1c([2H])c([2H])c([2H])c([2H])c1-2] | 95 |
| 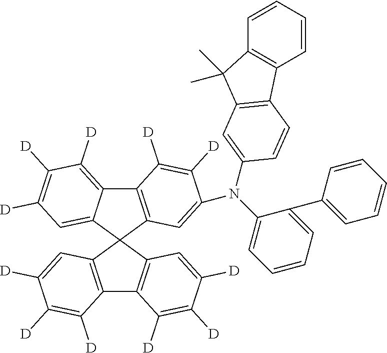 [SMILES: [2H]c1cc2c(c([2H])c1[2H])-c1c(cc([2H])c([2H])c1[2H])C21c2cc([2H])c([2H])c([2H])c2-c2c1cc(N(c1ccc3c(c1)C(C)(C)c1ccccc1-3)c1ccccc1-c1ccccc1)c([2H])c2[2H]] | 96 |
| 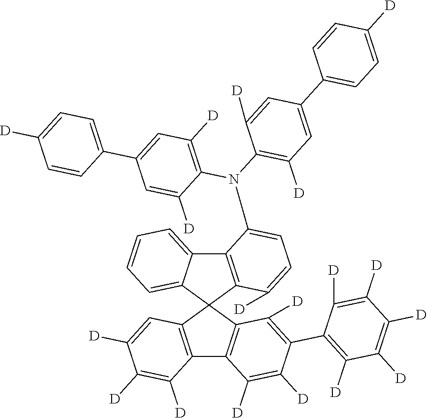 [SMILES: [2H]c1ccc(-c2cc([2H])c(N(c3ccc([2H])c4c3-c3ccccc3C43c4cc([2H])c([2H])c([2H])c4-c4c([2H])c([2H])c(-c5c([2H])c([2H])c([2H])c([2H])c5[2H])c([2H])c43)c3c([2H])cc(-c4ccc([2H])cc4)cc3[2H])c([2H])c2)cc1] | 97 |
| 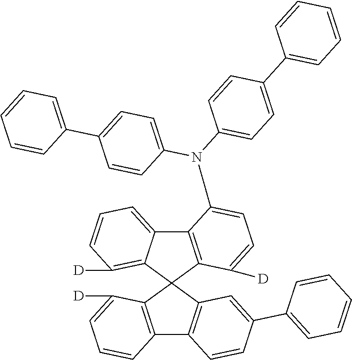 [SMILES: [2H]c1cccc2c1C1(c3cc(-c4ccccc4)ccc3-2)c2c([2H])cccc2-c2c(N(c3ccc(-c4ccccc4)cc3)c3ccc(-c4ccccc4)cc3)ccc([2H])c21] | 98 |
| 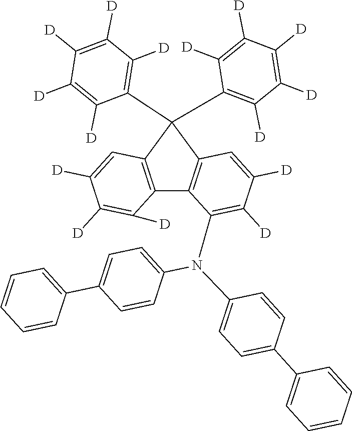 [SMILES: [2H]c1cc2c(c([2H])c1[2H])-c1c(cc([2H])c([2H])c1N(c1ccc(-c3ccccc3)cc1)c1ccc(-c3ccccc3)cc1)C2(c1c([2H])c([2H])c([2H])c([2H])c1[2H])c1c([2H])c([2H])c([2H])c([2H])c1[2H]] | 99 |
| 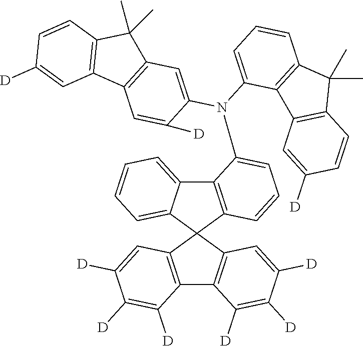 [SMILES: [2H]c1ccc2c(c1)-c1cc([2H])c(N(c3cccc4c3-c3cc([2H])ccc3C4(C)C)c3cccc4c3-c3ccccc3C43c4cc([2H])c([2H])c([2H])c4-c4c3cc([2H])c([2H])c4[2H])cc1C2(C)C] | 100 |
| 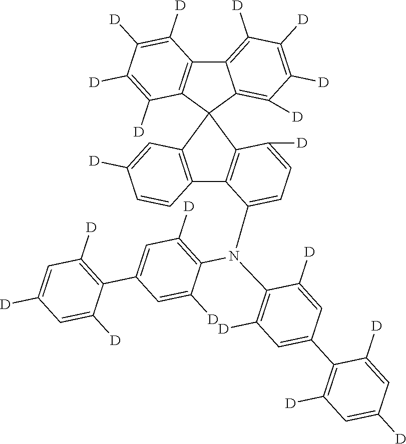 [SMILES: [2H]c1cc([2H])c(-c2cc([2H])c(N(c3ccc([2H])c4c3-c3ccc([2H])cc3C43c4c([2H])c([2H])c([2H])c([2H])c4-c4c([2H])c([2H])c([2H])c([2H])c43)c3c([2H])cc(-c4c([2H])cc([2H])cc4[2H])cc3[2H])c([2H])c2)c([2H])c1] | 101 |
| 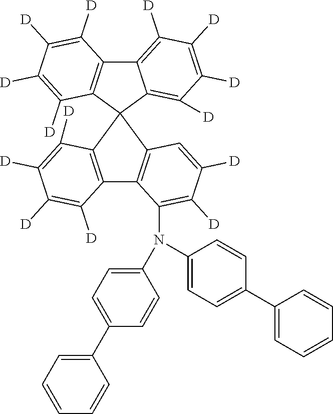 [SMILES: [2H]c1cc2c(c(N(c3ccc(-c4ccccc4)cc3)c3ccc(-c4ccccc4)cc3)c1[2H])-c1c([2H])c([2H])c([2H])c([2H])c1C21c2c([2H])c([2H])c([2H])c([2H])c2-c2c([2H])c([2H])c([2H])c([2H])c21] | 102 |
| 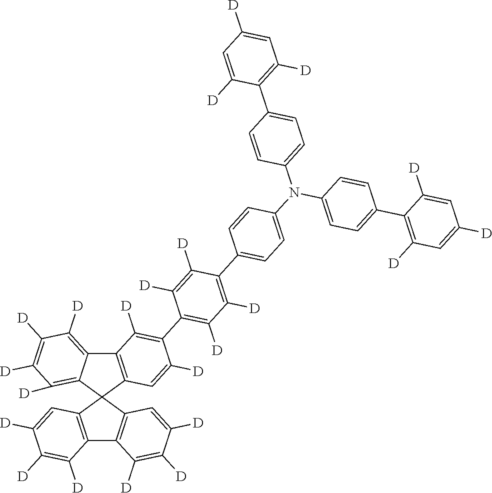 [SMILES: [2H]c1cc([2H])c(-c2ccc(N(c3ccc(-c4c([2H])cc([2H])cc4[2H])cc3)c3ccc(-c4c([2H])c([2H])c(-c5c([2H])cc6c(c5[2H])-c5c([2H])c([2H])c([2H])c([2H])c5C65c6cc([2H])c([2H])c([2H])c6-c6c5cc([2H])c([2H])c6[2H])c([2H])c4[2H])cc3)cc2)c([2H])c1] | 103 |
| 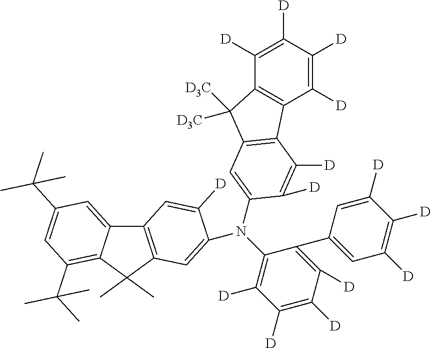 [SMILES: [2H]c1cc2c(cc1N(c1cc3c(c([2H])c1[2H])-c1c([2H])c([2H])c([2H])c([2H])c1C3(C([2H])([2H])[2H])C([2H])([2H])[2H])c1c([2H])c([2H])c([2H])c([2H])c1-c1cc([2H])c([2H])c([2H])c1)C(C)(C)c1c-2cc(C(C)(C)C)cc1C(C)(C)C] | 104 |
| 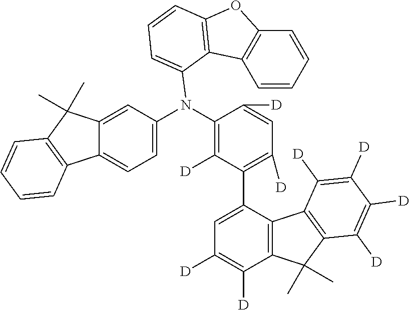 [SMILES: [2H]c1cc(-c2c([2H])cc([2H])c(N(c3ccc4c(c3)C(C)(C)c3ccccc3-4)c3cccc4oc5ccccc5c34)c2[2H])c2c(c1[2H])C(C)(C)c1c([2H])c([2H])c([2H])c([2H])c1-2] | 105 |
| 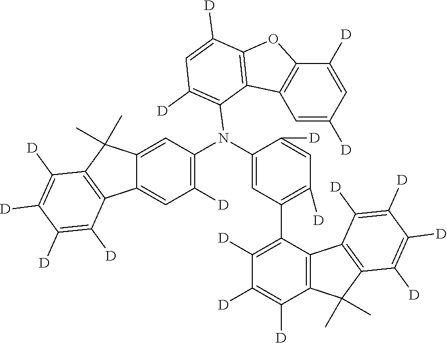 [SMILES: [2H]c1cc([2H])c2oc3c([2H])cc([2H])c(N(c4cc(-c5c([2H])c([2H])c([2H])c6c5-c5c([2H])c([2H])c([2H])c([2H])c5C6(C)C)c([2H])cc4[2H])c4cc5c(cc4[2H])-c4c([2H])c([2H])c([2H])c([2H])c4C5(C)C)c3c2c1] | 106 |
| 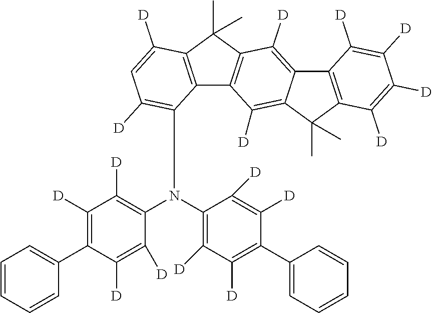 [SMILES: [2H]c1cc([2H])c2c(c1N(c1c([2H])c([2H])c(-c3ccccc3)c([2H])c1[2H])c1c([2H])c([2H])c(-c3ccccc3)c([2H])c1[2H])-c1c([2H])c3c(c([2H])c1C2(C)C)-c1c([2H])c([2H])c([2H])c([2H])c1C3(C)C] | 107 |
| 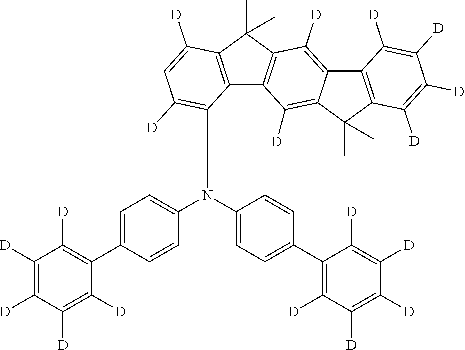 [SMILES: [2H]c1cc([2H])c2c(c1N(c1ccc(-c3c([2H])c([2H])c([2H])c([2H])c3[2H])cc1)c1ccc(-c3c([2H])c([2H])c([2H])c([2H])c3[2H])cc1)-c1c([2H])c3c(c([2H])c1C2(C)C)-c1c([2H])c([2H])c([2H])c([2H])c1C3(C)C] | 108 |
| 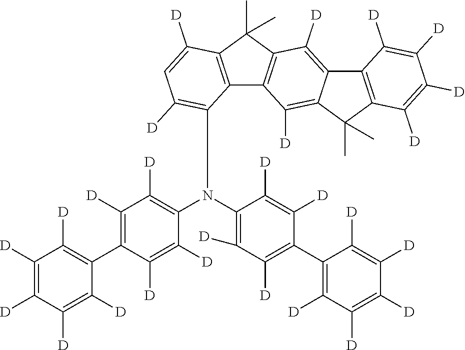 [SMILES: [2H]c1cc([2H])c2c(c1N(c1c([2H])c([2H])c(-c3c([2H])c([2H])c([2H])c([2H])c3[2H])c([2H])c1[2H])c1c([2H])c([2H])c(-c3c([2H])c([2H])c([2H])c([2H])c3[2H])c([2H])c1[2H])-c1c([2H])c3c(c([2H])c1C2(C)C)-c1c([2H])c([2H])c([2H])c([2H])c1C3(C)C] | 109 |
| 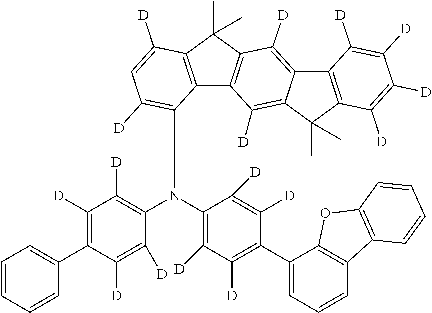 [SMILES: [2H]c1cc([2H])c2c(c1N(c1c([2H])c([2H])c(-c3ccccc3)c([2H])c1[2H])c1c([2H])c([2H])c(-c3cccc4c3oc3ccccc34)c([2H])c1[2H])-c1c([2H])c3c(c([2H])c1C2(C)C)-c1c([2H])c([2H])c([2H])c([2H])c1C3(C)C] | 110 |
| 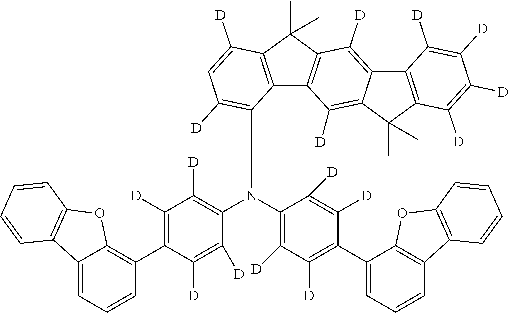 [SMILES: [2H]c1cc([2H])c2c(c1N(c1c([2H])c([2H])c(-c3cccc4c3oc3ccccc34)c([2H])c1[2H])c1c([2H])c([2H])c(-c3cccc4c3oc3ccccc34)c([2H])c1[2H])-c1c([2H])c3c(c([2H])c1C2(C)C)-c1c([2H])c([2H])c([2H])c([2H])c1C3(C)C] | 111 |
| 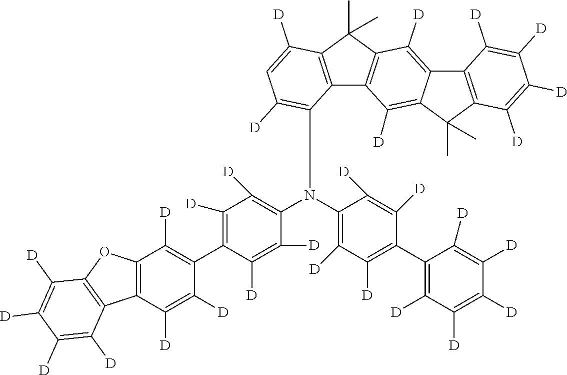 [SMILES: [2H]c1cc([2H])c2c(c1N(c1c([2H])c([2H])c(-c3c([2H])c([2H])c([2H])c([2H])c3[2H])c([2H])c1[2H])c1c([2H])c([2H])c(-c3c([2H])c([2H])c4c(oc5c([2H])c([2H])c([2H])c([2H])c54)c3[2H])c([2H])c1[2H])-c1c([2H])c3c(c([2H])c1C2(C)C)-c1c([2H])c([2H])c([2H])c([2H])c1C3(C)C] | 112 |
| 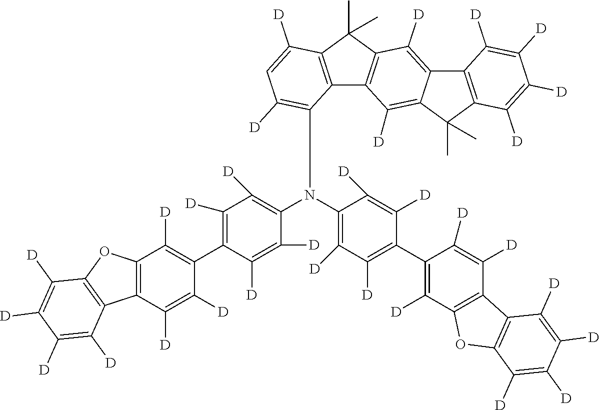 [SMILES: [2H]c1cc([2H])c2c(c1N(c1c([2H])c([2H])c(-c3c([2H])c([2H])c4c(oc5c([2H])c([2H])c([2H])c([2H])c54)c3[2H])c([2H])c1[2H])c1c([2H])c([2H])c(-c3c([2H])c([2H])c4c(oc5c([2H])c([2H])c([2H])c([2H])c54)c3[2H])c([2H])c1[2H])-c1c([2H])c3c(c([2H])c1C2(C)C)-c1c([2H])c([2H])c([2H])c([2H])c1C3(C)C] | 113 |
| 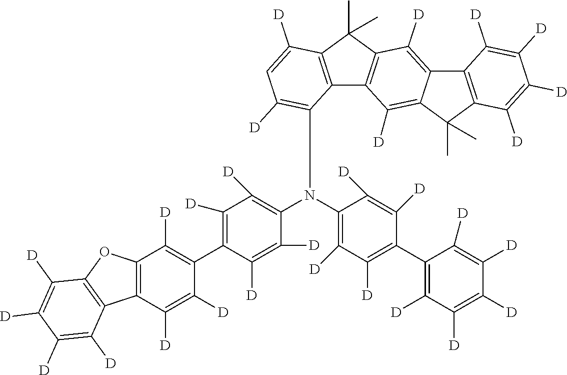 [SMILES: [2H]c1cc([2H])c2c(c1N(c1c([2H])c([2H])c(-c3c([2H])c([2H])c([2H])c([2H])c3[2H])c([2H])c1[2H])c1c([2H])c([2H])c(-c3c([2H])c([2H])c4c(oc5c([2H])c([2H])c([2H])c([2H])c54)c3[2H])c([2H])c1[2H])-c1c([2H])c3c(c([2H])c1C2(C)C)-c1c([2H])c([2H])c([2H])c([2H])c1C3(C)C] | 114 |
| 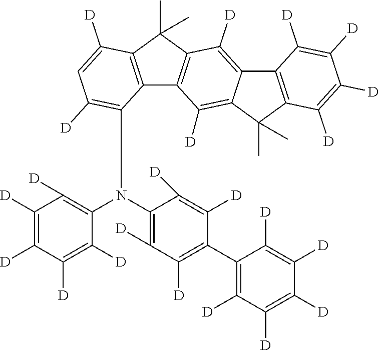 [SMILES: [2H]c1cc([2H])c2c(c1N(c1c([2H])c([2H])c([2H])c([2H])c1[2H])c1c([2H])c([2H])c(-c3c([2H])c([2H])c([2H])c([2H])c3[2H])c([2H])c1[2H])-c1c([2H])c3c(c([2H])c1C2(C)C)-c1c([2H])c([2H])c([2H])c([2H])c1C3(C)C] | 115 |
| 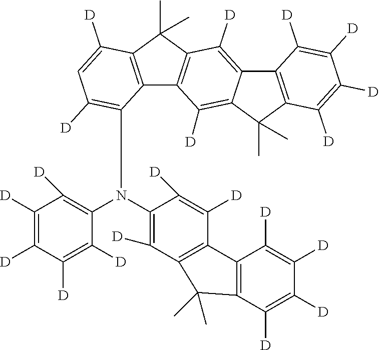 [SMILES: [2H]c1cc([2H])c2c(c1N(c1c([2H])c([2H])c([2H])c([2H])c1[2H])c1c([2H])c([2H])c3c(c1[2H])C(C)(C)c1c([2H])c([2H])c([2H])c([2H])c1-3)-c1c([2H])c3c(c([2H])c1C2(C)C)-c1c([2H])c([2H])c([2H])c([2H])c1C3(C)C] | 116 |
| 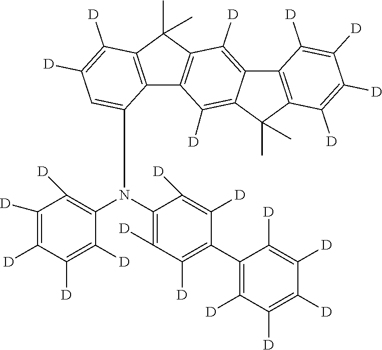 [SMILES: [2H]c1cc(N(c2c([2H])c([2H])c([2H])c([2H])c2[2H])c2c([2H])c([2H])c(-c3c([2H])c([2H])c([2H])c([2H])c3[2H])c([2H])c2[2H])c2c(c1[2H])C(C)(C)c1c([2H])c3c(c([2H])c1-2)C(C)(C)c1c([2H])c([2H])c([2H])c([2H])c1-3] | 117 |
| 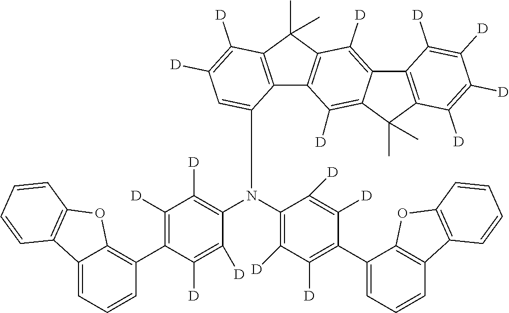 [SMILES: [2H]c1cc(N(c2c([2H])c([2H])c(-c3cccc4c3oc3ccccc34)c([2H])c2[2H])c2c([2H])c([2H])c(-c3cccc4c3oc3ccccc34)c([2H])c2[2H])c2c(c1[2H])C(C)(C)c1c([2H])c3c(c([2H])c1-2)C(C)(C)c1c([2H])c([2H])c([2H])c([2H])c1-3] | 118 |
| 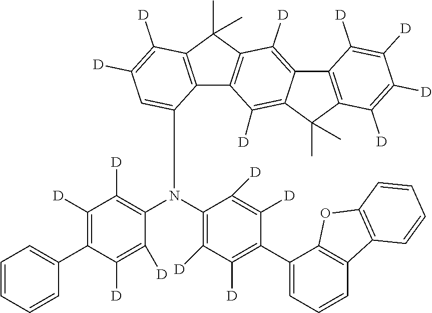 [SMILES: [2H]c1cc(N(c2c([2H])c([2H])c(-c3ccccc3)c([2H])c2[2H])c2c([2H])c([2H])c(-c3cccc4c3oc3ccccc34)c([2H])c2[2H])c2c(c1[2H])C(C)(C)c1c([2H])c3c(c([2H])c1-2)C(C)(C)c1c([2H])c([2H])c([2H])c([2H])c1-3] | 119 |
| 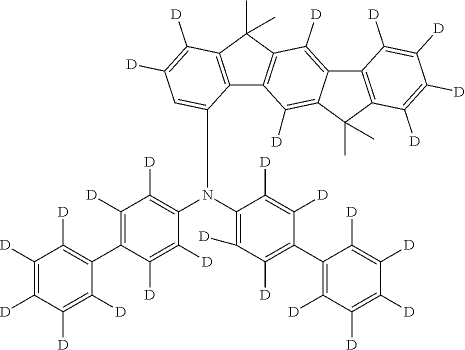 [SMILES: [2H]c1cc(N(c2c([2H])c([2H])c(-c3c([2H])c([2H])c([2H])c([2H])c3[2H])c([2H])c2[2H])c2c([2H])c([2H])c(-c3c([2H])c([2H])c([2H])c([2H])c3[2H])c([2H])c2[2H])c2c(c1[2H])C(C)(C)c1c([2H])c3c(c([2H])c1-2)C(C)(C)c1c([2H])c([2H])c([2H])c([2H])c1-3] | 120 |
| 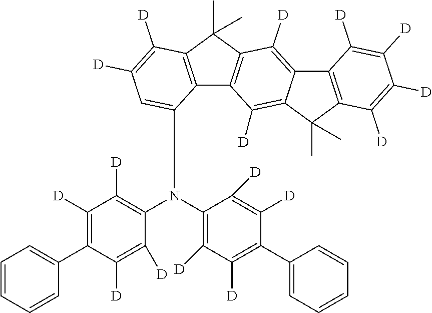 [SMILES: [2H]c1cc(N(c2c([2H])c([2H])c(-c3ccccc3)c([2H])c2[2H])c2c([2H])c([2H])c(-c3ccccc3)c([2H])c2[2H])c2c(c1[2H])C(C)(C)c1c([2H])c3c(c([2H])c1-2)C(C)(C)c1c([2H])c([2H])c([2H])c([2H])c1-3] | 121 |
| 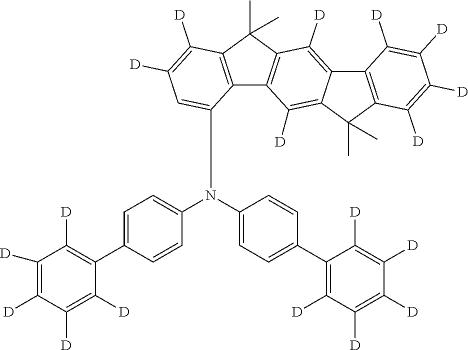 [SMILES: [2H]c1cc(N(c2ccc(-c3c([2H])c([2H])c([2H])c([2H])c3[2H])cc2)c2ccc(-c3c([2H])c([2H])c([2H])c([2H])c3[2H])cc2)c2c(c1[2H])C(C)(C)c1c([2H])c3c(c([2H])c1-2)C(C)(C)c1c([2H])c([2H])c([2H])c([2H])c1-3] | 122 |
| 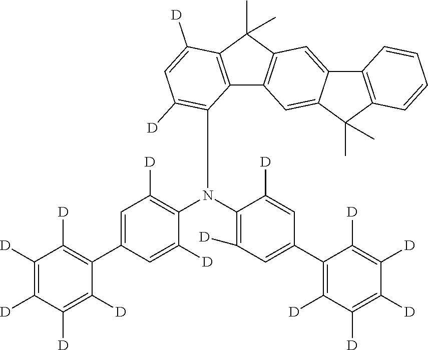 [SMILES: [2H]c1cc(-c2c([2H])c([2H])c([2H])c([2H])c2[2H])cc([2H])c1N(c1c([2H])cc(-c2c([2H])c([2H])c([2H])c([2H])c2[2H])cc1[2H])c1c([2H])cc([2H])c2c1-c1cc3c(cc1C2(C)C)-c1ccccc1C3(C)C] | 123 |
| 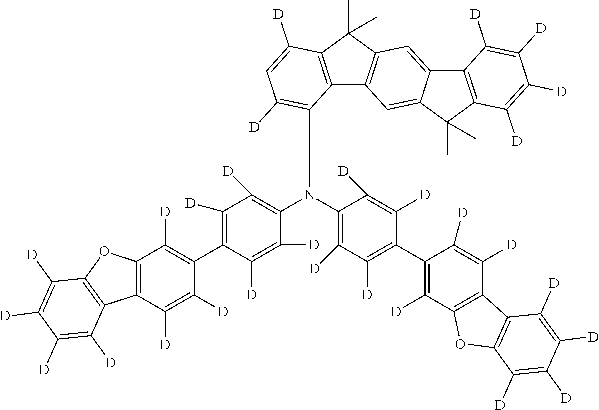 [SMILES: [2H]c1cc([2H])c2c(c1N(c1c([2H])c([2H])c(-c3c([2H])c([2H])c4c(oc5c([2H])c([2H])c([2H])c([2H])c54)c3[2H])c([2H])c1[2H])c1c([2H])c([2H])c(-c3c([2H])c([2H])c4c(oc5c([2H])c([2H])c([2H])c([2H])c54)c3[2H])c([2H])c1[2H])-c1cc3c(cc1C2(C)C)-c1c([2H])c([2H])c([2H])c([2H])c1C3(C)C] | 124 |
| 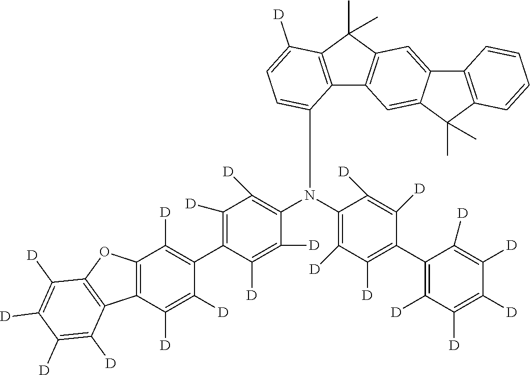 [SMILES: [2H]c1ccc(N(c2c([2H])c([2H])c(-c3c([2H])c([2H])c([2H])c([2H])c3[2H])c([2H])c2[2H])c2c([2H])c([2H])c(-c3c([2H])c([2H])c4c(oc5c([2H])c([2H])c([2H])c([2H])c54)c3[2H])c([2H])c2[2H])c2c1C(C)(C)c1cc3c(cc1-2)C(C)(C)c1ccccc1-3] | 125 |
| 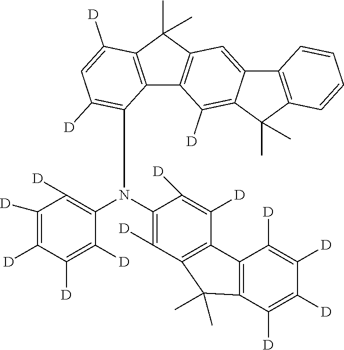 [SMILES: [2H]c1cc([2H])c2c(c1N(c1c([2H])c([2H])c([2H])c([2H])c1[2H])c1c([2H])c([2H])c3c(c1[2H])C(C)(C)c1c([2H])c([2H])c([2H])c([2H])c1-3)-c1c(cc3c(c1[2H])C(C)(C)c1ccccc1-3)C2(C)C] | 126 |
| 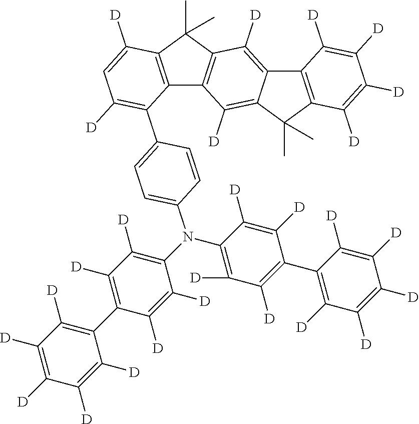 [SMILES: [2H]c1cc([2H])c2c(c1-c1ccc(N(c3c([2H])c([2H])c(-c4c([2H])c([2H])c([2H])c([2H])c4[2H])c([2H])c3[2H])c3c([2H])c([2H])c(-c4c([2H])c([2H])c([2H])c([2H])c4[2H])c([2H])c3[2H])cc1)-c1c([2H])c3c(c([2H])c1C2(C)C)-c1c([2H])c([2H])c([2H])c([2H])c1C3(C)C] | 127 |
| 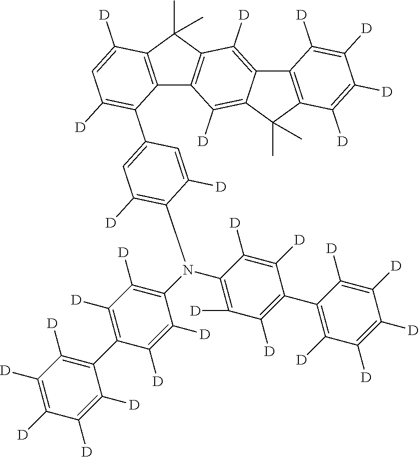 [SMILES: [2H]c1cc([2H])c2c(c1-c1cc([2H])c(N(c3c([2H])c([2H])c(-c4c([2H])c([2H])c([2H])c([2H])c4[2H])c([2H])c3[2H])c3c([2H])c([2H])c(-c4c([2H])c([2H])c([2H])c([2H])c4[2H])c([2H])c3[2H])c([2H])c1)-c1c([2H])c3c(c([2H])c1C2(C)C)-c1c([2H])c([2H])c([2H])c([2H])c1C3(C)C] | 128 |
| 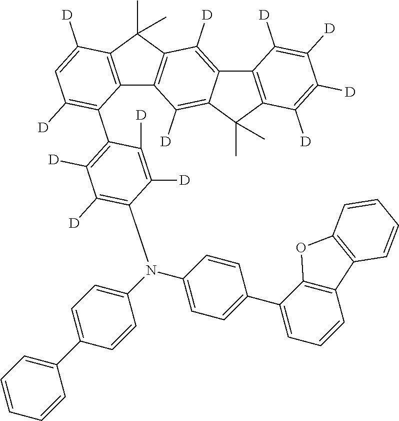 [SMILES: [2H]c1cc([2H])c2c(c1-c1c([2H])c([2H])c(N(c3ccc(-c4ccccc4)cc3)c3ccc(-c4cccc5c4oc4ccccc45)cc3)c([2H])c1[2H])-c1c([2H])c3c(c([2H])c1C2(C)C)-c1c([2H])c([2H])c([2H])c([2H])c1C3(C)C] | 129 |
| 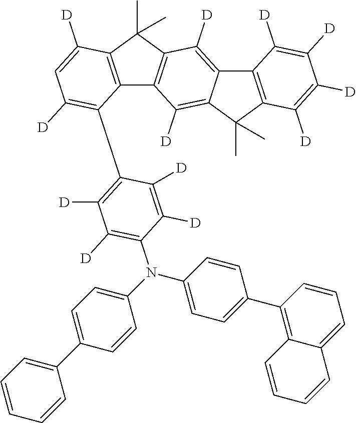 [SMILES: [2H]c1cc([2H])c2c(c1-c1c([2H])c([2H])c(N(c3ccc(-c4ccccc4)cc3)c3ccc(-c4cccc5ccccc45)cc3)c([2H])c1[2H])-c1c([2H])c3c(c([2H])c1C2(C)C)-c1c([2H])c([2H])c([2H])c([2H])c1C3(C)C] | 130 |
| 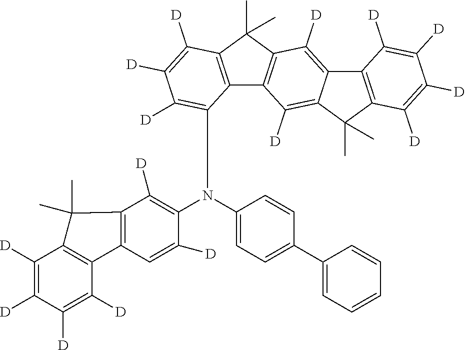 [SMILES: [2H]c1cc2c(c([2H])c1N(c1ccc(-c3ccccc3)cc1)c1c([2H])c([2H])c([2H])c3c1-c1c([2H])c4c(c([2H])c1C3(C)C)-c1c([2H])c([2H])c([2H])c([2H])c1C4(C)C)C(C)(C)c1c([2H])c([2H])c([2H])c([2H])c1-2] | 131 |
| 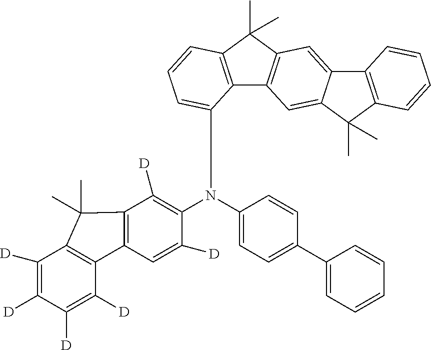 [SMILES: [2H]c1cc2c(c([2H])c1N(c1ccc(-c3ccccc3)cc1)c1cccc3c1-c1cc4c(cc1C3(C)C)-c1ccccc1C4(C)C)C(C)(C)c1c([2H])c([2H])c([2H])c([2H])c1-2] | 132 |
| 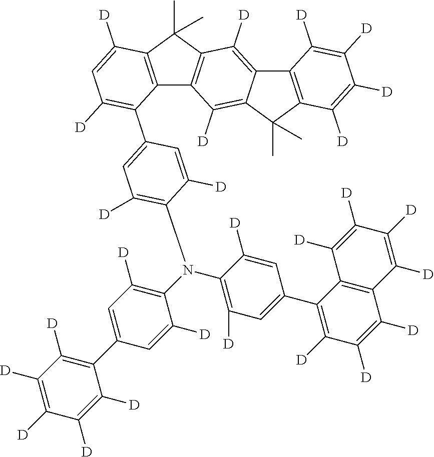 [SMILES: [2H]c1cc([2H])c2c(c1-c1cc([2H])c(N(c3c([2H])cc(-c4c([2H])c([2H])c([2H])c([2H])c4[2H])cc3[2H])c3c([2H])cc(-c4c([2H])c([2H])c([2H])c5c([2H])c([2H])c([2H])c([2H])c45)cc3[2H])c([2H])c1)-c1c([2H])c3c(c([2H])c1C2(C)C)-c1c([2H])c([2H])c([2H])c([2H])c1C3(C)C] | 133 |
| 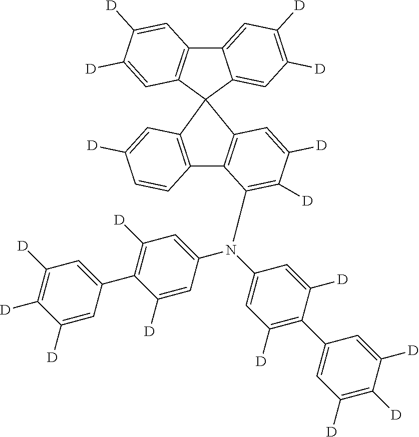 [SMILES: [2H]c1ccc2c(c1)C1(c3cc([2H])c([2H])cc3-c3cc([2H])c([2H])cc31)c1cc([2H])c([2H])c(N(c3cc([2H])c(-c4cc([2H])c([2H])c([2H])c4)c([2H])c3)c3cc([2H])c(-c4cc([2H])c([2H])c([2H])c4)c([2H])c3)c1-2] | 134 |
| 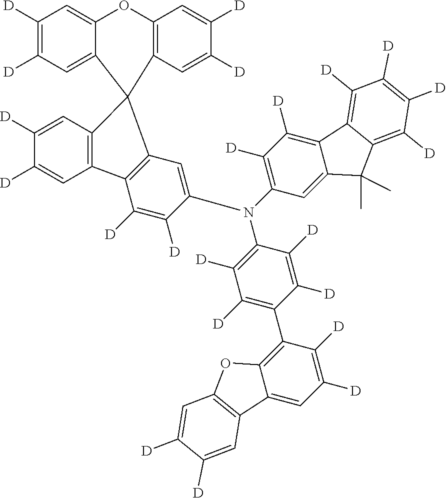 [SMILES: [2H]c1cc2c(cc1[2H])C1(c3cc([2H])c([2H])cc3O2)c2cc([2H])c([2H])cc2-c2c1cc(N(c1cc3c(c([2H])c1[2H])-c1c([2H])c([2H])c([2H])c([2H])c1C3(C)C)c1c([2H])c([2H])c(-c3c([2H])c([2H])cc4c3oc3cc([2H])c([2H])cc34)c([2H])c1[2H])c([2H])c2[2H]] | 135 |
| 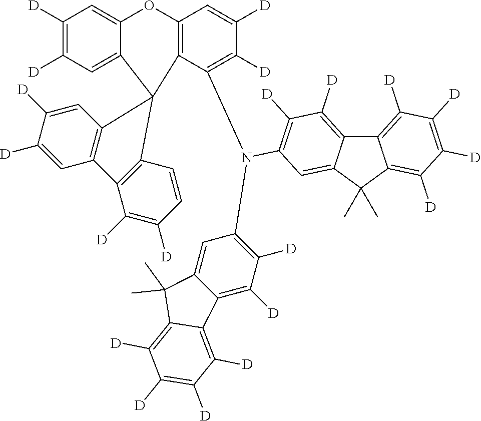 [SMILES: [2H]c1cc2c(cc1[2H])C1(c3cc([2H])c([2H])cc3-c3c1ccc([2H])c3[2H])c1c(cc([2H])c([2H])c1N(c1cc3c(c([2H])c1[2H])-c1c([2H])c([2H])c([2H])c([2H])c1C3(C)C)c1cc3c(c([2H])c1[2H])-c1c([2H])c([2H])c([2H])c([2H])c1C3(C)C)O2] | 136 |
| 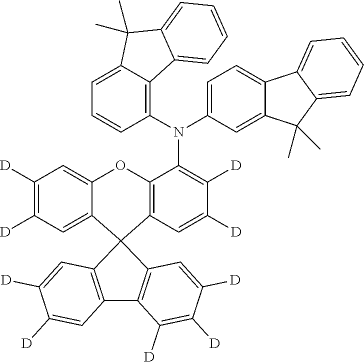 [SMILES: [2H]c1cc2c(cc1[2H])C1(c3cc([2H])c([2H])cc3-c3c1cc([2H])c([2H])c3[2H])c1cc([2H])c([2H])c(N(c3ccc4c(c3)C(C)(C)c3ccccc3-4)c3cccc4c3-c3ccccc3C4(C)C)c1O2] | 137 |
| 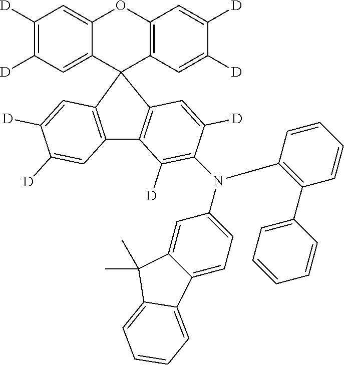 [SMILES: [2H]c1cc2c(cc1[2H])C1(c3cc([2H])c([2H])cc3O2)c2cc([2H])c([2H])cc2-c2c1cc([2H])c(N(c1ccc3c(c1)C(C)(C)c1ccccc1-3)c1ccccc1-c1ccccc1)c2[2H]] | 138 |
| 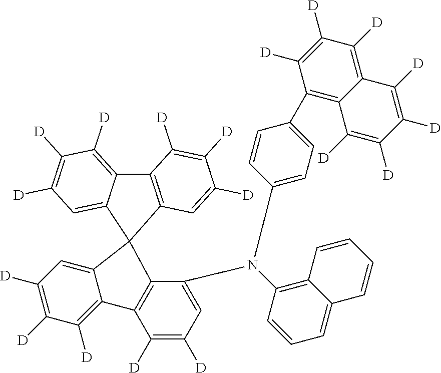 [SMILES: [2H]c1cc2c(c([2H])c1[2H])-c1c(cc([2H])c([2H])c1[2H])C21c2cc([2H])c([2H])c([2H])c2-c2c([2H])c([2H])cc(N(c3ccc(-c4c([2H])c([2H])c([2H])c5c([2H])c([2H])c([2H])c([2H])c45)cc3)c3cccc4ccccc34)c21] | 139 |
| 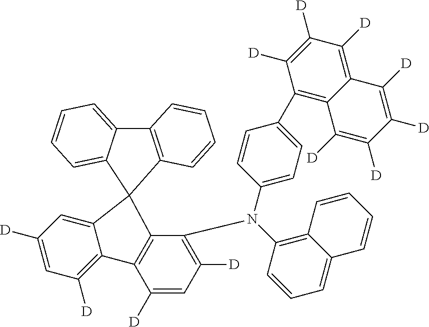 [SMILES: [2H]c1cc([2H])c2c(c1)C1(c3ccccc3-c3ccccc31)c1c-2c([2H])cc([2H])c1N(c1ccc(-c2c([2H])c([2H])c([2H])c3c([2H])c([2H])c([2H])c([2H])c23)cc1)c1cccc2ccccc12] | 140 |
| 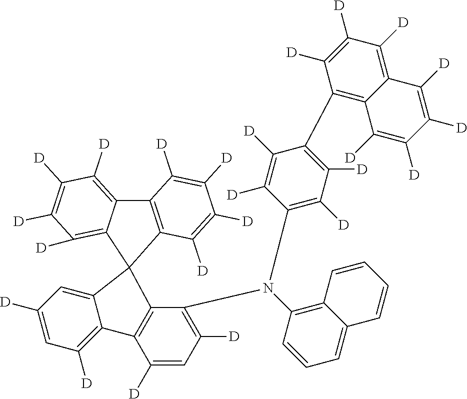 [SMILES: [2H]c1cc([2H])c2c(c1)C1(c3c([2H])c([2H])c([2H])c([2H])c3-c3c([2H])c([2H])c([2H])c([2H])c31)c1c-2c([2H])cc([2H])c1N(c1c([2H])c([2H])c(-c2c([2H])c([2H])c([2H])c3c([2H])c([2H])c([2H])c([2H])c23)c([2H])c1[2H])c1cccc2ccccc12] | 141 |
| 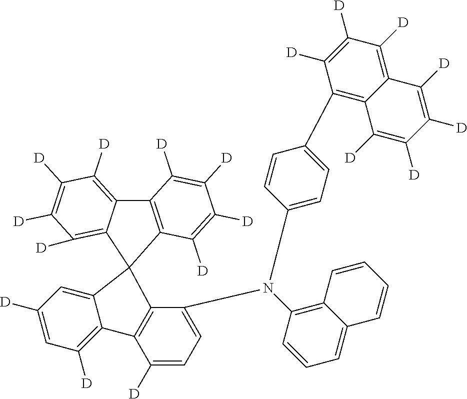 [SMILES: [2H]c1cc([2H])c2c(c1)C1(c3c(N(c4ccc(-c5c([2H])c([2H])c([2H])c6c([2H])c([2H])c([2H])c([2H])c56)cc4)c4cccc5ccccc45)ccc([2H])c3-2)c2c([2H])c([2H])c([2H])c([2H])c2-c2c([2H])c([2H])c([2H])c([2H])c21] | 142 |
| 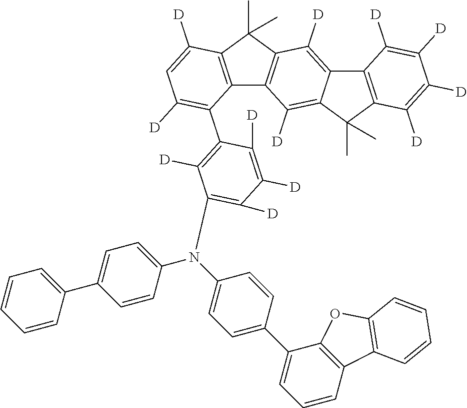 [SMILES: [2H]c1cc([2H])c2c(c1-c1c([2H])c([2H])c([2H])c(N(c3ccc(-c4ccccc4)cc3)c3ccc(-c4cccc5c4oc4ccccc45)cc3)c1[2H])-c1c([2H])c3c(c([2H])c1C2(C)C)-c1c([2H])c([2H])c([2H])c([2H])c1C3(C)C] | 143 |
| 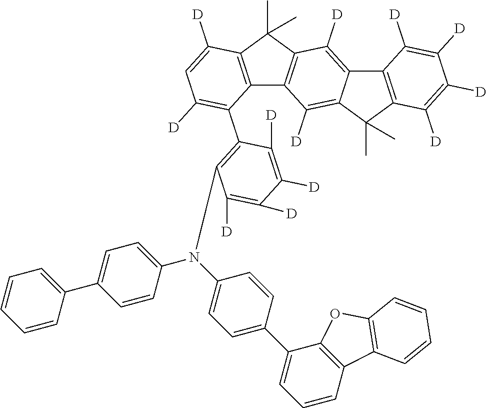 [SMILES: [2H]c1cc([2H])c2c(c1-c1c([2H])c([2H])c([2H])c([2H])c1N(c1ccc(-c3ccccc3)cc1)c1ccc(-c3cccc4c3oc3ccccc34)cc1)-c1c([2H])c3c(c([2H])c1C2(C)C)-c1c([2H])c([2H])c([2H])c([2H])c1C3(C)C] | 144 |
| 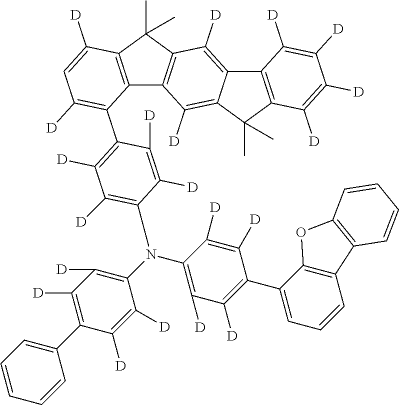 [SMILES: [2H]c1cc([2H])c2c(c1-c1c([2H])c([2H])c(N(c3c([2H])c([2H])c(-c4ccccc4)c([2H])c3[2H])c3c([2H])c([2H])c(-c4cccc5c4oc4ccccc45)c([2H])c3[2H])c([2H])c1[2H])-c1c([2H])c3c(c([2H])c1C2(C)C)-c1c([2H])c([2H])c([2H])c([2H])c1C3(C)C] | 145 |
| 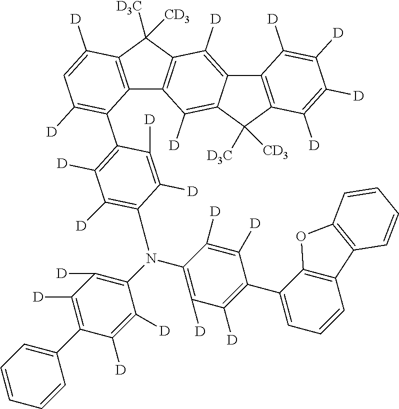 [SMILES: [2H]c1cc([2H])c2c(c1-c1c([2H])c([2H])c(N(c3c([2H])c([2H])c(-c4ccccc4)c([2H])c3[2H])c3c([2H])c([2H])c(-c4cccc5c4oc4ccccc45)c([2H])c3[2H])c([2H])c1[2H])-c1c([2H])c3c(c([2H])c1C2(C([2H])([2H])[2H])C([2H])([2H])[2H])-c1c([2H])c([2H])c([2H])c([2H])c1C3(C([2H])([2H])[2H])C([2H])([2H])[2H]] | 146 |
| 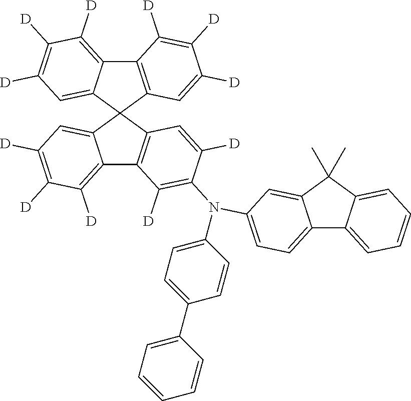 [SMILES: [2H]c1cc2c(c([2H])c1[2H])-c1c(cc([2H])c([2H])c1[2H])C21c2cc([2H])c([2H])c([2H])c2-c2c1cc([2H])c(N(c1ccc(-c3ccccc3)cc1)c1ccc3c(c1)C(C)(C)c1ccccc1-3)c2[2H]] | 147 |
| 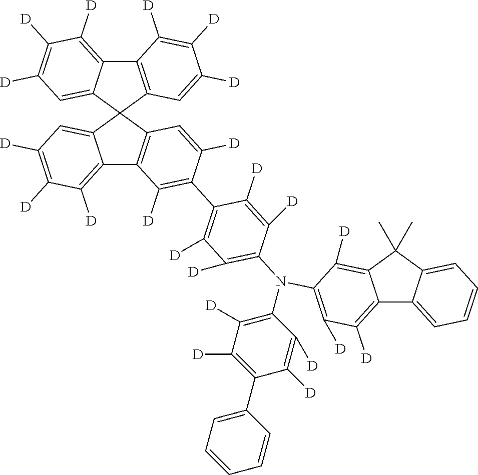 [SMILES: [2H]c1cc2c(c([2H])c1[2H])-c1c(cc([2H])c([2H])c1[2H])C21c2cc([2H])c([2H])c([2H])c2-c2c1cc([2H])c(-c1c([2H])c([2H])c(N(c3c([2H])c([2H])c(-c4ccccc4)c([2H])c3[2H])c3c([2H])c([2H])c4c(c3[2H])C(C)(C)c3ccccc3-4)c([2H])c1[2H])c2[2H]] | 148 |
| 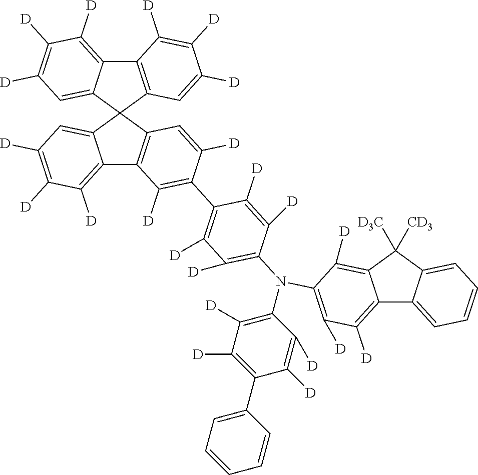 [SMILES: [2H]c1cc2c(c([2H])c1[2H])-c1c(cc([2H])c([2H])c1[2H])C21c2cc([2H])c([2H])c([2H])c2-c2c1cc([2H])c(-c1c([2H])c([2H])c(N(c3c([2H])c([2H])c(-c4ccccc4)c([2H])c3[2H])c3c([2H])c([2H])c4c(c3[2H])C(C([2H])([2H])[2H])(C([2H])([2H])[2H])c3ccccc3-4)c([2H])c1[2H])c2[2H]] | 149 |
| 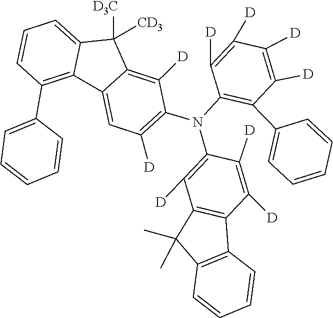 [SMILES: [2H]c1cc2c(c([2H])c1N(c1c([2H])c([2H])c3c(c1[2H])C(C)(C)c1ccccc1-3)c1c([2H])c([2H])c([2H])c([2H])c1-c1ccccc1)C(C([2H])([2H])[2H])(C([2H])([2H])[2H])c1cccc(-c3ccccc3)c1-2] | 150 |
| 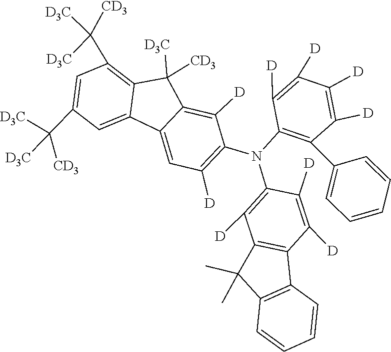 [SMILES: [2H]c1cc2c(c([2H])c1N(c1c([2H])c([2H])c3c(c1[2H])C(C)(C)c1ccccc1-3)c1c([2H])c([2H])c([2H])c([2H])c1-c1ccccc1)C(C([2H])([2H])[2H])(C([2H])([2H])[2H])c1c-2cc(C(C([2H])([2H])[2H])(C([2H])([2H])[2H])C([2H])([2H])[2H])cc1C(C([2H])([2H])[2H])(C([2H])([2H])[2H])C([2H])([2H])[2H]] | 151 |
| 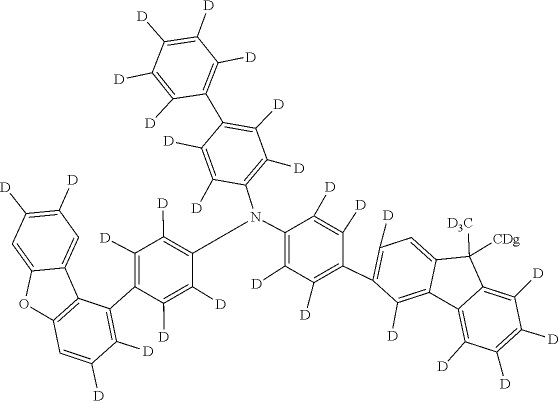 | 152 |
| 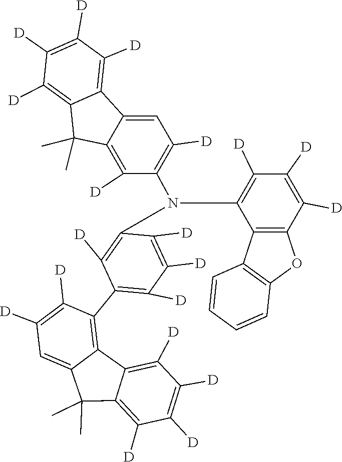 [SMILES: [2H]c1cc2c(c(-c3c([2H])c([2H])c([2H])c(N(c4c([2H])cc5c(c4[2H])C(C)(C)c4c([2H])c([2H])c([2H])c([2H])c4-5)c4c([2H])c([2H])c([2H])c5oc6ccccc6c45)c3[2H])c1[2H])-c1c([2H])c([2H])c([2H])c([2H])c1C2(C)C] | 153 |
| 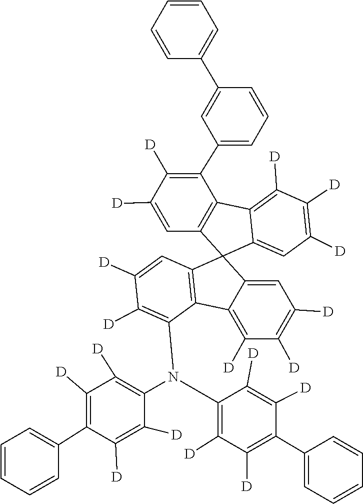 [SMILES: [2H]c1cc2c(c([2H])c1[2H])-c1c(cc([2H])c([2H])c1-c1cccc(-c3ccccc3)c1)C21c2cc([2H])c([2H])c([2H])c2-c2c1cc([2H])c([2H])c2N(c1c([2H])c([2H])c(-c2ccccc2)c([2H])c1[2H])c1c([2H])c([2H])c(-c2ccccc2)c([2H])c1[2H]] | 154 |

The compounds according to the application and the mixtures according to the application may be produced by various synthesis routes, especially using deuteration reactions. Where the syntheses of compounds according to the application are discussed hereinafter, this also means the mixtures according to the application.

Two different basic approaches to the synthesis of the compounds according to the application are presented hereinafter.

In a preferred approach for the synthesis, a compound, preferably a compound suitable for use in electronic devices, especially organic electroluminescent devices, is converted in a deuteration reaction to a compound according to the application. The starting compound is preferably undeuterated. One example of this is the following reaction shown in scheme 1:

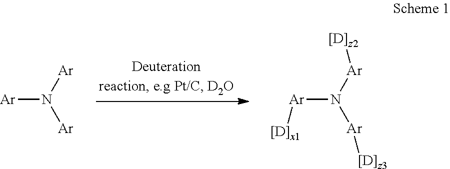

Ar here is the same or different and is selected from aromatic and heteroaromatic ring systems that may optionally be substituted, and z1, z2, z3 are each identical or different natural numbers, where hydrogen atoms in reactant and in product are not shown.

In an alternative, likewise preferred approach for the synthesis, a reactive compound, preferably an intermediate, more preferably an intermediate of a Buchwald reaction, is deuterated, preferably partly deuterated, in a deuteration reaction, and then converted further. It is only by this further conversion that a compound according to the application is obtained. One example of this approach for the synthesis is shown in scheme 2 below:

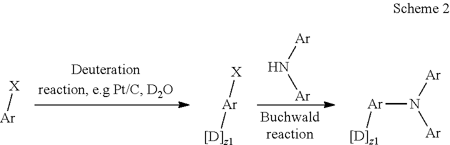

Ar here is the same or different and is selected from aromatic and heteroaromatic ring systems that may optionally be substituted, and z1 is a natural number, where hydrogen atoms in reactant and in product are not shown, and X is a reactive group, preferably Cl, Br or I.

Preferred embodiments of the reactant Ar-X in the synthesis method shown above are the following intermediates derived from the groups of the formulae (G-1) and (G-2) and (G-3):

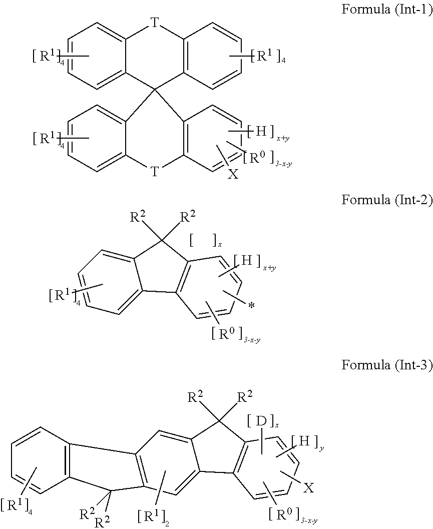

where the groups that occur are as defined above, and preferably correspond to their preferred embodiments.

Particularly preferred embodiments of these reactants conform to the following formulae:

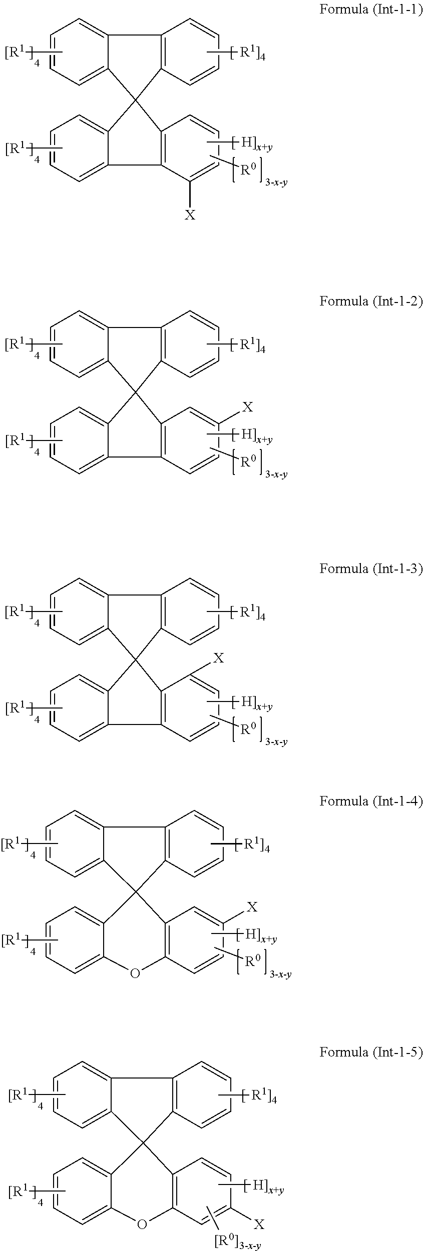

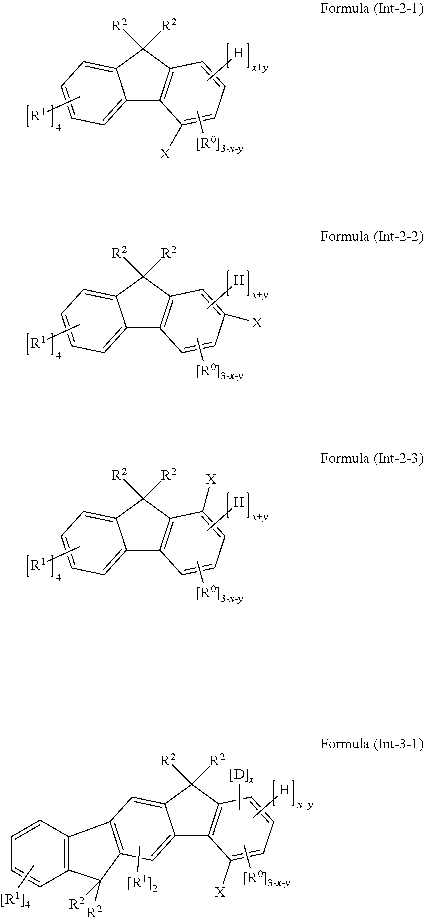

where the groups that occur are as defined above, and preferably correspond to their preferred embodiments.

In the context of the two approaches, different deuteration reactions may be used. A preferred deuteration reaction uses a transition metal catalyst and a deuterium source, for example a deuterated solvent, and a high reaction temperature. The term “deuterium source” here encompasses any compound that contains one or more deuterium atoms and is able to release them under suitable conditions. The reaction temperature here is preferably between 100° C. and 200° C., more preferably between 140° C. and 180° C. The transition metal catalyst is preferably selected from Pt on activated carbon, preferably 5% dry platinum on charcoal, and palladium on charcoal, preferably 5% dry palladium on charcoal. The deuterated solvent and the deuterium source are preferably the same or different and are selected from D20, benzene-d6, chloroform-d, acetonitrile-d3, acetone-d6, acetic acid-d4, methanol-d4, toluene-d8 and mixtures of these solvents. A preferred deuterium source is D20 or a combination of D20 and a fully deuterated organic solvent. A particularly preferred deuterium source is the combination of D20 with a fully deuterated organic solvent, where the fully deuterated solvent here is not restricted. Particularly suitable fully deuterated solvents here are benzene-d6 and toluene-d8. A particularly preferred deuterium source or deuterated solvent is a mixture of D20 and toluene-d8. In addition, the reaction is preferably conducted under elevated pressure.

The application thus provides a process for producing a compound or mixture according to the application, characterized in that an H/D isotopolog of the compound in which the number of deuterium atoms is smaller by an integer d than in the compound according to the application, and the number of hydrogen atoms is greater by the integer d than in the compound according to the application, is converted with a transition metal catalyst and using a deuterated solvent to one or more different compounds according to the application. The H/D isotopolog of the compound according to the application is preferably an undeuterated compound. The integer d is at least 1, preferably at least 5, more preferably at least 10.

In this deuteration reaction, which characteristically uses a transition metal catalyst, hydrogen atoms having poor steric accessibility are preferentially not exchanged for D. These especially include hydrogen atoms in the 1 position of fluorenyl groups and spirobifluorenyl groups, as follows marked by an arrow in formulae (G-1) and (G-2) and (G-3):

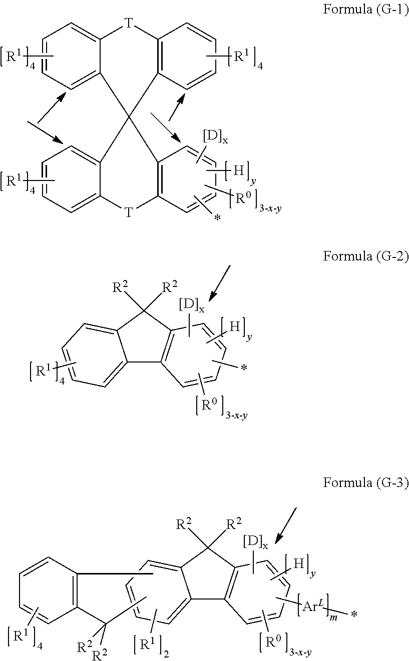

If compounds of the formulae (I-A) to (I-J) are converted by this reaction, what are preferably obtained are compounds of the formulae (I-A-a), (I-A-a-1), (I-B-a), (I-C-a), (I-D-a), (I-E-a), (I-F-a), (I-G-a), (I-H-a) and (I-J-a).

An alternative preferred deuteration reaction uses acidic conditions, D20, optionally in combination with a further deuterated solvent, which is preferably aromatic and/or protic, and is more preferably selected from benzene-d6, chloroform-d, acetonitrile-d3, acetone-d6, acetic acid-d4, methanol-d4 and toluene-d8, and a low reaction temperature. The reaction temperature is preferably −10° C. to 30° C. In a first step, preference is given to working at a temperature between 1° and 30° C., preferably between 15 and 25° C., and a second step in which D20 is added is conducted at a lower temperature, preferably between −10° C. and 10° C., more preferably between −5° C. and 5° C. Deuterated solvents are preferably selected from aromatic and/or protic solvents, more preferably D20, benzene-d6, chloroform-d, acetonitrile-d3, acetone-d6, acetic acid-d4, methanol-d4 and toluene-d8, and mixtures of these solvents. The acidic conditions are preferably established by addition of a strong organic acid, preferably selected from trifluoromethanesulfonic acid, p-toluenesulfonic acid, benzenesulfonic acid, fluoroantimonic acid, methanesulfonic acid, pentacyanocyclopentadiene, sulfonic acid-based ion exchanger, tricyanomethane and trifluoroacetic acid, most preferably trifluoromethanesulfonic acid.

The application thus provides a process for producing a compound or mixture according to the application, characterized in that an H/D isotopolog of the compound in which the number of deuterium atoms is smaller by an integer d than in the compound according to the application, and the number of hydrogen atoms is greater by the integer d than in the compound according to the application, is converted under the action of acid and using a deuterated solvent to one or more different compounds according to the application. The H/D isotopolog of the compound according to the application is preferably an undeuterated compound. The integer d is at least 1, preferably at least 5, more preferably at least 10.

In this deuteration reaction, which is characteristically conducted under acidic conditions, hydrogen atoms in positions that are in a meta position to a substituent with a +M effect, such as the amino group on the aromatic six-membered ring in formula (I) or a chlorine, bromine or iodine atom, are preferentially not converted to D. The person skilled in the art knows which substituents exert the abovementioned +M effect or ortho/para-directing effect in the electrophilic aromatic substitution reaction aside from the abovementioned amino group and chlorine, iodine and bromine atoms, and so they will be able in these cases to predict the selectivity of the H/D exchange by the deuteration reaction under acidic conditions.

If compounds of the formulae (I-A) to (I-J) are converted by this reaction, what are preferably obtained are compounds of the formulae (I-A-b), (I-A-b-1), (I-B-b), (I-C-b), (I-D-b), (I-E-b), (I-F-b), (I-G-b), (I-H-b) and (I-J-b).

For the processing of the compounds and mixtures according to the application from a liquid phase, for example by spin-coating or by printing methods, formulations of the compounds or mixtures according to the application are required. These formulations may, for example, be solutions, dispersions or emulsions. For this purpose, it may be preferable to use mixtures of two or more solvents. Suitable and preferred solvents are, for example, toluene, anisole, o-, m- or p-xylene, methyl benzoate, mesitylene, tetralin, veratrole, THF, methyl-THF, THP, chlorobenzene, dioxane, phenoxytoluene, especially 3-phenoxytoluene, (−)-fenchone, 1,2,3,5-tetramethylbenzene, 1,2,4,5-tetramethylbenzene, 1-methylnaphthalene, 2-methylbenzothiazole, 2-phenoxyethanol, 2-pyrrolidinone, 3-methylanisole, 4-methylanisole, 3,4-dimethylanisole, 3,5-dimethylanisole, acetophenone, alpha-terpineol, benzothiazole, butyl benzoate, cumene, cyclohexanol, cyclohexanone, cyclohexylbenzene, decalin, dodecylbenzene, ethyl benzoate, indane, methyl benzoate, NMP, p-cymene, phenetole, 1,4-diisopropylbenzene, dibenzyl ether, diethylene glycol butyl methyl ether, triethylene glycol butyl methyl ether, diethylene glycol dibutyl ether, triethylene glycol dimethyl ether, diethylene glycol monobutyl ether, tripropylene glycol dimethyl ether, tetraethylene glycol dimethyl ether, 2-isopropylnaphthalene, pentylbenzene, hexylbenzene, heptylbenzene, octylbenzene, 1,1-bis(3,4-dimethylphenyl)ethane, or mixtures of these solvents.

The invention therefore further provides a formulation, especially a solution, dispersion or emulsion, comprising at least one compound or mixture according to the application and at least one solvent, preferably an organic solvent. The way in which such solutions can be prepared is known to those skilled in the art.

The compounds and mixtures according to the application are suitable for use in an electronic device, especially an organic electroluminescent device (OLED). Depending on the substitution, they can be used in different functions and layers. Preference is given to use as a hole-transporting material in a hole-transporting layer, especially an electron blocker layer, and/or as matrix material in an emitting layer, more preferably in combination with a phosphorescent emitter.

The invention therefore further provides for the use of a compound or mixture according to the application in an electronic device. This electronic device is preferably selected from the group consisting of organic integrated circuits (OICs), organic field-effect transistors (OFETs), organic thin-film transistors (OTFTs), organic light-emitting transistors (OLETs), organic solar cells (OSCs), organic optical detectors, organic photoreceptors, organic field-quench devices (OFQDs), organic light-emitting electrochemical cells (OLECs), organic laser diodes (O-lasers) and more preferably organic electroluminescent devices (OLEDs).

The invention further provides an electronic device comprising at least one compound or mixture according to the application. This electronic device is preferably selected from the abovementioned devices.

Particular preference is given to an organic electroluminescent device comprising an anode, cathode and at least one emitting layer, characterized in that at least one organic layer comprising at least one compound or mixture according to the application is present in the device. Preference is given to an organic electroluminescent device comprising an anode, cathode and at least one emitting layer, characterized in that at least one organic layer in the device, selected from hole-transporting and emitting layers, comprises at least one compound or mixture according to the application.

A hole-transporting layer is understood here to mean all layers disposed between anode and emitting layer, preferably hole injection layer, hole transport layer and electron blocker layer. A hole injection layer is understood here to mean a layer that directly adjoins the anode. A hole transport layer is understood here to mean a layer which is between the anode and emitting layer but does not directly adjoin the anode, and preferably does not directly adjoin the emitting layer either. An electron blocker layer is understood here to mean a layer which is between the anode and emitting layer and directly adjoins the emitting layer. An electron blocker layer preferably has a high-energy LUMO and hence prevents electrons from exiting from the emitting layer.

Apart from the cathode, anode and emitting layer, the electronic device may comprise further layers. These are selected, for example, from in each case one or more hole injection layers, hole transport layers, hole blocker layers, electron transport layers, electron injection layers, electron blocker layers, exciton blocker layers, interlayers, charge generation layers and/or organic or inorganic p/n junctions. However, it should be pointed out that not every one of these layers need necessarily be present and the choice of layers always depends on the compounds used and especially also on whether the device is a fluorescent or phosphorescent electroluminescent device.

The sequence of layers in the electronic device is preferably as follows:
-anode-
-hole injection layer-
-hole transport layer-
-optionally further hole transport layers-
-electron blocker layer-
-emitting layer-
-optionally hole blocker layer-
-electron transport layer-
-electron injection layer-
-cathode-.

It is not obligatory for all the layers mentioned to be present, and/or further layers may additionally be present.

The sequence of layers in the electronic device is more preferably as follows:
-anode-
-hole injection layer-
-hole transport layer-
-electron blocker layer-
-emitting layer-
-hole blocker layer-
-electron transport layer-
-electron injection layer-
-cathode-.

The compound or mixture according to the application is preferably present here in the electron blocker layer of the electronic device with the abovementioned layer sequence.

In a preferred embodiment, the electronic device containing the compound or mixture according to the application contains multiple emitting layers arranged in succession, each having different emission maxima between 380 nm and 750 nm. In other words, different emitting compounds used in each of the multiple emitting layers fluoresce or phosphoresce and emit blue, green, yellow, orange or red light. In a preferred embodiment, the electronic device contains three emitting layers in succession in a stack, of which one in each case exhibits blue emission, one green emission, and one orange or red, preferably red, emission. Preferably, in this case, the blue-emitting layer is a fluorescent layer, and the green-emitting layer is a phosphorescent layer, and the red- or orange-emitting layer is a phosphorescent layer. The compound or mixture according to the application is preferably present in a hole-transporting layer or in the emitting layer. It should be noted that, for the production of white light, rather than a plurality of color-emitting emitter compounds, an emitter compound used individually which emits over a broad wavelength range may also be suitable.

It is preferable that the compound or mixture according to the application is used as hole transport material, especially in an electron blocker layer. The emitting layer here may be a fluorescent emitting layer, or it may be a phosphorescent emitting layer. The emitting layer is preferably a blue-fluorescing layer or a green-phosphorescing layer.

When the device containing the compound or mixture according to the application contains a phosphorescent emitting layer, it is preferable that this layer contains two or more, preferably exactly two, different matrix materials (mixed matrix system). Preferred embodiments of mixed matrix systems are described in detail further down.

If the compound or mixture according to the application is used as hole transport material in a hole transport layer, a hole injection layer or an electron blocker layer, the compound or mixture according to the application can be used on its own, i.e. in a proportion of 100%, in the hole transport layer, or it can be used in combination with one or more further compounds.

In a preferred embodiment, a hole-transporting layer comprising the compound or mixture according to the application additionally comprises one or more further hole-transporting compounds. These further hole-transporting compounds are preferably selected from triarylamine compounds, more preferably from monotriarylamine compounds. They are most preferably selected from the preferred embodiments of hole transport materials that are specified further down. In the preferred embodiment described, the compound or mixture according to the application and the one or more further hole-transporting compounds are preferably each present in a proportion of at least 10%, more preferably each in a proportion of at least 20%.

In a preferred embodiment, a hole-transporting layer comprising the compound or mixture according to the application additionally contains one or more p-dopants. p-Dopants used according to the present invention are preferably those organic electron acceptor compounds capable of oxidizing one or more of the other compounds in the mixture.

Particularly preferred as p-dopants are quinodimethane compounds, azaindenofluorenediones, azaphenalenes, azatriphenylenes, 12, metal halides, preferably transition metal halides, metal oxides, preferably metal oxides comprising at least one transition metal or a metal from main group 3, and transition metal complexes, preferably complexes of Cu, Co, Ni, Pd and Pt with ligands containing at least one oxygen atom as binding site.

Preference is further given to transition metal oxides as dopants, preferably oxides of rhenium, molybdenum and tungsten, more preferably Re₂O₇, MoO₃, WO₃ and ReO₃. Still further preference is given to complexes of bismuth in the (III) oxidation state, more particularly bismuth(III) complexes with electron-deficient ligands, more particularly carboxylate ligands.

The p-dopants are preferably in substantially homogeneous distribution in the p-doped layers. This can be achieved, for example, by co-evaporation of the p-dopant and the hole transport material matrix. The p-dopant is preferably present in a proportion of 1% to 10% in the p-doped layer.

Especially preferred p-dopants are the compounds shown in the table on page 99 to page 100 of WO2021/104749.

In a preferred embodiment, a hole injection layer that conforms to one of the following embodiments is present in the device: a) it contains a triarylamine and a p-dopant; or b) it contains a single electron-deficient material (electron acceptor). In a preferred embodiment of embodiment a), the triarylamine is a monotriarylamine, especially one of the preferred triarylamine derivatives mentioned further down. In a preferred embodiment of embodiment b), the electron-deficient material is a hexaazatriphenylene derivative as described in US 2007/0092755.

The compound or mixture according to the application may be present in a hole injection layer, in a hole transport layer and/or in an electron blocker layer of the device. When the compound is present in a hole injection layer or in a hole transport layer, it has preferably been p-doped, meaning that it is in mixed form with a p-dopant, as described above, in the layer.

More preferably, the compound or mixture according to the application is present in an electron blocker layer. In this case, it is preferably not p-doped. Further preferably, in this case, it is preferably present alone in the layer without addition of a further compound.

In an alternative preferred embodiment, the compound or mixture according to the application is used in an emitting layer as matrix material in combination with one or more emitting compounds, preferably phosphorescent emitting compounds. The phosphorescent emitting compounds here are preferably selected from red-phosphorescing and green-phosphorescing compounds.

The proportion of the matrix material in the emitting layer in this case is between 50.0% and 99.9% by volume, preferably between 80.0% and 99.5% by volume, and more preferably between 85.0% and 97.0% by volume.

Correspondingly, the proportion of the emitting compound is between 0.1% and 50.0% by volume, preferably between 0.5% and 20.0% by volume, and more preferably between 3.0% and 15.0% by volume.

An emitting layer of an organic electroluminescent device may also contain systems comprising a plurality of matrix materials (mixed matrix systems) and/or a plurality of emitting compounds. In this case too, the emitting compounds are generally those compounds having the smaller proportion in the system and the matrix materials are those compounds having the greater proportion in the system. In individual cases, however, the proportion of a single matrix material in the system may be less than the proportion of a single emitting compound.

It is preferable that the compound or mixture according to the application is used as a component of mixed matrix systems, preferably for phosphorescent emitters. The mixed matrix systems preferably comprise two or three different matrix materials, more preferably two different matrix materials. Preferably, in this case, one of the two materials is a material having hole-transporting properties and the other material is a material having electron-transporting properties. It is further preferable when one of the materials is selected from compounds having a large energy differential between HOMO and LUMO (wide-bandgap materials). The compound or mixture according to the application in a mixed matrix system is preferably the matrix material having hole-transporting properties. Correspondingly, when the compound or mixture according to the application is used as matrix material for a phosphorescent emitter in the emitting layer of an OLED, a second matrix compound having electron-transporting properties is present in the emitting layer. The two different matrix materials may be present here in a ratio of 1:50 to 1:1, preferably 1:20 to 1:1, more preferably 1:10 to 1:1 and most preferably 1:4 to 1:1.

The desired electron-transporting and hole-transporting properties of the mixed matrix components may, however, also be combined mainly or entirely in a single mixed matrix component, in which case the further mixed matrix component(s) fulfil(s) other functions.

Preference is given to using the following material classes in the abovementioned layers of the device:

### Phosphorescent Emitters:

The term “phosphorescent emitters” typically encompasses compounds where the emission of light is effected through a spin-forbidden transition, for example a transition from an excited triplet state or a state having a higher spin quantum number, for example a quintet state.

Suitable phosphorescent emitters are especially compounds which, when suitably excited, emit light, preferably in the visible region, and also contain at least one atom of atomic number greater than 20, preferably greater than 38, and less than 84, more preferably greater than 56 and less than 80. Preference is given to using, as phosphorescent emitters, compounds containing copper, molybdenum, tungsten, rhenium, ruthenium, osmium, rhodium, iridium, palladium, platinum, silver, gold or europium, especially compounds containing iridium, platinum or copper.

In the context of the present invention, all luminescent iridium, platinum or copper complexes are considered to be phosphorescent compounds.

In general, all phosphorescent complexes as used for phosphorescent OLEDs according to the prior art and as known to those skilled in the art in the field of organic electroluminescent devices are suitable for use in the devices according to the application. The compounds depicted in the following table are especially suitable:

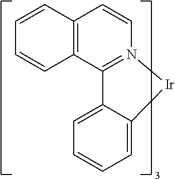

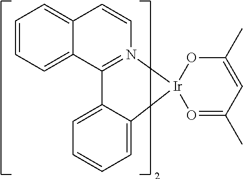

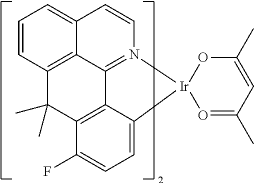

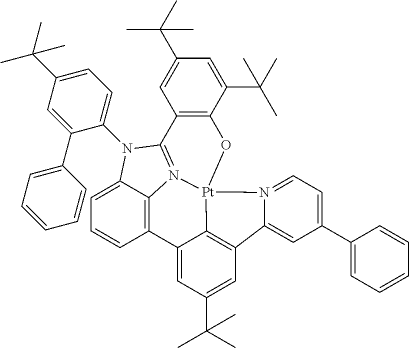

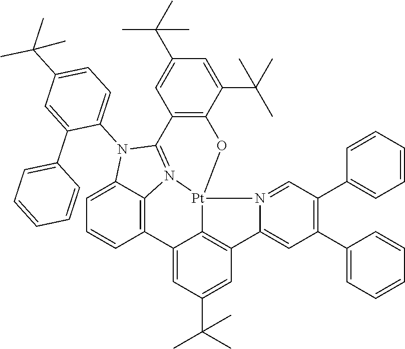

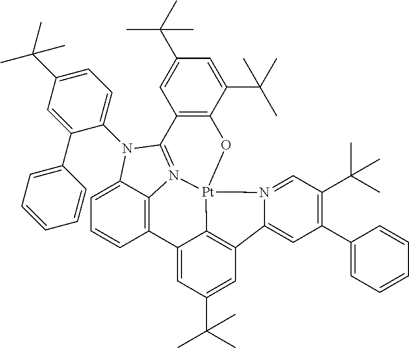

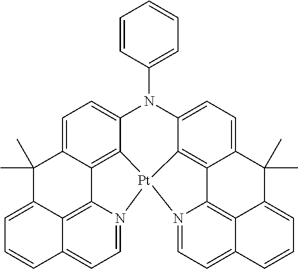

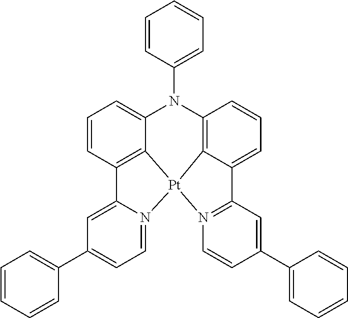

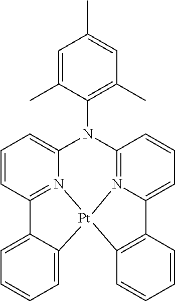

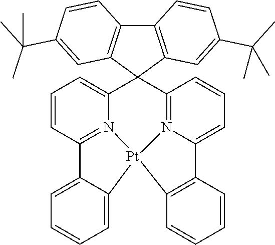

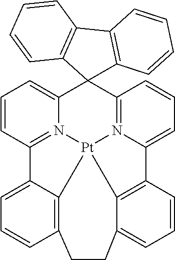

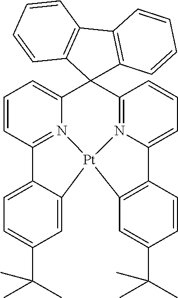

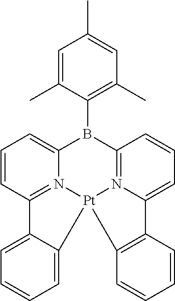

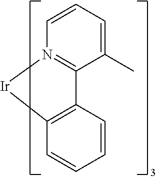

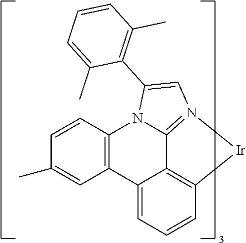

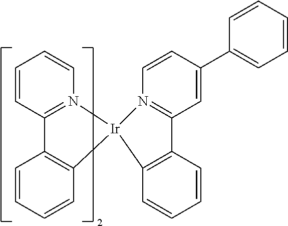

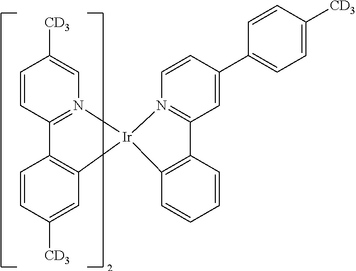

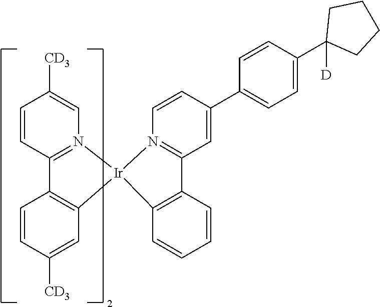

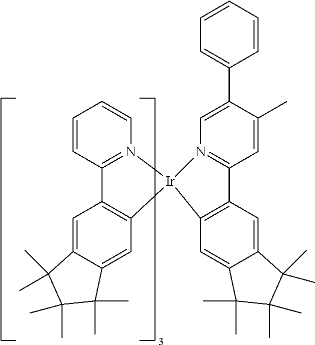

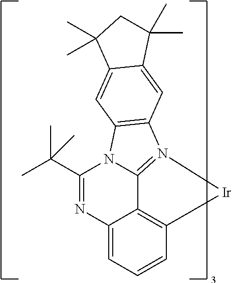

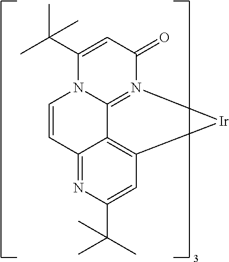

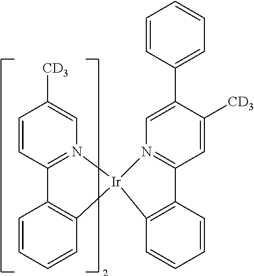

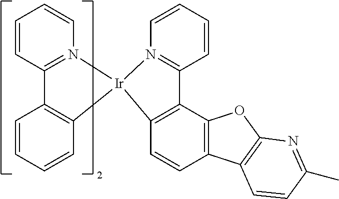

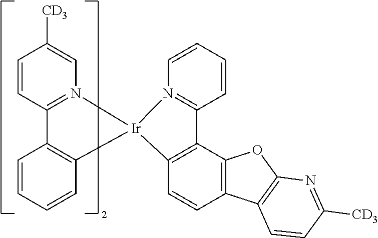

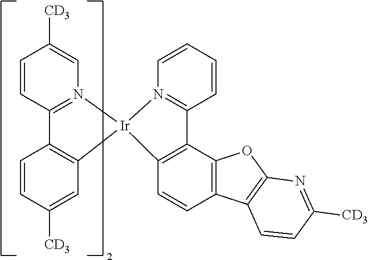

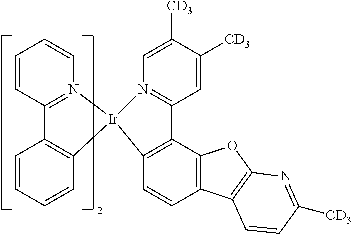

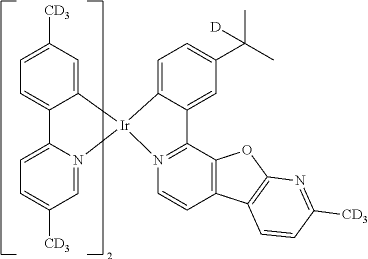

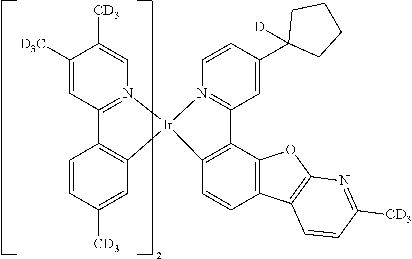

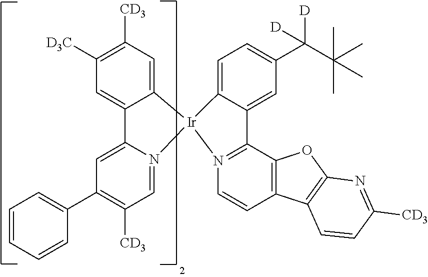

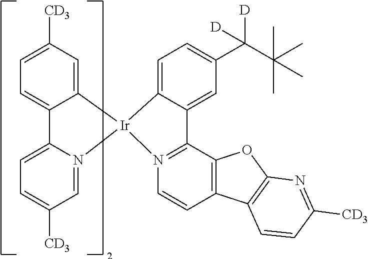

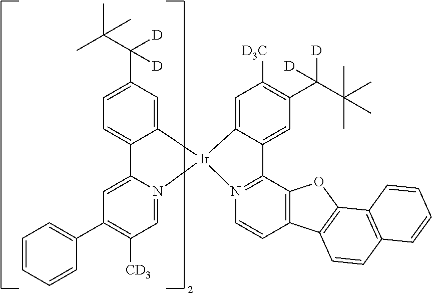

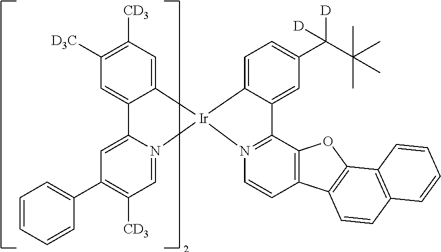

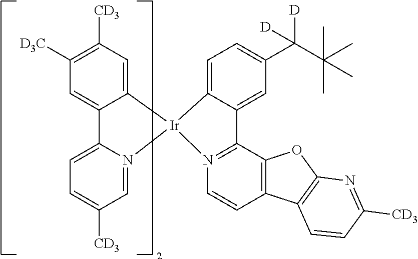

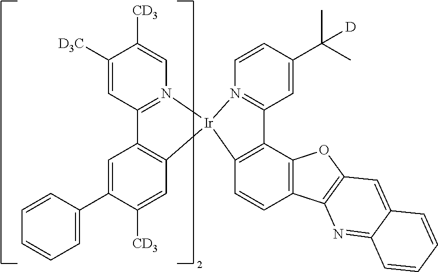

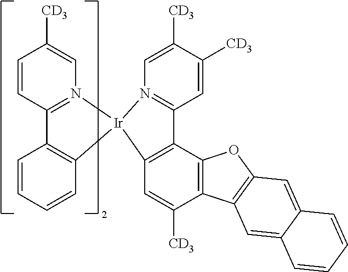

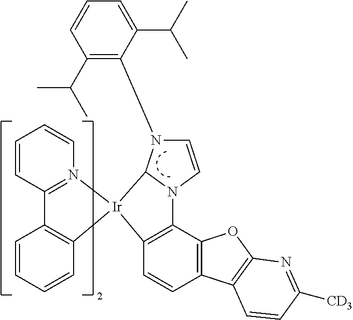

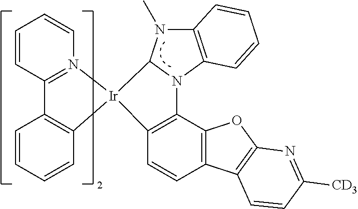

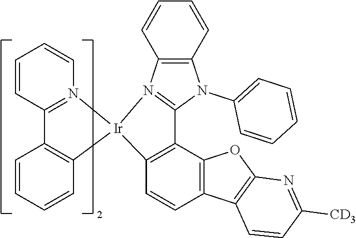

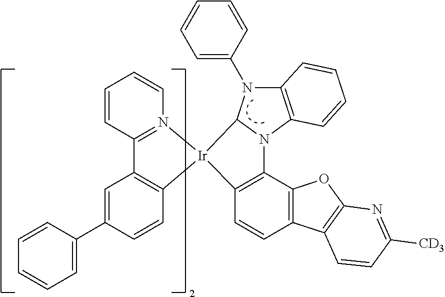

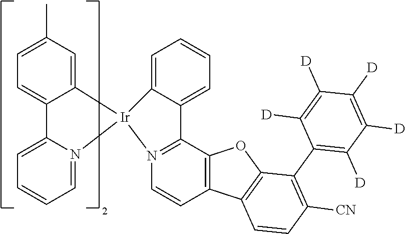

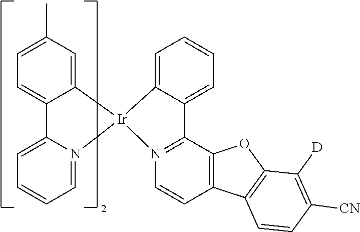

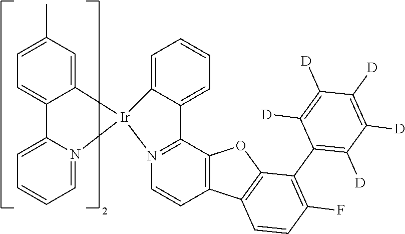

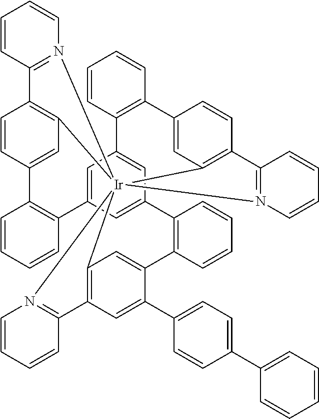

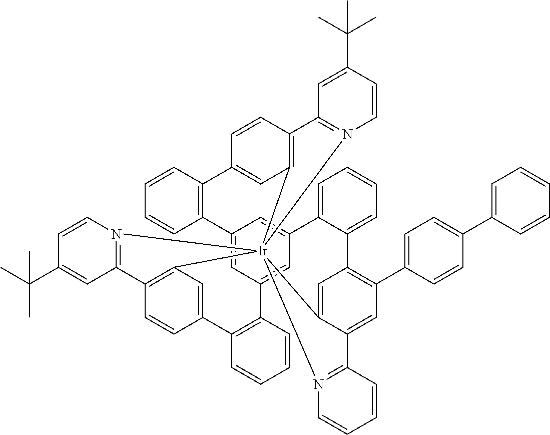

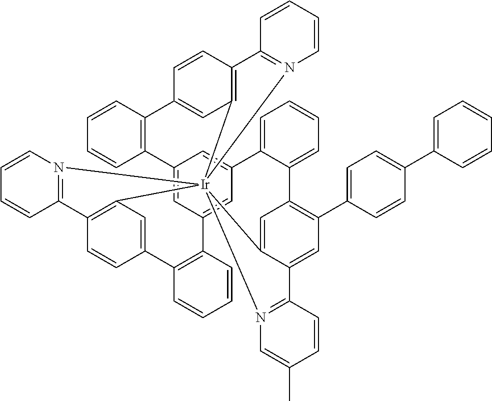

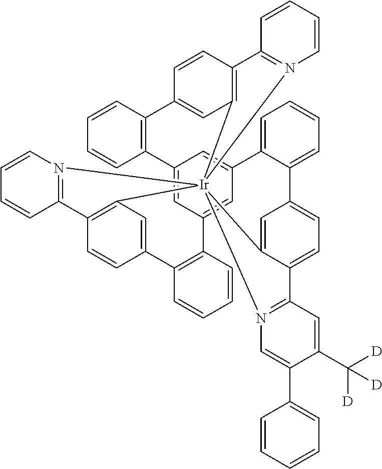

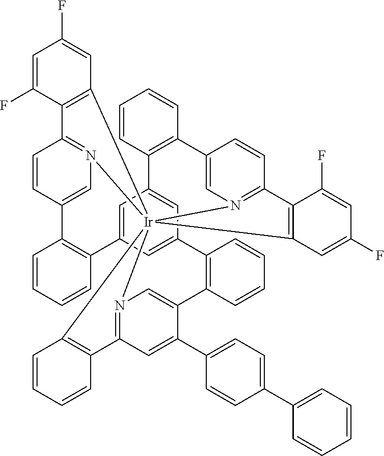

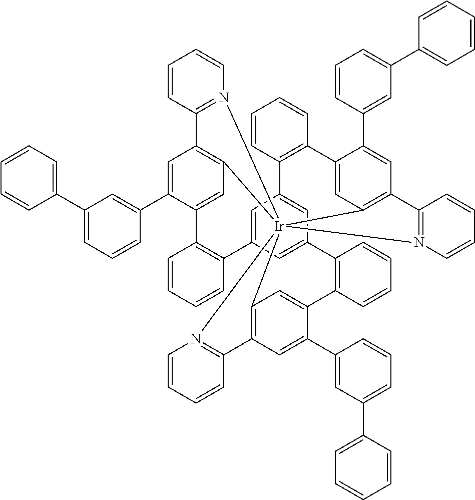

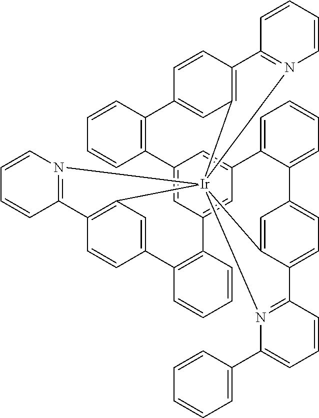

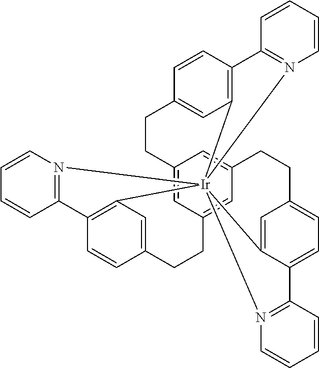

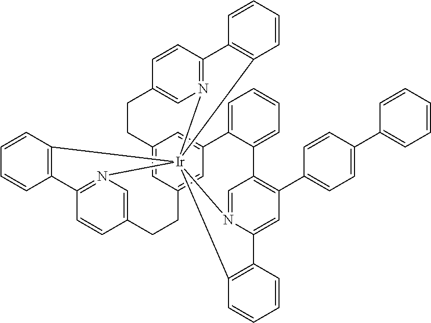

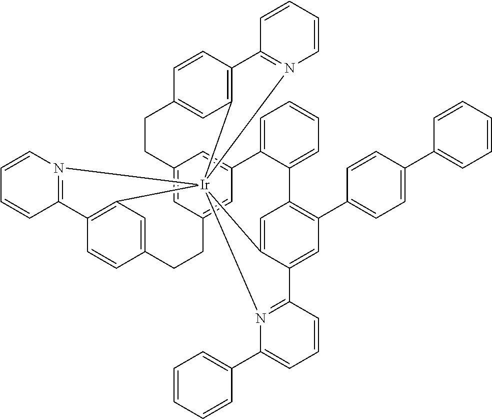

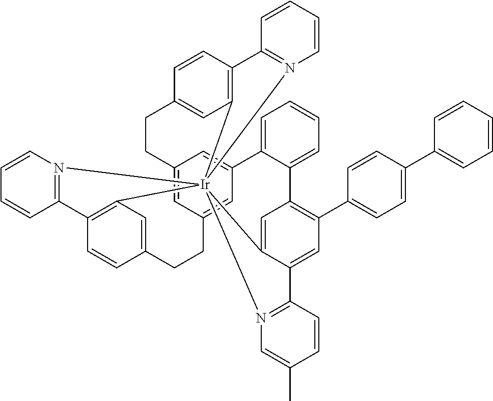

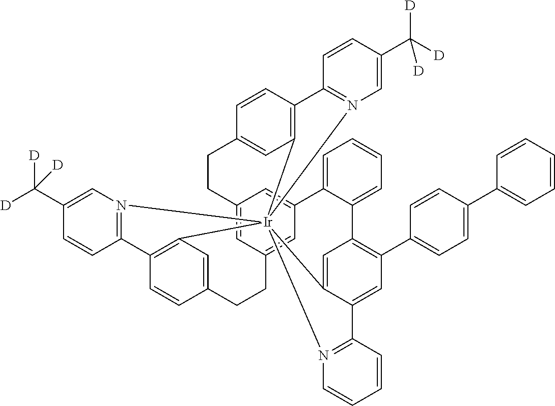

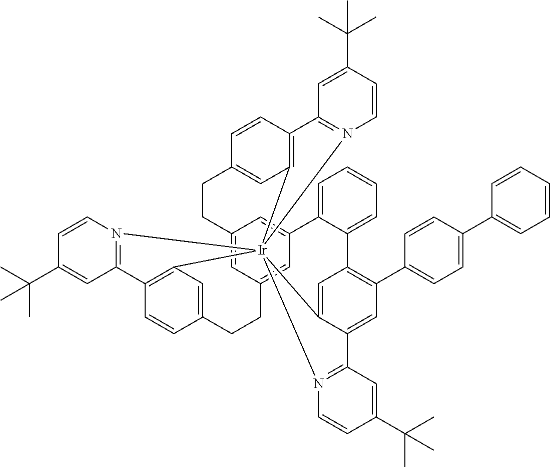

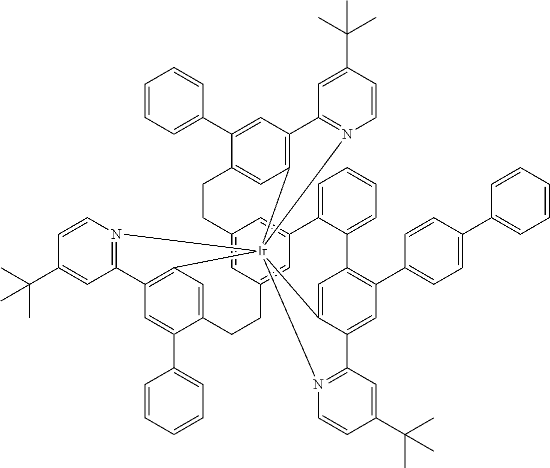

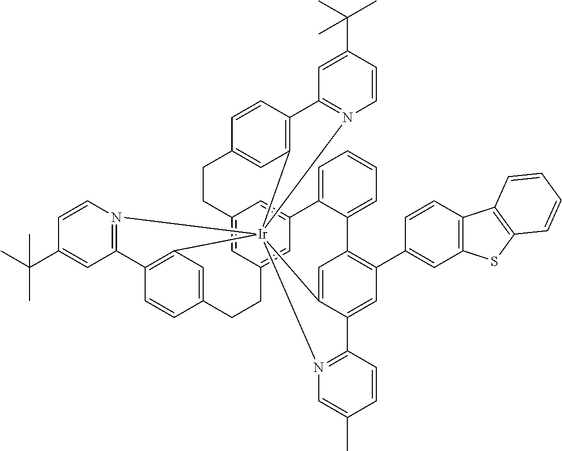

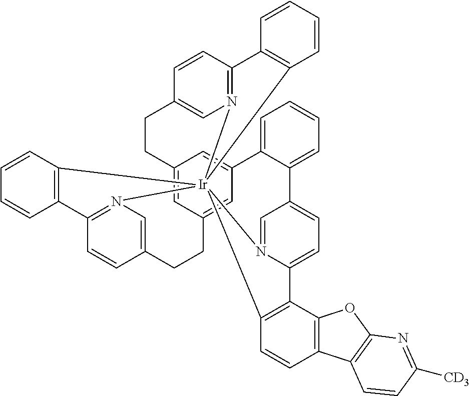

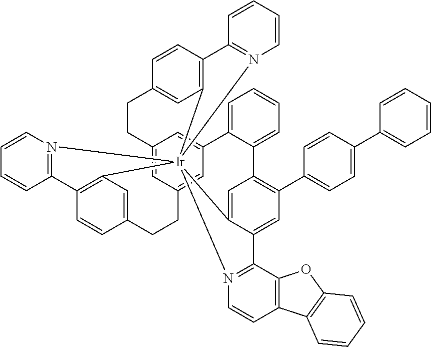

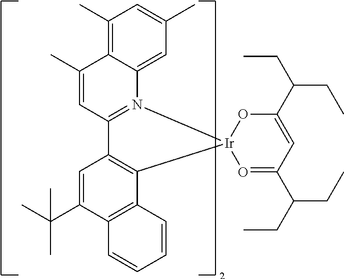

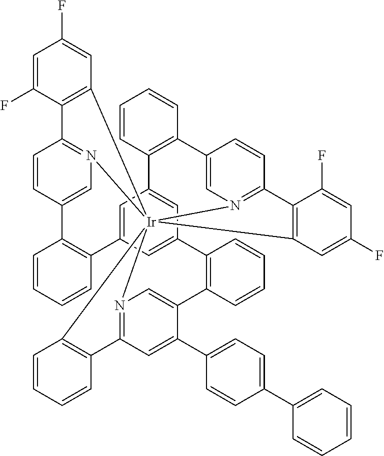

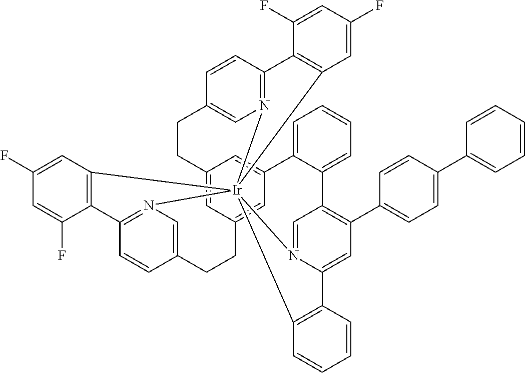

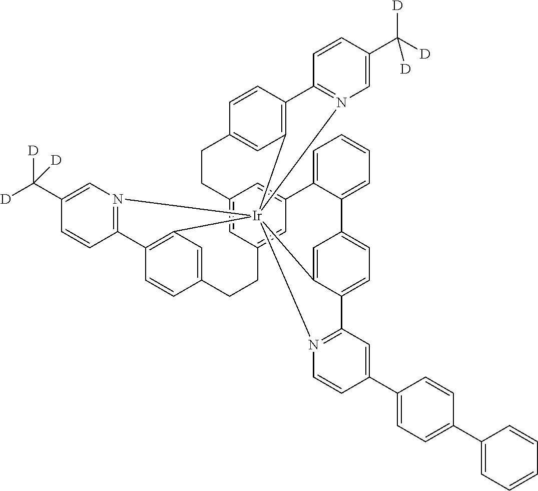

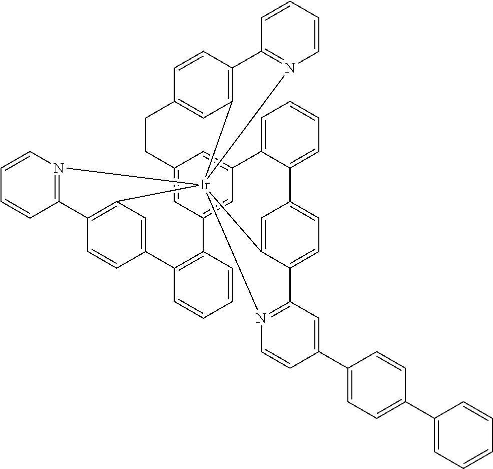

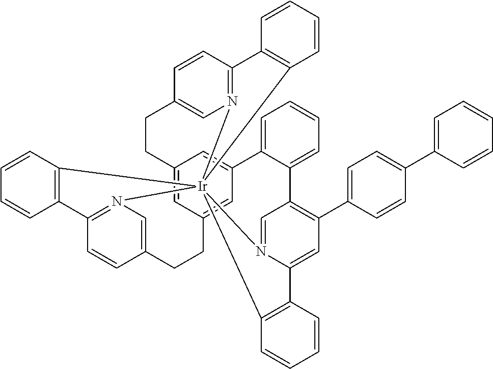

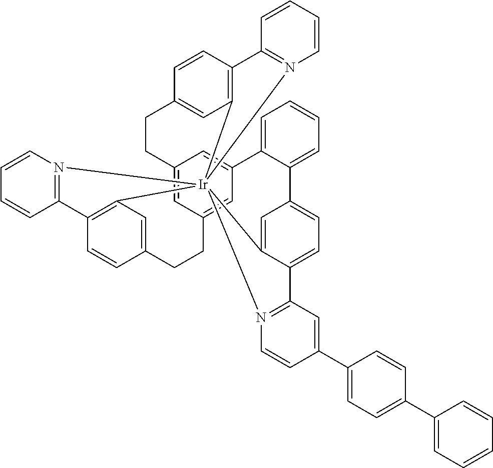

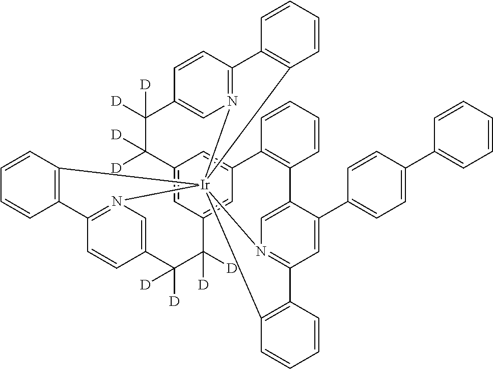

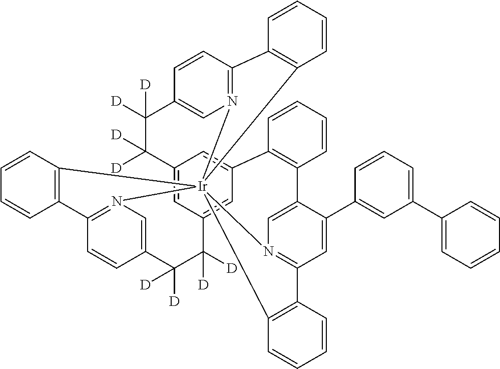

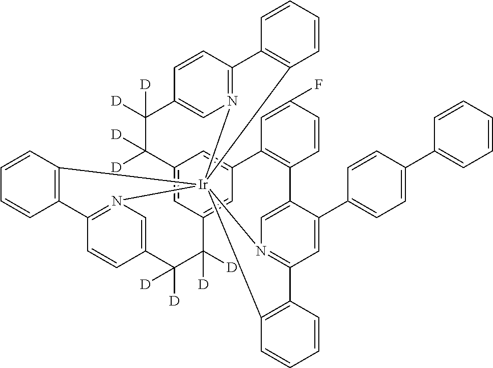

### Fluorescent Emitters:

Preferred fluorescent emitting compounds are selected from the class of the arylamines. An arylamine or an aromatic amine in the context of this invention is understood to mean a compound containing three substituted or unsubstituted aromatic or heteroaromatic ring systems bonded directly to the nitrogen. Preferably, at least one of these aromatic or heteroaromatic ring systems is a fused ring system, more preferably having at least 14 aromatic ring atoms. Preferred examples of these are aromatic anthraceneamines, aromatic anthracenediamines, aromatic pyreneamines, aromatic pyrenediamines, aromatic chryseneamines or aromatic chrysenediamines. An aromatic anthraceneamine is understood to mean a compound in which a diarylamino group is bonded directly to an anthracene group, preferably in the 9 position. An aromatic anthracenediamine is understood to mean a compound in which two diarylamino groups are bonded directly to an anthracene group, preferably in the 9,10 positions. Aromatic pyreneamines, pyrenediamines, chryseneamines and chrysenediamines are defined analogously, where the diarylamino groups are bonded to the pyrene preferably in the 1 position or 1,6 positions. Further preferred emitting compounds are indenofluoreneamines or -diamines, benzoindenofluoreneamines or -diamines, and dibenzoindenofluoreneamines or -diamines, and indenofluorene derivatives having fused aryl groups. Likewise preferred are pyrenearylamines.

Likewise preferred are benzoindenofluoreneamines, benzofluoreneamines, extended benzoindenofluorenes, phenoxazines, and fluorene derivatives joined to furan units or to thiophene units.

### Matrix Materials for Fluorescent Emitters:

Preferred matrix materials for fluorescent emitters are selected from the classes of the oligoarylenes (e.g. 2,2′,7,7′-tetraphenylspirobifluorene), especially the oligoarylenes containing fused aromatic groups, the oligoarylenevinylenes, the polypodal metal complexes, the hole-conducting compounds, the electron-conducting compounds, especially ketones, phosphine oxides and sulfoxides; the atropisomers, the boronic acid derivatives or the benzanthracenes. Particularly preferred matrix materials are selected from the classes of the oligoarylenes comprising naphthalene, anthracene, benzanthracene and/or pyrene or atropisomers of these compounds, the oligoarylenevinylenes, the ketones, the phosphine oxides and the sulfoxides. Very particularly preferred matrix materials are selected from the classes of the oligoarylenes comprising anthracene, benzanthracene, benzophenanthrene and/or pyrene or atropisomers of these compounds. An oligoarylene in the context of this invention shall be understood to mean a compound in which at least three aryl or arylene groups are bonded to one another.

### Matrix Materials for Phosphorescent Emitters:

Preferred matrix materials for phosphorescent emitters, as well as the compounds or mixtures according to the application, are aromatic ketones, aromatic phosphine oxides or aromatic sulfoxides or sulfones, triarylamines, carbazole derivatives, e.g. CBP (N,N-biscarbazolylbiphenyl) or carbazole derivatives, indolocarbazole derivatives, indenocarbazole derivatives, azacarbazole derivatives, bipolar matrix materials, silanes, azaboroles or boronic esters, triazine derivatives, zinc complexes, diazasilole or tetraazasilole derivatives, diazaphosphole derivatives, bridged carbazole derivatives, triphenylene derivatives, or lactams.

### Electron-Transporting Materials:

Suitable electron-transporting materials are, for example, the compounds disclosed in Y. Shirota et al., Chem. Rev. 2007, 107(4), 953-1010, or other materials used in these layers according to the prior art.

Materials used for the electron transport layer may be any materials that are used as electron transport materials in the electron transport layer according to the prior art. Especially suitable are aluminum complexes, for example Alq₃, zirconium complexes, for example Zrq₄, lithium complexes, for example Liq, benzimidazole derivatives, triazine derivatives, pyrimidine derivatives, pyridine derivatives, pyrazine derivatives, quinoxaline derivatives, quinoline derivatives, oxadiazole derivatives, aromatic ketones, lactams, boranes, diazaphosphole derivatives and phosphine oxide derivatives.

Preferred electron transport and electron injection materials are the compounds shown in the table on page 122 to page 123 of WO2020/127176.

In a preferred embodiment, the electron transport layer(s) and the hole blocker layer of the electronic device containing at least one compound or mixture according to the application contain a compound containing a triazine group.

In a further preferred embodiment of the invention, the electron transport layer(s), preferably the electron transport layer(s) and the electron injection layer, of the electronic device contain a mixture containing lithium quinolinate and at least one further compound.

### Hole-Transporting Materials:

Further compounds which, in addition to the compounds or mixtures according to the application, are used with preference in hole-transporting layers of the OLEDs according to the application are indenofluoreneamine derivatives, amine derivatives, hexaazatriphenylene derivatives, amine derivatives with fused aromatic systems, monobenzoindenofluoreneamines, dibenzoindenofluoreneamines, spirobifluoreneamines, fluoreneamines, spirodibenzopyranamines, dihydroacridine derivatives, spirodibenzofurans and spirodibenzothiophenes, phenanthrenediarylamines, spirotribenzotropolones, spirobifluorenes having meta-phenyldiamine groups, spirobisacridines, xanthenediarylamines, and 9,10-dihydroanthracene spiro compounds having diarylamino groups. Preferred hole-transporting compounds are especially the compounds disclosed in the table from the bottom of page 116 to the bottom of page 120 in WO 2021/104749.

Compounds especially suitable for use in layers having a hole-transporting function in any OLEDs, not only the OLEDs according to the definitions of the present application, include the following compounds HT-1 to HT-3:

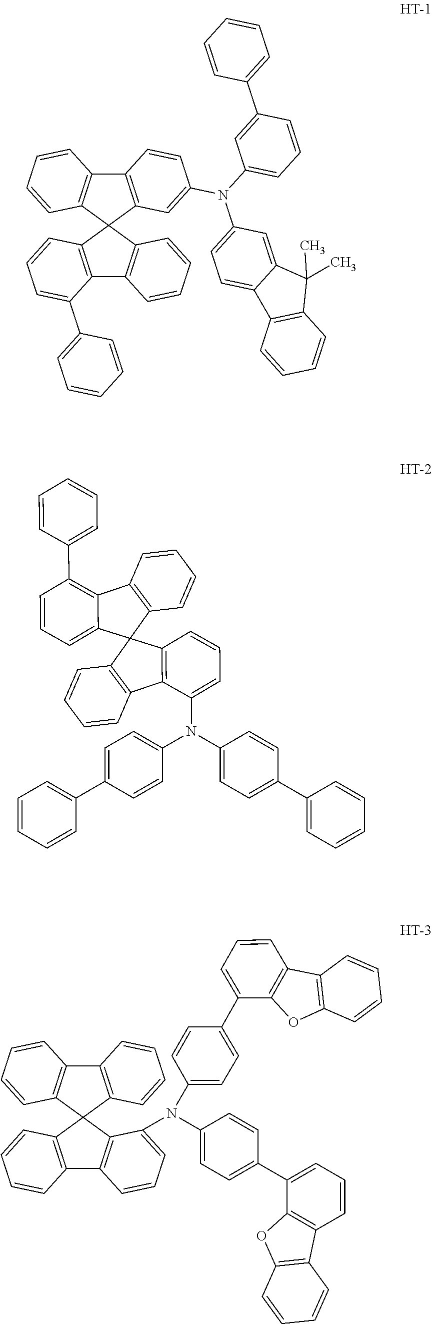 [SMILES: CC1(C)c2ccccc2-c2ccc(N(c3cccc(-c4ccccc4)c3)c3ccc4c(c3)C3(c5ccccc5-4)c4ccccc4-c4c(-c5ccccc5)cccc43)cc21 ; c1ccc(-c2ccc(N(c3ccc(-c4ccccc4)cc3)c3cccc4c3-c3ccccc3C43c4ccccc4-c4c(-c5ccccc5)cccc43)cc2)cc1 ; c1ccc2c(c1)-c1ccccc1C21c2ccccc2-c2cccc(N(c3ccc(-c4cccc5c4oc4ccccc45)cc3)c3ccc(-c4cccc5c4oc4ccccc45)cc3)c21]

The compounds HT-1 to HT-3 are generally suitable for use in hole-transporting layers. Their use is not limited to particular OLEDs, such as for example the OLEDs described in the present application.

The compounds HT-1 to HT-3 may be prepared by the methods disclosed in WO2012/034627A1 and in application EP20205399.7, which is yet to be published. The further teaching relating to the use and preparation of the compounds disclosed in these patent applications is hereby explicitly incorporated by reference and is preferably to be combined with the teaching given above relating to the use of the abovementioned compound as hole-transporting material. The compounds show exceptional properties when used in OLEDs, in particular exceptional lifetime and efficiency.

Compounds especially suitable for use in layers having a hole-transporting function in any OLEDs, not only the OLEDs according to the definitions of the present application, include the following compounds HT-4 to HT-13:

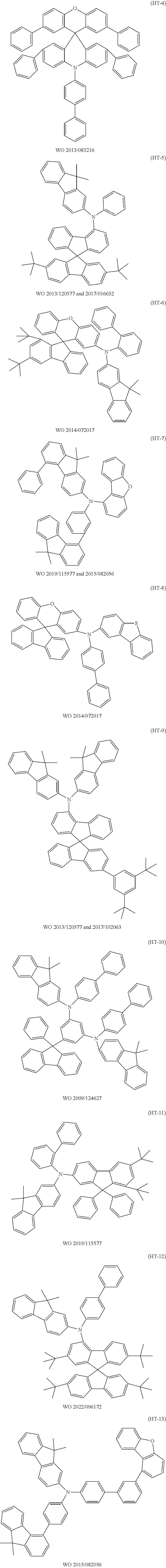

The compounds HT-4 to HT-13 are generally suitable for use in hole-transporting layers. Their use is not limited to particular OLEDs, such as for example the OLEDs described in the present application.

The compounds HT-4 to HT-13 may be prepared by the methods disclosed in the patent specifications cited in association with the compounds in the above table. The further teaching relating to the use and preparation of the compounds disclosed in these patent applications is hereby explicitly incorporated by reference and is preferably to be combined with the teaching given above relating to the use of the abovementioned compound as hole-transporting material. The compounds show exceptional properties when used in OLEDs, in particular exceptional lifetime and efficiency.

Preferred cathodes of the electronic device are metals having a low work function, metal alloys or multilayer structures composed of various metals, for example alkaline earth metals, alkali metals, main group metals or lanthanoids (e.g. Ca, Ba, Mg, Al, In, Mg, Yb, Sm, etc.). Additionally suitable are alloys composed of an alkali metal or alkaline earth metal and silver, for example an alloy composed of magnesium and silver. In the case of multilayer structures, in addition to the metals mentioned, it is also possible to use further metals having a relatively high work function, for example Ag or Al, in which case combinations of the metals such as Ca/Ag, Mg/Ag or Ba/Ag, for example, are generally used. It may also be preferable to introduce a thin interlayer of a material having a high dielectric constant between a metallic cathode and the organic semiconductor. Examples of useful materials for this purpose are alkali metal or alkaline earth metal fluorides, but also the corresponding oxides or carbonates (e.g. LiF, Li₂O, BaF₂, MgO, NaF, CsF, Cs₂CO₃, etc.). It is also possible to use lithium quinolinate (LiQ) for this purpose. The layer thickness of this layer is preferably between 0.5 and 5 nm.

Preferred anodes are materials having a high work function. Preferably, the anode has a work function of greater than 4.5 eV versus vacuum. Firstly, metals having a high redox potential are suitable for this purpose, for example Ag, Pt or Au. Secondly, metal/metal oxide electrodes (e.g. Al/Ni/NiOₓ, Al/PtOₓ) may also be preferred. For some applications, at least one of the electrodes has to be transparent or partly transparent in order to enable either the irradiation of the organic material (organic solar cell) or the emission of light (OLED, O-LASER). Preferred anode materials here are conductive mixed metal oxides. Particular preference is given to indium tin oxide (ITO) or indium zinc oxide (IZO). Preference is further given to conductive doped organic materials, especially conductive doped polymers. In addition, the anode may also consist of two or more layers, for example of an inner layer of ITO and an outer layer of a metal oxide, preferably tungsten oxide, molybdenum oxide or vanadium oxide.

In a preferred embodiment, the electronic device is characterized in that one or more layers are coated by a sublimation process. In this case, the materials are applied by vapor deposition in vacuum sublimation systems at an initial pressure of less than 10⁻⁵ mbar, preferably less than 10⁻⁶ mbar. In this case, however, it is also possible that the initial pressure is even lower, for example less than 10⁻⁷ mbar.

Preference is likewise given to an electronic device, characterized in that one or more layers are coated by the OVPD (organic vapor phase deposition) method or with the aid of a carrier gas sublimation. In this case, the materials are applied at a pressure between 10⁻⁵ mbar and 1 bar. A special case of this method is the OVJP (organic vapor jet printing) method, in which the materials are applied directly by a nozzle and thus structured (for example M. S. Arnold et al., Appl. Phys. Lett. 2008, 92, 053301).

Preference is additionally given to an electronic device, characterized in that one or more layers are produced from solution, for example by spin-coating, or by any printing method, for example screen printing, flexographic printing, nozzle printing or offset printing, but more preferably LITI (light-induced thermal imaging, thermal transfer printing) or inkjet printing. For this purpose, soluble compounds are needed. High solubility can be achieved by suitable substitution of the compounds.

It is further preferable that an electronic device according to the application is produced by applying one or more layers from solution and one or more layers by a sublimation method.

After application of the layers, according to the use, the device is structured, contact-connected and finally sealed, in order to rule out damaging effects of water and air.

According to the invention, the electronic devices comprising a compound or mixture according to the application can be used in displays, as light sources in lighting applications and as light sources in medical and/or cosmetic applications.

### EXAMPLES

### A) Synthesis Examples

The syntheses which follow, unless stated otherwise, are conducted under a protective gas atmosphere in dried solvents. The numbers for the reactants known from the literature, some of which are stated in square brackets, are the corresponding CAS numbers.

### Example 1

### d₂₁-N-(9,9-dimethyl-9H-fluoren-2-yl)-N-[3-(9,9-dimethyl-9H-fluoren-4-yl)phenyl]-8-oxatricyclo[7.4.0.0^{2,7}]trideca-1(9),2,4,6,10,12-hexaene-3-amine

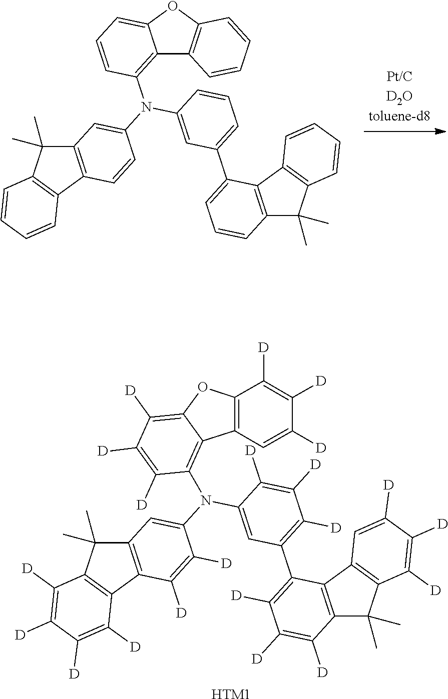

The starting compound of the synthesis may be prepared as described in WO2015/082056A1, pages 86-87.

10.0 g (15.5 mmol; 1.00 eq) of N-(9,9-dimethyl-9H-fluoren-2-yl)-N-[3-(9,9-dimethyl-9H-fluoren-4-yl)phenyl]-8-oxatricyclo[7.4.0.0^{2,7}]trideca-1(9),2,4,6,10,12-hexaene-3-amine (synthesis can be performed as described in WO 2015/082056 A1, example 1, pages 86 ff., with the appropriate reactants) and 20.0 g of Pt 5% on activated carbon are suspended in 400 g (502 mmol; 1.00 eq) of deuterium oxide [CAS 7789-20-0] and 200 g (778 mmol; 1.55 eq) of toluene-d8 [CAS 2037-26-5]. The reaction mixture is stirred at 165° C. and elevated autogenous pressure for 5 hours. Cooling is followed by two extractions with tetrahydrofuran and washing of the combined organic phases with saline solution and drying over sodium sulfate. After filtration, the solvent is removed under reduced pressure. The product shown above, in a mixture with fractions of H/D isotopomers and H/D isotopologs (4.52 g, 6.82 mmol, 44% of theory) is obtained after further purification by extraction, recrystallization and sublimation.

### Example 2

### d₁₉-N-(9,9-dimethyl-9H-fluoren-2-yl)-N-[3-(9,9-dimethyl-9H-fluoren-4-yl)phenyl]-8-oxatricyclo[7.4.0.0^{2,7}]trideca-1(9),2,4,6,10,12-hexaene-3-amine

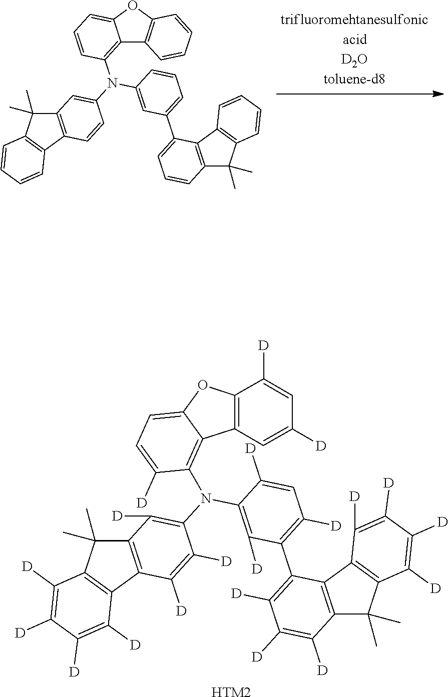

10.0 g (15.5 mmol; 1.00 eq) of N-(9,9-dimethyl-9H-fluoren-2-yl)-N-[3-(9,9-dimethyl-9H-fluoren-4-yl)phenyl]-8-oxatricyclo[7.4.0.0^{2,7}]trideca-1(9),2,4,6,10,12-hexaene-3-amine (synthesis can be performed as described in WO 2015/082056 A1, example 1, pages 86 ff., with the appropriate reactants) is suspended in 200 ml (120 eq) of toluene-d8 [CAS 2037-26-5]. Added to this mixture while cooling is 13.6 ml (10 eq.) of trifluoromethanesulfonic acid. The reaction mixture is stirred at room temperature for 6 hours. Thereafter, 36.4 ml (130 eq) of deuterium oxide [CAS 7789-20-0] is added dropwise at 0° C. Neutralization with a potassium sulfate solution is followed by extraction with toluene and washing of the combined organic phases with saline solution and drying over sodium sulfate. After filtration, the solvent is removed under reduced pressure. 7.90 g (11.9 mmol, 77% of theory) of the product shown above is obtained in a mixture with fractions of H/D isotopomers and H/D isotopologs after further purification by extraction, recrystallization and sublimation.

The following compounds can be obtained analogously:

| Example | Reactant | Product | Yield |
|---|---|---|---|
| 2b | 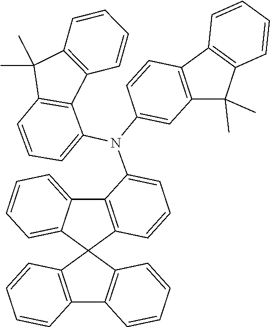 [SMILES: CC1(C)c2ccccc2-c2ccc(N(c3cccc4c3-c3ccccc3C4(C)C)c3cccc4c3-c3ccccc3C43c4ccccc4-c4ccccc43)cc21] [2647462-22-2] | 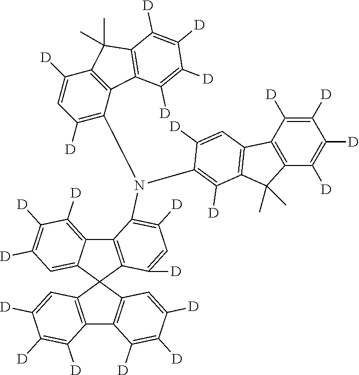 [SMILES: [2H]c1cc2c(c([2H])c1[2H])-c1c(cc([2H])c([2H])c1[2H])C21c2cc([2H])c([2H])c([2H])c2-c2c(N(c3c([2H])cc4c(c3[2H])C(C)(C)c3c([2H])c([2H])c([2H])c([2H])c3-4)c3c([2H])cc([2H])c4c3-c3c([2H])c([2H])c([2H])c([2H])c3C4(C)C)c([2H])cc([2H])c21] | 45% |
| 2c | 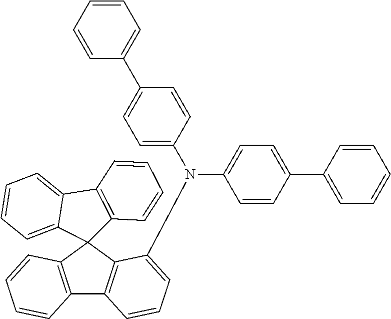 [SMILES: c1ccc(-c2ccc(N(c3ccc(-c4ccccc4)cc3)c3cccc4c3C3(c5ccccc5-c5ccccc53)c3ccccc3-4)cc2)cc1] | 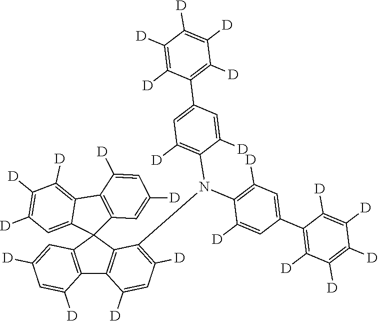 [SMILES: [2H]c1cc([2H])c2c(c1)C1(c3cc([2H])cc([2H])c3-c3c([2H])cc([2H])c(N(c4c([2H])cc(-c5c([2H])c([2H])c([2H])c([2H])c5[2H])cc4[2H])c4c([2H])cc(-c5c([2H])c([2H])c([2H])c([2H])c5[2H])cc4[2H])c31)c1cc([2H])c([2H])c([2H])c1-2] | 80% |
| | [1450933-27-3] | | |
| 2d | 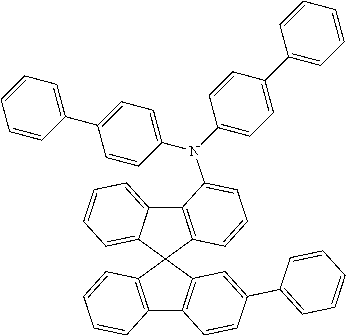 [SMILES: c1ccc(-c2ccc(N(c3ccc(-c4ccccc4)cc3)c3cccc4c3-c3ccccc3C43c4ccccc4-c4ccc(-c5ccccc5)cc43)cc2)cc1] [2102016-21-5] | 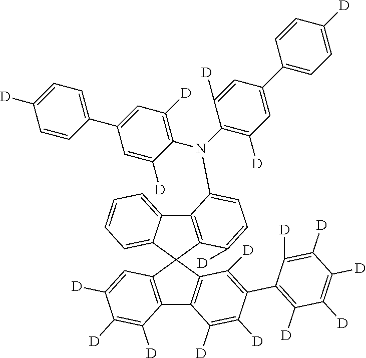 [SMILES: [2H]c1ccc(-c2cc([2H])c(N(c3ccc([2H])c4c3-c3ccccc3C43c4cc([2H])c([2H])c([2H])c4-c4c([2H])c([2H])c(-c5c([2H])c([2H])c([2H])c([2H])c5[2H])c([2H])c43)c3c([2H])cc(-c4ccc([2H])cc4)cc3[2H])c([2H])c2)cc1] | 62% |
| 2e | 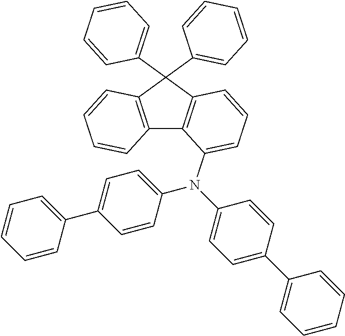 [SMILES: c1ccc(-c2ccc(N(c3ccc(-c4ccccc4)cc3)c3cccc4c3-c3ccccc3C4(c3ccccc3)c3ccccc3)cc2)cc1] | 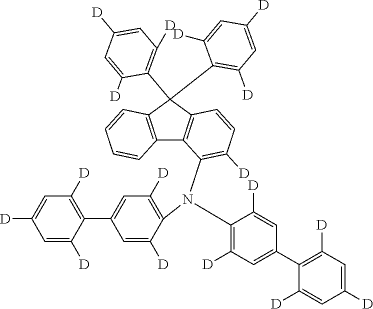 [SMILES: [2H]c1cc([2H])c(-c2cc([2H])c(N(c3c([2H])cc(-c4c([2H])cc([2H])cc4[2H])cc3[2H])c3c([2H])ccc4c3-c3ccccc3C4(c3c([2H])cc([2H])cc3[2H])c3c([2H])cc([2H])cc3[2H])c([2H])c2)c([2H])c1] | 58% |
| | [1547491-36-0] | | |
| 2f | 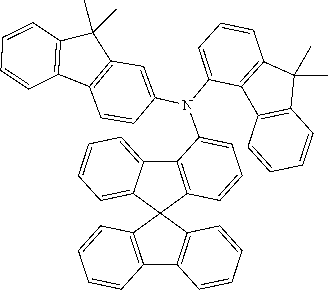 [SMILES: CC1(C)c2ccccc2-c2ccc(N(c3cccc4c3-c3ccccc3C4(C)C)c3cccc4c3-c3ccccc3C43c4ccccc4-c4ccccc43)cc21] [2647462-04-0] | 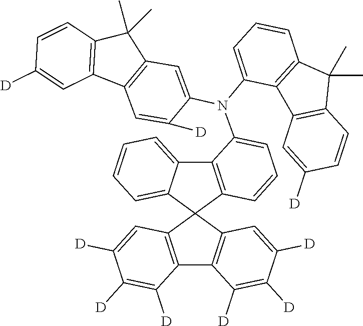 [SMILES: [2H]c1ccc2c(c1)-c1cc([2H])c(N(c3cccc4c3-c3cc([2H])ccc3C4(C)C)c3cccc4c3-c3ccccc3C43c4cc([2H])c([2H])c([2H])c4-c4c3cc([2H])c([2H])c4[2H])cc1C2(C)C] | 75% |
| 2g | 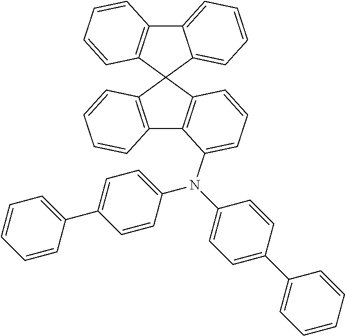 [SMILES: c1ccc(-c2ccc(N(c3ccc(-c4ccccc4)cc3)c3cccc4c3-c3ccccc3C43c4ccccc4-c4ccccc43)cc2)cc1] [1450933-43-3] | 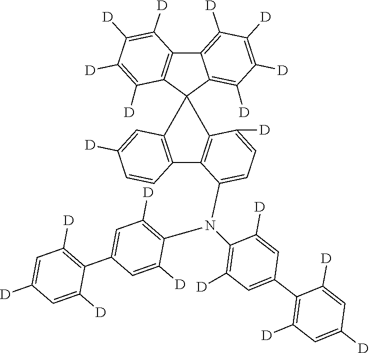 [SMILES: [2H]c1cc([2H])c(-c2cc([2H])c(N(c3ccc([2H])c4c3-c3ccc([2H])cc3C43c4c([2H])c([2H])c([2H])c([2H])c4-c4c([2H])c([2H])c([2H])c([2H])c43)c3c([2H])cc(-c4c([2H])cc([2H])cc4[2H])cc3[2H])c([2H])c2)c([2H])c1] | 70% |
| 2h | 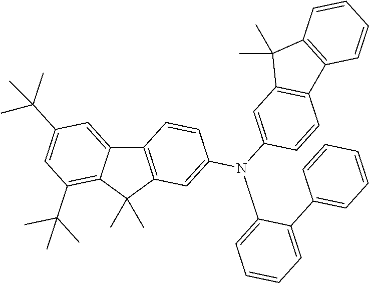 [SMILES: CC(C)(C)c1cc2c(c(C(C)(C)C)c1)C(C)(C)c1cc(N(c3ccc4c(c3)C(C)(C)c3ccccc3-4)c3ccccc3-c3ccccc3)ccc1-2] WO2019/115577 | 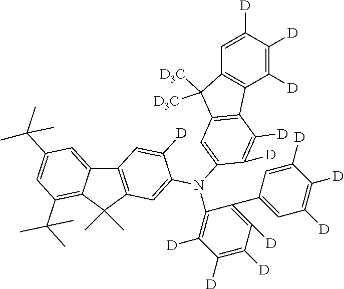 [SMILES: [2H]c1cc2c(cc1N(c1cc3c(c([2H])c1[2H])-c1c(cc([2H])c([2H])c1[2H])C3(C([2H])([2H])[2H])C([2H])([2H])[2H])c1c([2H])c([2H])c([2H])c([2H])c1-c1cc([2H])c([2H])c([2H])c1)C(C)(C)c1c-2cc(C(C)(C)C)cc1C(C)(C)C] | 63% |
| 2i | 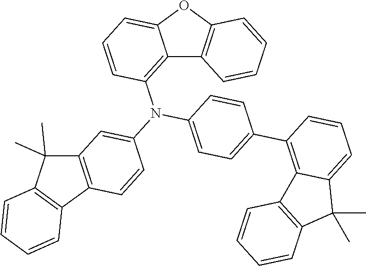 [SMILES: CC1(C)c2ccccc2-c2ccc(N(c3ccc(-c4cccc5c4-c4ccccc4C5(C)C)cc3)c3cccc4oc5ccccc5c34)cc21] WO2015/082056 | 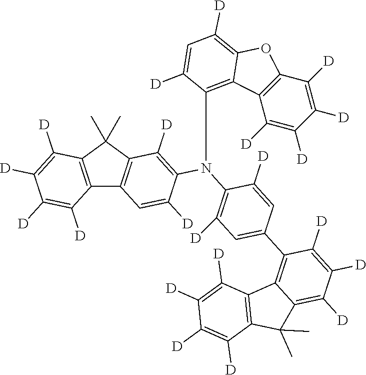 [SMILES: [2H]c1cc(-c2c([2H])c([2H])c([2H])c3c2-c2c([2H])c([2H])c([2H])c([2H])c2C3(C)C)cc([2H])c1N(c1c([2H])cc2c(c1[2H])C(C)(C)c1c([2H])c([2H])c([2H])c([2H])c1-2)c1c([2H])cc([2H])c2oc3c([2H])c([2H])c([2H])c([2H])c3c12] | 71% |
| 2j | 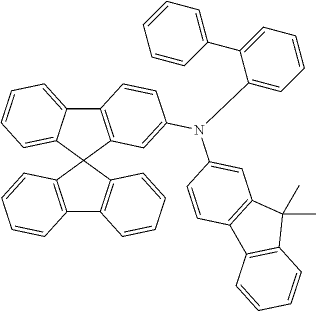 [SMILES: CC1(C)c2ccccc2-c2ccc(N(c3ccc4c(c3)C3(c5ccccc5-c5ccccc53)c3ccccc3-4)c3ccccc3-c3ccccc3)cc21] [1364603-07-5] | 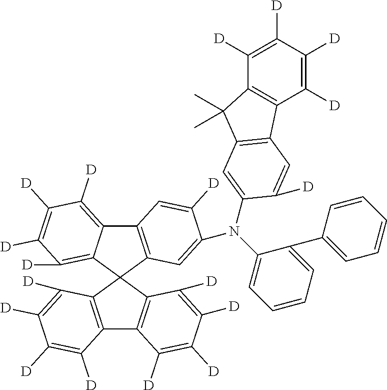 [SMILES: [2H]c1cc2c(cc1N(c1cc3c(cc1[2H])-c1c([2H])c([2H])c([2H])c([2H])c1C31c3c([2H])c([2H])c([2H])c([2H])c3-c3c([2H])c([2H])c([2H])c([2H])c31)c1ccccc1-c1ccccc1)C(C)(C)c1c([2H])c([2H])c([2H])c([2H])c1-2] | 74% |
| 2k | 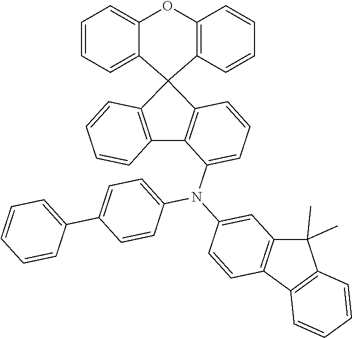 [SMILES: CC1(C)c2ccccc2-c2ccc(N(c3ccc(-c4ccccc4)cc3)c3cccc4c3-c3ccccc3C43c4ccccc4Oc4ccccc43)cc21] [1609484-48-1] | 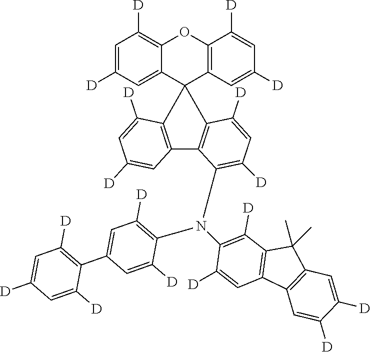 [SMILES: [2H]c1cc([2H])c(-c2cc([2H])c(N(c3c([2H])cc4c(c3[2H])C(C)(C)c3cc([2H])c([2H])cc3-4)c3c([2H])cc([2H])c4c3-c3cc([2H])cc([2H])c3C43c4cc([2H])cc([2H])c4Oc4c([2H])cc([2H])cc43)c([2H])c2)c([2H])c1] | 66% |
| 2l | 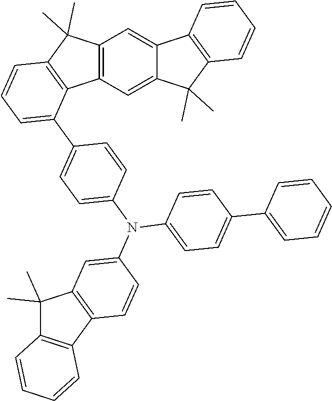 [SMILES: CC1(C)c2ccccc2-c2ccc(N(c3ccc(-c4ccccc4)cc3)c3ccc(-c4cccc5c4-c4cc6c(cc4C5(C)C)-c4ccccc4C6(C)C)cc3)cc21] [2299232-17-8] | 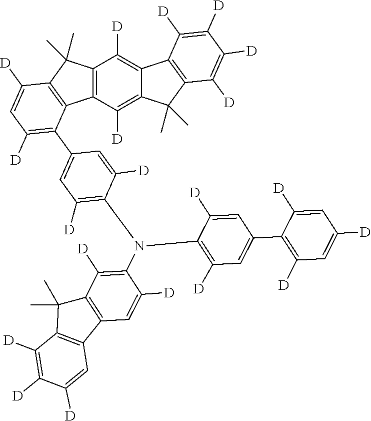 [SMILES: [2H]c1cc([2H])c(-c2cc([2H])c(N(c3c([2H])cc(-c4c([2H])cc([2H])c5c4-c4c([2H])c6c(c([2H])c4C5(C)C)-c4c([2H])c([2H])c([2H])c([2H])c4C6(C)C)cc3[2H])c3c([2H])cc4c(c3[2H])C(C)(C)c3c-4cc([2H])c([2H])c3[2H])c([2H])c2)c([2H])c1] | 58% |
| 2m | 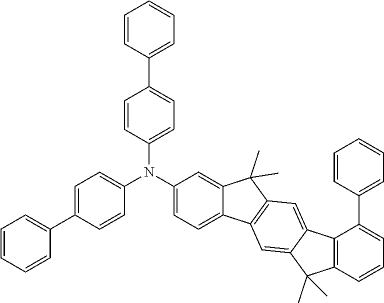 [SMILES: CC1(C)c2cc(N(c3ccc(-c4ccccc4)cc3)c3ccc(-c4ccccc4)cc3)ccc2-c2cc3c(cc21)-c1c(-c2ccccc2)cccc1C3(C)C] | 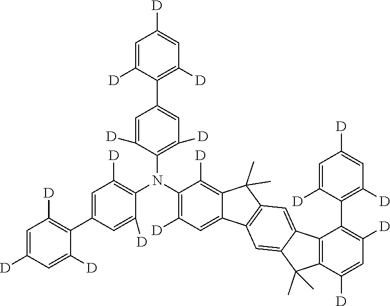 [SMILES: [2H]c1cc([2H])c(-c2cc([2H])c(N(c3c([2H])cc(-c4c([2H])cc([2H])cc4[2H])cc3[2H])c3c([2H])cc4c(c3[2H])C(C)(C)c3cc5c(cc3-4)C(C)(C)c3c([2H])cc([2H])c(-c4c([2H])cc([2H])cc4[2H])c3-5)c([2H])c2)c([2H])c1] | 44% |
| | [2300016-25-3] | | |
| 2n | 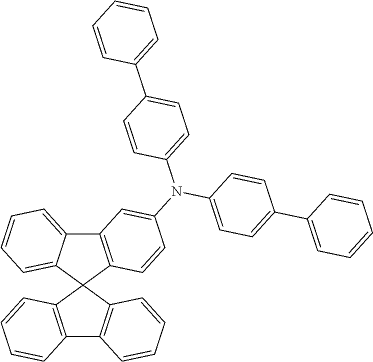 [SMILES: c1ccc(-c2ccc(N(c3ccc(-c4ccccc4)cc3)c3ccc4c(c3)-c3ccccc3C43c4ccccc4-c4ccccc43)cc2)cc1] | 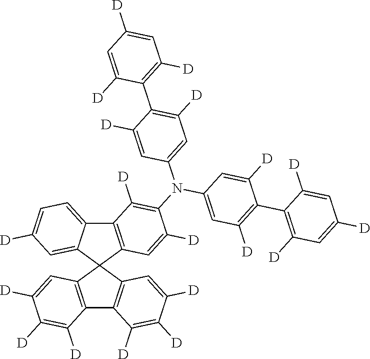 [SMILES: [2H]c1cc([2H])c(-c2c([2H])cc(N(c3cc([2H])c(-c4c([2H])cc([2H])cc4[2H])c([2H])c3)c3c([2H])cc4c(c3[2H])-c3ccc([2H])cc3C43c4cc([2H])c([2H])c([2H])c4-c4c3cc([2H])c([2H])c4[2H])cc2[2H])c([2H])c1] | 51% |
| | [1450933-35-3] | | |
| 2o | 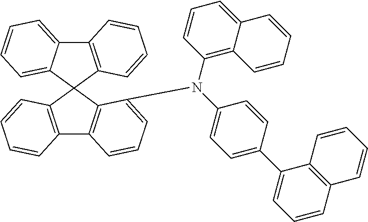 [SMILES: c1ccc2c(c1)-c1ccccc1C21c2ccccc2-c2cccc(N(c3ccc(-c4cccc5ccccc45)cc3)c3cccc4ccccc34)c21] [2730012-53-8] | 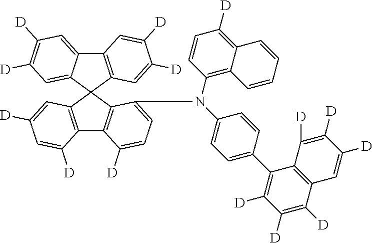 [SMILES: [2H]c1cc([2H])c2c(c1)C1(c3cc([2H])c([2H])cc3-c3cc([2H])c([2H])cc31)c1c(N(c3ccc(-c4c([2H])c([2H])c([2H])c5cc([2H])c([2H])c([2H])c45)cc3)c3ccc([2H])c4ccccc34)ccc([2H])c1-2] | 49% |

### Example 3

### d₁₀-6′-bromo(2,2′,3,4,4′,5,6,7,7′-2H9)spiro[fluorene-9,9′-xanthene]

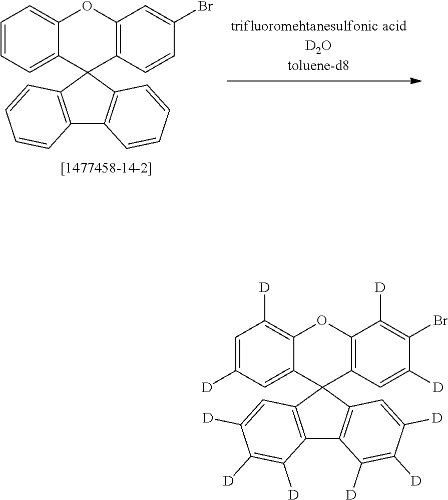 [SMILES: Brc1ccc2c(c1)Oc1ccccc1C21c2ccccc2-c2ccccc21 ; [2H]c1cc([2H])c2c(c1)C1(c3cc([2H])c(Br)c([2H])c3O2)c2cc([2H])c([2H])c([2H])c2-c2c1cc([2H])c([2H])c2[2H]]

20.5 g (50.0 mmol; 1.00 eq) of 6′-bromo(2,2′,3,4,4′,5,6,7,7′-2H9)spiro[fluorene-9,9′-xanthene](commercially available) is suspended in 640 ml (120 eq) of toluene-d8 [CAS 2037-26-5]. Added to this mixture while cooling is 16.6 ml (6.00 eq.) of trifluoromethanesulfonic acid. The reaction mixture is stirred at room temperature for 6 hours. Thereafter, 120 ml (130 eq) of deuterium oxide [CAS 7789-20-0] is added dropwise at 0° C. Neutralization with a potassium sulfate solution is followed by extraction with toluene and washing of the combined organic phases with saline solution and drying over sodium sulfate. After filtration, the solvent is removed under reduced pressure. 17.4 g (41.4 mmol, 83% of theory) of the product shown above is obtained in a mixture with fractions of H/D isotopomers and H/D isotopologs after purification by chromatography.

The following compounds can be obtained analogously:

| Ex. | Reactant | Product | Yield |
|---|---|---|---|
| 3b | 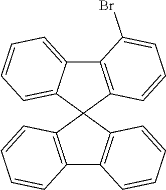 [SMILES: Brc1cccc2c1-c1ccccc1C21c2ccccc2-c2ccccc21] [1161009-88-6] | 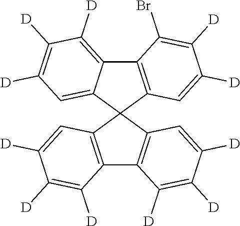 [SMILES: [2H]c1cc2c(c([2H])c1[2H])-c1c(cc([2H])c([2H])c1[2H])C21c2cc([2H])c([2H])c([2H])c2-c2c1cc([2H])c([2H])c2Br] | 95% |
| 3c | 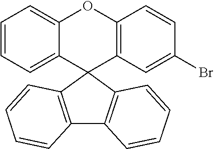 [SMILES: Brc1ccc2c(c1)C1(c3ccccc3O2)c2ccccc2-c2ccccc21] [1477458-14-2] | 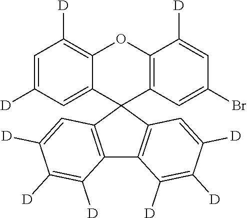 [SMILES: [2H]c1cc([2H])c2c(c1)C1(c3cc(Br)cc([2H])c3O2)c2cc([2H])c([2H])c([2H])c2-c2c1cc([2H])c([2H])c2[2H]] | 78% |
| 3d | 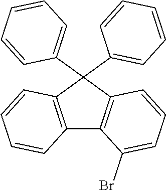 [SMILES: Brc1cccc2c1-c1ccccc1C2(c1ccccc1)c1ccccc1] [713125-22-5] | 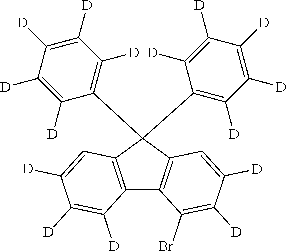 [SMILES: [2H]c1cc2c(c([2H])c1[2H])-c1c(cc([2H])c([2H])c1Br)C2(c1c([2H])c([2H])c([2H])c([2H])c1[2H])c1c([2H])c([2H])c([2H])c([2H])c1[2H]] | 66% |
| 3e | 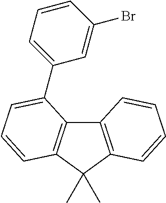 [SMILES: CC1(C)c2ccccc2-c2c(-c3cccc(Br)c3)cccc21] [1860896-40-7] | 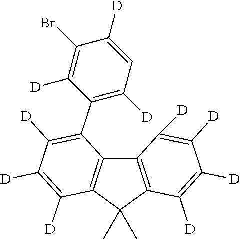 [SMILES: [2H]c1cc([2H])c(-c2c([2H])c([2H])c([2H])c3c2-c2c([2H])c([2H])c([2H])c([2H])c2C3(C)C)c([2H])c1Br] | 72% |
| 3f | 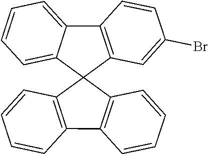 [SMILES: Brc1ccc2c(c1)C1(c3ccccc3-c3ccccc31)c1ccccc1-2] [171408-76-7] | 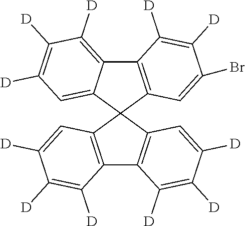 [SMILES: [2H]c1cc2c(c([2H])c1[2H])-c1c(cc([2H])c([2H])c1[2H])C21c2cc([2H])c([2H])c([2H])c2-c2c1cc(Br)c([2H])c2[2H]] | 82% |
| 3g | 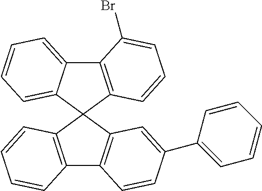 [SMILES: Brc1cccc2c1-c1ccccc1C21c2ccccc2-c2ccc(-c3ccccc3)cc21] | 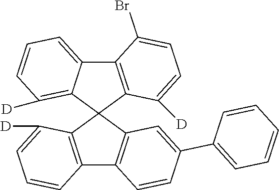 [SMILES: [2H]c1cccc2c1C1(c3cc(-c4ccccc4)ccc3-2)c2c([2H])cccc2-c2c(Br)ccc([2H])c21] | 71% |
| | [1911626-20-4] | | |
| 3h | 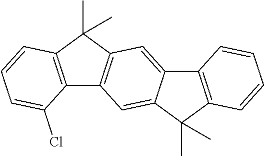 [SMILES: CC1(C)c2ccccc2-c2cc3c(cc21)-c1c(Cl)cccc1C3(C)C] | 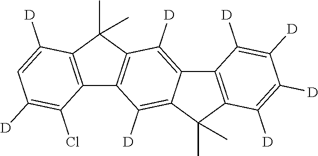 [SMILES: [2H]c1cc([2H])c2c(c1Cl)-c1c([2H])c3c(c([2H])c1C2(C)C)-c1c([2H])c([2H])c([2H])c([2H])c1C3(C)C] | 78% |
| | [2299231-59-5] | | |

### Example 4

### d10-N,N-bis({[1,1′-biphenyl]-4-yl))(2,2′,3,4,4′,5,6,7,7′-2H9)spiro[fluorene-9,9′-xanthene]-6′-amine

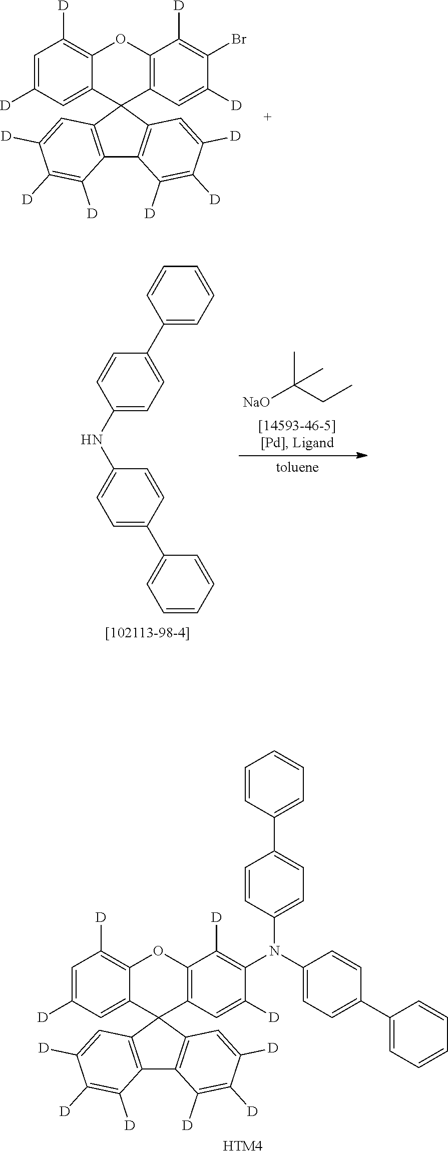

An initial charge of 16.3 g (38.9 mmol; 1.00 eq.) of de-6′-bromo(2,2′,3,4,4′,5,6,7,7′-2H9)spiro[fluorene-9,9′-xanthene], 12.6 g (39.3 mmol; 1.01 eq.) of N-{[1,1′-biphenyl]-4-yl}-[1,1′-biphenyl]-4-amine [CAS 102113-98-4] and 4.96 g (42.7 mmol; 1.10 eq.) of sodium tert-pentoxide [CAS 14593-46-5] in 200 ml of toluene [CAS 108-88-3] is inertized in an argon stream for 30 minutes. Then 479 mg (1.17 mmol; 3 mol %) of dicyclohexyl-(2′,6′-dimethoxybiphenyl-2-yl)phosphane (SPhos) [CAS 657408-07-6], 262 mg (1.17 mmol; 3 mol %) of palladium acetate [CAS 3375-31-3] are added and the mixture is heated to reflux for 18 hours. After completion of conversion and cooling to room temperature, 500 ml of water are added to the reaction. After separation of the phases and extraction of the aqueous phase with toluene [CAS 108-88-3], the combined organic phases are concentrated and heptane is added. The precipitated solids are isolated. Purification by means of Soxhlet extraction, recrystallization and vacuum sublimation gives the desired product (14.5 g; 21.9 mmol; 56% of theory).

The following compounds can be obtained analogously:

| Ex. | Reactant | Reactant | Product | Yield |
|---|---|---|---|---|
| 4b | 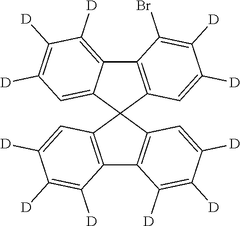 [SMILES: [2H]c1cc2c(c([2H])c1[2H])-c1c(cc([2H])c([2H])c1[2H])C21c2cc([2H])c([2H])c([2H])c2-c2c1cc([2H])c([2H])c2Br] | 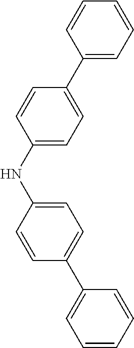 [SMILES: c1ccc(-c2ccc(Nc3ccc(-c4ccccc4)cc3)cc2)cc1] [102113-98-4] | 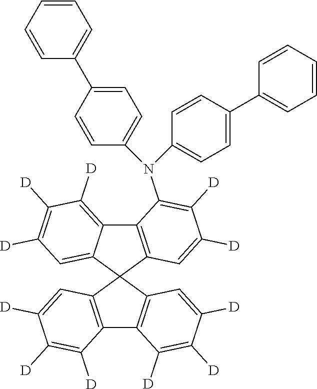 [SMILES: [2H]c1cc2c(c([2H])c1[2H])-c1c(cc([2H])c([2H])c1[2H])C21c2cc([2H])c([2H])c([2H])c2-c2c1cc([2H])c([2H])c2N(c1ccc(-c2ccccc2)cc1)c1ccc(-c2ccccc2)cc1] | 53% |
| | | | HTM4b | |
| 4c | 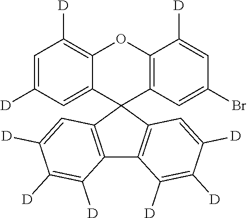 [SMILES: [2H]c1cc([2H])c2c(c1)C1(c3cc(Br)cc([2H])c3O2)c2cc([2H])c([2H])c([2H])c2-c2c1cc([2H])c([2H])c2[2H]] | 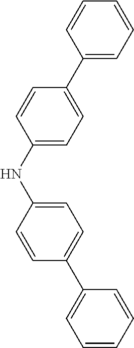 [SMILES: c1ccc(-c2ccc(Nc3ccc(-c4ccccc4)cc3)cc2)cc1] | 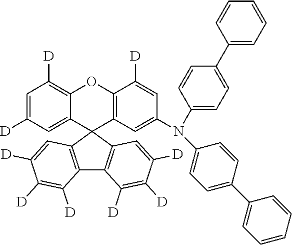 [SMILES: [2H]c1cc([2H])c2c(c1)C1(c3cc(N(c4ccc(-c5ccccc5)cc4)c4ccc(-c5ccccc5)cc4)cc([2H])c3O2)c2cc([2H])c([2H])c([2H])c2-c2c1cc([2H])c([2H])c2[2H]] HTM4c | 53% |
| | | [102113-98-4] | | |
| 4d | 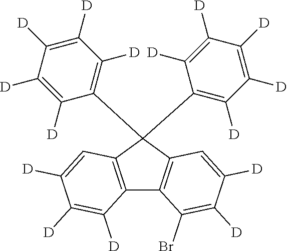 [SMILES: [2H]c1cc2c(c([2H])c1[2H])-c1c(cc([2H])c([2H])c1Br)C2(c1c([2H])c([2H])c([2H])c([2H])c1[2H])c1c([2H])c([2H])c([2H])c([2H])c1[2H]] | 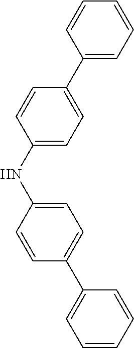 [SMILES: c1ccc(-c2ccc(Nc3ccc(-c4ccccc4)cc3)cc2)cc1] [102113-98-4] | 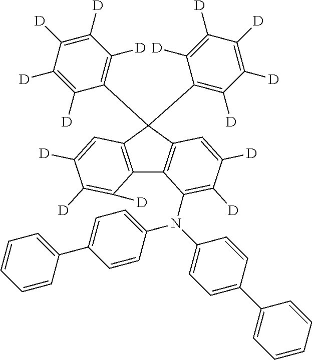 [SMILES: [2H]c1cc2c(c([2H])c1[2H])-c1c(cc([2H])c([2H])c1N(c1ccc(-c3ccccc3)cc1)c1ccc(-c3ccccc3)cc1)C2(c1c([2H])c([2H])c([2H])c([2H])c1[2H])c1c([2H])c([2H])c([2H])c([2H])c1[2H]] | 65% |
| 4e | 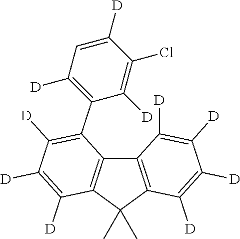 [SMILES: [2H]c1cc([2H])c(-c2c([2H])c([2H])c([2H])c3c2-c2c([2H])c([2H])c([2H])c([2H])c2C3(C)C)c([2H])c1Cl] | 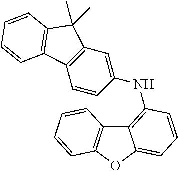 [SMILES: CC1(C)c2ccccc2-c2ccc(Nc3cccc4oc5ccccc5c34)cc21] [2225845-23-6] | 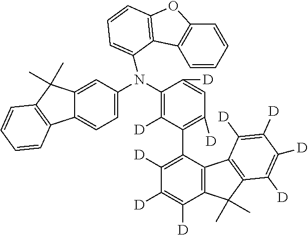 [SMILES: [2H]c1cc([2H])c(N(c2ccc3c(c2)C(C)(C)c2ccccc2-3)c2cccc3oc4ccccc4c23)c([2H])c1-c1c([2H])c([2H])c([2H])c2c1-c1c([2H])c([2H])c([2H])c([2H])c1C2(C)C] | 67% |
| 4f | 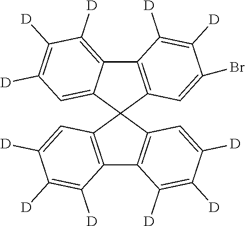 [SMILES: [2H]c1cc2c(c([2H])c1[2H])-c1c(cc([2H])c([2H])c1[2H])C21c2cc([2H])c([2H])c([2H])c2-c2c1cc(Br)c([2H])c2[2H]] | 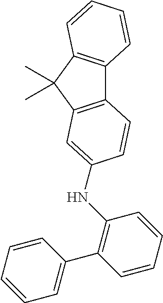 [SMILES: CC1(C)c2ccccc2-c2ccc(Nc3ccccc3-c3ccccc3)cc21] | 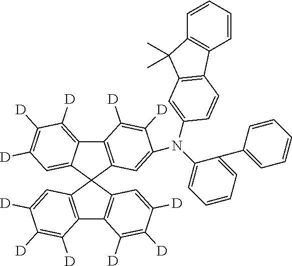 [SMILES: [2H]c1cc2c(c([2H])c1[2H])-c1c(cc([2H])c([2H])c1[2H])C21c2cc([2H])c([2H])c([2H])c2-c2c1cc(N(c1ccc3c(c1)C(C)(C)c1ccccc1-3)c1ccccc1-c1ccccc1)c([2H])c2[2H]] | 58% |
| | | [1198395-24-2] | | |
| 4g | 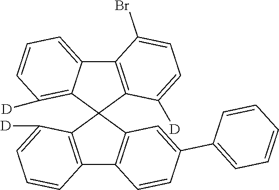 [SMILES: [2H]c1cccc2c1C1(c3cc(-c4ccccc4)ccc3-2)c2c([2H])cccc2-c2c(Br)ccc([2H])c21] | 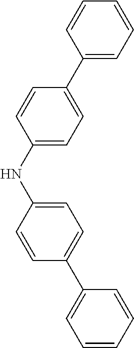 [SMILES: c1ccc(-c2ccc(Nc3ccc(-c4ccccc4)cc3)cc2)cc1] | 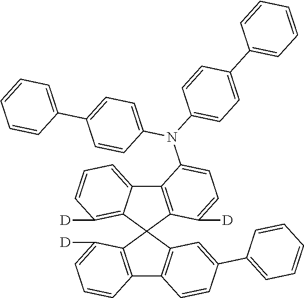 [SMILES: [2H]c1cccc2c1C1(c3cc(-c4ccccc4)ccc3-2)c2c([2H])cccc2-c2c(N(c3ccc(-c4ccccc4)cc3)c3ccc(-c4ccccc4)cc3)ccc([2H])c21] | 71% |
| | | [102113-98-4] | | |
| 4h | 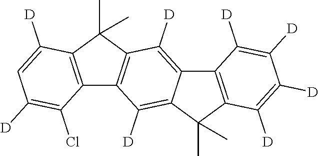 [SMILES: [2H]c1cc([2H])c2c(c1Cl)-c1c([2H])c3c(c([2H])c1C2(C)C)-c1c([2H])c([2H])c([2H])c([2H])c1C3(C)C] | 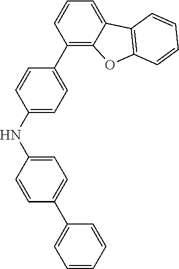 [SMILES: c1ccc(-c2ccc(Nc3ccc(-c4cccc5c4oc4ccccc45)cc3)cc2)cc1] [955959-89-4] | 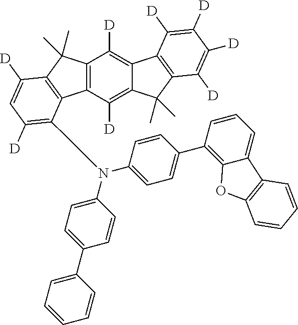 [SMILES: [2H]c1cc([2H])c2c(c1N(c1ccc(-c3ccccc3)cc1)c1ccc(-c3cccc4c3oc3ccccc34)cc1)-c1c([2H])c3c(c([2H])c1C2(C)C)-c1c([2H])c([2H])c([2H])c([2H])c1C3(C)C] | 55% |

### B) Device Examples

### Production of the OLEDs

In examples V-1 to V-9 and B-1 to B-10 which follow (see tables 1 to 5), the data of various OLEDs are presented.

### Pretreatment for Examples V-1 to V-9 and B1 to B-10

Glass plates coated with structured ITO (indium tin oxide) of thickness 50 nm are treated prior to coating with an oxygen plasma, followed by an argon plasma. These plasma-treated glass plates form the substrates to which the OLEDs are applied.

The OLEDs basically have the following layer structure: substrate/hole injection layer (HIL)/hole transport layer (HTL)/electron blocker layer (EBL)/emission layer (EML)/optional hole blocker layer (HBL)/electron transport layer (ETL)/optional electron injection layer (EIL) and finally a cathode. The cathode is formed by an aluminum layer of thickness 100 nm. The exact structure of the OLEDs can be found in table 1 and table 4. The materials required for production of the OLEDs are shown in table 3 if not described above.

All materials are applied by thermal vapor deposition in a vacuum chamber. In this case, the emission layer always consists of at least one matrix material (host material) and an emitting dopant (emitter) which is added to the matrix material(s) in a particular proportion by volume by co-evaporation. Details given in such a form as E1:SdT1:TEG1 (32%:60%:8%) mean here that the material E1 is present in the layer in a proportion by volume of 32%, SdT1 in a proportion of 60% and TEG1 in a proportion of 8%. Analogously, the electron transport layer may also consist of a mixture of two materials.

The OLEDs are characterized in a standard manner. For this purpose, the electroluminescence spectra, the voltage and the external quantum efficiency (EQE, measured in percent) are determined as a function of luminance, calculated from current-voltage-luminance characteristics (IUL characteristics) assuming Lambertian radiation characteristics, and the lifetime. Electroluminescence spectra are determined at a luminance of 1000 cd/m², and these are used to calculate the CIE 1931 x and y color coordinates. The parameter U1000 in table 2 and table 5 refers here to the voltage which is required for a luminance of 1000 cd/m². CE1000 denotes the current efficiency which is achieved at 1000 cd/m². Finally, EQE1000 refers to the external quantum efficiency at an operating luminance of 1000 cd/m². The lifetime LD95@1000cd/m³ is defined as the time after which the starting luminance has fallen from 1000 cd/m² here to a certain fraction. A figure LD95 in table 2 or LD80 in table 5 means that the lifetime given in the LD95 or LD80 column corresponds to the time after which the starting luminance drops from 1000 cd/m² to 95% or from 20 000 cd/m² to 80% of its starting value. The data for the various OLEDs are collated in table 2 and table 5. Examples V-1 to V-9 are comparative examples according to the prior art; Examples B1-B10 show data of OLEDs of the invention.

Some of the examples are elucidated in detail hereinafter, in order to illustrate the advantages of the OLEDs of the invention.

### Use of the Compounds of the Invention as Electron Blocker Layer (EBL) in Blue-Fluorescing OLEDs

The inventive compounds 2c, 2d, 2e, 2g, 4b and 4h are compared with the prior art materials SdT1 to SdT5 in the use of an electron blocker layer (EBL) in blue-fluorescing OLEDs. According to the present application, the compounds 2c, 2d, 2e, 2g, 4b and 4h are partly deuterated derivatives of the undeuterated compounds SdT1 to SdT5.

TABLE 1
Device structure of the blue-fluorescing OLEDs

| | HIL | HTL | EBL | EML | ETL | EIL |
|---|---|---|---|---|---|---|
| | Thickness/ | Thickness/ | Thickness/ | Thickness/ | Thickness/ | Thickness/ |
| Ex. | nm | nm | nm | nm | nm | nm |
| V1 | HTM: p-dopant (5%) | HTM | SdT1 | H: SEB(3%) | ETM1: LiQ(50%) | LiQ |
| | 20 nm | 160 nm | 10 nm | 20 nm | 30 nm | 1 nm |
| V2 | HTM: p-dopant (5%) | HTM | SdT2 | H: SEB(3%) | ETM1: LiQ(50%) | LiQ |
| | 20 nm | 160 nm | 10 nm | 20 nm | 30 nm | 1 nm |
| V3 | HTM: p-dopant (5%) | HTM | SdT3 | H: SEB(3%) | ETM1: LiQ(50%) | LiQ |
| | 20 nm | 160 nm | 10 nm | 20 nm | 30 nm | 1 nm |
| V4 | HTM: p-dopant (5%) | HTM | SdT4 | H: SEB(3%) | ETM1: LiQ(50%) | LiQ |
| | 20 nm | 160 nm | 10 nm | 20 nm | 30 nm | 1 nm |
| V5 | HTM: p-dopant (5%) | HTM | SdT5 | H: SEB(3%) | ETM1: LiQ(50%) | LiQ |
| | 20 nm | 160 nm | 10 nm | 20 nm | 30 nm | 1 nm |
| B1 | HTM: p-dopant (5%) | HTM | 2c | H: SEB(3%) | ETM1: LiQ(50%) | LiQ |
| | 20 nm | 160 nm | 10 nm | 20 nm | 30 nm | 1 nm |
| B2 | HTM: p-dopant (5%) | HTM | 2d | H: SEB(3%) | ETM1: LiQ(50%) | LiQ |
| | 20 nm | 160 nm | 10 nm | 20 nm | 30 nm | 1 nm |
| B3 | HTM: p-dopant (5%) | HTM | 2e | H: SEB(3%) | ETM1: LiQ(50%) | LiQ |
| | 20 nm | 160 nm | 10 nm | 20 nm | 30 nm | 1 nm |
| B4 | HTM: p-dopant (5%) | HTM | 2g | H: SEB(3%) | ETM1: LiQ(50%) | LiQ |
| | 20 nm | 160 nm | 10 nm | 20 nm | 30 nm | 1 nm |
| B5 | HTM: p-dopant (5%) | HTM | 4b | H: SEB(3%) | ETM1: LiQ(50%) | LiQ |
| | 20 nm | 160 nm | 10 nm | 20 nm | 30 nm | 1 nm |
| B6 | HTM: p-dopant (5%) | HTM | 4h | H: SEB(3%) | ETM1: LiQ(50%) | LiQ |
| | 20 nm | 160 nm | 10 nm | 20 nm | 30 nm | 1 nm |

The performance data attained can be found in table 2.

TABLE 2
Performance data of the blue-fluorescing OLEDs

| | | | LD95 @ | CIE x/y @ |
|---|---|---|---|---|
| Ex. | U1000 (V) | EQE1000 (%) | 1000 cd/m² (h) | 1000 cd/m² |
| V-1 | 3.7 | 9.1 | 360 | 0.14/0.19 |
| V-2 | 3.6 | 8.8 | 330 | 0.15/0.18 |
| V-3 | 3.7 | 9.2 | 310 | 0.15/0.18 |
| V-4 | 3.7 | 8.9 | 340 | 0.15/0.18 |
| V-5 | 3.8 | 9.0 | 300 | 0.15/0.18 |
| B-1 | 3.7 | 9.2 | 480 | 0.14/0.19 |
| B-2 | 3.7 | 8.7 | 420 | 0.15/0.18 |
| B-3 | 3.7 | 9.0 | 370 | 0.15/0.18 |
| B-4 | 3.8 | 9.0 | 440 | 0.15/0.18 |
| B-5 | 3.8 | 9.1 | 400 | 0.15/0.18 |
| B-6 | 3.7 | 8.9 | 400 | 0.15/0.18 |

The inventive examples B-1 to B-6, by comparison with prior art examples V-1 to V-5, have distinctly improved lifetime coupled with comparable operating voltage and efficiency. Surprisingly, this benefit in the case of the partly deuterated compounds according to the application is similarly notable to that for fully deuterated compounds.

TABLE 3
Materials for OLED devices

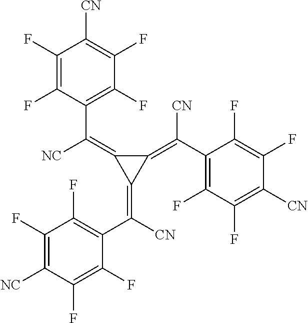 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F]

p-Dopant

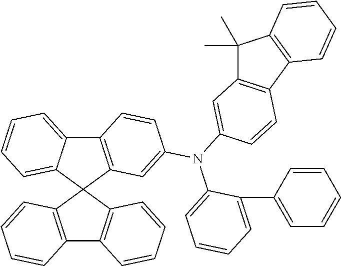 [SMILES: CC1(C)c2ccccc2-c2ccc(N(c3ccc4c(c3)C3(c5ccccc5-c5ccccc53)c3ccccc3-4)c3ccccc3-c3ccccc3)cc21]

HTM

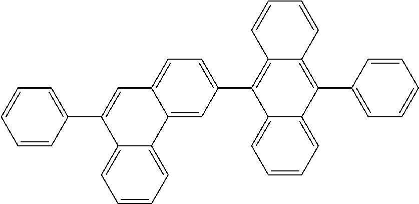 [SMILES: c1ccc(-c2c3ccccc3c(-c3ccc4cc(-c5ccccc5)c5ccccc5c4c3)c3ccccc23)cc1]

H

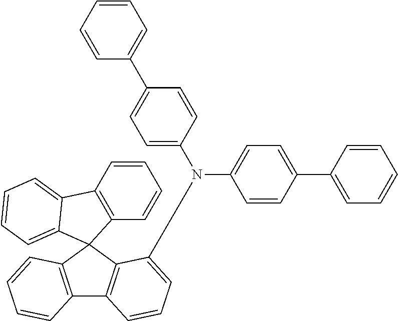 [SMILES: c1ccc(-c2ccc(N(c3ccc(-c4ccccc4)cc3)c3cccc4c3C3(c5ccccc5-c5ccccc53)c3ccccc3-4)cc2)cc1]

SdT1

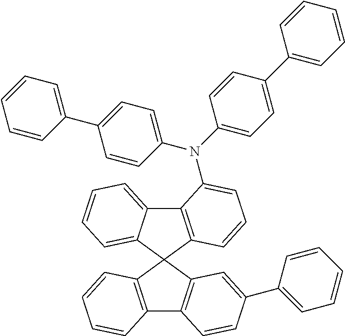 [SMILES: c1ccc(-c2ccc(N(c3ccc(-c4ccccc4)cc3)c3cccc4c3-c3ccccc3C43c4ccccc4-c4ccc(-c5ccccc5)cc43)cc2)cc1]

SdT2

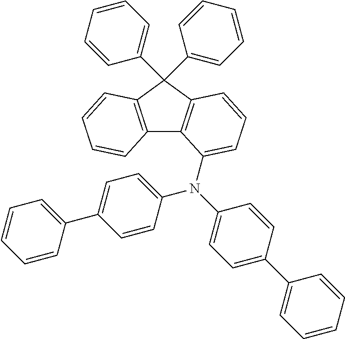 [SMILES: c1ccc(-c2ccc(N(c3ccc(-c4ccccc4)cc3)c3cccc4c3-c3ccccc3C4(c3ccccc3)c3ccccc3)cc2)cc1]

SdT3

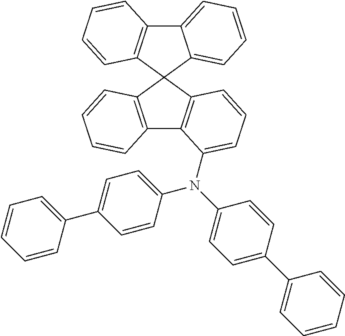 [SMILES: c1ccc(-c2ccc(N(c3ccc(-c4ccccc4)cc3)c3cccc4c3-c3ccccc3C43c4ccccc4-c4ccccc43)cc2)cc1]

SdT4

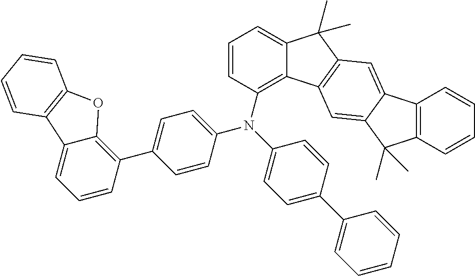 [SMILES: CC1(C)c2ccccc2-c2cc3c(cc21)-c1c(N(c2ccc(-c4ccccc4)cc2)c2ccc(-c4cccc5c4oc4ccccc45)cc2)cccc1C3(C)C]

SdT5

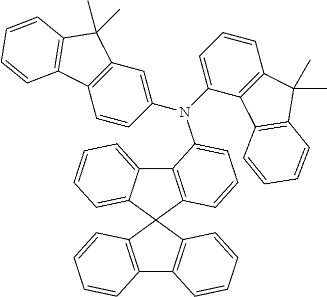 [SMILES: CC1(C)c2ccccc2-c2ccc(N(c3cccc4c3-c3ccccc3C4(C)C)c3cccc4c3-c3ccccc3C43c4ccccc4-c4ccccc43)cc21]

SdT6

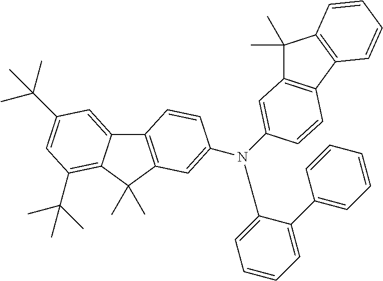 [SMILES: CC(C)(C)c1cc2c(c(C(C)(C)C)c1)C(C)(C)c1cc(N(c3ccc4c(c3)C(C)(C)c3ccccc3-4)c3ccccc3-c3ccccc3)ccc1-2]

SdT7

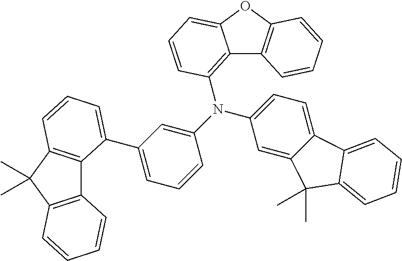 [SMILES: CC1(C)c2ccccc2-c2ccc(N(c3cccc(-c4cccc5c4-c4ccccc4C5(C)C)c3)c3cccc4oc5ccccc5c34)cc21]

SdT8

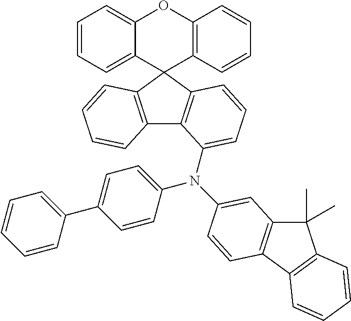 [SMILES: CC1(C)c2ccccc2-c2ccc(N(c3ccc(-c4ccccc4)cc3)c3cccc4c3-c3ccccc3C43c4ccccc4Oc4ccccc43)cc21]

SdT9

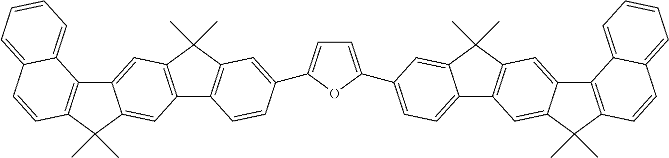 [SMILES: CC1(C)c2cc(-c3ccc(-c4ccc5c(c4)C(C)(C)c4cc6c(cc4-5)C(C)(C)c4ccc5ccccc5c4-6)o3)ccc2-c2cc3c(cc21)-c1c(ccc2ccccc12)C3(C)C]

SEB

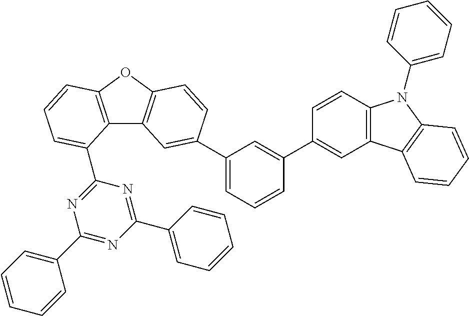 [SMILES: c1ccc(-c2nc(-c3ccccc3)nc(-c3cccc4oc5ccc(-c6cccc(-c7ccc8c(c7)c7ccccc7n8-c7ccccc7)c6)cc5c34)n2)cc1]

TMM1

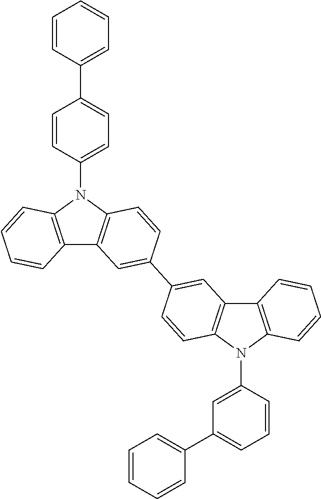 [SMILES: c1ccc(-c2ccc(-n3c4ccccc4c4cc(-c5ccc6c(c5)c5ccccc5n6-c5cccc(-c6ccccc6)c5)ccc43)cc2)cc1]

TMM2

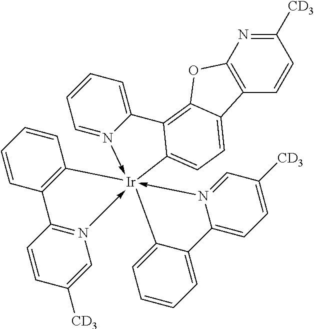

TEG

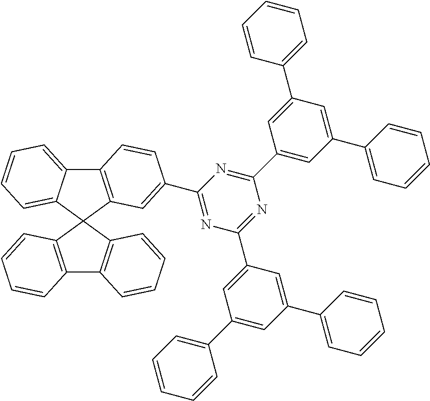 [SMILES: c1ccc(-c2cc(-c3ccccc3)cc(-c3nc(-c4cc(-c5ccccc5)cc(-c5ccccc5)c4)nc(-c4ccc5c(c4)C4(c6ccccc6-c6ccccc64)c4ccccc4-5)n3)c2)cc1]

ETM1

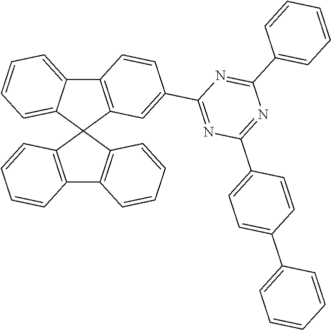 [SMILES: c1ccc(-c2ccc(-c3nc(-c4ccccc4)nc(-c4ccc5c(c4)C4(c6ccccc6-c6ccccc64)c4ccccc4-5)n3)cc2)cc1]

ETM2

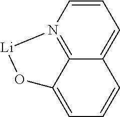

LiQ

### Use of the Inventive Compounds in the EBL of Green-Phosphorescing OLEDs

The inventive compounds 2b, 2h, 2k and 4e are compared with the prior art materials SdT6 to SdT9 in the use of an electron blocker layer (EBL) in green-phosphorescing OLEDs. According to the present application, the compounds 2b, 2h, 2k and 4e are partly deuterated derivatives of the undeuterated compounds SdT6 to SdT9.

The following OLEDs are produced:

TABLE 4
Device structure of the green-phosphorescing OLEDs

| | HIL | HTL1 | HTL2 | EBL | EML | HBL | ETL | EIL |
|---|---|---|---|---|---|---|---|---|
| | Thickness/ | Thickness/ | Thickness | Thickness/ | Thickness/ | Thickness/ | Thickness/ | Thickness/ |
| Ex. | nm | nm | nm | nm | nm | nm | nm | nm |
| V-6 | HTM: p- | HTM | SdT6: p- | SdT6 | TMM1(42%) | ETM2 | ETM2: | LiQ |
| | dopant (5%) | 210 nm | dopant (5%) | 20 nm | TMM2(50%) | 30 nm | LiQ(30%) | 1 nm |
| | 20 nm | | 20 nm | | TEG (8%) | | 10 nm | |
| | | | | | 30 nm | | | |
| V-7 | HTM: p- | HTM | SdT7: p- | SdT7 | TMM1(42%) | ETM2 | ETM2: | LiQ |
| | dopant (5%) | 210 nm | dopant (5%) | 20 nm | TMM2(50%) | 30 nm | LiQ(30%) | 1 nm |
| | 20 nm | | 20 nm | | TEG (8%) | | 10 nm | |
| | | | | | 30 nm | | | |
| V-8 | HTM: p- | HTM | SdT8: p- | SdT8 | TMM1(42%) | ETM2 | ETM2: | LiQ |
| | dopant (5%) | 210 nm | dopant (5%) | 20 nm | TMM2(50%) | 30 nm | LiQ(30%) | 1 nm |
| | 20 nm | | 20 nm | | TEG (8%) | | 10 nm | |
| | | | | | 30 nm | | | |
| V-9 | HTM: p- | HTM | SdT9: p- | SdT9 | TMM1(42%) | ETM2 | ETM2: | LiQ |
| | dopant (5%) | 210 nm | dopant (5%) | 20 nm | TMM2(50%) | 30 nm | LiQ(30%) | 1 nm |
| | 20 nm | | 20 nm | | TEG (8%) | | 10 nm | |
| | | | | | 30 nm | | | |
| B-7 | HTM: p- | HTM | 2b: p- | 2b | TMM1(42%) | ETM2 | ETM2: | LiQ |
| | dopant (5%) | 210 nm | dopant (5%) | 20 nm | TMM2(50%) | 30 nm | LiQ(30%) | 1 nm |
| | 20 nm | | 20 nm | | TEG (8%) | | 10 nm | |
| | | | | | 30 nm | | | |
| B-8 | HTM: p- | HTM | 2h: p- | 2h | TMM1(42%) | ETM2 | ETM2: | LiQ |
| | dopant (5%) | 210 nm | dopant (5%) | 20 nm | TMM2(50%) | 30 nm | LiQ(30%) | 1 nm |
| | 20 nm | | 20 nm | | TEG (8%) | | 10 nm | |
| | | | | | 30 nm | | | |
| B-9 | HTM: p- | HTM | 4e: p- | 4e | TMM1(42%) | ETM2 | ETM2: | LiQ |
| | dopant (5%) | 210 nm | dopant (5%) | 20 nm | TMM2(50%) | 30 nm | LiQ(30%) | 1 nm |
| | 20 nm | | 20 nm | | TEG (8%) | | 10 nm | |
| | | | | | 30 nm | | | |
| B-10 | HTM: p- | HTM | 2k: p- | 2k | TMM1(42%) | ETM2 | ETM2: | LiQ |
| | dopant (5%) | 210 nm | dopant (5%) | 20 nm | TMM2(50%) | 30 nm | LiQ(30%) | 1 nm |
| | 20 nm | | 20 nm | | TEG (8%) | | 10 nm | |
| | | | | | 30 nm | | | |

TABLE 5
Performance data of the green-phosphorescing OLEDs

| | | | LD80 @ | CIE x/y @ |
|---|---|---|---|---|
| Ex. | U1000 (V) | EQE1000 (%) | 20000 cd/m² (h) | 1000 cd/m² |
| V-6 | 2.8 | 24.2 | 1340 | 0.34/0.63 |
| V-7 | 2.7 | 23.5 | 1500 | 0.34/0.63 |
| V-8 | 3.0 | 24.4 | 1340 | 0.34/0.63 |
| V-9 | 2.8 | 23.9 | 1350 | 0.34/0.63 |
| B-7 | 2.8 | 24.1 | 1590 | 0.34/0.63 |
| B-8 | 2.8 | 23.6 | 1650 | 0.34/0.63 |
| B-9 | 2.9 | 24.4 | 1550 | 0.34/0.63 |
| B-10 | 2.8 | 24.0 | 1590 | 0.34/0.63 |

The inventive examples B-7 to B-10, by comparison with prior art examples V-6 to V-9, have distinctly improved lifetime coupled with comparable operating voltage and efficiency. Surprisingly, this benefit in the case of the partly deuterated compounds according to the application is similarly notable to that for fully deuterated compounds.

1.-18. (canceled)

19. A compound of the formula (I) 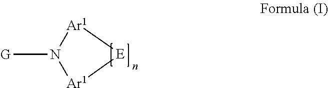
where:
G conforms to formula (G-1), (G-2) or (G-3) 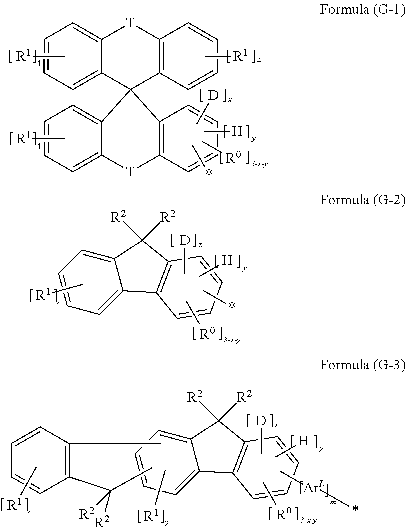
where the bond to the rest of the formula (I) is labeled *, and where:
T is the same or different at each instance and is selected from single bond, C(R²)₂, C═O, Si(R²)₄, NR², O and S;
E is selected from single bond, C(R³)₂, C(R³)₂—C(R³)₂, C(R³)═C(R³), C═O, Si(R³)₄, NR³, O and S;
Ar¹ is the same or different at each instance and is selected from aromatic ring systems which have 6 to 40 aromatic ring atoms and are substituted by R³ radicals, and heteroaromatic ring systems which have 5 to 40 aromatic ring atoms and are substituted by R³ radicals;
Ar^{L} is selected from aromatic ring systems which have 6 to 40 aromatic ring atoms and are substituted by R³ radicals and heteroaromatic ring systems which have 5 to 40 aromatic ring atoms and are substituted by R³ radicals;
R⁰ is the same or different at each instance and is selected from F, Cl, Br, I, C(═O)R⁴, CN, Si(R⁴)₃, N(R⁴)₂, P(═O)(R⁴)₂, OR⁴, S(═O)R⁴, S(═O)₂R⁴, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R⁰ radicals may be joined to one another and may form a ring; where the alkyl, alkoxy, alkenyl and alkynyl groups and the aromatic ring systems and heteroaromatic ring systems are each substituted by R⁴ radicals; and where one or more CH₂ groups in the alkyl, alkoxy, alkenyl and alkynyl groups may be replaced by —R⁴C═CR⁴—, —C≡C—, Si(R⁴)₂, C═O, C═NR⁴, —C(═O)O—, —C(═O)NR⁴—, NR⁴, P(═O)(R⁴), —O—, —S—, SO or SO₂;
R¹ is the same or different at each instance and is selected from H, D, F, Cl, Br, I, C(═O)R⁴, CN, Si(R⁴)₃, N(R⁴)₂, P(═O)(R⁴)₂, OR⁴, S(═O)R⁴, S(═O)₂R⁴, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R¹ radicals may be joined to one another and may form a ring; where the alkyl, alkoxy, alkenyl and alkynyl groups and the aromatic ring systems and heteroaromatic ring systems are each substituted by R⁴ radicals; and where one or more CH₂ groups in the alkyl, alkoxy, alkenyl and alkynyl groups may be replaced by —R⁴C═CR⁴—, —C≡C—, Si(R⁴)₂, C═O, C═NR⁴, —C(═O)O—, —C(═O)NR⁴—, NR⁴, P(═O)(R⁴), —O—, —S—, SO or SO₂;
R² is the same or different at each instance and is selected from H, D, F, Cl, Br, I, C(═O)R⁴, CN, Si(R⁴)₃, N(R⁴)₂, P(═O)(R⁴)₂, OR⁴, S(═O)R⁴, S(═O)₂R⁴, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R² radicals may be joined to one another and may form a ring; where the alkyl, alkoxy, alkenyl and alkynyl groups and the aromatic ring systems and heteroaromatic ring systems are each substituted by R⁴ radicals; and where one or more CH₂ groups in the alkyl, alkoxy, alkenyl and alkynyl groups may be replaced by —R⁴C═CR⁴—, —C≡C—, Si(R⁴)₂, C═O, C═NR⁴, —C(═O)O—, —C(═O)NR⁴—, NR⁴, P(═O)(R⁴), —O—, —S—, SO or SO₂;
R³ is the same or different at each instance and is selected from H, D, F, Cl, Br, I, C(═O)R⁴, CN, Si(R⁴)₃, N(R⁴)₂, P(═O)(R⁴)₂, OR⁴, S(═O)R⁴, S(═O)₂R⁴, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R³ radicals may be joined to one another and may form a ring; where the alkyl, alkoxy, alkenyl and alkynyl groups and the aromatic ring systems and heteroaromatic ring systems are each substituted by R⁴ radicals; and where one or more CH₂ groups in the alkyl, alkoxy, alkenyl and alkynyl groups may be replaced by —R⁴C═CR⁴—, —C≡C—, Si(R⁴)₂, C═O, C═NR⁴, —C(═O)O—, —C(═O)NR⁴—, NR⁴, P(═O)(R⁴), —O—, —S—, SO or SO₂;
R⁴ is the same or different at each instance and is selected from H, D, F, Cl, Br, I, C(═O)R⁵, CN, Si(R⁵)₃, N(R⁵)₂, P(═O)(R⁵)₂, OR⁵, S(═O)R⁵, S(═O)₂R⁵, straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R⁴ radicals may be joined to one another and may form a ring; where the alkyl, alkoxy, alkenyl and alkynyl groups and the aromatic ring systems and heteroaromatic ring systems are each substituted by R⁵ radicals; and where one or more CH₂ groups in the alkyl, alkoxy, alkenyl and alkynyl groups may be replaced by —R⁵C═CR⁵—, —C≡C—, Si(R⁵)₂, C═O, C═NR⁵, —C(═O)O—, —C(═O)NR^{S}—, NRS, P(═O)(R⁵), —O—, —S—, SO or SO₂;
R⁵ is the same or different at each instance and is selected from H, D, F, Cl, Br, I, CN, alkyl or alkoxy groups having 1 to 20 carbon atoms, alkenyl or alkynyl groups having 2 to 20 carbon atoms, aromatic ring systems having 6 to 40 aromatic ring atoms and heteroaromatic ring systems having 5 to 40 aromatic ring atoms; where two or more R⁵ radicals may be joined to one another and may form a ring; and where the alkyl, alkoxy, alkenyl and alkynyl groups, aromatic ring systems and heteroaromatic ring systems may be substituted by one or more radicals selected from F and CN;
x is 1 or 2; where the sum total of x and y is not more than 3;
y is 1 or 2; where the sum total of x and y is not more than 3;
n is 0 or 1, where, when n=0, the E group is absent, and the two Ar¹ groups are not bonded to one another;
m is 0 or 1, where, when m=0, the two groups that bind to Ar^{L} are bonded directly to one another.

20. The compound as claimed in claim 19, wherein
a) in formula (I), the Ar¹, Ar¹ and G groups that bind to the nitrogen atom are each partly deuterated or fully deuterated, on their aromatic or heteroaromatic rings, or
b) in formula (I), only the G group is partly deuterated or fully deuterated, on its aromatic or heteroaromatic rings, and the Ar¹ groups are undeuterated.

21. The compound as claimed in claim 19, wherein all the aliphatic groups present in the compound are undeuterated.

22. The compound as claimed in claim 19, wherein the compound conforms to one of the following formulae: 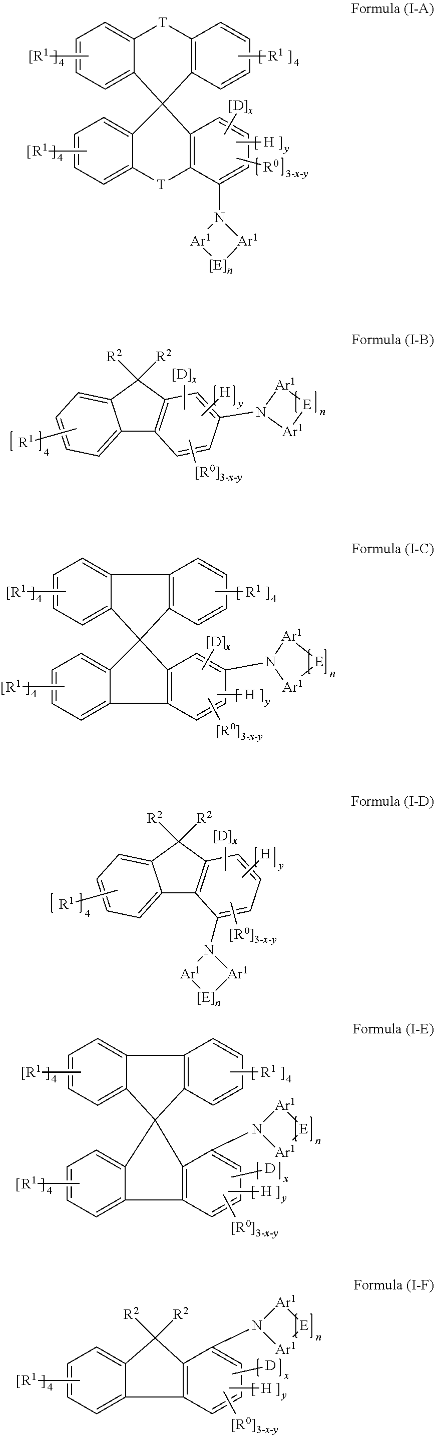 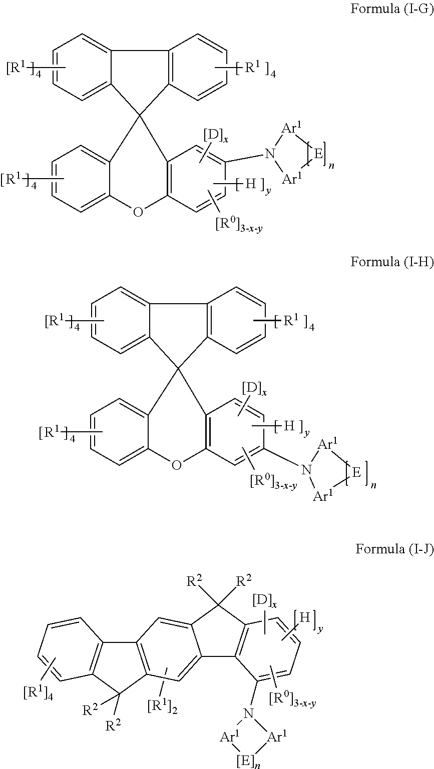
where the variables that occur are as defined in claim 19.

23. The compound as claimed in claim 19, wherein the compound conforms to one of the following formulae: 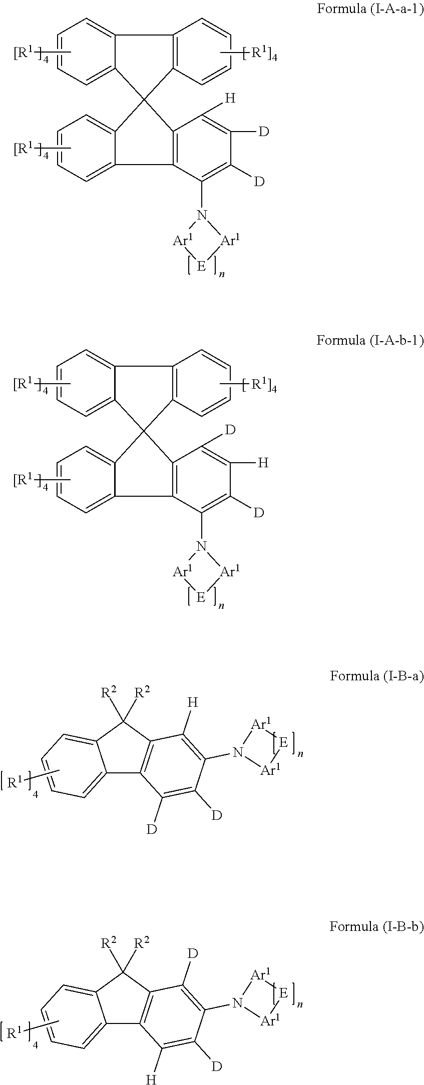 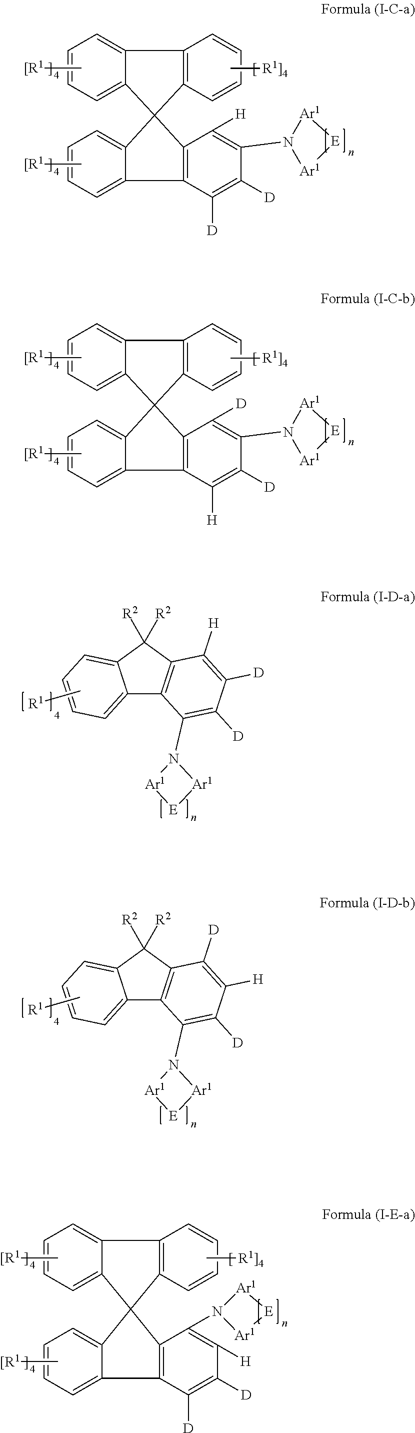 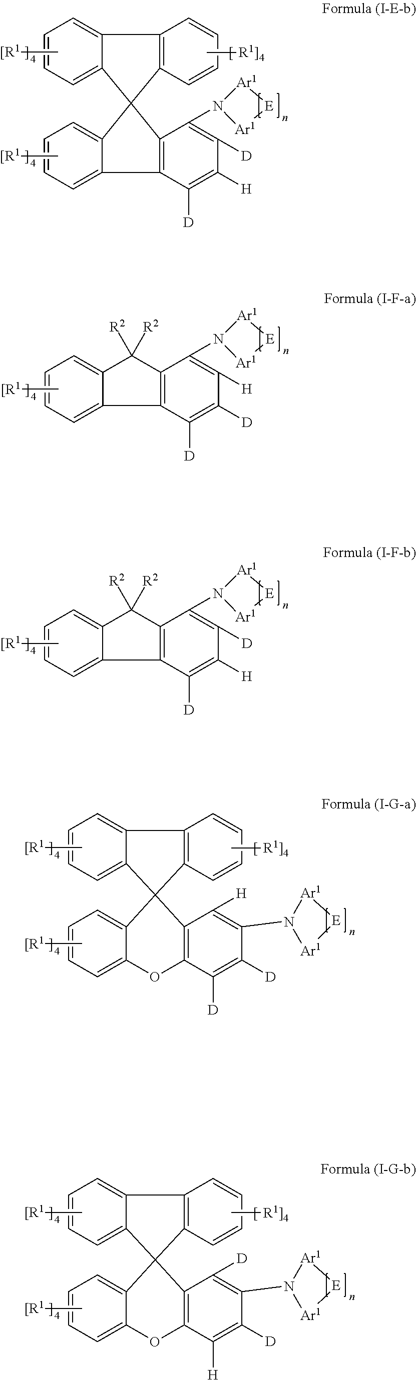 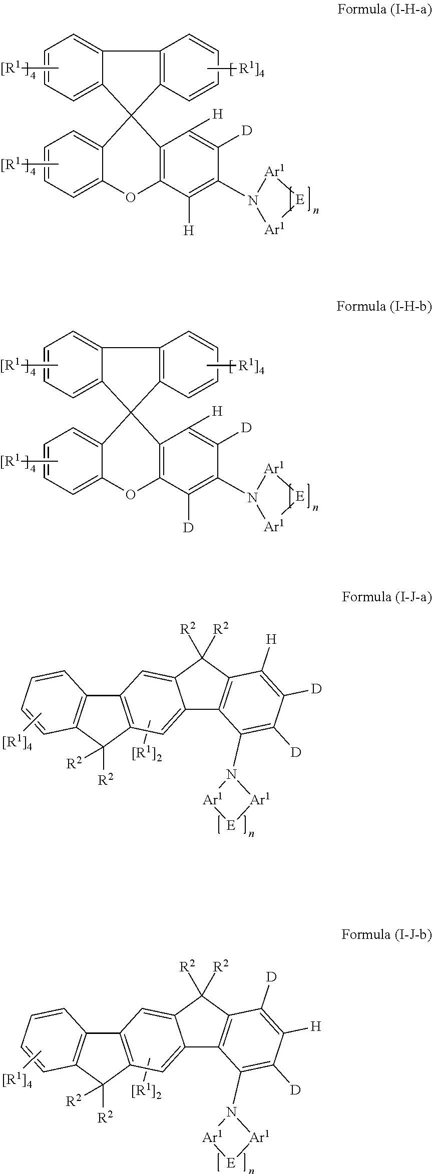
where the variables that occur are as defined in claim 19.

24. The compound as claimed in claim 19, wherein, in the compound of the formula (I), exactly one Ar¹ or G group is selected from 1-spirobifluorenyl groups, 4-spirobifluorenyl groups, 1-fluorenyl groups and 4-fluorenyl groups, and exactly one further Ar¹ or G group is selected from 2-spirobifluorenyl groups and 2-fluorenyl groups, and the remaining third Ar¹ or G group is selected from 1-spirobifluorenyl groups, 4-spirobifluorenyl groups, 1-fluorenyl groups, 4-fluorenyl groups, 2-spirobifluorenyl groups, 2-fluorenyl groups, and other aromatic or heteroaromatic ring systems having 5 or 6 to 40 aromatic ring atoms.

25. The compound as claimed in claim 19, wherein the compound contains a spiroxanthene group as G and/or Ar¹ group.

26. The compound as claimed in claim 19, wherein at least one Ar¹ group therein conforms to one of the following formulae: 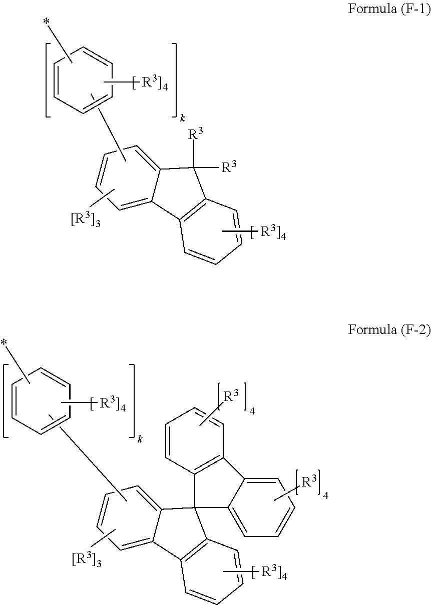
where k is 0, 1, 2 or 3, and R³ is the same or different at each instance and is selected from H and D, and the position of attachment to the rest of the formula is labeled *, and the other variables are as defined in claim 19.

27. A compound as claimed in claim 26, wherein at least one Ar¹ group therein conforms to one of the following formulae: 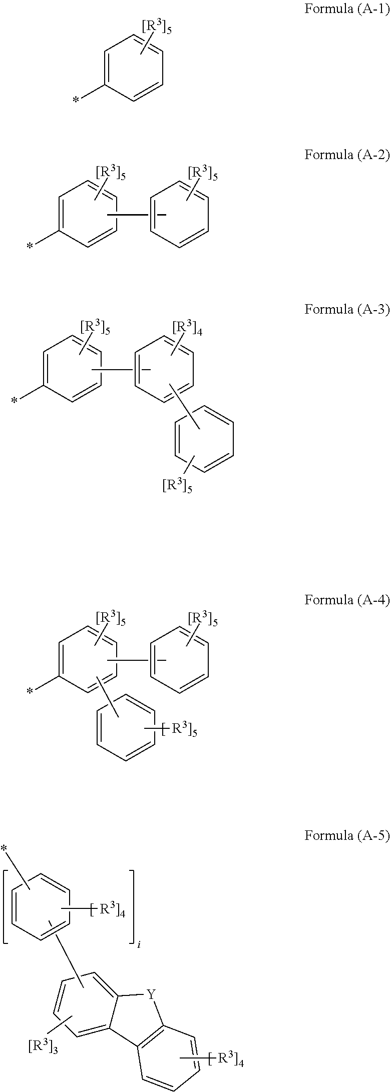
where Y is O or S, and i is 0, 1, 2 or 3, and R³ is the same or different at each instance and is selected from H and D, and the position of attachment to the rest of the formula is labeled *.

28. The compound as claimed in claim 19, wherein n is 0.

29. The compound as claimed in claim 19, wherein the sum total of x and y is 3.

30. A mixture comprising two or more compounds as claimed in claim 19 wherein the compounds are H/D isotopomers or H/D isotopologs of one another and are covered by formula (I).

31. The mixture as claimed in claim 30, wherein the ratio of hydrogen atoms to deuterium atoms averaged over all isotopomeric and isotopologous compounds in the mixture is between 1:10 and 10:1.

32. A process for preparing a compound as claimed in claim 19, wherein an H/D isotopolog of the compound in which the number of deuterium atoms is smaller by an integer d than in the compound, and the number of hydrogen atoms is greater by the integer d than in the compound,
a) is converted with a transition metal catalyst and using a deuterated solvent to one or more different compounds, or
b) is converted under the action of acid and using a deuterated solvent to one or more different compounds.

33. A formulation comprising a compound as claimed in claim 19 and at least one solvent.

34. A method comprising incorporating the compound as claimed in claim 19 in an electronic device.

35. An electronic device comprising the compound as claimed in claim 19.

36. The electronic device as claimed in claim 35, wherein the device is an organic electroluminescent device comprising an anode, a cathode, an emitting layer, and an electron blocker layer, where the electron blocker layer contains the compound.
